(19) United States
(12) Patent Application Publication
(10) Pub. No.: US 2023/0219981 A1
(43) Pub. Date: Jul. 13, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: Hirokazu KUWABARA, Yokohama (JP); Ryuhei FURUE, Yokohama (JP); Yuma AOKI, Yokohama (JP); Yuuki MIYAZAKI, Yokohama (JP)

(73) Assignee: Samsung Display Co., Ltd., Yongin-si (KR)

(21) Appl. No.: 18/074,777

(22) Filed: Dec. 5, 2022

(30) Foreign Application Priority Data
Jan. 7, 2022 (KR) 10-2022-0002464

(51) Int. Cl. C07F 5/02; H10K 85/30; H10K 85/60; H10K 50/11

(52) U.S. Cl. CPC C07F 5/027; H01L 51/008; H01L 51/0072; H01L 51/0054; H01L 51/0073; H01L 51/0061; H01L 51/5012; C07B 2200/05

(57) ABSTRACT

Embodiments provide a polycyclic compound and a light emitting element that includes the polycyclic compound. The light emitting element includes a first electrode, a second electrode disposed on the first electrode, and at least one functional layer disposed between the first electrode and the second electrode, wherein the at least one functional layer includes the polycyclic compound, which is represented by Formula 1. Formula 1 is defined in the specification. The light emitting element exhibits a long service life.

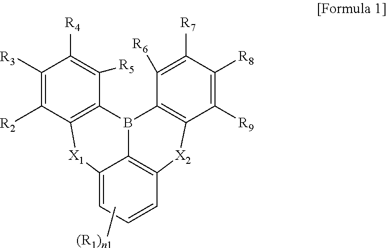

### CROSS-REFERENCE TO RELATED APPLICATION(S)

This application claims priority to and benefits of Korean Patent Application No. 10-2022-0002464 under 35 U.S.C. § 119, filed on Jan. 7, 2022 in the Korean Intellectual Property Office, the entire contents of which are incorporated herein by reference.

### BACKGROUND

### 1. Technical Field

The disclosure relates to a polycyclic compound and a light emitting element including the same.

### 2. Description of the Related Art

Active development continues for an organic electroluminescence display device as an image display device. The organic electroluminescence display device includes a so-called self-luminescent light emitting element in which holes and electrons respectively injected from a first electrode and a second electrode recombine in an emission layer, so that a luminescent material in the emission layer emits light to achieve display.

In the application of a light emitting element to a display device, there is a demand for a light emitting element having a low driving voltage, high luminous efficiency, and a long service life, and continuous development is required on materials for a light emitting element which is capable of stably attaining such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element exhibiting a long service life.

The disclosure also provides a polycyclic compound which is a material for a light emitting element having a long service life.

An embodiment provides a light emitting element which may include a first electrode, a second electrode disposed on the first electrode, and at least one functional layer disposed between the first electrode and the second electrode. The at least one functional layer may include: a first compound represented by Formula 1; and at least one of a second compound represented by Formula HT-1, a third compound represented by Formula ET-1, or a fourth compound represented by Formula M-b:

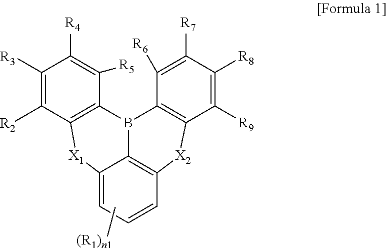

In Formula 1, X₁ and X₂ may each independently be N(R₁₀), O, or S; R₁ to R₁₀ may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; n1 may be an integer from 0 to 3; at least one of R₁ to R₁₀ may each independently be a group represented by Formula 2; when R₃ or R₄ is a substituted or unsubstituted boron group, R₃ and R₄ may be bonded to each other to form a ring; when R₇ or R₈ is a substituted or unsubstituted boron group, R₇ and R₈ may be bonded to each other to form a ring; and when neither of R₃, R₄, R₇, and R₈ is a substituted or unsubstituted boron group, any one of R₃ and R₄ and any one of R₇ and R₈ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms:

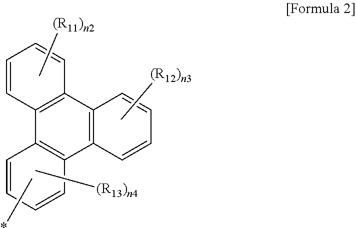

In Formula 2, R₁₁ to R₁₃ may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n2 and n3 may each independently be an integer from 0 to 4; n4 may be an integer from 0 to 3, and [symbol] represents a binding site to Formula 1:

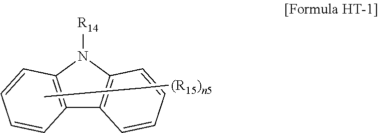

In Formula HT-1, R₁₀ and R₁₅ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms; and n5 may be an integer from 0 to 8:

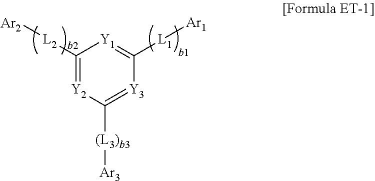

In Formula ET-1, at least one of Y₁ to Y₃ may be N; the remainder of Y₁ to Y₃ may each independently be C(Rₐ); Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b 1 to b3 may each independently be an integer from 0 to 10; Li to L3 may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms:

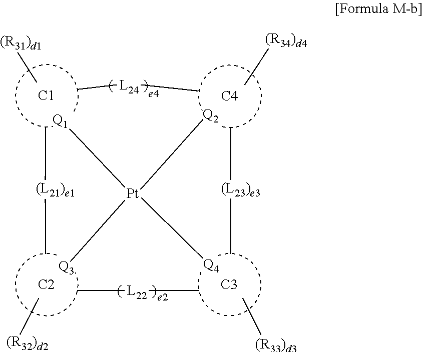

In Formula M-b, Q₁ to Q₄ may each independently be C or N; C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms; e1 to 34 may each independently be 0 or 1; L₂₁ to L₂₄ may each independently be a direct linkage,

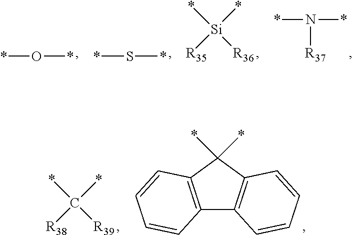

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; d1 to d4 may each independently be an integer from 0 to 4; and R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the at least one functional layer may include an emission layer, a hole transport region disposed between the first electrode and the emission layer, and an electron transport region disposed between the emission layer and the second electrode. The emission layer may include: the first compound; and at least one of the second compound, the third compound, or the fourth compound.

In an embodiment, the first compound represented by Formula 1 may be represented by Formula 1-1 or Formula 1-2:

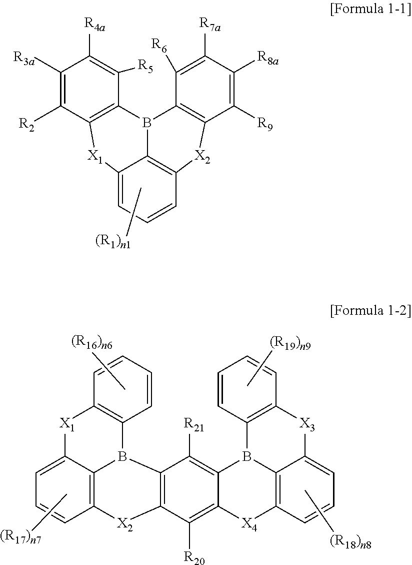

In Formula 1-1, R₃ₐ, R₄ₐ, R₇ₐ, and R₈ₐ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; at least one of R₁, R₂, R₅, R₆, R₉, R₁₀, R₃ₐ, R₄ₐ, R₇ₐ, or R₈ₐ may be a group represented by Formula 2, and any one of R₃ₐ and R₄ₐ and any one of R₇ₐ and R₈ₐ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms. In Formula 1-2, X₃ and X₄ may each independently be N(R₂₂), O, or S; R₁₆ to R₂₂ may each independently be a hydrogen atom, a deuterium atom, a halogen atom, a substituted or unsubstituted amine group, a substituted or unsubstituted boron atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; at least one of R₁₆ to R₂₂ may be a group represented by Formula 2; n6 and n9 may each independently be an integer from 0 to 4; and n7 and n8 may each independently be an integer from 0 to 3. In Formula 1-1 and Formula 1-2, X₁, X₂, R₁, R₂, R₅, R₆, R₉, R₁₀, and n1 are each the same as defined in Formula 1.

In an embodiment, the first compound represented by Formula 1-1 may be represented by Formula 1-1a:

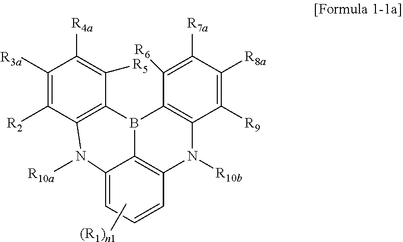

In Formula 1-la, R_{10b} and R_{10b} may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; at least one of R₁, R₂, R₅, R₆, R₉, R₃ₐ, R₄ₐ, R₇ₐ, R₈ₐ, R₁₀ₐ, or R_{10b} may be a group represented by Formula 2; R₃ₐ, R₄ₐ, R₇ₐ, and R₈ are each the same as defined in Formula 1-1; and R₁, R₂, R₅, R₆, R₉, and n1 are each the same as defined in Formula 1.

In an embodiment, the first compound represented by Formula 1-2 may be represented by any one of Formulae 1-2a to 1-2e:

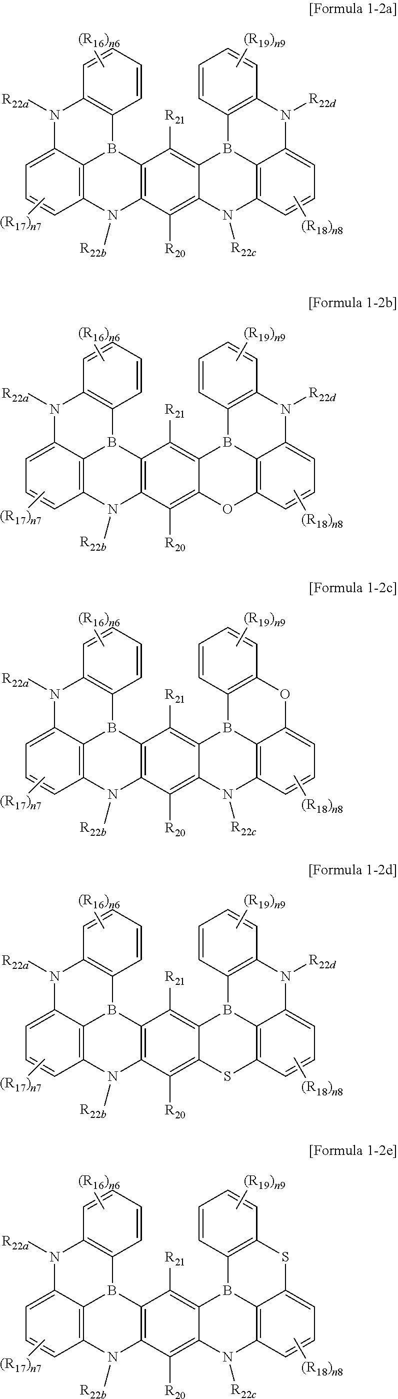

In Formula 1-2a to Formula 1-2e, R₂₂ₐ to R_{22d} may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; at least one of R₁₆ to R₂₁ and R₂₂ₐ to R_{22d} may be a group represented by Formula 2; and R₁₆ to R₂₁ and n6 to n9 are each the same as defined in Formula 1-2.

In an embodiment, the first compound represented by Formula 1 may be represented by Formula 1-3:

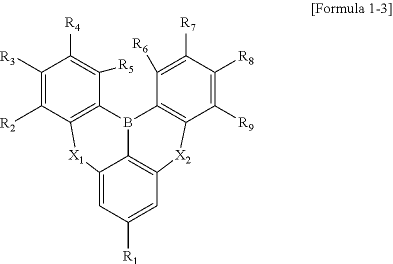

In Formula 1-3, X₁, X₂, and R₁ to R₉ are each the same as defined in Formula 1.

In an embodiment, the group represented by Formula 2 may be represented by Formula 2-1:

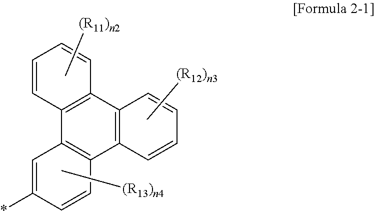

In Formula 2-1, R₁₁, R₁₂, R₁₃, n2 to n4, and [symbol] are each the same as defined in Formula 2.

In an embodiment, R₁ may be a hydrogen atom, a substituted or unsubstituted t-butyl group, a substituted or unsubstituted phenyl group, a substituted or unsubstituted diphenylamine group, a substituted or unsubstituted triphenylenyl group, a substituted or unsubstituted carbazole group, a substituted or unsubstituted dibenzofuran group, or a substituted or unsubstituted dibenzothiophene group.

In an embodiment, R₂, R₅, R₆, and R₉ may each independently be a hydrogen atom or a deuterium atom.

In an embodiment, R₃, R₄, R₇, and R₈ may each independently be a hydrogen atom, a deuterium atom, a substituted or unsubstituted boron group, a substituted or unsubstituted phenyl group, a substituted or unsubstituted triphenylenyl group, a substituted or unsubstituted carbazole group, or a substituted or unsubstituted diphenylamine group.

In an embodiment, R₁₀ may be a substituted or unsubstituted phenyl group, a substituted or unsubstituted biphenyl group, a substituted or unsubstituted terphenyl group, or a substituted or unsubstituted triphenylenyl group.

In an embodiment, R₁₁, R₁₂, and R₁₃ may each be a hydrogen atom.

In an embodiment, the at least one functional layer may include the first compound, the second compound, and the third compound.

In an embodiment, the at least one functional layer may include the first compound, the second compound, the third compound, and the fourth compound.

In an embodiment, the first compound may be selected from Compound Group 1, which is explained below.

In an embodiment, a light emitting element may include a first electrode, a second electrode disposed on the first electrode, and an emission layer disposed between the first electrode and the second electrode and including a polycyclic compound represented by Formula 1:

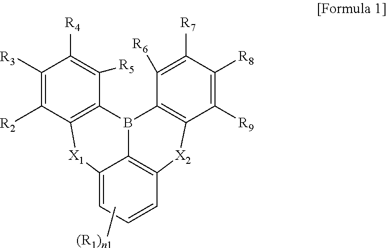

In Formula 1, X₁ and X₂ may each independently be N(R₁₀), O, or S; R₁ to R₁₀ may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; n1 may be an integer from 0 to 3; at least one of R₁ to R₁₀ may be a group represented by Formula 2; when R₃ or R₄ is a substituted or unsubstituted boron group, R₃ and R₄ may be bonded to each other to form a ring; when R₇ or R₈ is a substituted or unsubstituted boron group, R₇ and R₈ may be bonded to each other to form a ring; and when neither of R₃, R₄, R₇, and R₈ is a substituted or unsubstituted boron group, any one of R₃ and R₄ and any one of R₇ and R₈ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms:

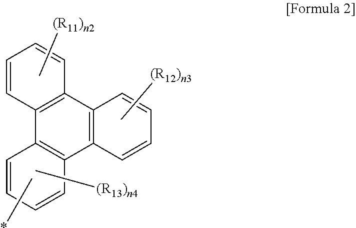

In Formula 2, R₁₁ to R₁₃ may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n2 and n3 may each independently be an integer from 0 to 4; n4 may be an integer from 0 to 3; and [symbol] represents a binding site to Formula 1.

In an embodiment, the polycyclic compound represented by Formula 1 may be represented by Formula 1-1 or Formula 1-2, which are explained below.

In an embodiment, the group represented by Formula 2 may be represented by Formula 2-1, which is explained below.

In an embodiment, a polycyclic compound may be represented by Formula 1:

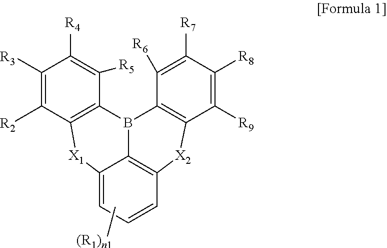

In Formula 1, X₁ and X₂ may each independently be N(R₁₀), O, or S; R₁ to R₁₀ may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring, or may be a group represented by Formula 2; n1 may be an integer from 0 to 3; at least one of R₁ to R₁₀ may be a group represented by Formula 2; when R₃ or R₄ is a substituted or unsubstituted boron group, R₃ and R₄ may be bonded to each other to form a ring; when R₇ or R₈ is a substituted or unsubstituted boron group, R₇ and R₈ may be bonded to each other to form a ring; and when neither of R₃, R₄, R₇, and R₈ is a substituted or unsubstituted boron group, any one of R₃ and R₄ and any one of R₇ and R₈ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms:

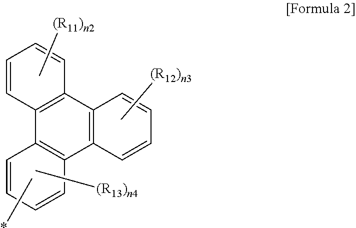

In Formula 2, Ru to Ria may each independently be a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n2 and n3 may each independently be an integer from 0 to 4; n4 may be an integer from 0 to 3; and [symbol] represents a binding site to Formula 1.

In an embodiment, the polycyclic compound represented by Formula 1 may be represented by Formula 1-1 or Formula 1-2, which are explained below.

In an embodiment, the polycyclic compound represented by Formula 1-1 may be represented by Formula 1-1a, which is explained below.

In an embodiment, the polycyclic compound represented by Formula 1-2 may be represented by any one of Formulae 1-2a to 1-2e, which are explained below.

In an embodiment, the polycyclic compound represented by Formula 1 may be represented by Formula 1-3, which is explained below.

In an embodiment, the group represented by Formula 2 may be represented by Formula 2-1, which is explained below.

In an embodiment, the polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view illustrating a display device according to an embodiment;

FIG. 2 is a schematic cross-sectional view of a display device according to an embodiment;

FIG. 3 is a schematic cross-sectional view illustrating a light emitting element according to an embodiment;

FIG. 4 is a schematic cross-sectional view illustrating a light emitting element according to an embodiment;

FIG. 5 is a schematic cross-sectional view illustrating a light emitting element according to an embodiment;

FIG. 6 is a schematic cross-sectional view illustrating a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view illustrating a display device according to an embodiment; and

FIG. 10 is a schematic cross-sectional view illustrating a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may mean a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may mean a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may mean a substituent that is substituted for an atom which is directly linked to an atom substituted with a corresponding substituent, another substituent that is substituted for an atom which is substituted with a corresponding substituent, or a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes one or more carbon-carbon double bonds in the middle of or at a terminus of an alkyl group having two or more carbon atoms. The alkenyl group may be linear or branched. The number of carbon atoms in an alkenyl group is not limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the specification, an alkynyl group may be a hydrocarbon group including at least one carbon-carbon triple bond in the middle or at a terminus of an alkyl group having 2 or more carbon atoms. The alkynyl group may be linear or branched. The number of carbon atoms in an alkynyl group is not limited, but may be 2 to 30, 2 to 20, or 2 to 10. Examples of the alkynyl group may include an ethynyl group, a propynyl group, etc., without limitation.

In the specification a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of such substituted fluorenyl groups may include the following compounds. However, embodiments are not limited thereto.

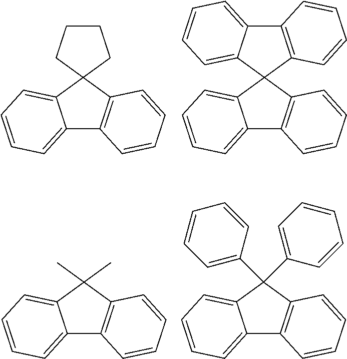

In the specification, a heterocyclic group may be any functional group or substituent derived from a ring including at least one of B, O, N, P, Si, S, or Se as a heteroatom. The heterocyclic group may be an aliphatic heterocyclic group or an aromatic heterocyclic group. An aromatic heterocyclic group may be a heteroaryl group. The aliphatic heterocycle and the aromatic heterocycle may each independently be monocyclic or polycyclic.

If the heterocyclic group includes two or more heteroatoms, the two or more heteroatoms may be the same as or different from each other. In the specification, a heterocyclic group may be monocyclic or polycyclic, and a heterocyclic group may be a heteroaryl group. The number of ring-forming carbon atoms in the heterocyclic group may be 2 to 30, 2 to 20, or 2 to 10.

In the specification, an aliphatic heterocyclic group may include at least one of B, O, N, P, Si, S, or Se as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, or Se as a heteroatom. When the heteroaryl group includes two or more heteroatoms, the two or more heteroatoms may be the same as or different from each other. The heteroaryl group may be monocyclic or polycyclic. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. The above description of the heteroaryl group may be applied to a heteroarylene group, except that the heteroarylene group is a divalent group.

In the specification, a boron group may be an alkyl boron group or an aryl boron group. Examples of the boron group may include a dimethylboron group, a trimethylboron group, a t-butyldimethylboron group, a diphenylboron group, a phenylboron group, etc., but embodiments are not limited thereto. For example, an alkyl group in the alkyl boron group may be the same as an example of the alkyl group described above, and an aryl group in the aryl boron group may be the same as an example of the aryl group described above.

In the specification, a silyl group may be an alkyl silyl group or an aryl silyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, embodiments are not limited thereto.

In the specification, the number of carbon atoms in a carbonyl group is not limited, but may be 1 to 40, 1 to 30, or 1 to 20. For example, a carbonyl group may have one of the following structures, but embodiments are not limited thereto:

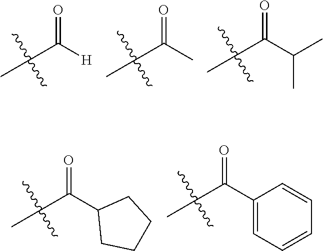

In the specification, the number of carbon atoms in a sulfinyl group or a sulfonyl group is not limited, but may be 1 to 30. The sulfinyl group may be an alkyl sulfinyl group or an aryl sulfinyl group. The sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. The oxy group may be an alkoxy group or an aryl oxy group. The alkoxy group may be linear, branched, or cyclic. The number of carbon atoms in the alkoxy group is not limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, the number of carbon atoms in an amine group is not limited, but may be 1 to 30. The amine group may be an alkyl amine group or an aryl amine group. Examples of the amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group that is included in an alkylthio group, an alkylsulfoxy group, an alkylaryl group, an alkylamino group, an alkyl boron group, an alkyl silyl group, or an alkyl amine group may be the same as an example of the alkyl group as described above.

In the specification, an aryl group that is included in an aryloxy group, an arylthio group, an arylsulfoxy group, an arylamino group, an arylboron group, an arylsilyl group, or an arylamine group may be the same as an example of the aryl group as described above.

In the specification, a direct linkage may be a single bond.

In the specification, the symbols

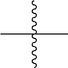

and [symbol] each represents a binding site to a neighboring atom.

Hereinafter, embodiments will be described with reference to the accompanying drawings.

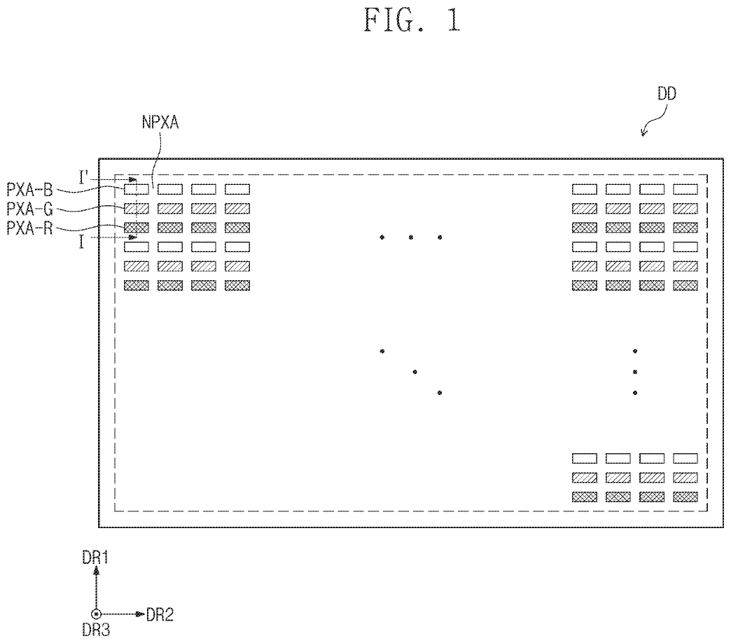

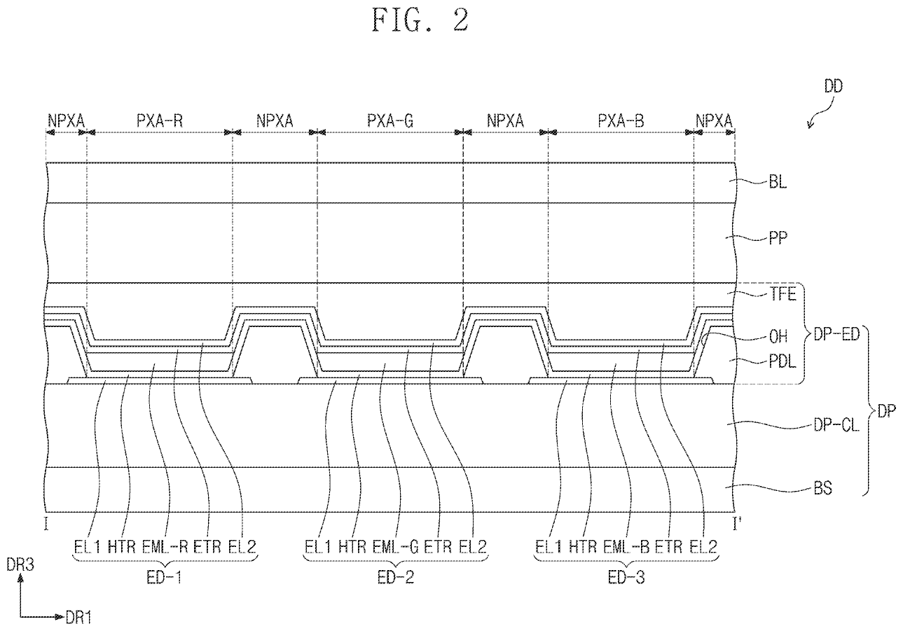

FIG. 1 is a plan view illustrating an embodiment of a display device DD. FIG. 2 is a schematic cross-sectional view of a display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting elements ED-1, ED-2, and ED-3 of the display element layer DP-ED.

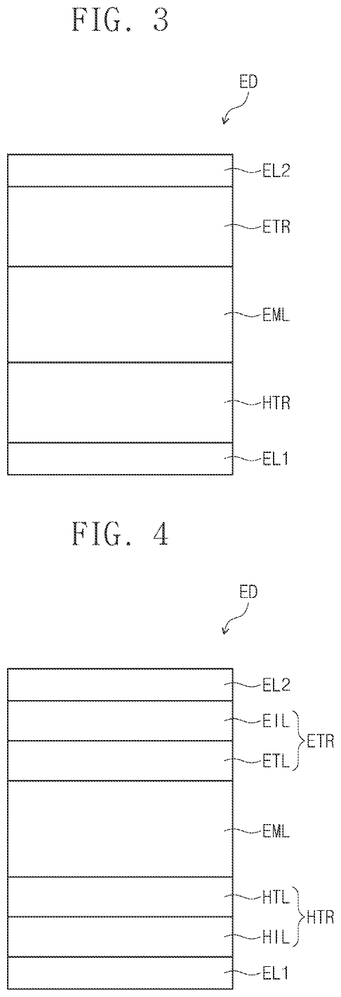

Each of the light emitting elements ED-1, ED-2, and ED-3 may have a structure of a light emitting element ED of an embodiment according to FIGS. 3 to 6, which will be described later. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may be provided by each being patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include a non-light emitting regions NPXA and light emitting regions PXA-R, PXA-G, and PXA-B. The light emitting regions PXA-R, PXA-G, and PXA-B may each be a region in which light generated by the respective light emitting elements ED-1, ED-2, and ED-3 is emitted. The light emitting regions PXA-R, PXA-G, and PXA-B may be spaced apart from each other in a plan view.

Each of the light emitting regions PXA-R, PXA-G, and PXA-B may be a region separated by the pixel defining film PDL. The non-light emitting regions NPXA may be regions between adjacent light emitting regions PXA-R, PXA-G, and PXA-B, and may correspond to portions of the pixel defining film PDL. For example, in an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B which respectively emit red light, green light, and blue light, are illustrated as an example. For example, the display device DD according to an embodiment may include the red light emitting region PXA-R, the green light emitting region PXA-G, and the blue light emitting region PXA-B, which are separated from each other.

In the display device DD according to an embodiment, the light emitting elements ED-1, ED-2, and ED-3 may emit light having wavelengths different from each other. In an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR_{2.} In another embodiment, the red light emitting region PXA-R, the green light emitting region PXA-G, and the blue light emitting region PXA-B may be alternately arranged in this order along a first directional axis DR_{1.}

FIGS. 1 and 2 illustrate that the light emitting regions PXA-R, PXA-G, and PXA-B have a similar area to each other, but embodiments are not limited thereto. The light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first directional axis DR1 and the second directional axis DR2.

The arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display device DD. For example, the light emitting regions PXA-R, PXA-G, and PXA-B may be arranged in a PENTILE® configuration or in a diamond configuration.

In an embodiment, the areas of the light emitting regions PXA-R, PXA-G, and PXA-B may be different from each other. For example, in an embodiment, an area of the green light emitting region PXA-G may be smaller than an area of the blue light emitting region PXA-B, but embodiments are not limited thereto.

In the display device DD according to an embodiment illustrated in FIG. 2, at least one of the first to third light emitting elements ED-1, ED-2, and ED-3 may include a polycyclic compound according to an embodiment which will be described below.

Hereinafter, FIGS. 3 to 6 are each a schematic cross-sectional view illustrating a light emitting element according to an embodiment. The light emitting elements ED according to embodiments may each include a first electrode EL1, a second electrode EL2 facing the first electrode EL1, and at least one functional layer disposed between the first electrode EL1 and the second electrode EL2. The light emitting element ED according to an embodiment may include a polycyclic compound according to an embodiment, which will be described below, in at least one functional layer. The polycyclic compound according to an embodiment may be herein referred to as a first compound.

Each of the light emitting elements ED may include, as the at least one functional layer, a hole transport region HTR, an emission layer EML, and an electron transport region ETR, which are sequentially stacked. Referring to FIG. 3, the light emitting element ED according to an embodiment may include a first electrode EL1, a hole transport region HTR, an emission layer EML, an electron transport region ETR, and a second electrode EL2, which are sequentially stacked. In the light emitting element ED according to an embodiment, the emission layer EML may include the polycyclic compound according to an embodiment, which will be described below.

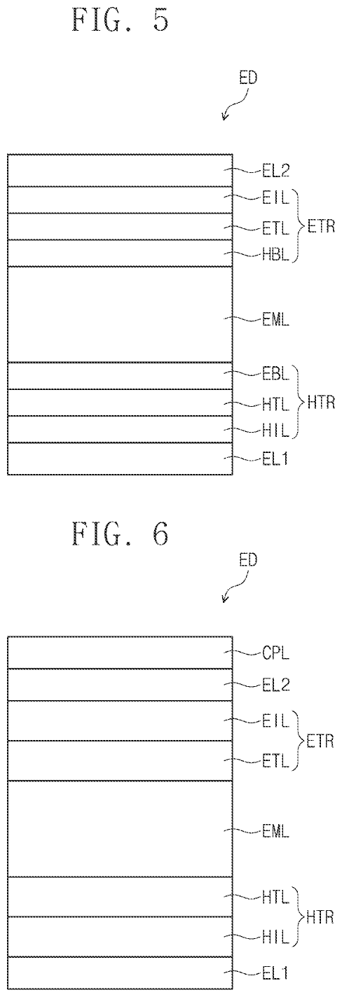

In comparison to FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED according to an embodiment that includes a capping layer CPL disposed on a second electrode EL2.

In an embodiment, the emission layer EML may include a core moiety that includes a boron atom as a ring-forming atom and at least one triphenylenyl group substituted at the core moiety. The emission layer EML may further include at least one of a second compound, a third compound, or a fourth compound. The second compound may include a substituted or unsubstituted carbazole. The third compound may include a hexagonal ring moiety containing at least one nitrogen atom as a ring-forming atom. The fourth compound may be a platinum-containing compound.

In the light emitting element ED according to an embodiment, the first electrode EL1 has conductivity. The first electrode EL1 may include a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/A1 (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. However, embodiments are not limited thereto, and the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, a thickness of the first electrode EL1 may be in a range of about 1,000 Å to about 3,000 Å.

The hole transport region HTR is provided on the first electrode EL1. The hole transport region HTR may be a layer formed of a single material, a layer formed of different materials, or a structure including multiple layers formed of different materials.

The hole transport region HTR may include at least one of a hole injection layer HIL, a hole transport layer HTL, or an electron blocking layer EBL. Although not shown in the drawings, in an embodiment, the hole transport region HTR may include a stack of multiple hole transport layers.

For example, the hole transport region HTR may have a single layer structure of a hole injection layer HIL or a hole transport layer HTL, or the hole transport region HTR may have a single layer structure formed of a hole injection material and a hole transport material. In an embodiment, the hole transport region HTR may be a single layer structure formed of different materials, or may be a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR of the light emitting element ED according to an embodiment may include a compound represented by Formula H-1:

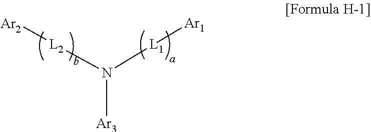

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a orb is 2 or greater, multiple Li groups or multiple L2 groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, a compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any selected from Compound Group H. However, the compounds listed in Compound Group H are presented only as examples, and the compounds represented by Formula H-1 are not limited to Compound Group H:

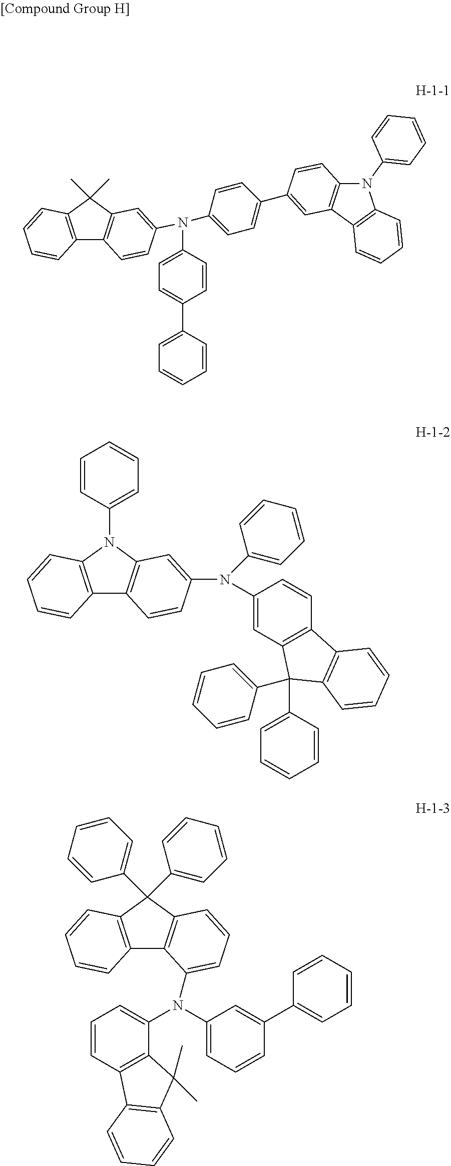 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

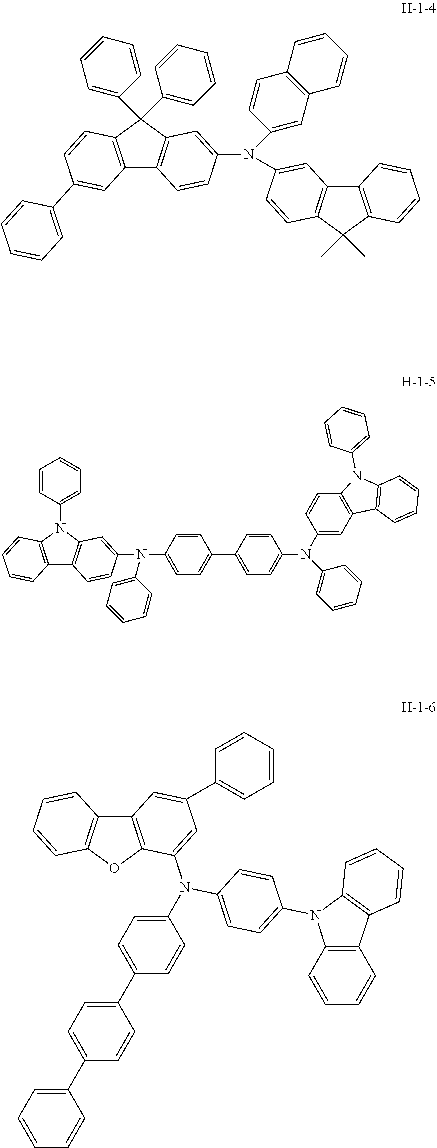 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

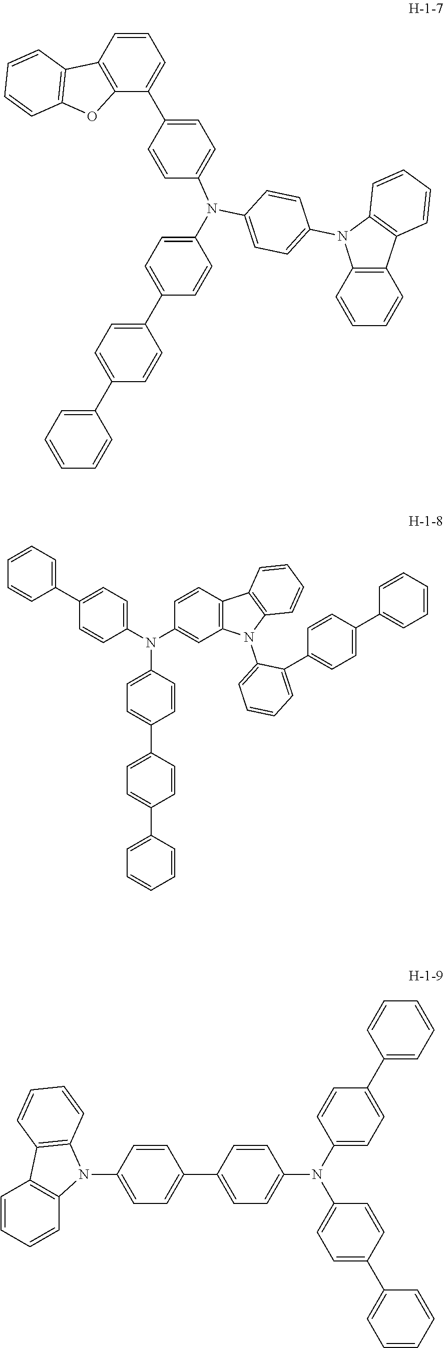 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

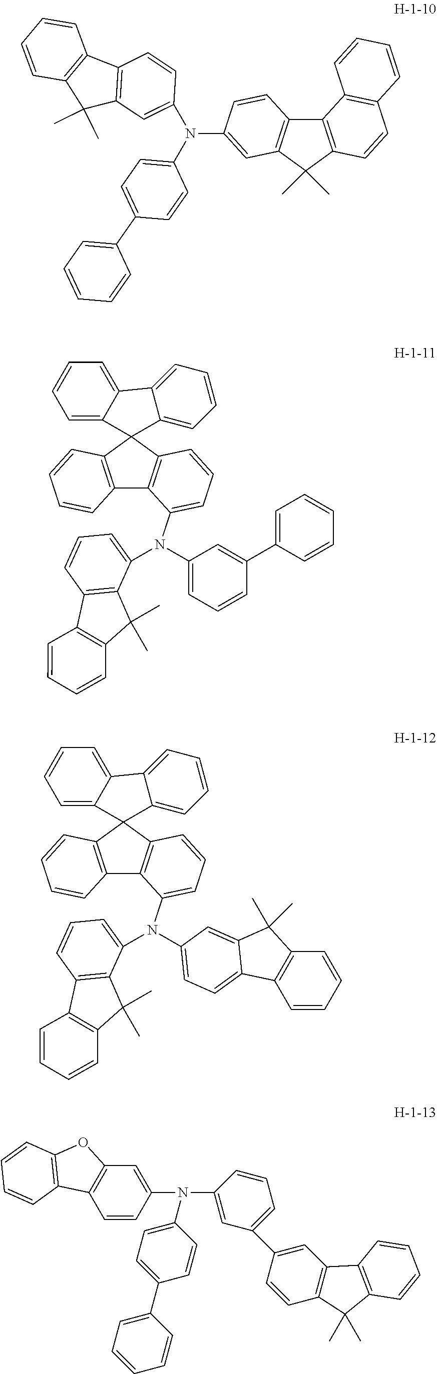 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

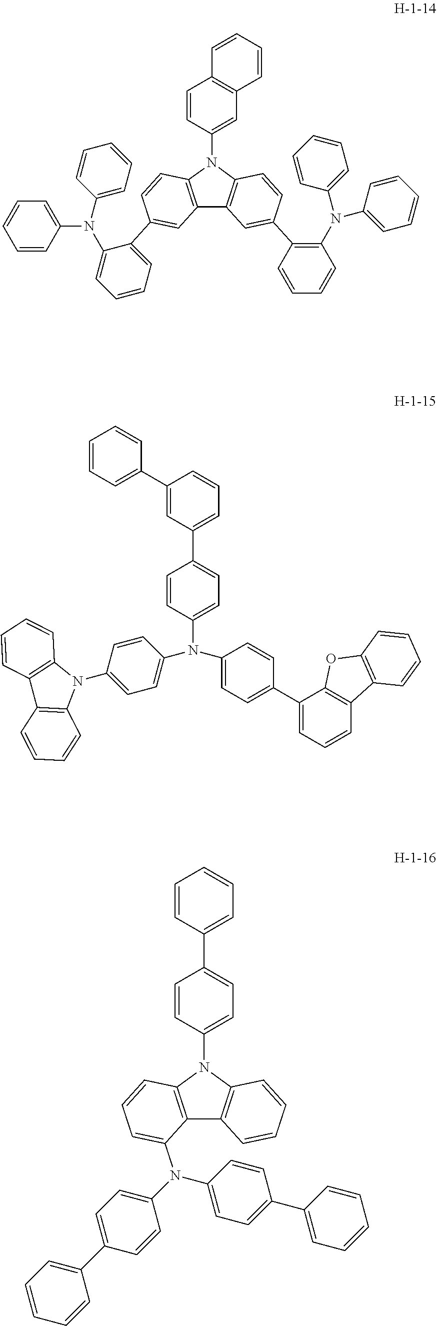 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

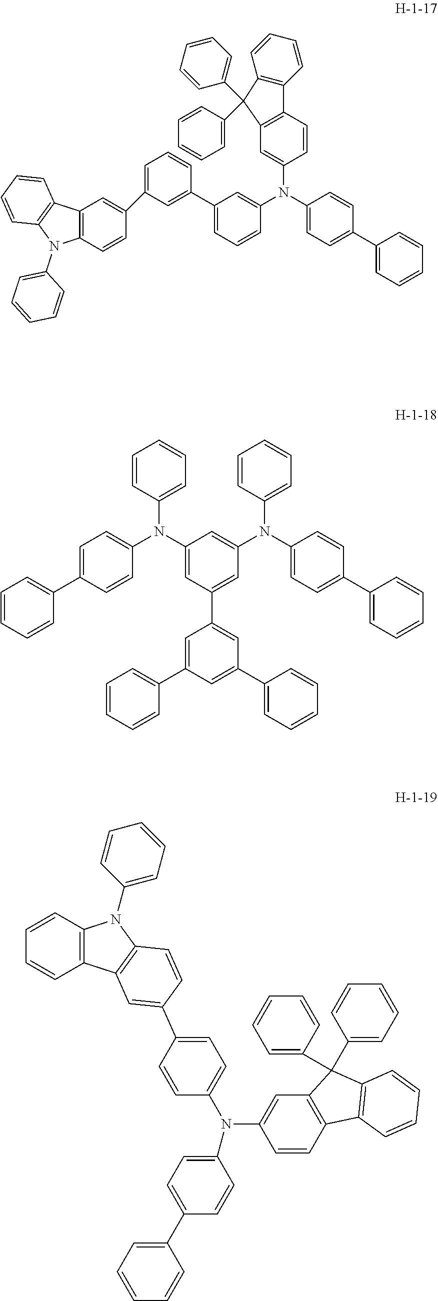 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/C SA), polyaniline/poly(4-styrenesulfonate) (PANI/PSS), N,N′-di(naphthalene-1-yl)-N,N′-diphenyl-benzidine (NPB or NPD of α-NPD), triphenylamine-containing polyetherketone (TPAPEK), 4-isopropyl-4′ -methyldiphenyliodonium[tetrakis(pentafluorophenyl)borate], dipyrazino[2,3-f: 2′,3′-h]quinoxaline-2,3 ,6,7, 10, 11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalene-1-yl)-N,N′-diphenyl -benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7, 8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5, 6-tetrafluorophenyl)methylidene] cyclopropylidene]-cyanom ethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from the emission layer EML, and may thus increase light emission efficiency. A material that may be included in the hole transport region HTR may be used as a material included in the buffer layer (not shown). The electron blocking layer EBL may prevent the injection of electrons from the electron transport region ETR to the hole transport region HTR.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

In an embodiment, the emission layer EML may include a first compound represented by Formula 1. The first compound corresponds to the polycyclic compound according to an embodiment:

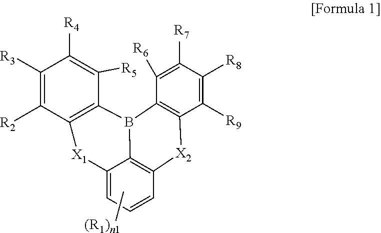

In Formula 1, X₁ and X₂ may each independently be N(R₁₀), O, or S. For example, X₁ and X₂ may each independently be N(R₁₀), or one of X₁ and X₂ may be N(R₁₀), and the other of X₁ and X₂ may be O or S.

In Formula 1, R₁ to R₁₀ may each independently be: a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or may be bonded to an adjacent group to form a ring; or may be a group represented by Formula 2. In Formula 1, at least one of R₁ to R₁₀ may be a group represented by Formula 2. In Formula 1, when R₃ or R₄ is a substituted or unsubstituted boron group, R₃ and R₄ may be bonded to each other to form a ring. In Formula 1, when R₇ or R₈ is a substituted or unsubstituted boron group, R₇ and R₈ may be bonded to each other to form a ring. In Formula 1, when neither or R₃, R₄, R₇, and R₈ is a substituted or unsubstituted boron group, any one of R₃ and R₄ and any one of R₇ and R₈ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms.

In an embodiment, Ri may be a hydrogen atom, a substituted or unsubstituted t-butyl group, a substituted or unsubstituted phenyl group, a substituted or unsubstituted diphenylamine group, a substituted or unsubstituted triphenylenyl group, a substituted or unsubstituted carbazole group, a substituted or unsubstituted dibenzofuran group, or a substituted or unsubstituted dibenzothiophene group.

In an embodiment, R₂, R₅, R₆, and R₉ may each independently be a hydrogen atom or a deuterium atom.

In an embodiment, R₃, R₄, R₇, and R₈ may each independently be a hydrogen atom, a deuterium atom, a substituted or unsubstituted boron group, a substituted or unsubstituted phenyl group, a substituted or unsubstituted triphenylenyl group, a substituted or unsubstituted carbazole group, or a substituted or unsubstituted diphenylamine group. As described above, when R₃ or R₄ is a substituted or unsubstituted boron group, R₃ and R₄ may be bonded to each other to form a ring. For example, when R₃ or R₄ is a substituted or unsubstituted boron group, R₃ and R₄ may be bonded to each other to form fused rings including a boron atom. As described above, when R₇ or R₈ is a substituted or unsubstituted boron group, R₇ and R₈ may be bonded to each other to form a ring. For example, when R₇ or R₈ is a substituted or unsubstituted boron group, R₇ and R₈ may be bonded to each other to form fused rings including a boron atom. However, embodiments are not limited thereto. As described above, when neither of R₃, R₄, R₇, and R₈ is a substituted or unsubstituted boron group, any one of R₃ and R₄ and any one of R₇ and R₈ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms.

In an embodiment, R₁₀ may be a substituted or unsubstituted phenyl group, a substituted or unsubstituted biphenyl group, a substituted or unsubstituted terphenyl group, or a substituted or unsubstituted triphenylenyl group.

For example, each of R₁ to R₁₀ may be bonded to an adjacent group to form a ring.

In an embodiment, R₃ and R₄ may be bonded to each other to form a ring. For example, R₃ and R₄ may be bonded to each other to form a phenanthrene group, and the phenanthrene group may be fused to a benzene ring, to which R₃ and R₄ in Formula 1 are linked, to form triphenylene.

In an embodiment, R₇ and R₈ may be bonded to each other to form a ring. For example, R₇ and R₈ may be bonded to each other to form a phenanthrene group, and the phenanthrene group may be fused to a benzene ring, to which R₇ and R₈ in Formula 1 are linked, to form triphenylene. However, embodiments are not limited thereto.

In Formula 1, n1 may be an integer from 0 to 3. For example, n1 may be 0 or 1. A case where n1 is 0 may be the same as a case where all R₁ groups are hydrogen atoms. It may be understood that when n1 is 0, R₁ is not substituted at the polycyclic compound represented by Formula 1.

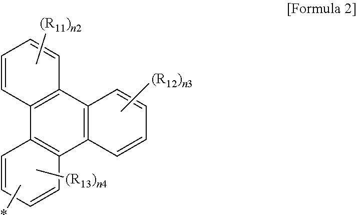

In Formula 2, [symbol] represents a binding site to Formula 1.

In Formula 2, R₁₁ to R₁₃ may each independently be a hydrogen atom, a deuterium atom, a halogen atom, a substituted or unsubstituted amine group, substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, R₁₁, R₁₂, and R₁₃ may each be a hydrogen atom. However, embodiments are not limited thereto.

In Formula 2, n2 and n3 may each independently be an integer from 0 to 4. For example, each of n2 and n3 may be 0. A case where n2 is 0 may be the same as a case where all R₁₁ groups are hydrogen atoms. It may be understood that when n2 is 0, R₁₁ is not substituted at the group represented by Formula 2. A case where n3 is 0 may be the same as a case where all R₁₂ groups are hydrogen atoms. It may be understood that when n3 is 0, R₁₂ is not substituted at the group represented by Formula 2.

In Formula 2, n4 may be an integer from 0 to 3. For example, n4 may be 0. A case where n4 is 0 may be the same as a case where all R₁₃ groups are hydrogen atoms. It may be understood that when n4 is 0, R₁₃ is not substituted at the group represented by Formula 2.

As described above, in Formula 1, at least one of R₁ to R₁₀ may be a group represented by Formula 2. The group represented by Formula 2 may be a substituted or unsubstituted triphenylenyl group.

Thus, the polycyclic compound represented by Formula 1 has a bulky structure by including at least one substituted or unsubstituted triphenylenyl group, and therefore has a greater steric shielding effect which protects the molecular structure of the polycyclic compound, thereby contributing to a long service life by its inclusion in the light emitting element. Conventionally, an ortho-terphenyl group has been used as a substituent to impart a steric shielding effect to the molecule. The triphenylenyl group included in the polycyclic compound according to embodiments has fewer changes in the structure in an excited state as compared with the ortho-terphenyl group, and accordingly, the excitation stability of the molecule may be improved.

The light emitting element according to embodiments may have improved element service life characteristics by including the polycyclic compound represented by Formula 1 as a material for the emission layer EML.

In an embodiment, the polycyclic compound represented by Formula 1 may be represented by Formula 1-1 or Formula 1-2:

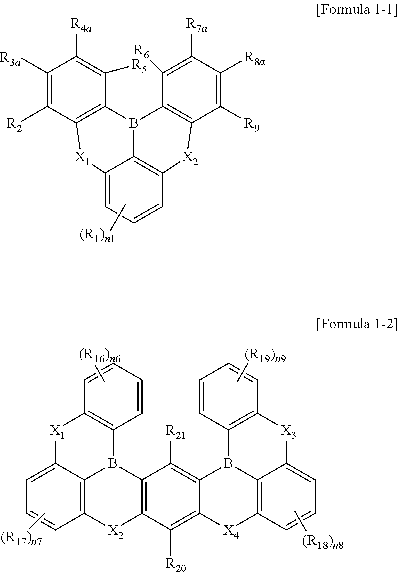

Referring to Formula 1-1 and Formula 1-2, the polycyclic compound according to an embodiment may include, as a core moiety, a pentacyclic fused ring including one boron atom, or a nonacyclic fused ring including two boron atoms.

In Formula 1-1, R₃ₐ, R₄ₐ, R₇ₐ, and R₈ₐ may each independently be: a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or may be bonded to an adjacent group to form a ring; or may be a group represented by Formula 2. In Formula 1-1, at least one of R₁, R₂, R₅, R₆, R₉, R₁₀, R₃ₐ, R₄ₐ, R₇ₐ, or R₈ₐ may be a group represented by Formula 2. In Formula 1-1, any one of R₃ₐ and R₄ₐ and any one of R₇ₐ and R₈ₐ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms.

For example, R₃ₐ, R₄ₐ, R₇ₐ, and R₈ₐ may be each independently a hydrogen atom, a deuterium atom, a substituted or unsubstituted boron group, a substituted or unsubstituted phenyl group, a substituted or unsubstituted triphenylenyl group, a substituted or unsubstituted carbazole group, or a substituted or unsubstituted diphenylamine group.

When the polycyclic compound represented by Formula 1 has a core moiety including one boron atom as represented by Formula 1-1, any one of R₃ₐ and R₄ₐ and any one of R₇ₐ and R₈ₐ may each independently be a substituted or unsubstituted amine group, a substituted or unsubstituted aryl group having 6 to 60 ring-forming carbon atoms, or a substituted or unsubstituted heteroaryl group having 2 to 60 ring-forming carbon atoms, thereby improving service life when it is included in a light emitting element according to an embodiment.

As described above, each of R₃ₐ, R₄ₐ, R₇ₐ, and R₈ₐ may be bonded to an adjacent group to form a ring. In an embodiment, R₃ₐ and R₄ₐ may be bonded to each other to form a ring. For example, R₃ₐ and R₄ₐ may be bonded to each other to form a phenanthrene group fused to a benzene ring to which R₃ₐ and R₄ₐ are linked. Thus, the polycyclic compound represented by Formula 1 may include a triphenylene moiety. In an embodiment, R₇ₐ and R₈ₐ may be bonded to each other to form a ring. For example, R₇ₐ and R₈ₐ may be bonded to each other to form a phenanthrene group fused to a benzene ring to which R₇ₐ and R₈ₐ are linked. Thus, the polycyclic compound represented by Formula 1 may include a triphenylene moiety. However, embodiments are not limited thereto.

In Formula 1-2, X₃ and X₄ may each independently be N(R₂₂), O, or S. For example, X₃ and X₄ may each independently be N(R₂₂), or one of X₃ and X₄ may be N(R₂₂), and the other of X₃ and X₄ may be O or S.

In Formula 1-2, R₁₆ to R₂₂ may each independently be: a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or may be bonded to an adjacent group to form a ring; or may be a group represented by Formula 2. In Formula 1-2, at least one of R₁₆ to R₂₂ may be a group represented by Formula 2.

For example, R₁₆ to R₂₁ may each independently be a hydrogen atom, a deuterium atom, a substituted or unsubstituted t-butyl group, or a substituted or unsubstituted phenyl group. For example, R₂₂ may be a substituted or unsubstituted phenyl group, a substituted or unsubstituted biphenyl group, a substituted or unsubstituted terphenyl group, or a substituted or unsubstituted triphenylenyl group.

In Formula 1-2, n6 and n9 may each independently be an integer from 0 to 4, and n7 and n8 may each independently be an integer from 0 to 3. For example, n6 and n9 may each be 0. For example, n7 and n8 may each independently be 0 or 1. A case where n6 to n9 are each 0 may be the same as a case where all R₁₆ groups, all R₁₇ groups, all R₁₈ groups, and all R₁₉ groups are hydrogen atoms. It may be understood that when n6 to n9 are each O, R₁₆, R₁₇, R₁₈, and R₁₉ may not be substituted at the polycyclic compound represented by Formula 1-2.

In Formula 1-1 and Formula 1-2, X₁, X₂, R₁, R₂, R₅, R₆, R₉, R₁₀, and n1 are each the same as defined in Formula 1.

In an embodiment, the polycyclic compound represented by Formula 1-1 may be represented by Formula 1-1a:

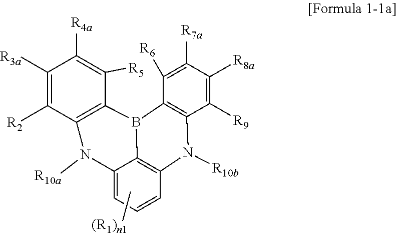

Formula 1-1a represents a case where in Formula 1-1, X₁ and X₂ are NR₁₀ₐ and NR_{10b}, respectively. Thus, a polycyclic compound according to an embodiment may include nitrogen atoms and a boron atom.

In Formula 1-1a, R₁₀ₐ and R_{10b} may each independently be: a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or may be bonded to an adjacent group to form a ring; or may be a group represented by Formula 2. In Formula 1-1a, at least one of R₁, R₂, R₅, R₆, R₉, R₃ₐ, R₄ₐ, R₇ₐ, R₈ₐ, R₁₀ₐ, or R_{10b} may be a group represented by Formula 2.

For example, R₁₀ₐ and R_{10b} may each independently be a substituted or unsubstituted phenyl group, a substituted or unsubstituted biphenyl group, or a substituted or unsubstituted triphenylenyl group.

In Formula 1-1a, R₃ₐ, R₄ₐ, R₇ₐ, and R₈ are each the same as defined in Formula 1-1, and R₁, R₂, R₅, R₆, R₉, and n1 are each the same as defined in Formula 1.

In an embodiment, the polycyclic compound represented by Formula 1-2 may be represented by any one of Formulae 1-2a to 1-2e:

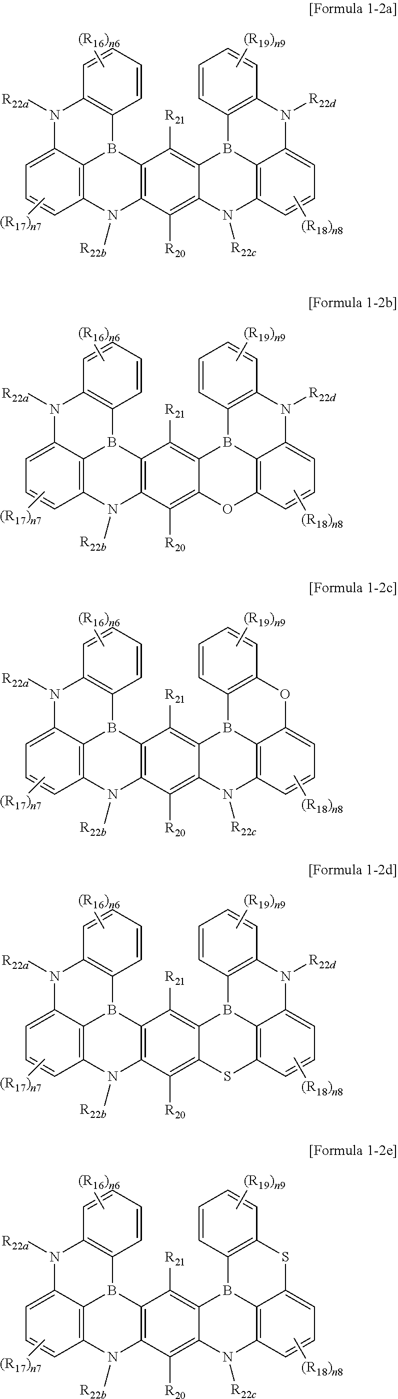

Formula 1-2a to Formula 1-2e each represent a case in which X₁ to X₄ are specified in Formula 1-2. Thus, the polycyclic compound according to an embodiment may include nitrogen atoms and boron atoms, and may further include an oxygen atom or a sulfur atom.

In Formulae 1-2a to 1-2e, R₂₂ₐ to R_{22d} may each independently be: a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or may be bonded to an adjacent group to form a ring; or may be a group represented by Formula 2. In Formulae 1-2a to 1-2e, at least one of R₁₆ to R₂₁ and R₂₂ₐ to R_{22d} may be a group represented by Formula 2.

For example, R₂₂ₐ to R_{22d} may each independently be a substituted or unsubstituted phenyl group, a substituted or unsubstituted biphenyl group, a substituted or unsubstituted terphenyl group, or a substituted or unsubstituted triphenylenyl group.

In Formulae 1-2a to 1-2e, R₁₆ to R₂₁ and n6 to n9 are each the same as defined in Formula 1-2.

In an embodiment, the polycyclic compound represented by Formula 1 may be represented by Formula 1-3:

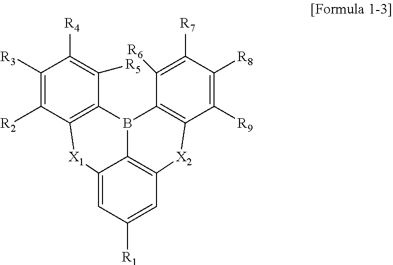

Formula 1-3 represents a case where n1=1 and the bonding position of R₁ in Formula 1 is specified. In the polycyclic compound according to an embodiment, when R₁ is not a hydrogen atom, R₁ may be a substituent at a para-position to the boron atom.

In Formula 1-3, X₁, X₂, and R₁ to R₉ are each the same as defined in Formula 1.

In an embodiment, the group represented by Formula 2 may be represented by Formula 2-1:

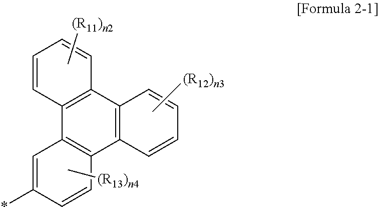

Formula 2-1 represents a case where a bonding position between Formula 1 and Formula 2 is specified.

In Formula 2-1, [symbol] represents a binding site to Formula 1.

In Formula 2-1, R₁₁, R₁₂, R₁₃, and n2 to n4 are each the same as defined in Formula 2.

The polycyclic compound according to an embodiment may include at least one deuterium atom as a substituent. In an embodiment, at least one of R₁ to R₁₀ in Formula 1 may be a deuterium atom, or may be a substituent including a deuterium atom.

The polycyclic compound according to an embodiment may be any compound selected from Compound Group 1. The light emitting element ED according to an embodiment may include any compound selected from Compound Group 1. In Compound Group 1, D is a deuterium atom.

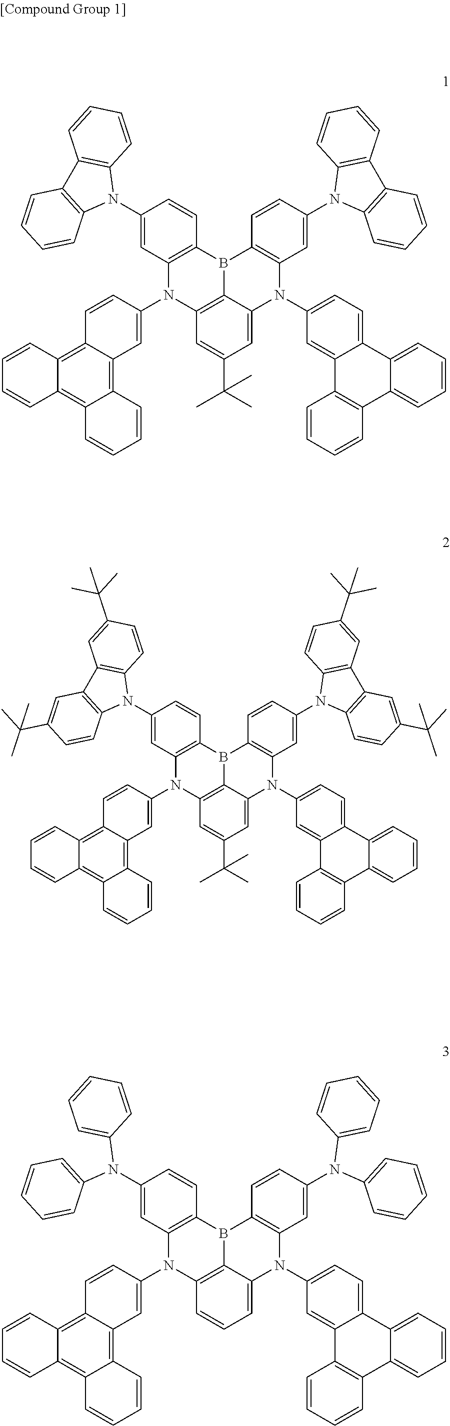 [SMILES: CC(C)(C)c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1ccc2c3ccccc3c3ccccc3c2c1 ; c1ccc(N(c2ccccc2)c2ccc3c(c2)N(c2ccc4c5ccccc5c5ccccc5c4c2)c2cccc4c2B3c2ccc(N(c3ccccc3)c3ccccc3)cc2N4c2ccc3c4ccccc4c4ccccc4c3c2)cc1]

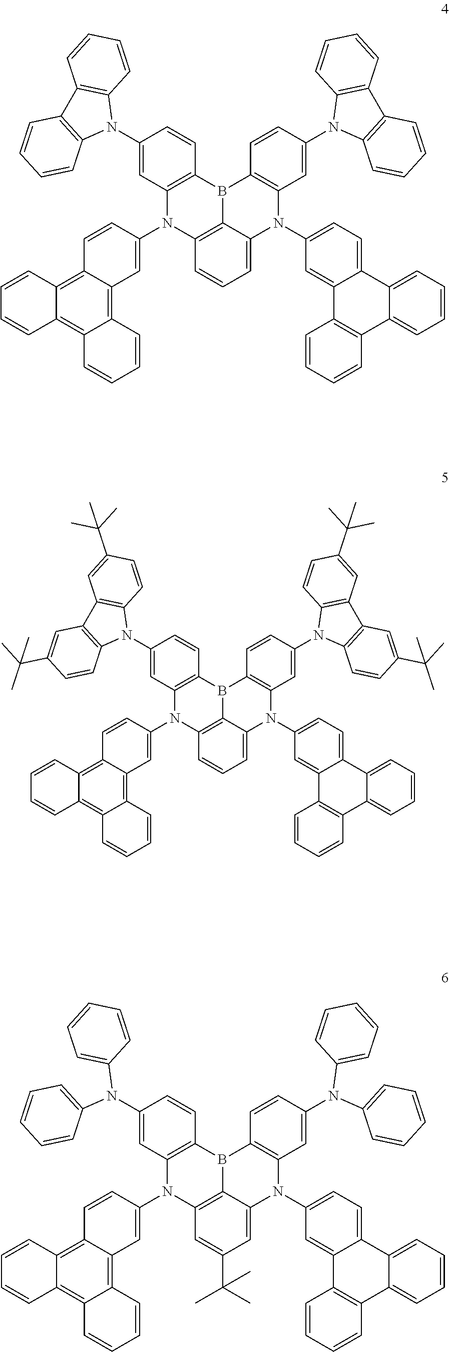 [SMILES: c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1ccc(-n2c4ccc(C(C)(C)C)cc4c4cc(C(C)(C)C)ccc42)cc1N3c1ccc2c3ccccc3c3ccccc3c2c1 ; CC(C)(C)c1cc2c3c(c1)N(c1ccc4c5ccccc5c5ccccc5c4c1)c1cc(N(c4ccccc4)c4ccccc4)ccc1B3c1ccc(N(c3ccccc3)c3ccccc3)cc1N2c1ccc2c3ccccc3c3ccccc3c2c1]

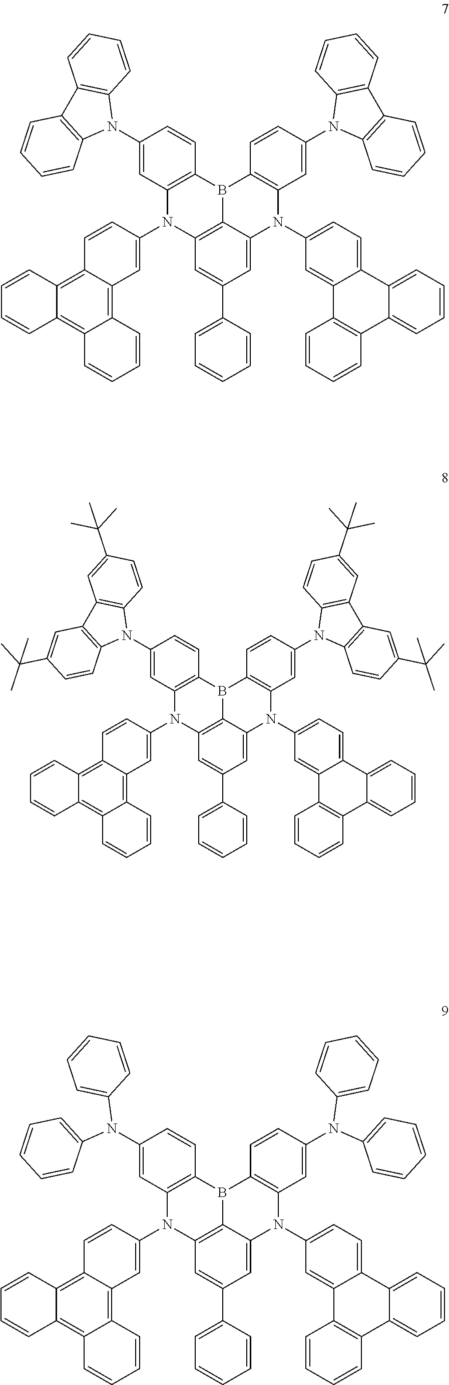 [SMILES: c1ccc(-c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1ccc(-n2c4ccc(C(C)(C)C)cc4c4cc(C(C)(C)C)ccc42)cc1N3c1ccc2c3ccccc3c3ccccc3c2c1 ; c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1]

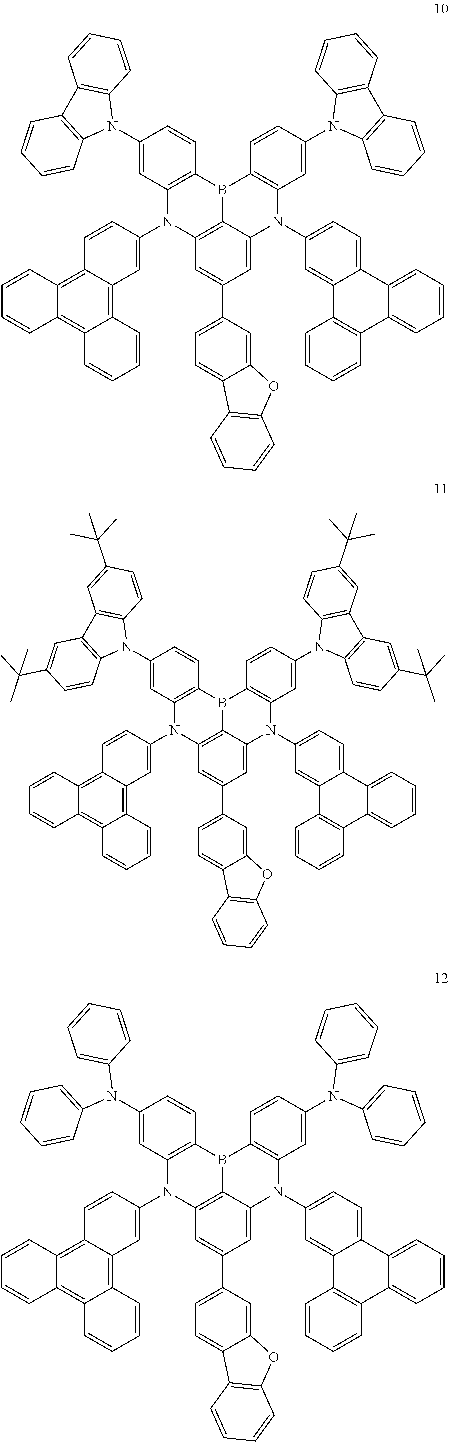

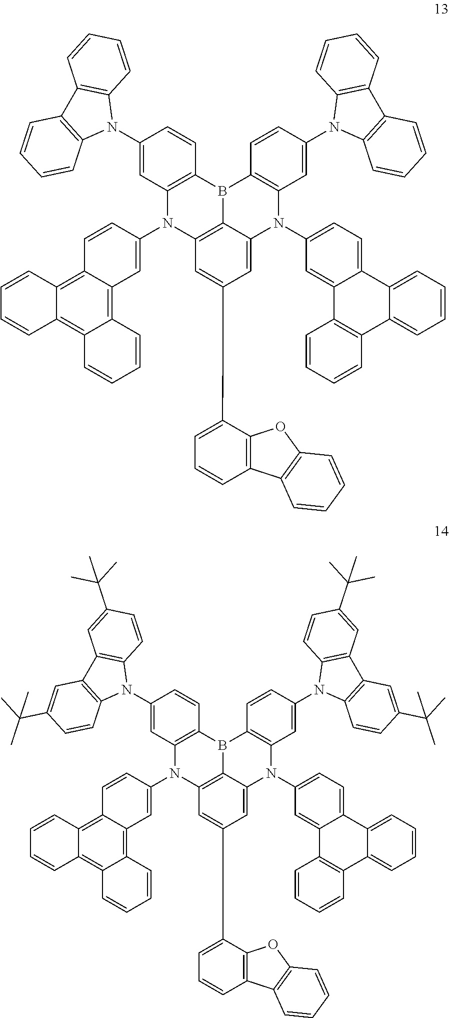 [SMILES: c1ccc2c(c1)oc1c(-c3cc4c5c(c3)N(c3ccc6c7ccccc7c7ccccc7c6c3)c3cc(-n6c7ccccc7c7ccccc76)ccc3B5c3ccc(-n5c6ccccc6c6ccccc65)cc3N4c3ccc4c5ccccc5c5ccccc5c4c3)cccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3cccc4c3oc3ccccc34)cc3c1B2c1ccc(-n2c4ccc(C(C)(C)C)cc4c4cc(C(C)(C)C)ccc42)cc1N3c1ccc2c3ccccc3c3ccccc3c2c1]

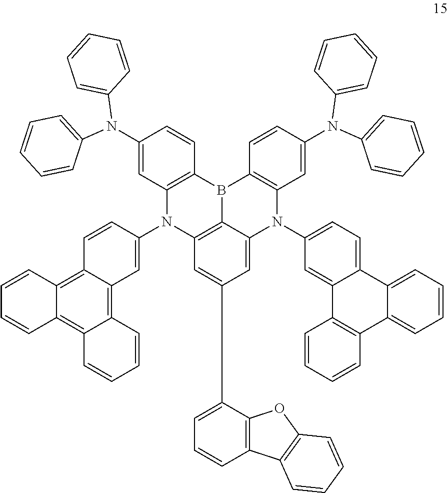 [SMILES: c1ccc(N(c2ccccc2)c2ccc3c(c2)N(c2ccc4c5ccccc5c5ccccc5c4c2)c2cc(-c4cccc5c4oc4ccccc45)cc4c2B3c2ccc(N(c3ccccc3)c3ccccc3)cc2N4c2ccc3c4ccccc4c4ccccc4c3c2)cc1]

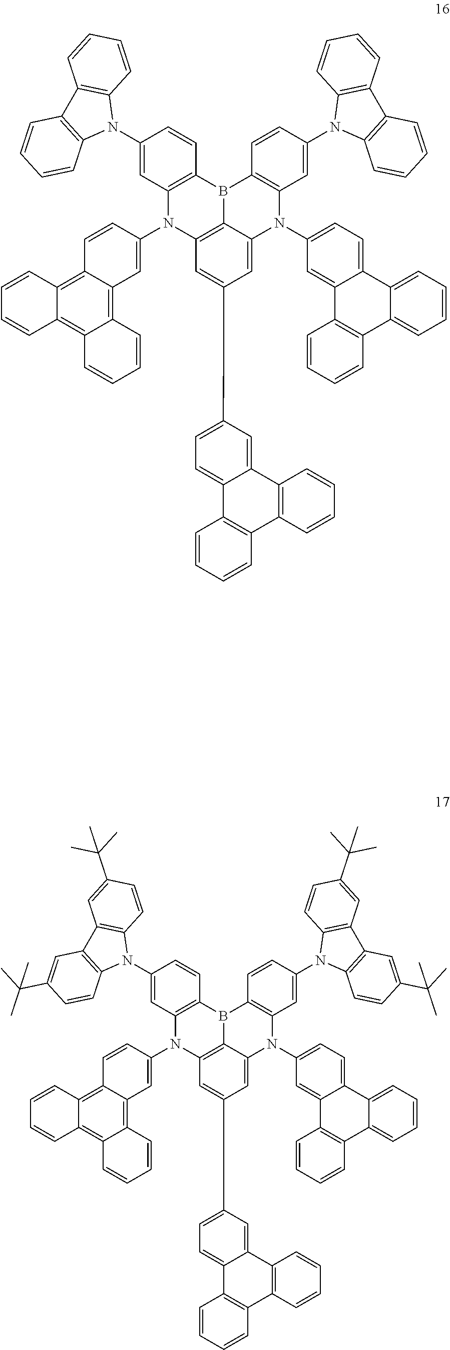 [SMILES: c1ccc2c(c1)c1ccccc1c1cc(-c3cc4c5c(c3)N(c3ccc6c7ccccc7c7ccccc7c6c3)c3cc(-n6c7ccccc7c7ccccc76)ccc3B5c3ccc(-n5c6ccccc6c6ccccc65)cc3N4c3ccc4c5ccccc5c5ccccc5c4c3)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c5ccccc5c5ccccc5c4c3)cc3c1B2c1ccc(-n2c4ccc(C(C)(C)C)cc4c4cc(C(C)(C)C)ccc42)cc1N3c1ccc2c3ccccc3c3ccccc3c2c1]

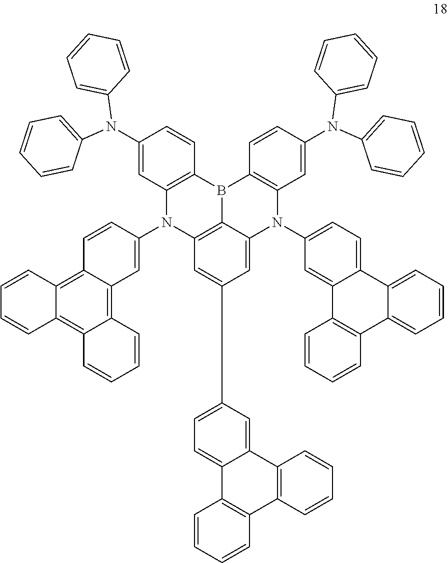 [SMILES: c1ccc(N(c2ccccc2)c2ccc3c(c2)N(c2ccc4c5ccccc5c5ccccc5c4c2)c2cc(-c4ccc5c6ccccc6c6ccccc6c5c4)cc4c2B3c2ccc(N(c3ccccc3)c3ccccc3)cc2N4c2ccc3c4ccccc4c4ccccc4c3c2)cc1]

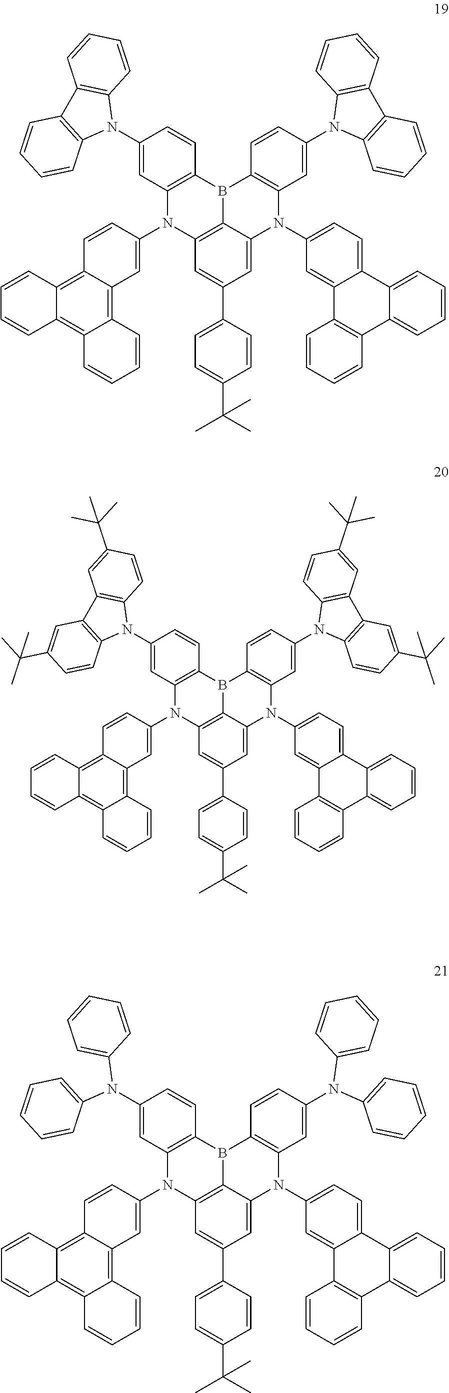 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1]

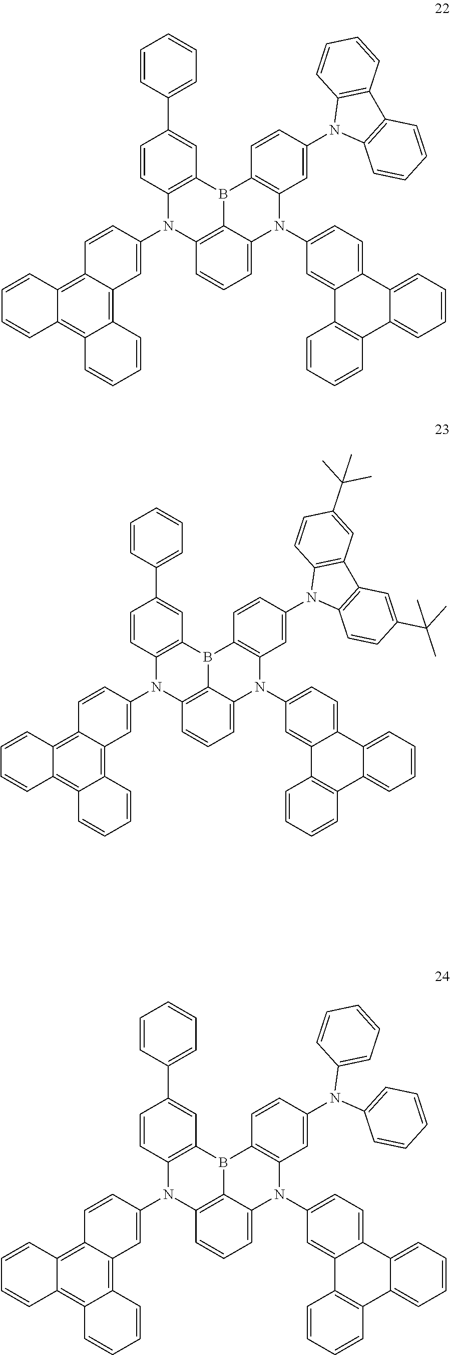 [SMILES: c1ccc(-c2ccc3c(c2)B2c4ccc(-n5c6ccccc6c6ccccc65)cc4N(c4ccc5c6ccccc6c6ccccc6c5c4)c4cccc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cccc(c42)N3c2ccc3c4ccccc4c4ccccc4c3c2)cc1]

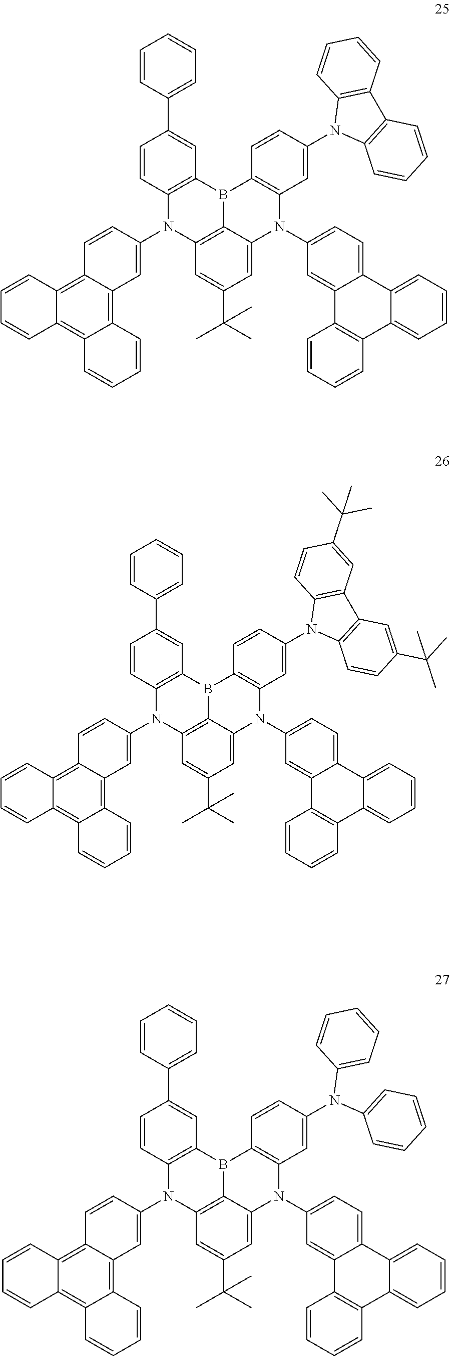 [SMILES: CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1cc(-c3ccccc3)ccc1N2c1ccc2c3ccccc3c3ccccc3c2c1 ; CC(C)(C)c1cc2c3c(c1)N(c1ccc4c5ccccc5c5ccccc5c4c1)c1cc(N(c4ccccc4)c4ccccc4)ccc1B3c1cc(-c3ccccc3)ccc1N2c1ccc2c3ccccc3c3ccccc3c2c1]

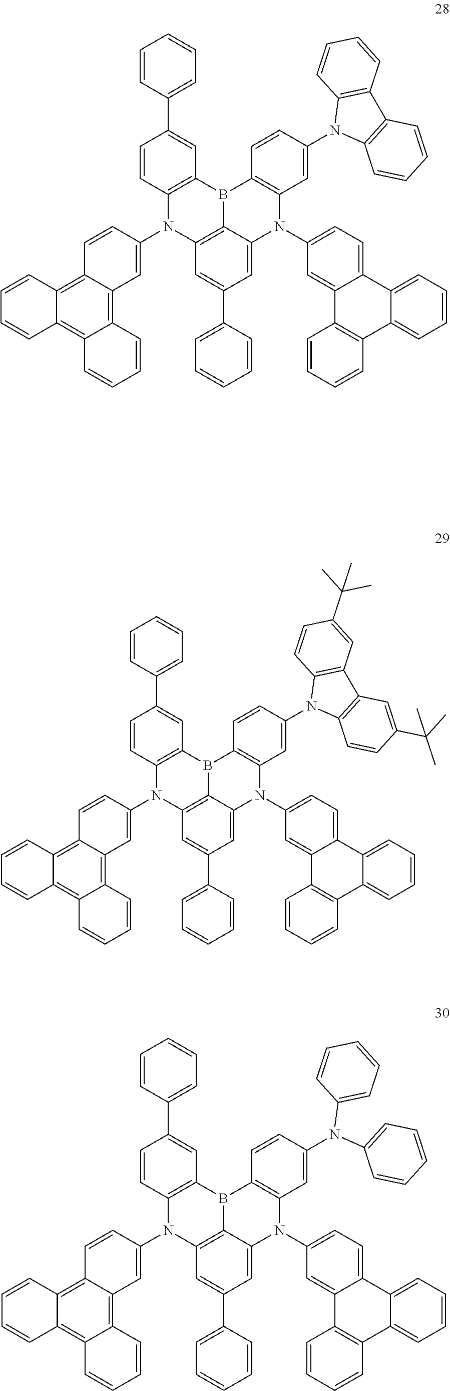 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-c5ccccc5)cc(c42)N3c2ccc3c4ccccc4c4ccccc4c3c2)cc1]

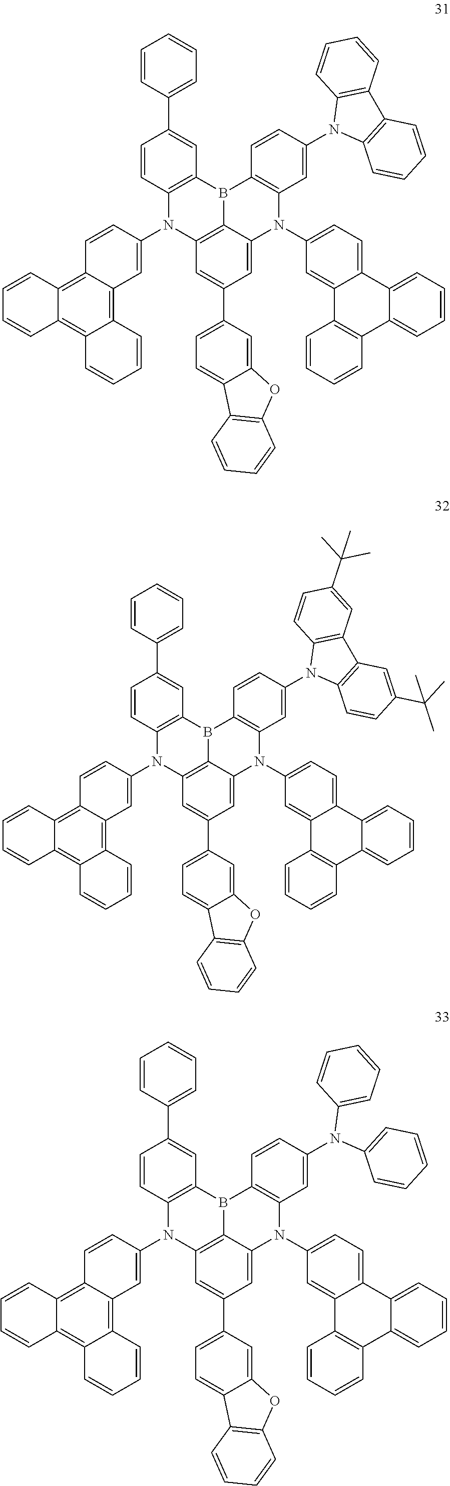 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1]

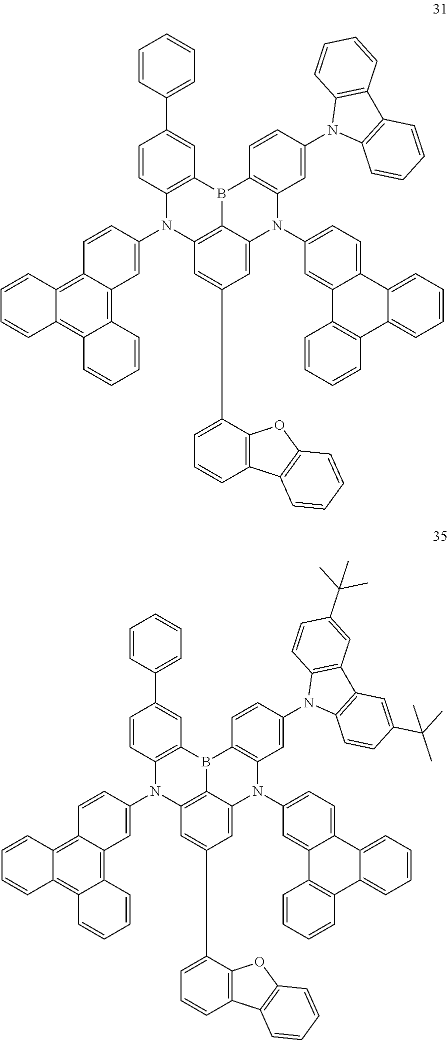 [SMILES: c1ccc(-c2ccc3c(c2)B2c4ccc(-n5c6ccccc6c6ccccc65)cc4N(c4ccc5c6ccccc6c6ccccc6c5c4)c4cc(-c5cccc6c5oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3cccc4c3oc3ccccc34)cc3c1B2c1cc(-c2ccccc2)ccc1N3c1ccc2c3ccccc3c3ccccc3c2c1]

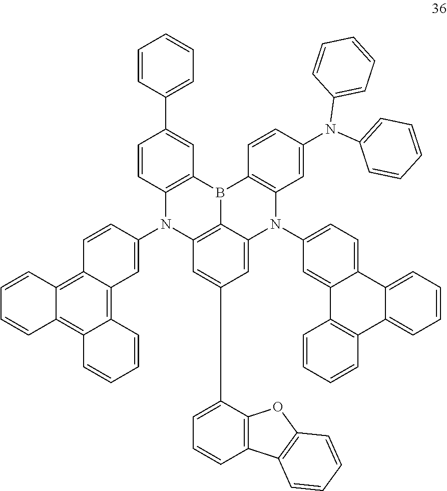 [SMILES: c1ccc(-c2ccc3c(c2)B2c4ccc(N(c5ccccc5)c5ccccc5)cc4N(c4ccc5c6ccccc6c6ccccc6c5c4)c4cc(-c5cccc6c5oc5ccccc56)cc(c42)N3c2ccc3c4ccccc4c4ccccc4c3c2)cc1]

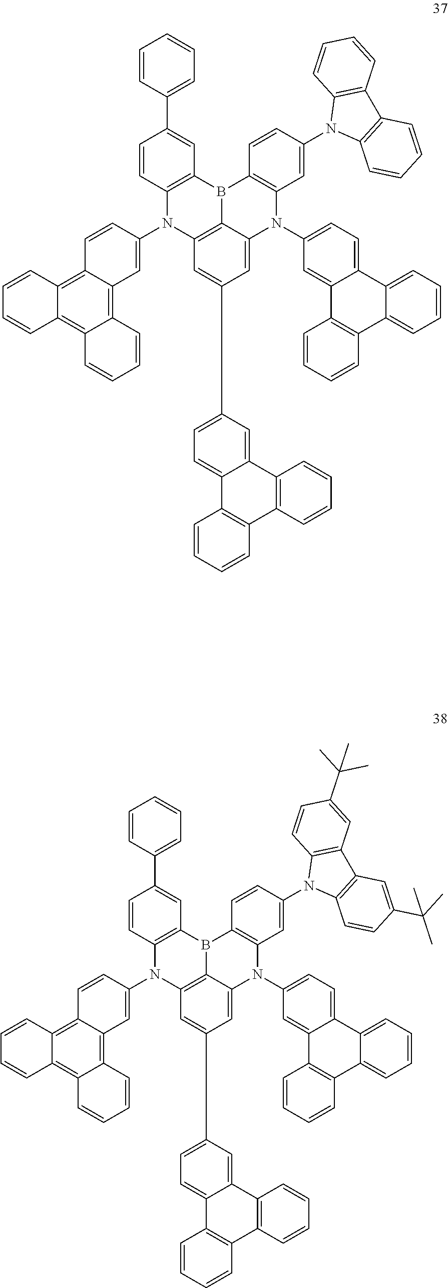 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccc6c7ccccc7c7ccccc7c6c5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c5ccccc5c5ccccc5c4c3)cc3c1B2c1cc(-c2ccccc2)ccc1N3c1ccc2c3ccccc3c3ccccc3c2c1]

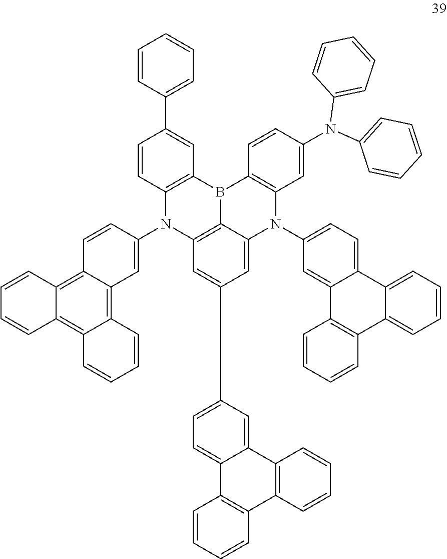 [SMILES: c1ccc(-c2ccc3c(c2)B2c4ccc(N(c5ccccc5)c5ccccc5)cc4N(c4ccc5c6ccccc6c6ccccc6c5c4)c4cc(-c5ccc6c7ccccc7c7ccccc7c6c5)cc(c42)N3c2ccc3c4ccccc4c4ccccc4c3c2)cc1]

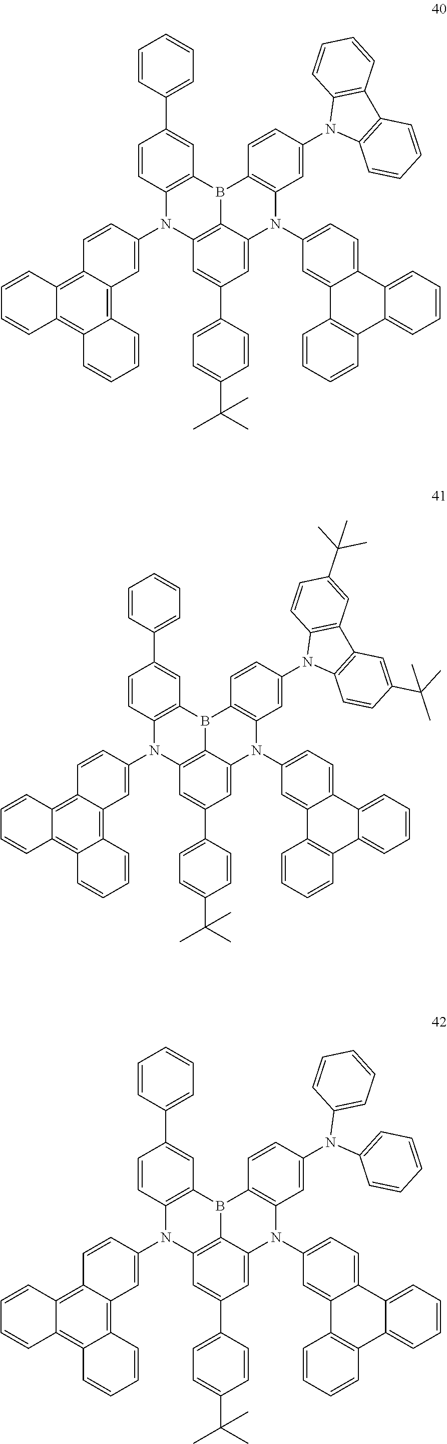 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2cc(-c4ccccc4)ccc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(N(c5ccccc5)c5ccccc5)ccc2B4c2cc(-c4ccccc4)ccc2N3c2ccc3c4ccccc4c4ccccc4c3c2)cc1]

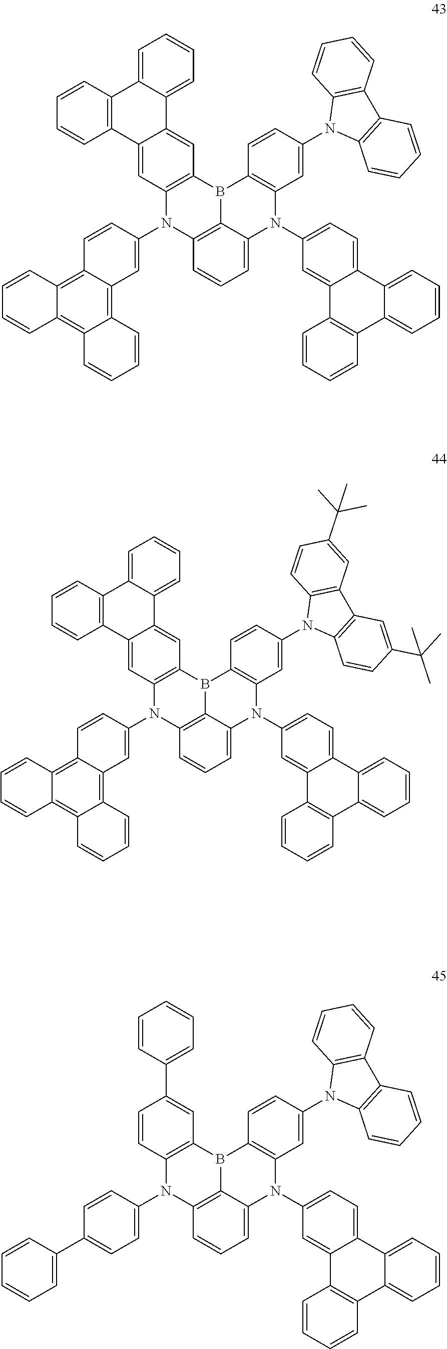 [SMILES: c1cc2c3c(c1)N(c1ccc4c5ccccc5c5ccccc5c4c1)c1cc4c5ccccc5c5ccccc5c4cc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1cc2c4ccccc4c4ccccc4c2cc1N3c1ccc2c3ccccc3c3ccccc3c2c1 ; c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cccc3c54)cc2)cc1]

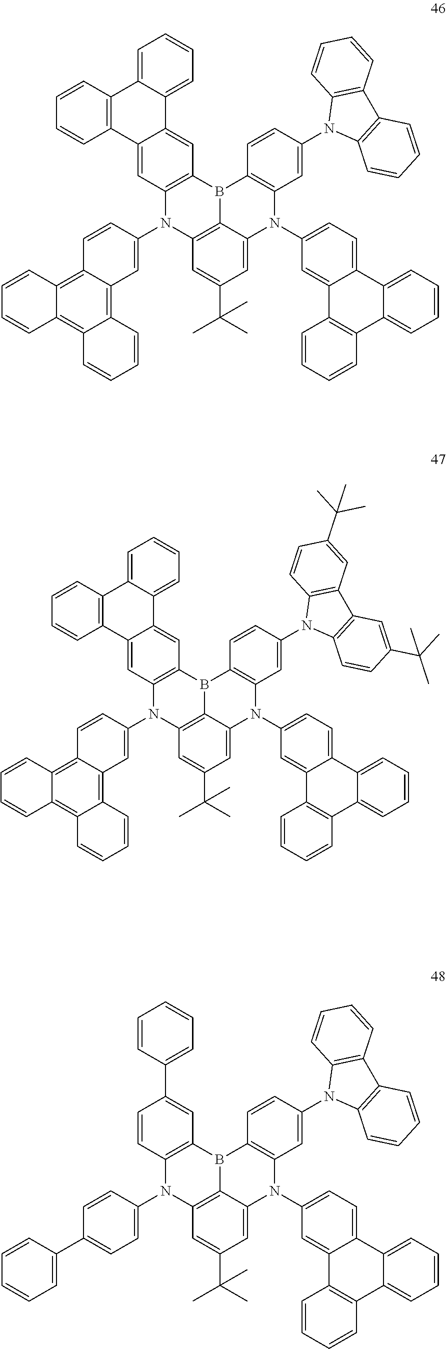 [SMILES: CC(C)(C)c1cc2c3c(c1)N(c1ccc4c5ccccc5c5ccccc5c4c1)c1cc4c5ccccc5c5ccccc5c4cc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc4c5ccccc5c5ccccc5c4cc1B3c1ccc(-n3c4ccc(C(C)(C)C)cc4c4cc(C(C)(C)C)ccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc(-c2ccccc2)cc1]

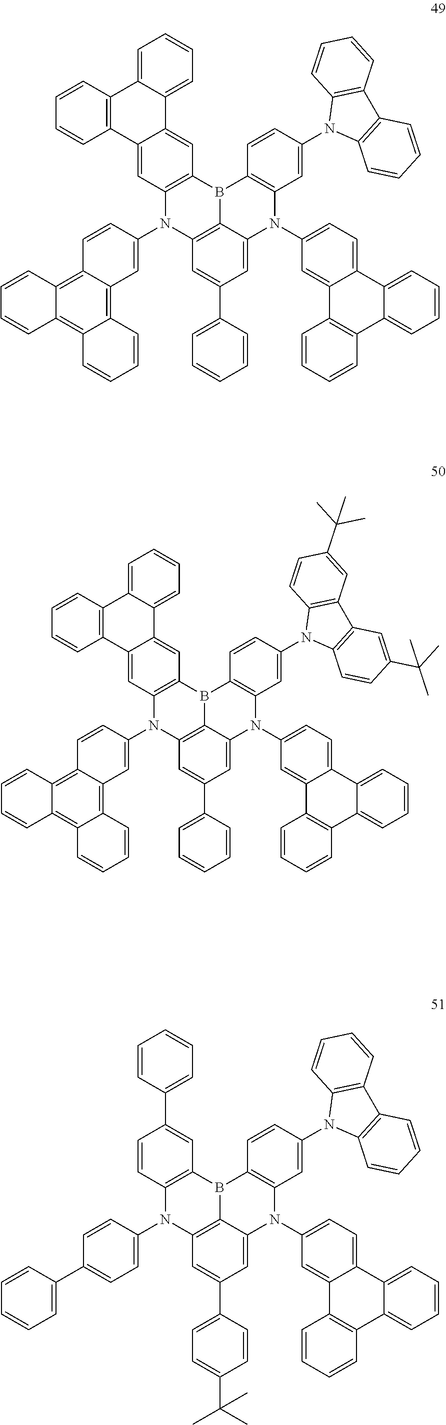 [SMILES: c1ccc(-c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1cc2c4ccccc4c4ccccc4c2cc1N3c1ccc2c3ccccc3c3ccccc3c2c1 ; CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc(-c3ccccc3)cc2)cc1]

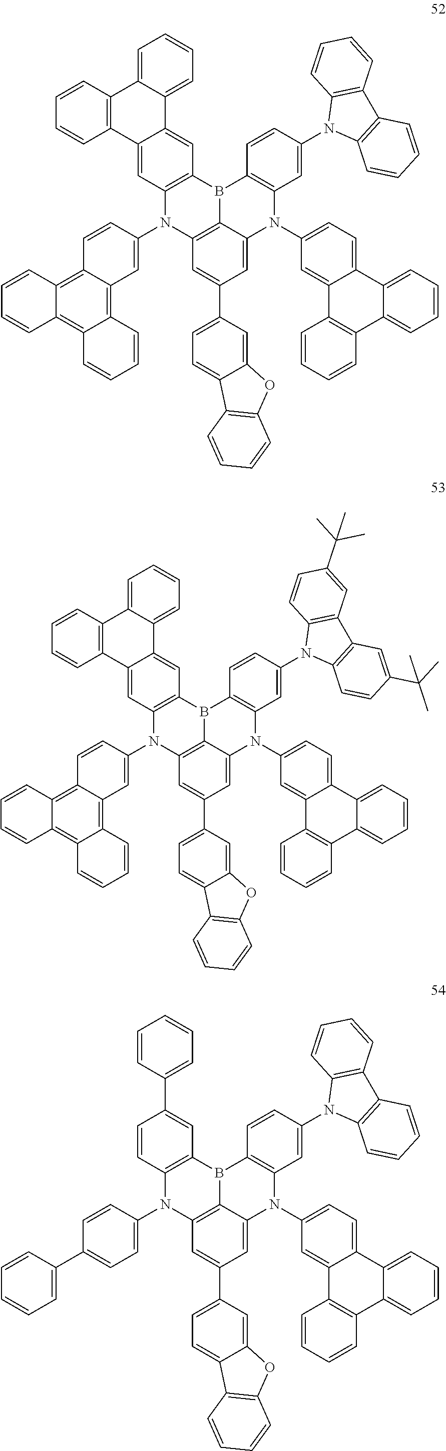 [SMILES: c1ccc2c(c1)oc1cc(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc2c4ccccc4c4ccccc4c2cc1N3c1ccc2c3ccccc3c3ccccc3c2c1 ; c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6ccc7c(c6)oc6ccccc67)cc3c54)cc2)cc1]

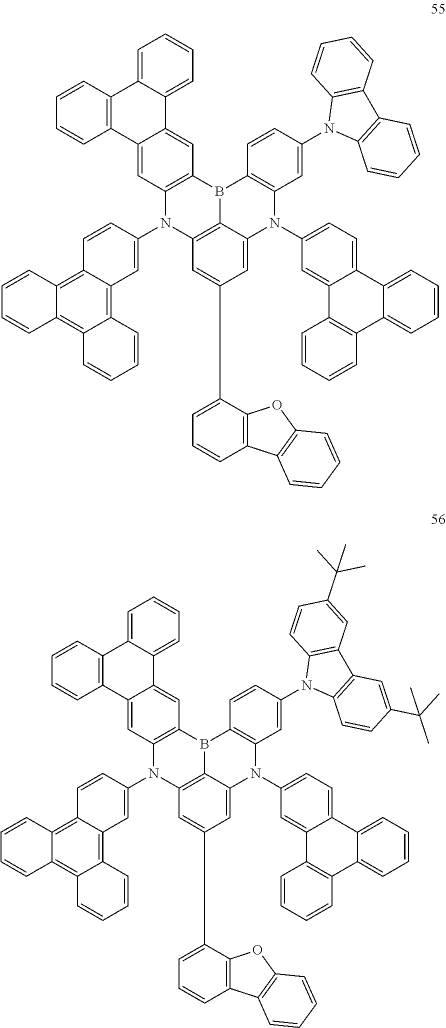 [SMILES: c1ccc2c(c1)oc1c(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)cccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3cccc4c3oc3ccccc34)cc3c1B2c1cc2c4ccccc4c4ccccc4c2cc1N3c1ccc2c3ccccc3c3ccccc3c2c1]

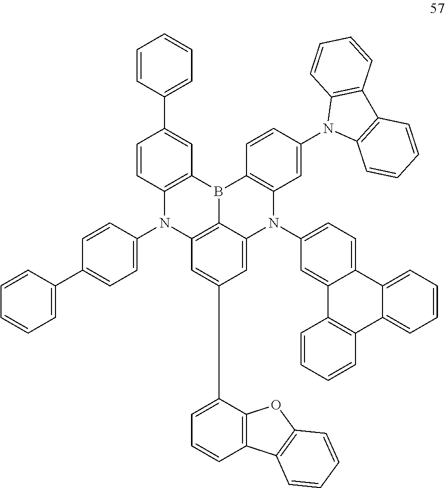 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6cccc7c6oc6ccccc67)cc3c54)cc2)cc1]

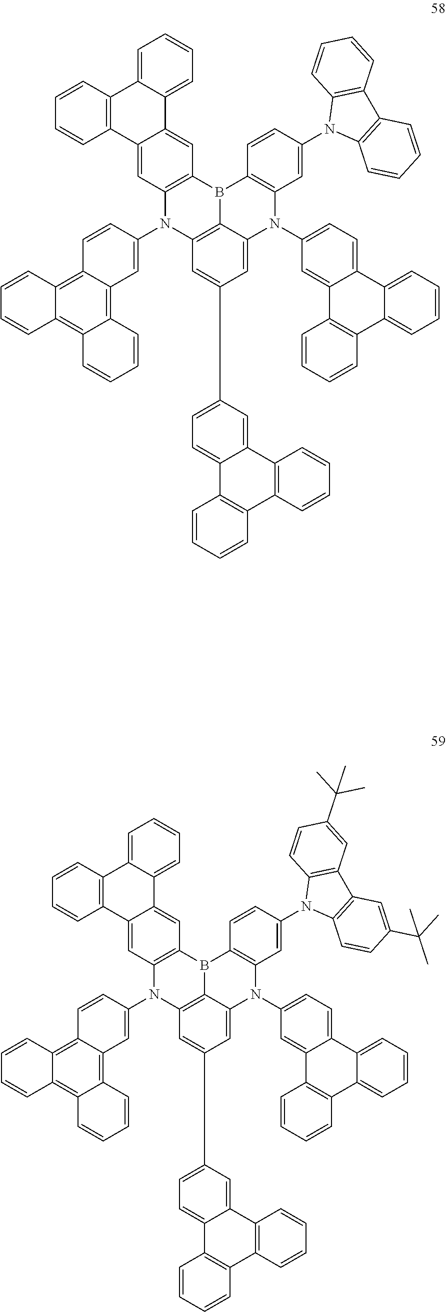 [SMILES: c1ccc2c(c1)c1ccccc1c1cc(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c5ccccc5c5ccccc5c4c3)cc3c1B2c1cc2c4ccccc4c4ccccc4c2cc1N3c1ccc2c3ccccc3c3ccccc3c2c1]

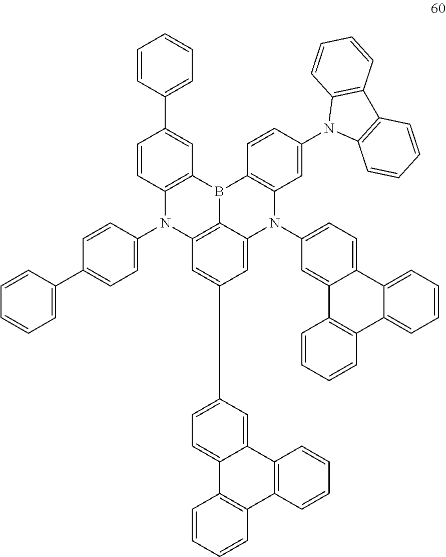 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6ccc7c8ccccc8c8ccccc8c7c6)cc3c54)cc2)cc1]

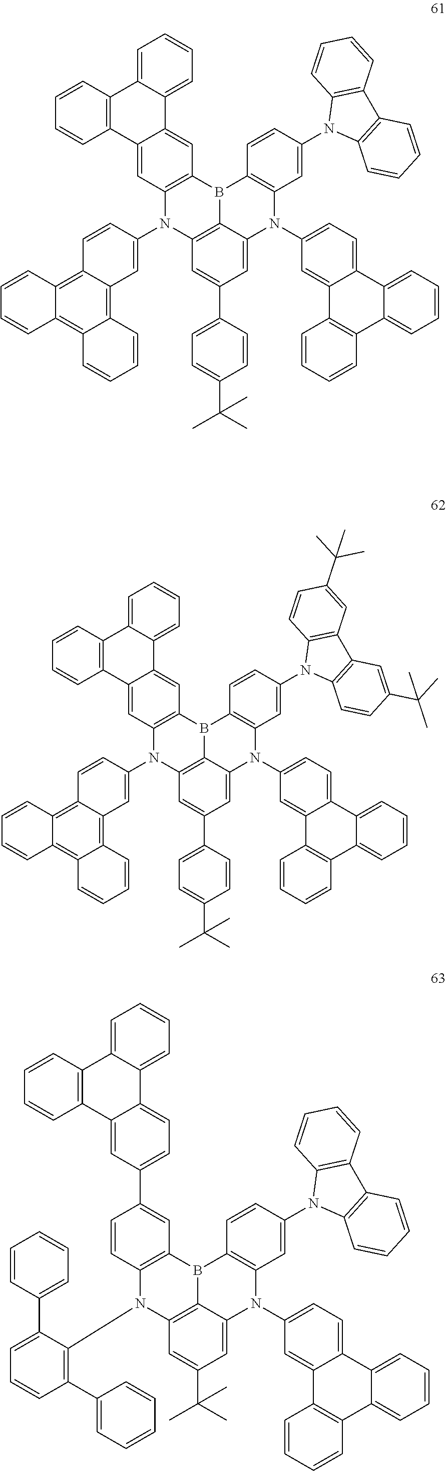 [SMILES: CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccc(C(C)(C)C)cc5c5cc(C(C)(C)C)ccc54)cc2N3c2ccc3c4ccccc4c4ccccc4c3c2)cc1 ; CC(C)(C)c1cc2c3c(c1)N(c1c(-c4ccccc4)cccc1-c1ccccc1)c1ccc(-c4ccc5c6ccccc6c6ccccc6c5c4)cc1B3c1ccc(-n3c4ccccc4c4ccccc43)cc1N2c1ccc2c3ccccc3c3ccccc3c2c1]

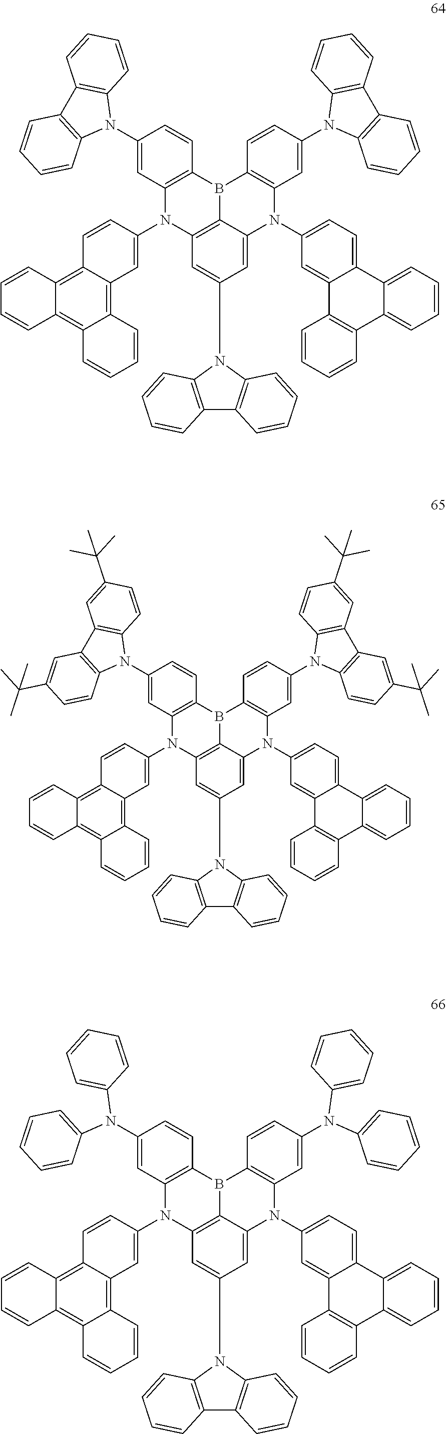

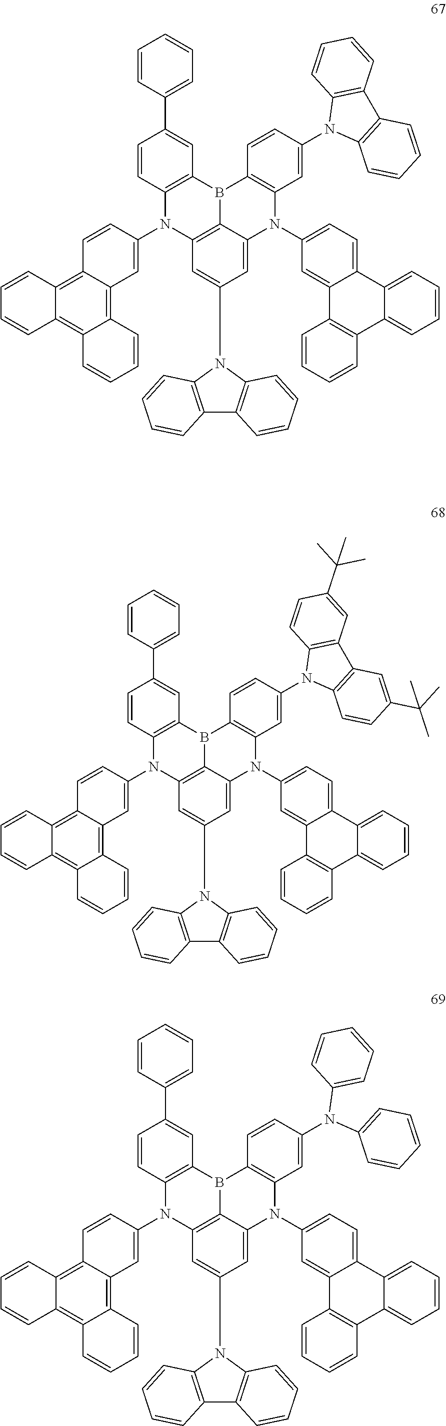 [SMILES: c1ccc(-c2ccc3c(c2)B2c4ccc(-n5c6ccccc6c6ccccc65)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1]

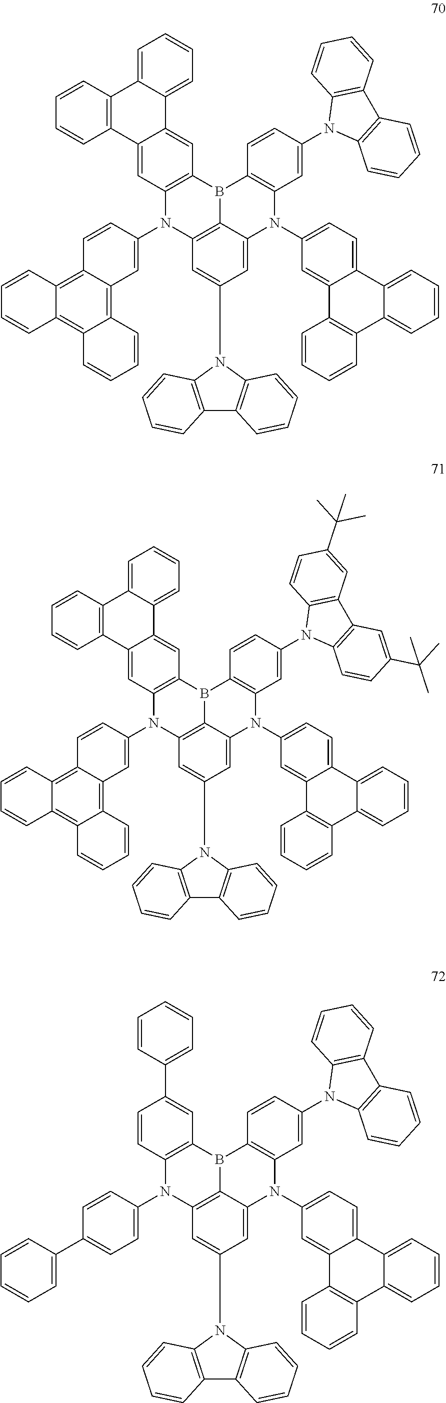 [SMILES: c1ccc2c(c1)c1ccccc1c1cc(N3c4cc(-n5c6ccccc6c6ccccc65)ccc4B4c5cc6c7ccccc7c7ccccc7c6cc5N(c5ccc6c7ccccc7c7ccccc7c6c5)c5cc(-n6c7ccccc7c7ccccc76)cc3c54)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc2c4ccccc4c4ccccc4c2cc1N3c1ccc2c3ccccc3c3ccccc3c2c1 ; c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-n6c7ccccc7c7ccccc76)cc3c54)cc2)cc1]

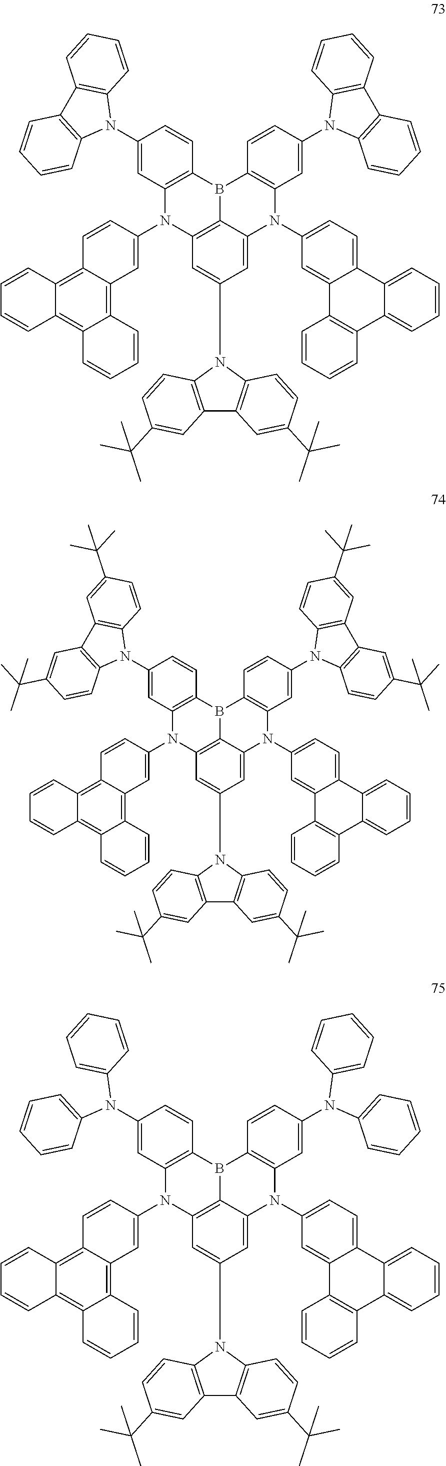

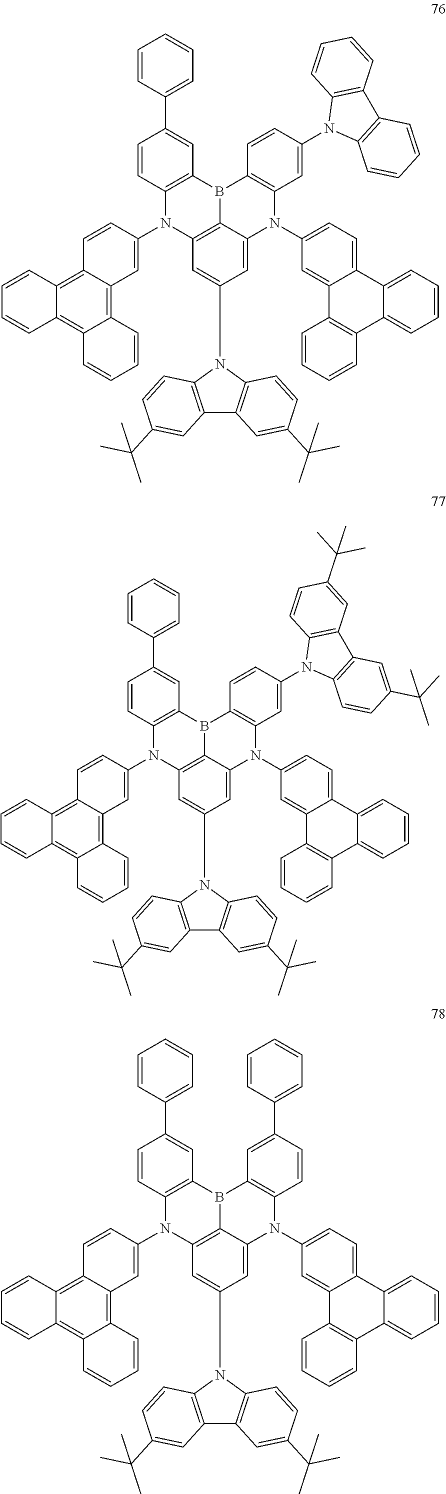

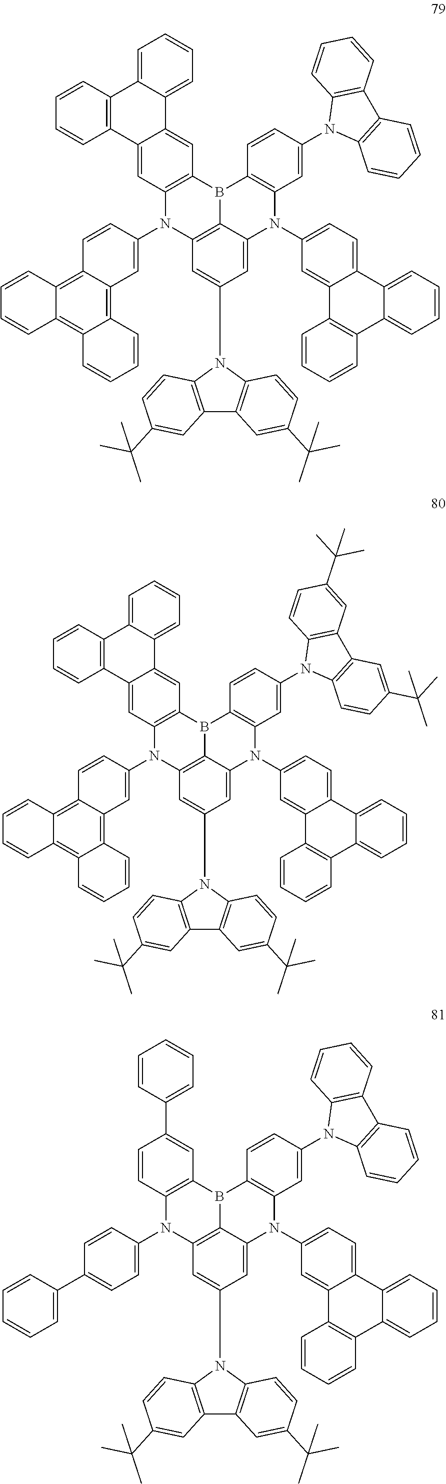

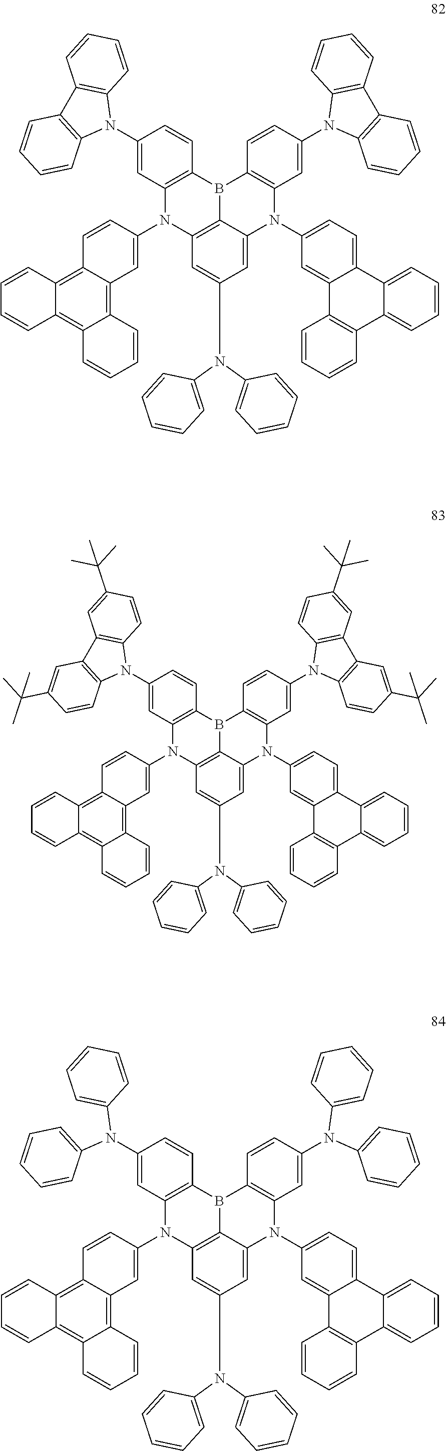 [SMILES: c1ccc(N(c2ccccc2)c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1ccc(-n2c4ccc(C(C)(C)C)cc4c4cc(C(C)(C)C)ccc42)cc1N3c1ccc2c3ccccc3c3ccccc3c2c1 ; c1ccc(N(c2ccccc2)c2ccc3c(c2)N(c2ccc4c5ccccc5c5ccccc5c4c2)c2cc(N(c4ccccc4)c4ccccc4)cc4c2B3c2ccc(N(c3ccccc3)c3ccccc3)cc2N4c2ccc3c4ccccc4c4ccccc4c3c2)cc1]

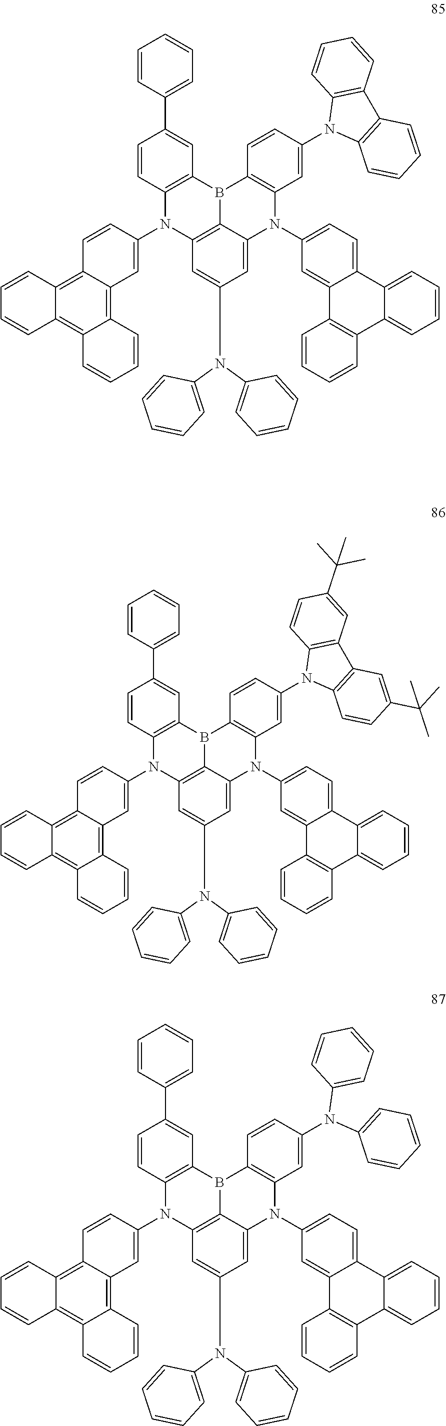 [SMILES: c1ccc(-c2ccc3c(c2)B2c4ccc(-n5c6ccccc6c6ccccc65)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1]

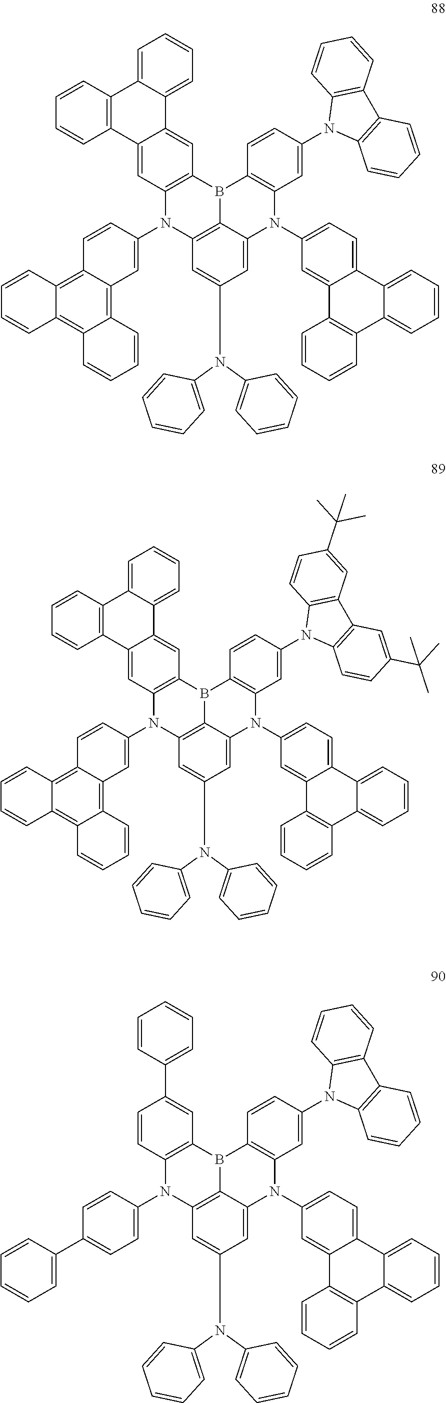 [SMILES: c1ccc(N(c2ccccc2)c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc2c4ccccc4c4ccccc4c2cc1N3c1ccc2c3ccccc3c3ccccc3c2c1 ; c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(N(c6ccccc6)c6ccccc6)cc3c54)cc2)cc1]

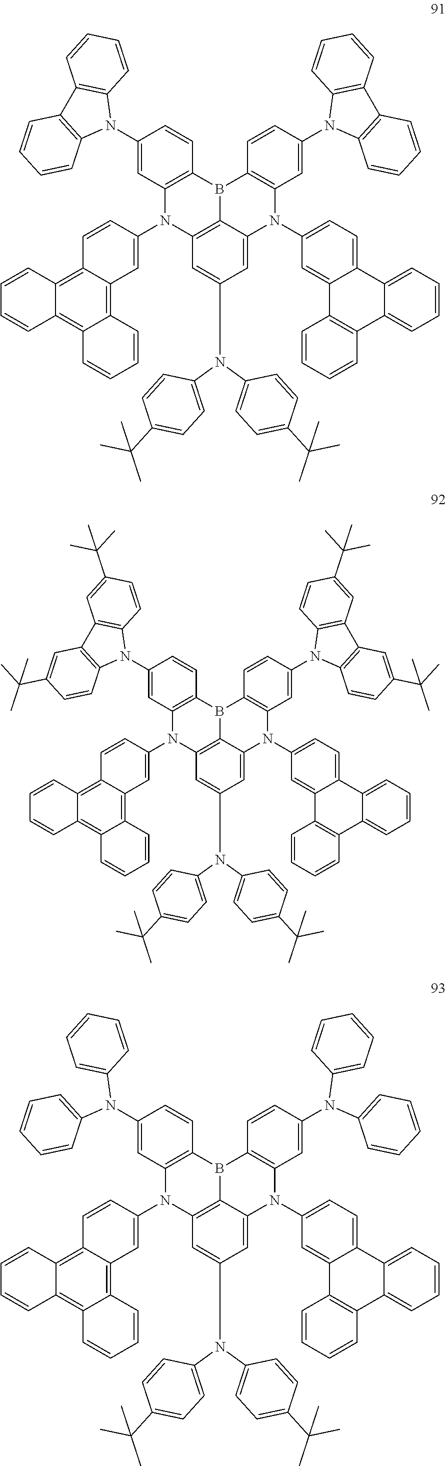

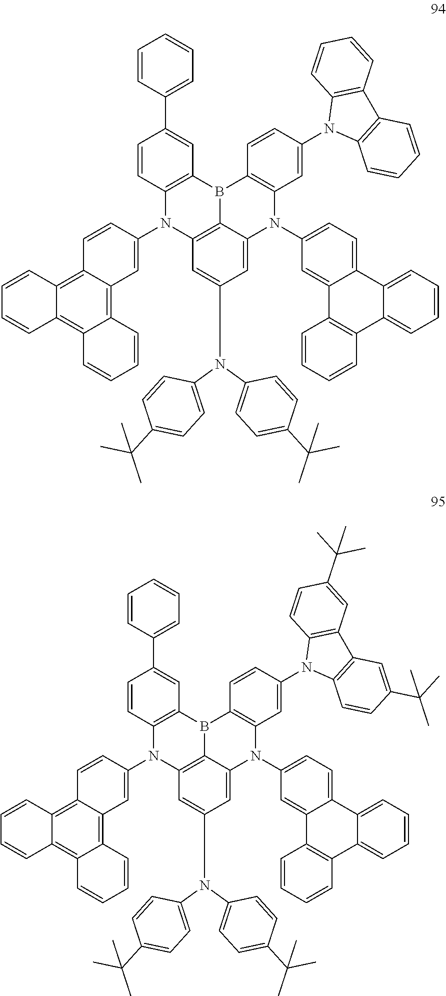 [SMILES: CC(C)(C)c1ccc(N(c2ccc(C(C)(C)C)cc2)c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc3c4ccccc4c4ccccc4c3c2)cc1 ; CC(C)(C)c1ccc(N(c2ccc(C(C)(C)C)cc2)c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2cc(-c4ccccc4)ccc2N3c2ccc3c4ccccc4c4ccccc4c3c2)cc1]

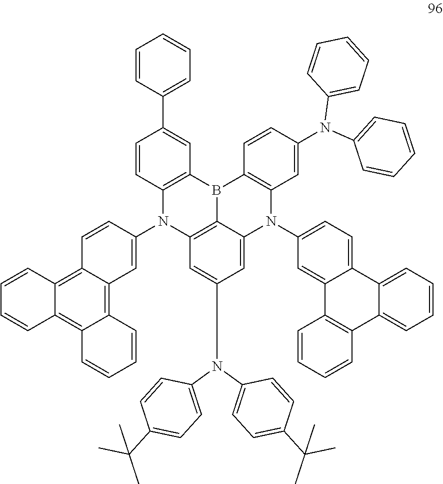 [SMILES: CC(C)(C)c1ccc(N(c2ccc(C(C)(C)C)cc2)c2cc3c4c(c2)N(c2ccc5c6ccccc6c6ccccc6c5c2)c2cc(N(c5ccccc5)c5ccccc5)ccc2B4c2cc(-c4ccccc4)ccc2N3c2ccc3c4ccccc4c4ccccc4c3c2)cc1]

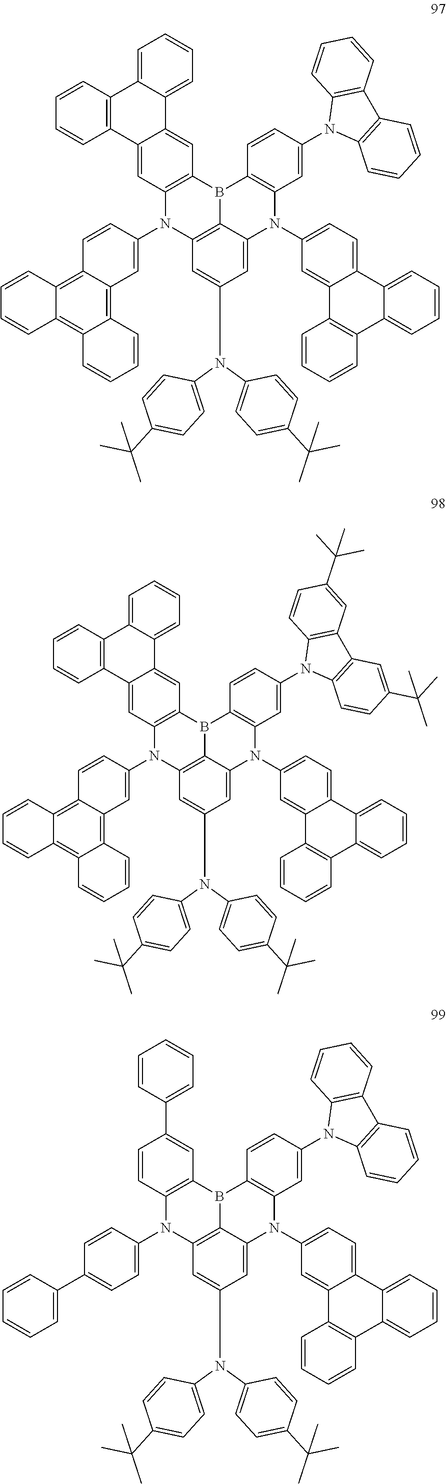

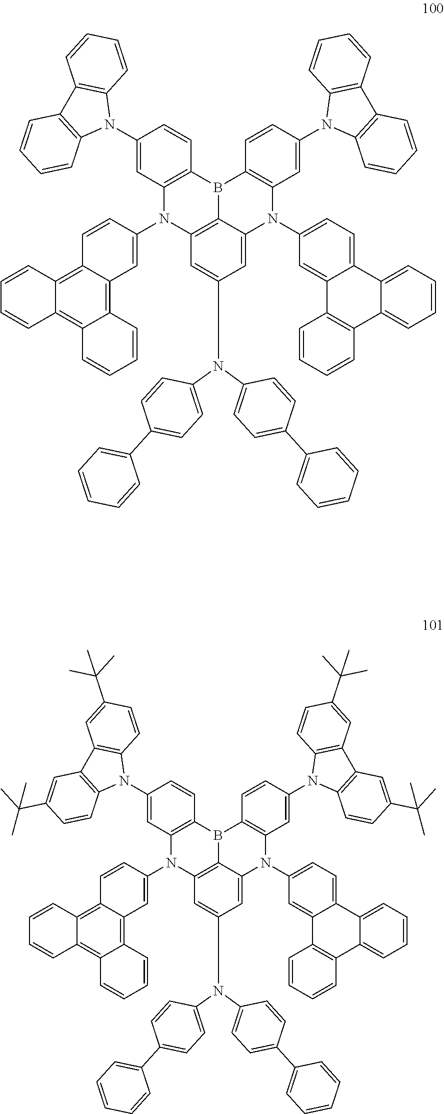 [SMILES: c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3ccc(-n5c6ccccc6c6ccccc65)cc3N4c3ccc4c5ccccc5c5ccccc5c4c3)cc2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1ccc(-n2c4ccc(C(C)(C)C)cc4c4cc(C(C)(C)C)ccc42)cc1N3c1ccc2c3ccccc3c3ccccc3c2c1]

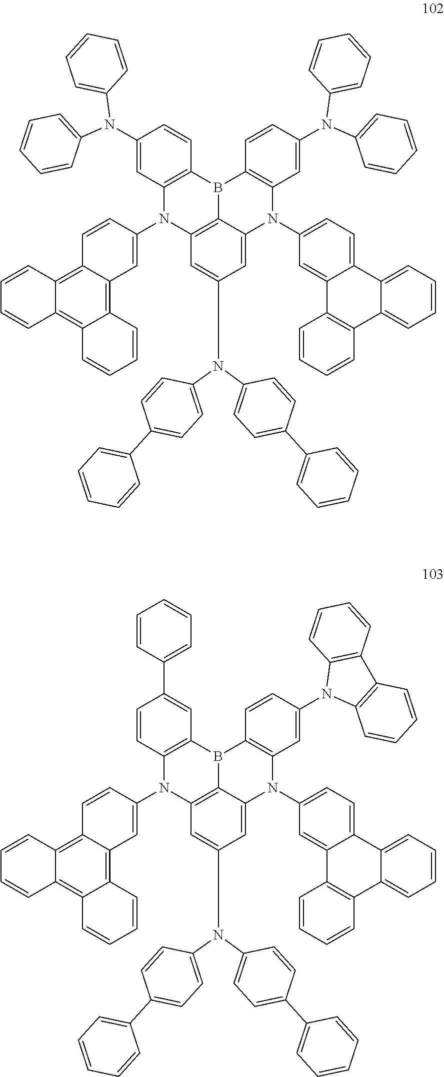 [SMILES: c1ccc(-c2ccc(N(c3ccc(-c4ccccc4)cc3)c3cc4c5c(c3)N(c3ccc6c7ccccc7c7ccccc7c6c3)c3cc(N(c6ccccc6)c6ccccc6)ccc3B5c3ccc(N(c5ccccc5)c5ccccc5)cc3N4c3ccc4c5ccccc5c5ccccc5c4c3)cc2)cc1 ; c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3cc(-c5ccccc5)ccc3N4c3ccc4c5ccccc5c5ccccc5c4c3)cc2)cc1]

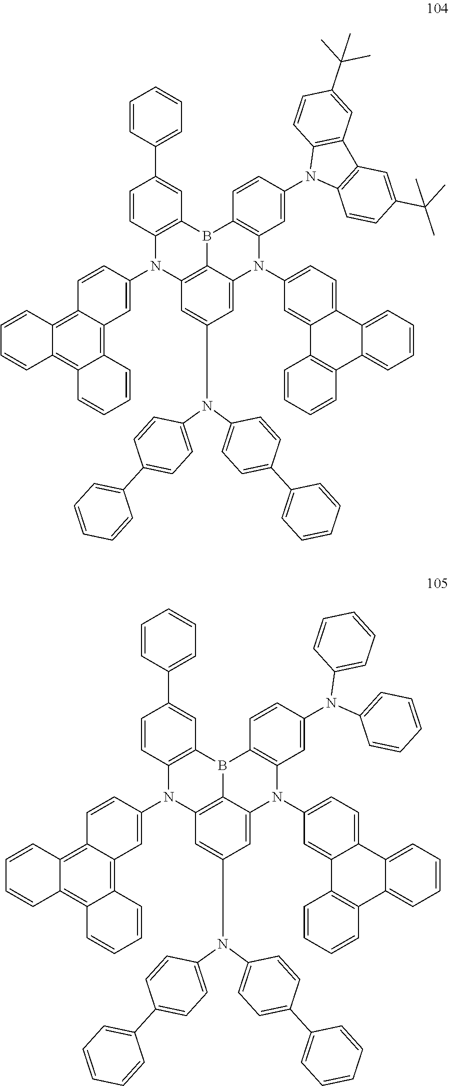 [SMILES: CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1cc(-c2ccccc2)ccc1N3c1ccc2c3ccccc3c3ccccc3c2c1 ; c1ccc(-c2ccc(N(c3ccc(-c4ccccc4)cc3)c3cc4c5c(c3)N(c3ccc6c7ccccc7c7ccccc7c6c3)c3cc(N(c6ccccc6)c6ccccc6)ccc3B5c3cc(-c5ccccc5)ccc3N4c3ccc4c5ccccc5c5ccccc5c4c3)cc2)cc1]

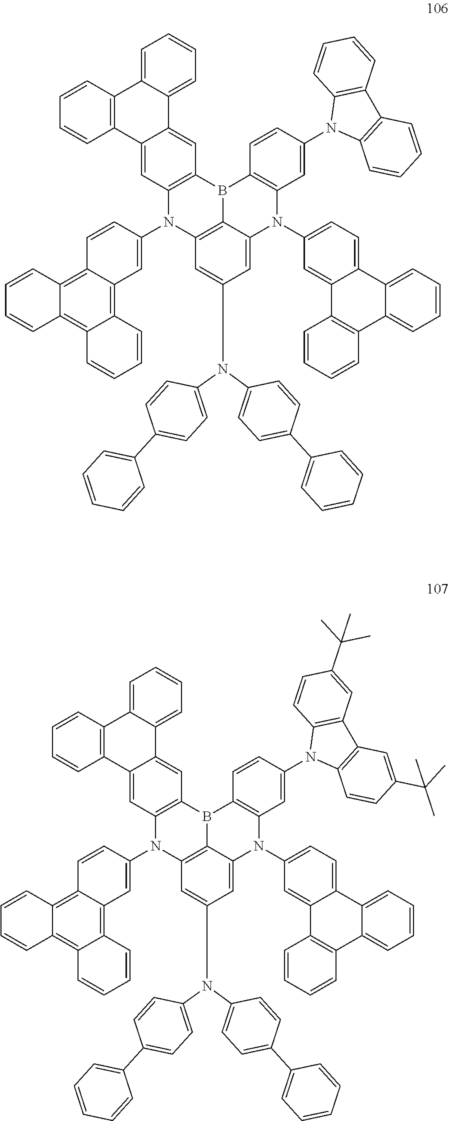 [SMILES: c1ccc(-c2ccc(N(c3ccc(-c4ccccc4)cc3)c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)cc2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1cc2c4ccccc4c4ccccc4c2cc1N3c1ccc2c3ccccc3c3ccccc3c2c1]

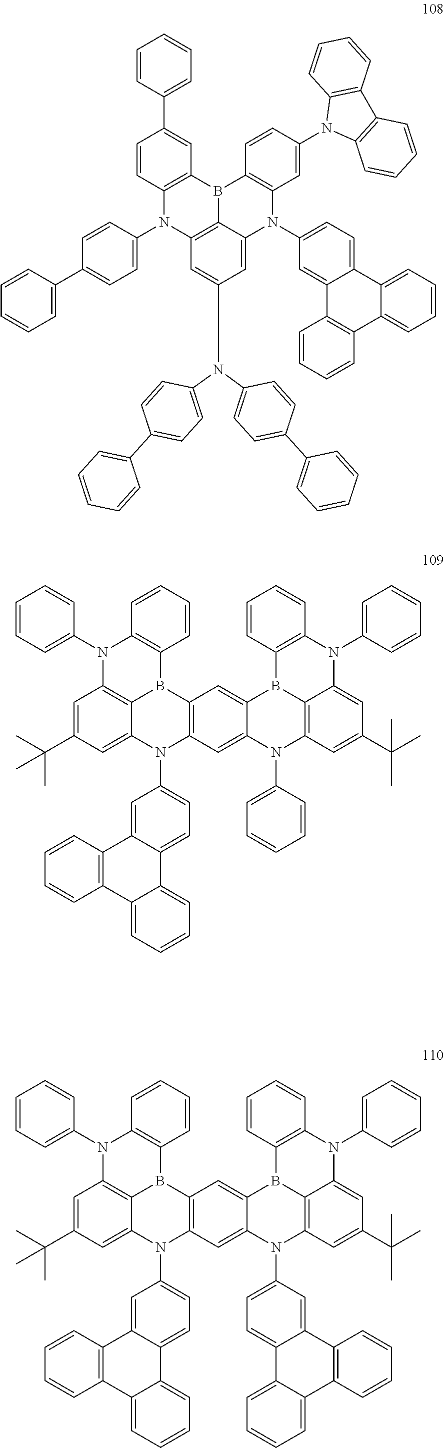 [SMILES: c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3cc(-c5ccccc5)ccc3N4c3ccc(-c4ccccc4)cc3)cc2)cc1 ; CC(C)(C)c1cc2c3c(c1)N(c1ccccc1)c1cc4c(cc1B3c1ccccc1N2c1ccccc1)B1c2ccccc2N(c2ccccc2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1N2c1ccccc1)B1c2ccccc2N(c2ccccc2)c2cc(C(C)(C)C)cc(c21)N4c1ccc2c3ccccc3c3ccccc3c2c1]

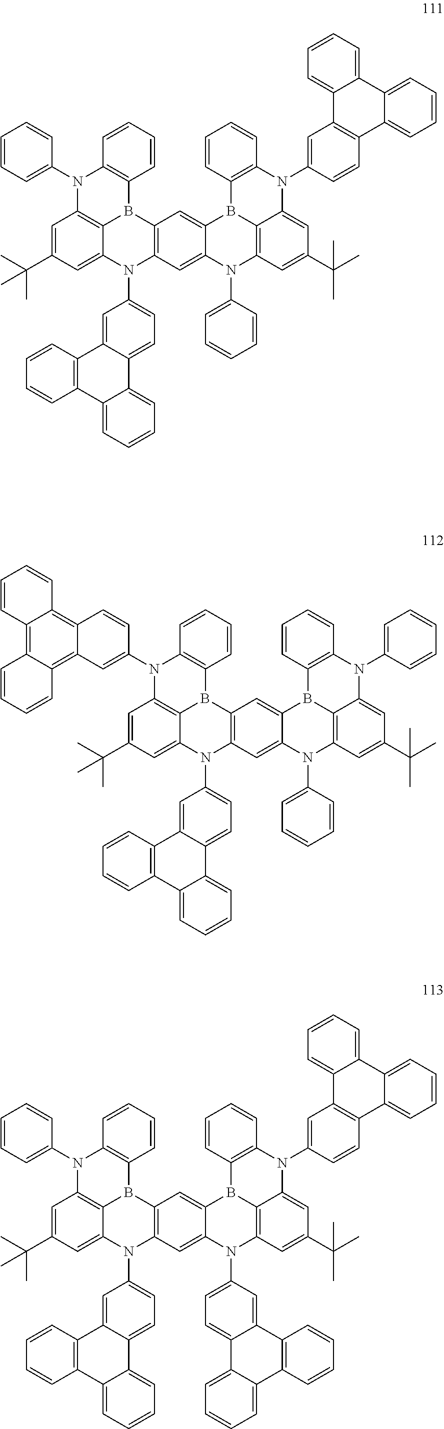 [SMILES: CC(C)(C)c1cc2c3c(c1)N(c1ccccc1)c1cc4c(cc1B3c1ccccc1N2c1ccc2c3ccccc3c3ccccc3c2c1)B1c2ccccc2N(c2ccccc2)c2cc(C(C)(C)C)cc(c21)N4c1ccc2c3ccccc3c3ccccc3c2c1 ; CC(C)(C)c1cc2c3c(c1)N(c1ccccc1)c1cc4c(cc1B3c1ccccc1N2c1ccccc1)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1N2c1ccccc1)B1c2ccccc2N(c2ccc3c5ccccc5c5ccccc5c3c2)c2cc(C(C)(C)C)cc(c21)N4c1ccc2c3ccccc3c3ccccc3c2c1]

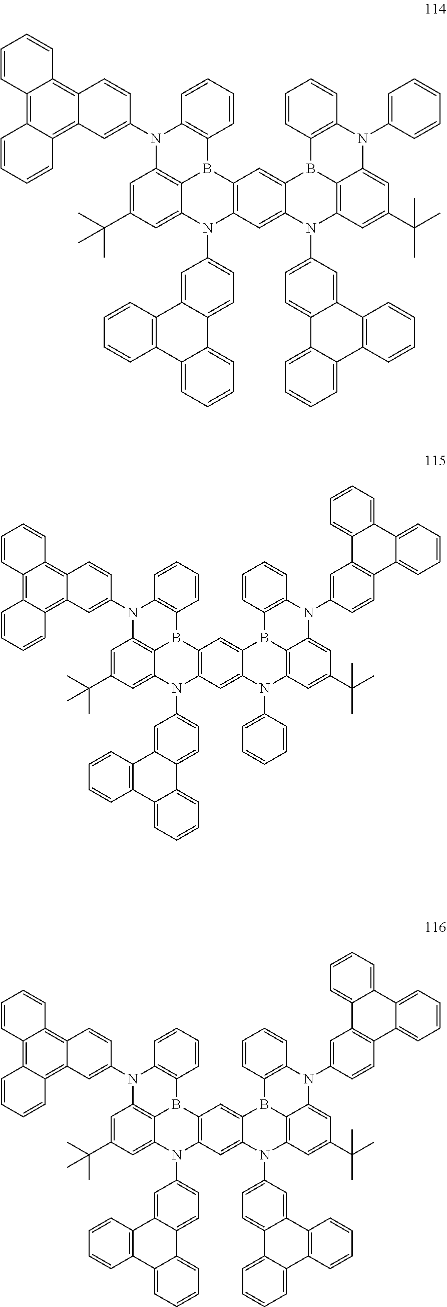

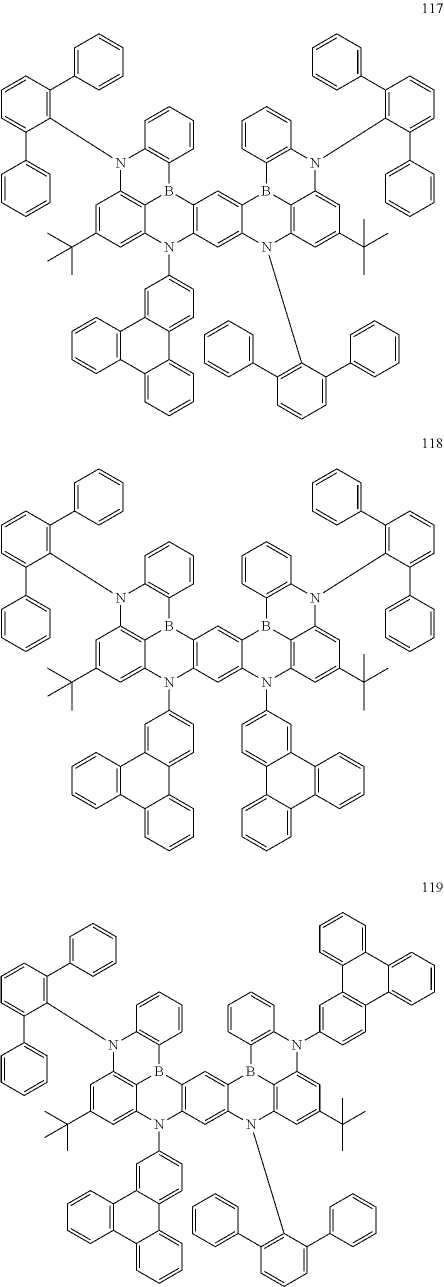

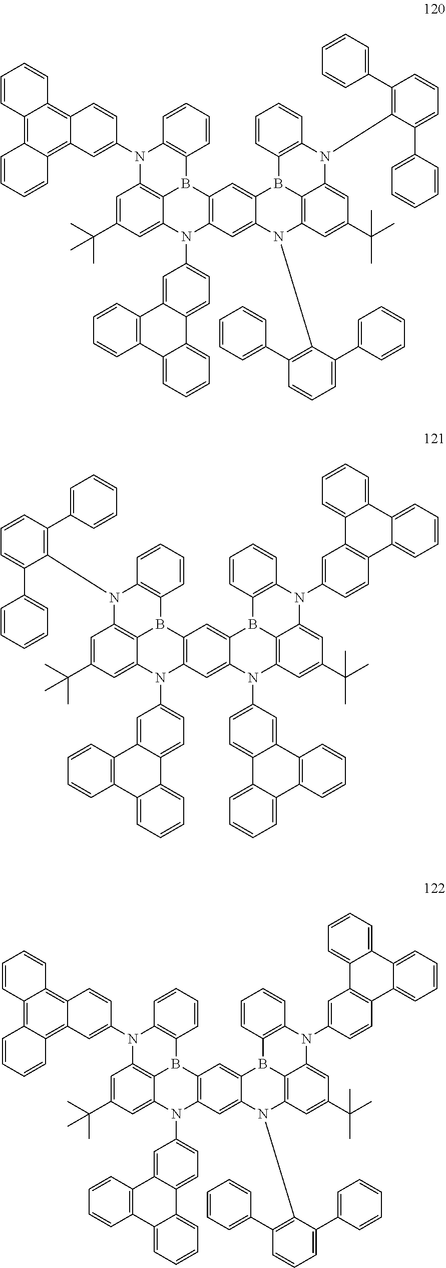

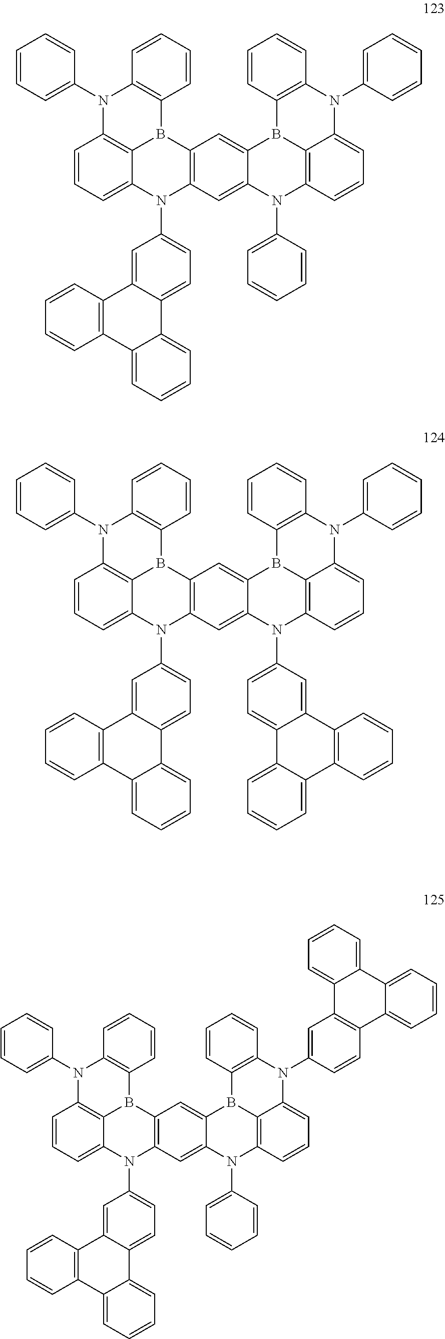 [SMILES: c1ccc(N2c3ccccc3B3c4cc5c(cc4N(c4ccccc4)c4cccc2c43)N(c2ccc3c4ccccc4c4ccccc4c3c2)c2cccc3c2B5c2ccccc2N3c2ccccc2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccccc2)cc1 ; c1ccc(N2c3ccccc3B3c4cc5c(cc4N(c4ccc6c7ccccc7c7ccccc7c6c4)c4cccc2c43)N(c2ccccc2)c2cccc3c2B5c2ccccc2N3c2ccc3c4ccccc4c4ccccc4c3c2)cc1]

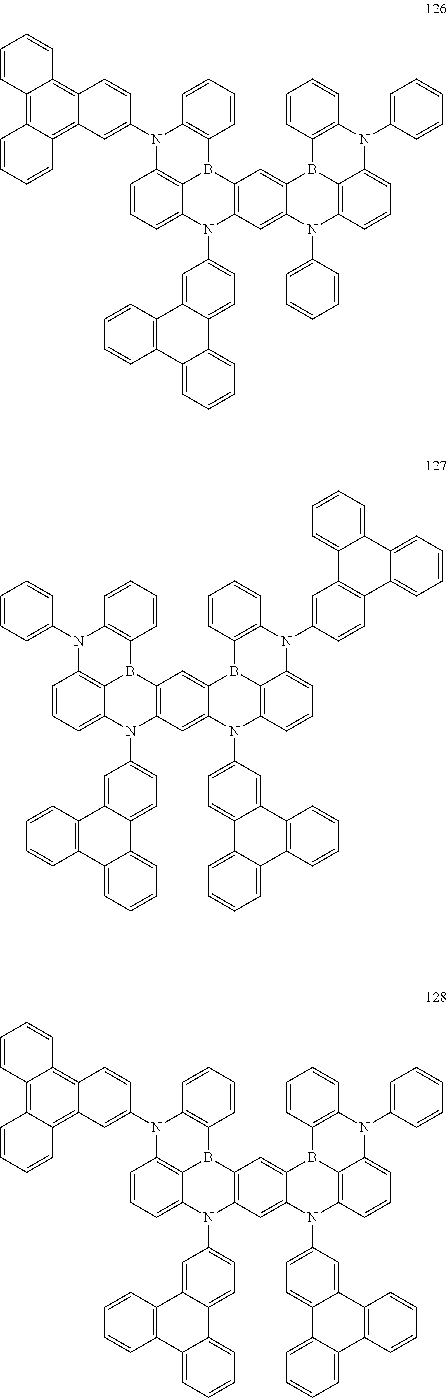 [SMILES: c1ccc(N2c3ccccc3B3c4cc5c(cc4N(c4ccccc4)c4cccc2c43)N(c2ccc3c4ccccc4c4ccccc4c3c2)c2cccc3c2B5c2ccccc2N3c2ccc3c4ccccc4c4ccccc4c3c2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccc3c4ccccc4c4ccccc4c3c2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccc3c4ccccc4c4ccccc4c3c2)cc1]

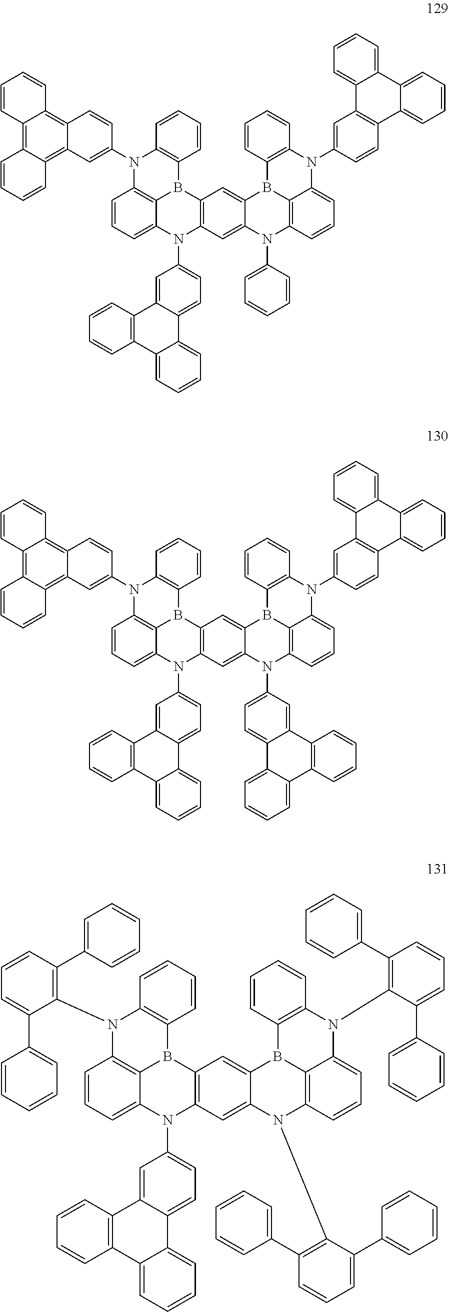 [SMILES: c1ccc(N2c3cc4c(cc3B3c5ccccc5N(c5ccc6c7ccccc7c7ccccc7c6c5)c5cccc2c53)B2c3ccccc3N(c3ccc5c6ccccc6c6ccccc6c5c3)c3cccc(c32)N4c2ccc3c4ccccc4c4ccccc4c3c2)cc1 ; c1ccc2c(c1)B1c3cc4c(cc3N(c3ccc5c6ccccc6c6ccccc6c5c3)c3cccc(c31)N2c1ccc2c3ccccc3c3ccccc3c2c1)N(c1ccc2c3ccccc3c3ccccc3c2c1)c1cccc2c1B4c1ccccc1N2c1ccc2c3ccccc3c3ccccc3c2c1 ; c1ccc(-c2cccc(-c3ccccc3)c2N2c3ccccc3B3c4cc5c(cc4N(c4ccc6c7ccccc7c7ccccc7c6c4)c4cccc2c43)N(c2c(-c3ccccc3)cccc2-c2ccccc2)c2cccc3c2B5c2ccccc2N3c2c(-c3ccccc3)cccc2-c2ccccc2)cc1]

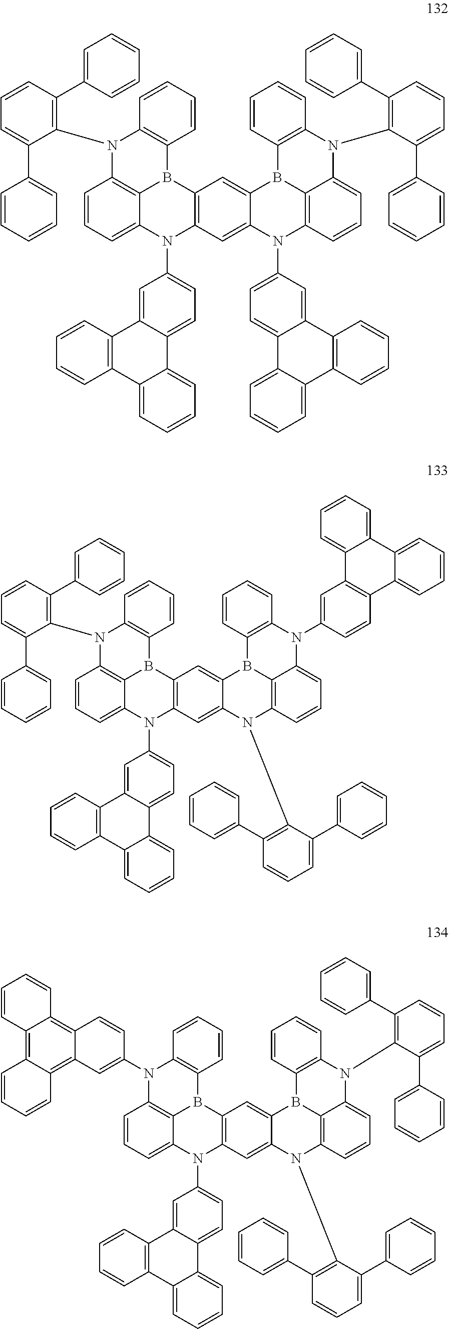

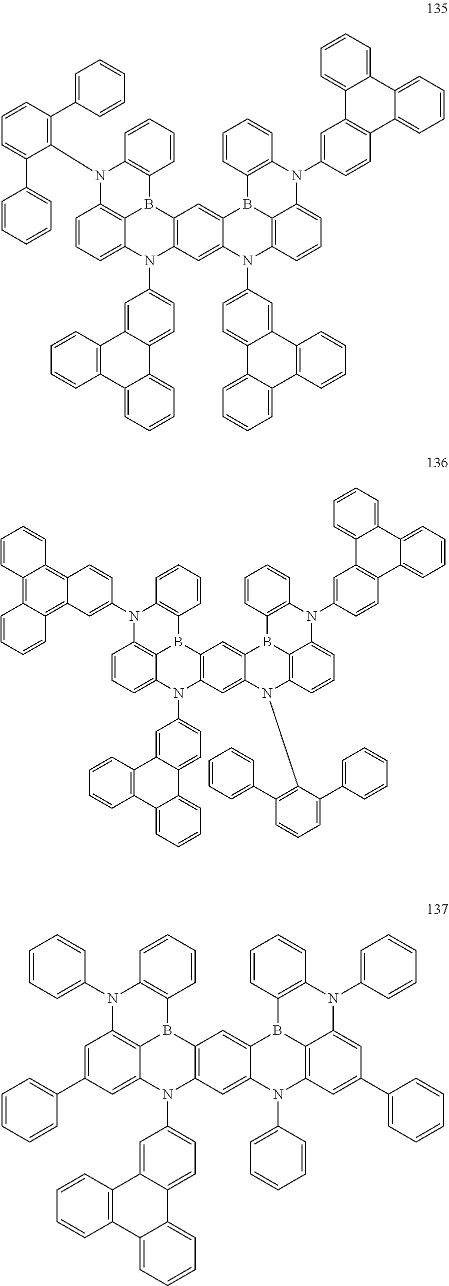 [SMILES: c1ccc(-c2cccc(-c3ccccc3)c2N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccc3c4ccccc4c4ccccc4c3c2)cc1 ; c1ccc(-c2cccc(-c3ccccc3)c2N2c3cc4c(cc3B3c5ccccc5N(c5ccc6c7ccccc7c7ccccc7c6c5)c5cccc2c53)B2c3ccccc3N(c3ccc5c6ccccc6c6ccccc6c5c3)c3cccc(c32)N4c2ccc3c4ccccc4c4ccccc4c3c2)cc1 ; c1ccc(-c2cc3c4c(c2)N(c2ccccc2)c2cc5c(cc2B4c2ccccc2N3c2ccccc2)B2c3ccccc3N(c3ccccc3)c3cc(-c4ccccc4)cc(c32)N5c2ccc3c4ccccc4c4ccccc4c3c2)cc1]

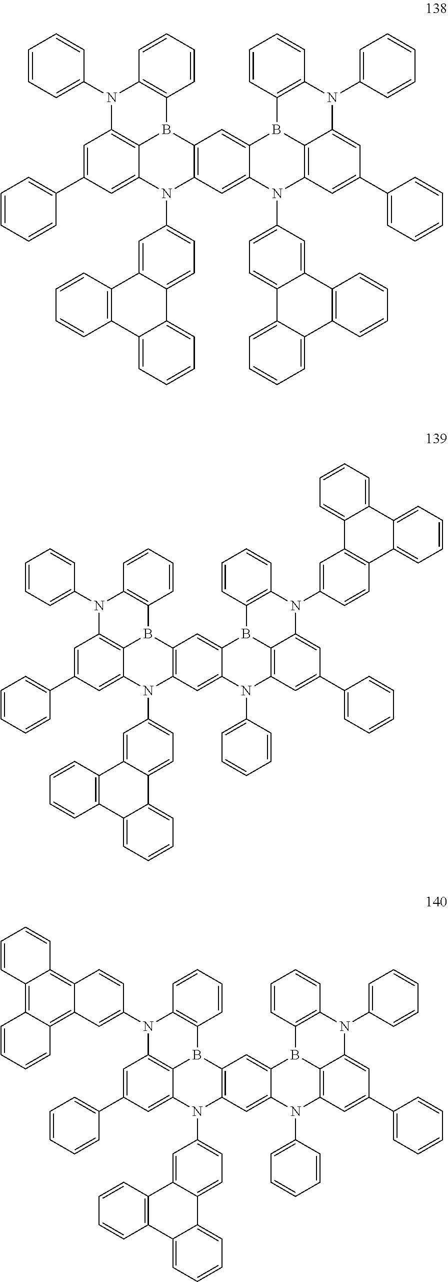 [SMILES: c1ccc(-c2cc3c4c(c2)N(c2ccc5c6ccccc6c6ccccc6c5c2)c2cc5c(cc2B4c2ccccc2N3c2ccccc2)B2c3ccccc3N(c3ccccc3)c3cc(-c4ccccc4)cc(c32)N5c2ccc3c4ccccc4c4ccccc4c3c2)cc1 ; c1ccc(-c2cc3c4c(c2)N(c2ccccc2)c2cc5c(cc2B4c2ccccc2N3c2ccc3c4ccccc4c4ccccc4c3c2)B2c3ccccc3N(c3ccccc3)c3cc(-c4ccccc4)cc(c32)N5c2ccc3c4ccccc4c4ccccc4c3c2)cc1 ; c1ccc(-c2cc3c4c(c2)N(c2ccccc2)c2cc5c(cc2B4c2ccccc2N3c2ccccc2)B2c3ccccc3N(c3ccc4c6ccccc6c6ccccc6c4c3)c3cc(-c4ccccc4)cc(c32)N5c2ccc3c4ccccc4c4ccccc4c3c2)cc1]

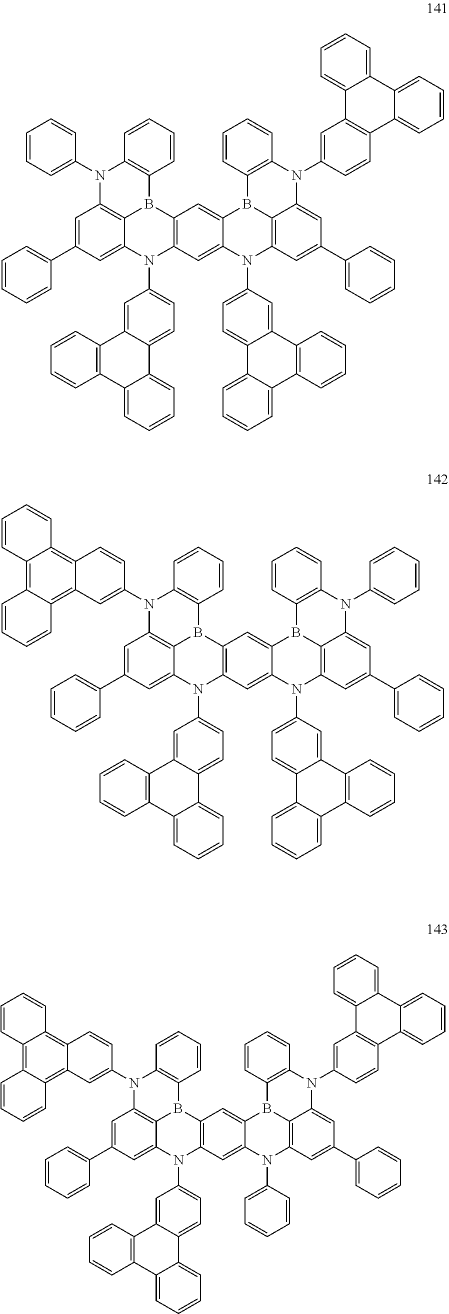

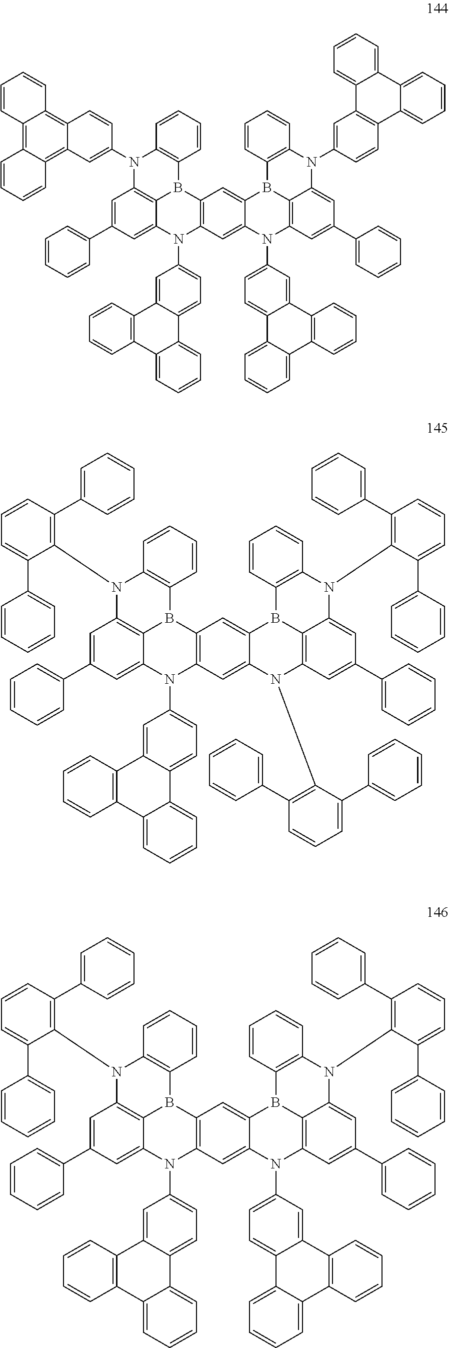

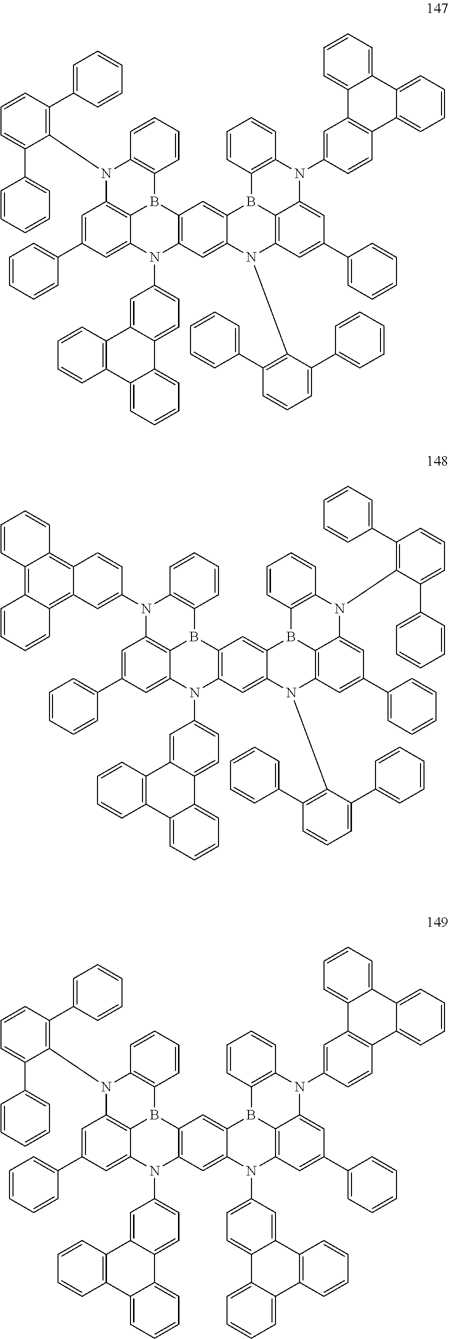

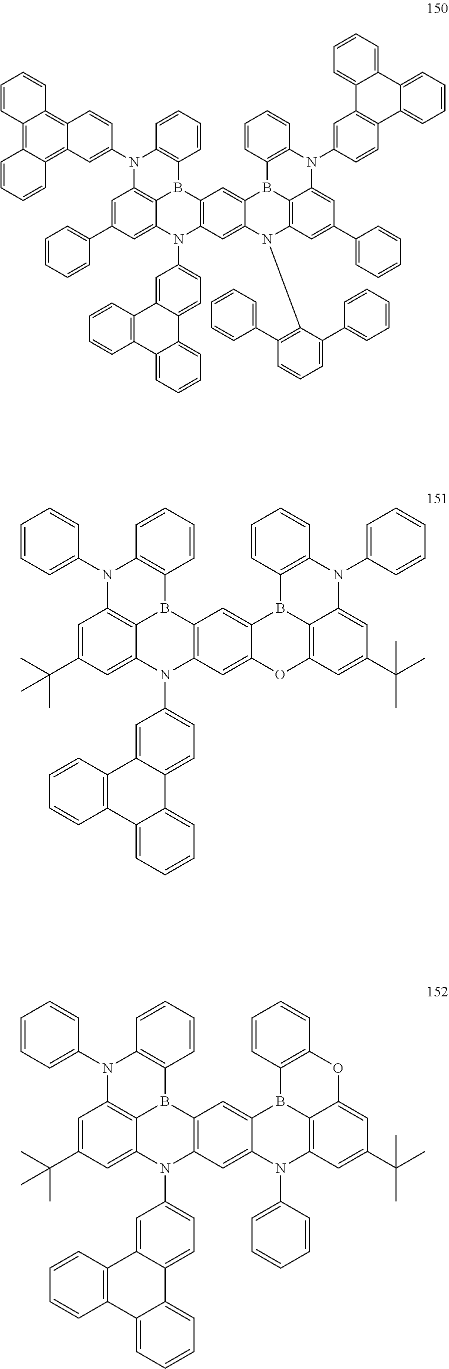 [SMILES: c1ccc(-c2cc3c4c(c2)N(c2ccc5c6ccccc6c6ccccc6c5c2)c2cc5c(cc2B4c2ccccc2N3c2ccc3c4ccccc4c4ccccc4c3c2)B2c3ccccc3N(c3ccc4c6ccccc6c6ccccc6c4c3)c3cc(-c4ccccc4)cc(c32)N5c2c(-c3ccccc3)cccc2-c2ccccc2)cc1 ; CC(C)(C)c1cc2c3c(c1)N(c1ccccc1)c1ccccc1B3c1cc3c(cc1O2)N(c1ccc2c4ccccc4c4ccccc4c2c1)c1cc(C(C)(C)C)cc2c1B3c1ccccc1N2c1ccccc1 ; CC(C)(C)c1cc2c3c(c1)N(c1ccccc1)c1cc4c(cc1B3c1ccccc1O2)B1c2ccccc2N(c2ccccc2)c2cc(C(C)(C)C)cc(c21)N4c1ccc2c3ccccc3c3ccccc3c2c1]

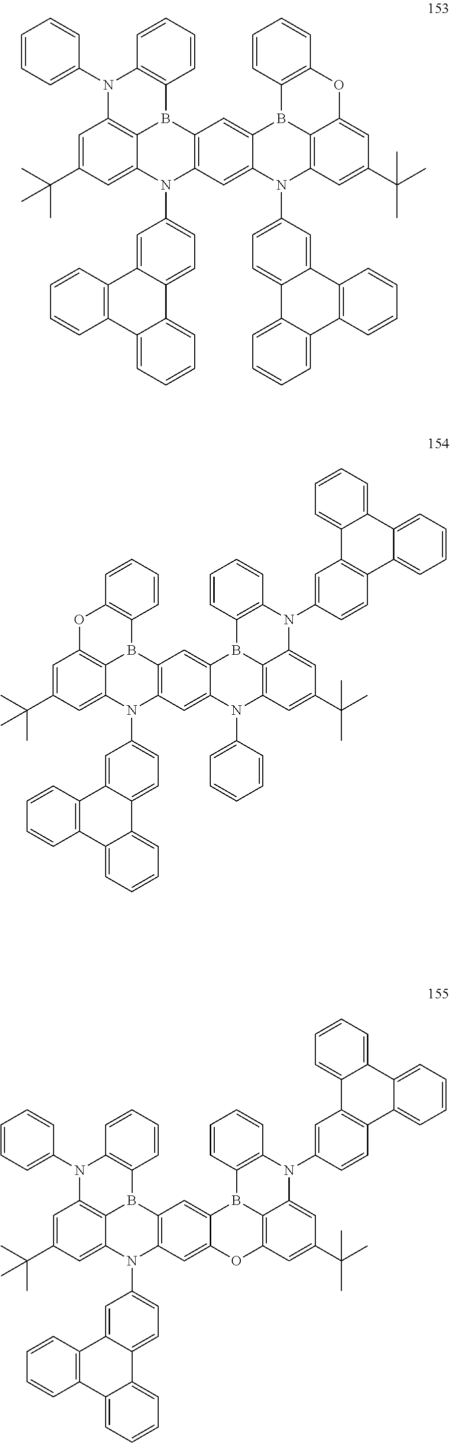

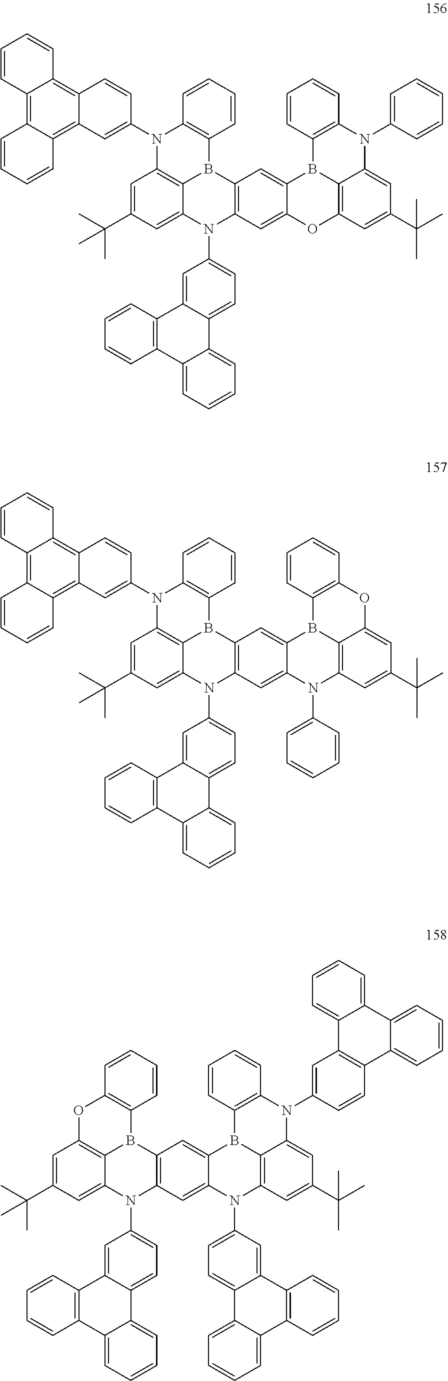

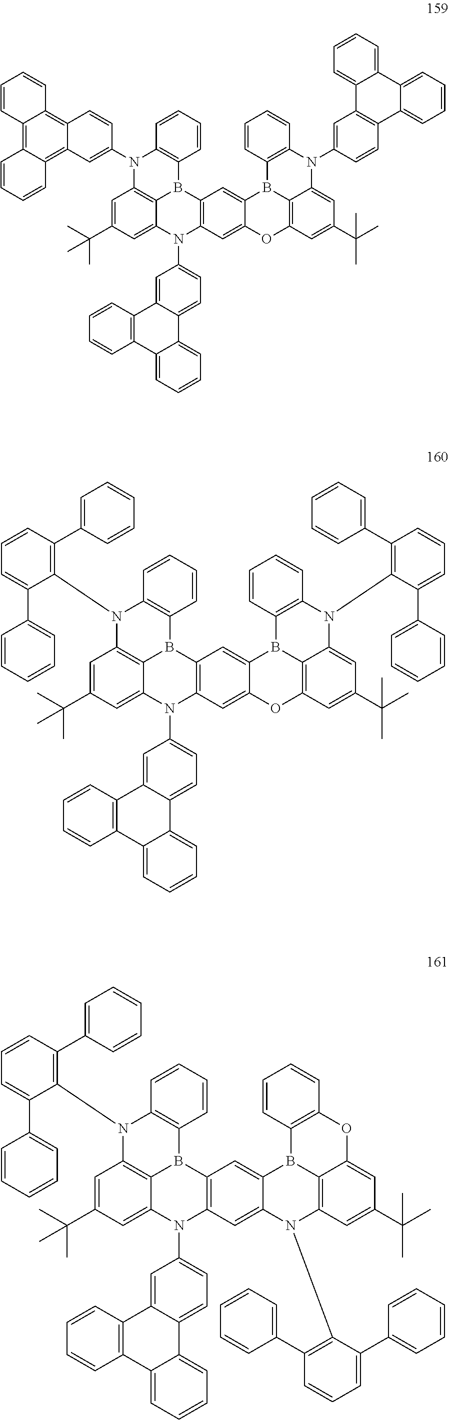 [SMILES: CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1 ; CC(C)(C)c1cc2c3c(c1)N(c1c(-c4ccccc4)cccc1-c1ccccc1)c1ccccc1B3c1cc3c(cc1O2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1O2)B1c2ccccc2N(c2c(-c3ccccc3)cccc2-c2ccccc2)c2cc(C(C)(C)C)cc(c21)N4c1ccc2c3ccccc3c3ccccc3c2c1]

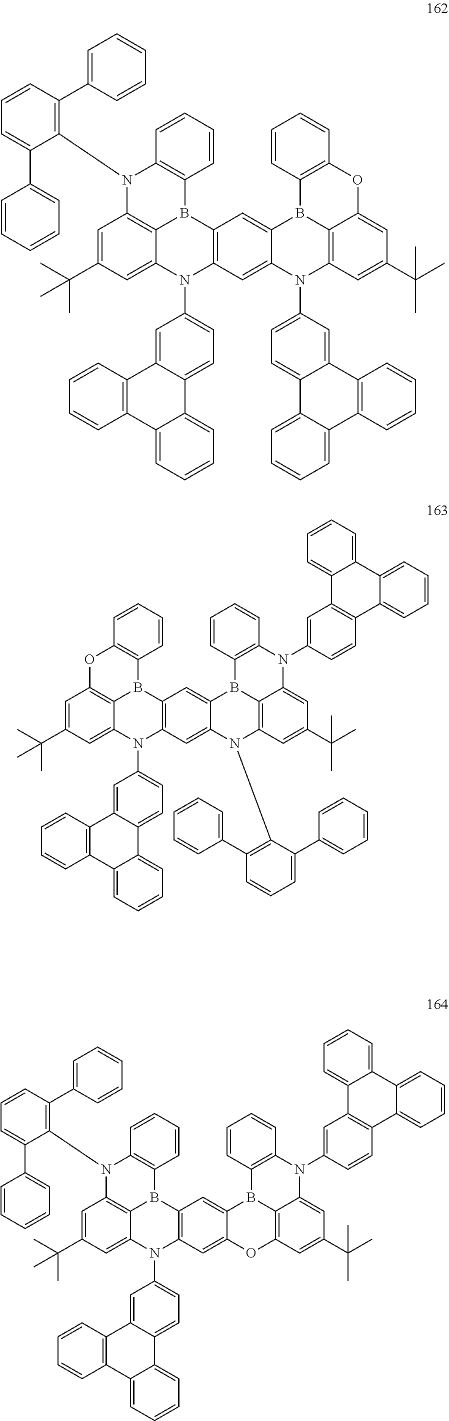

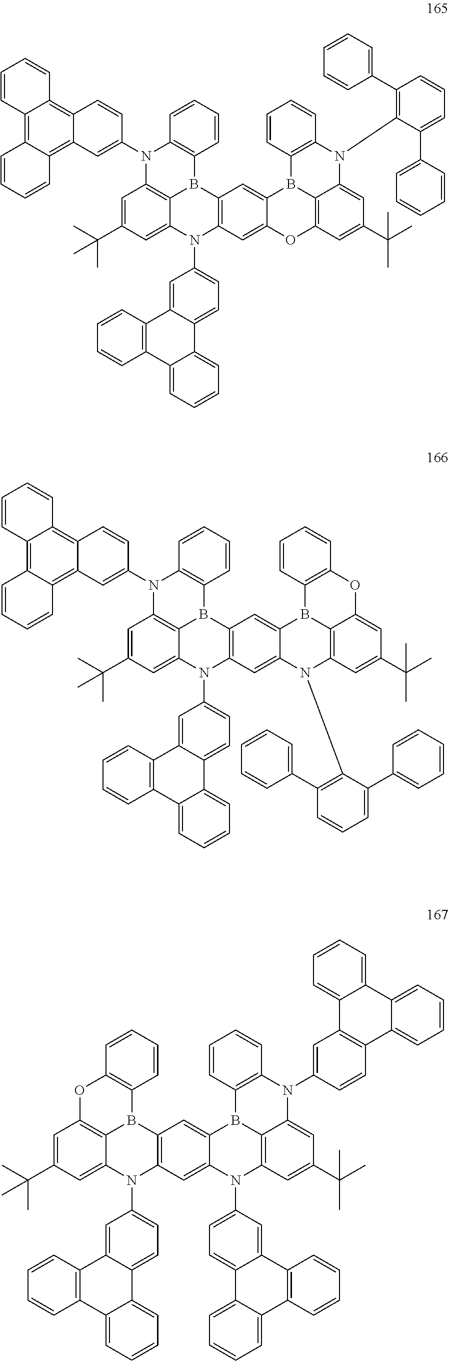 [SMILES: CC(C)(C)c1cc2c3c(c1)N(c1c(-c4ccccc4)cccc1-c1ccccc1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1 ; CC(C)(C)c1cc2c3c(c1)N(c1c(-c4ccccc4)cccc1-c1ccccc1)c1cc4c(cc1B3c1ccccc1O2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1O2)B1c2ccccc2N(c2ccc3c5ccccc5c5ccccc5c3c2)c2cc(C(C)(C)C)cc(c21)N4c1ccc2c3ccccc3c3ccccc3c2c1]

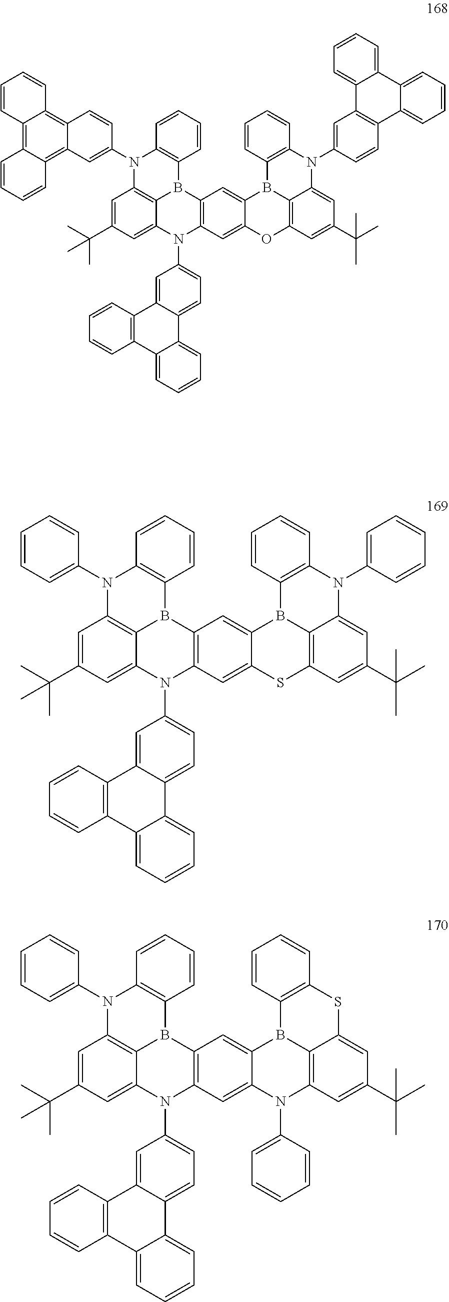 [SMILES: CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1 ; CC(C)(C)c1cc2c3c(c1)N(c1ccccc1)c1ccccc1B3c1cc3c(cc1S2)N(c1ccc2c4ccccc4c4ccccc4c2c1)c1cc(C(C)(C)C)cc2c1B3c1ccccc1N2c1ccccc1 ; CC(C)(C)c1cc2c3c(c1)N(c1ccccc1)c1cc4c(cc1B3c1ccccc1S2)B1c2ccccc2N(c2ccccc2)c2cc(C(C)(C)C)cc(c21)N4c1ccc2c3ccccc3c3ccccc3c2c1]

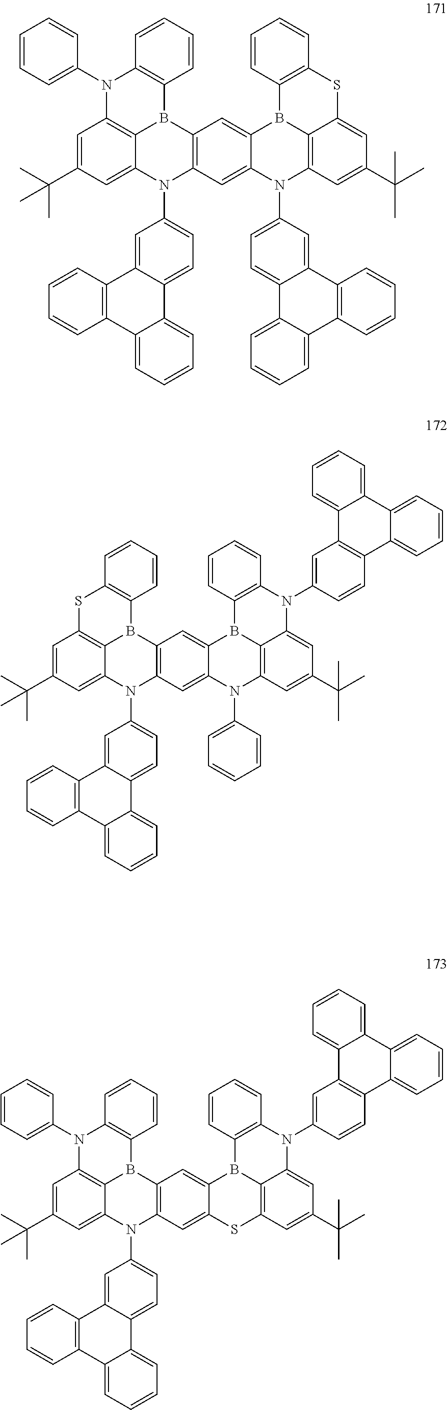

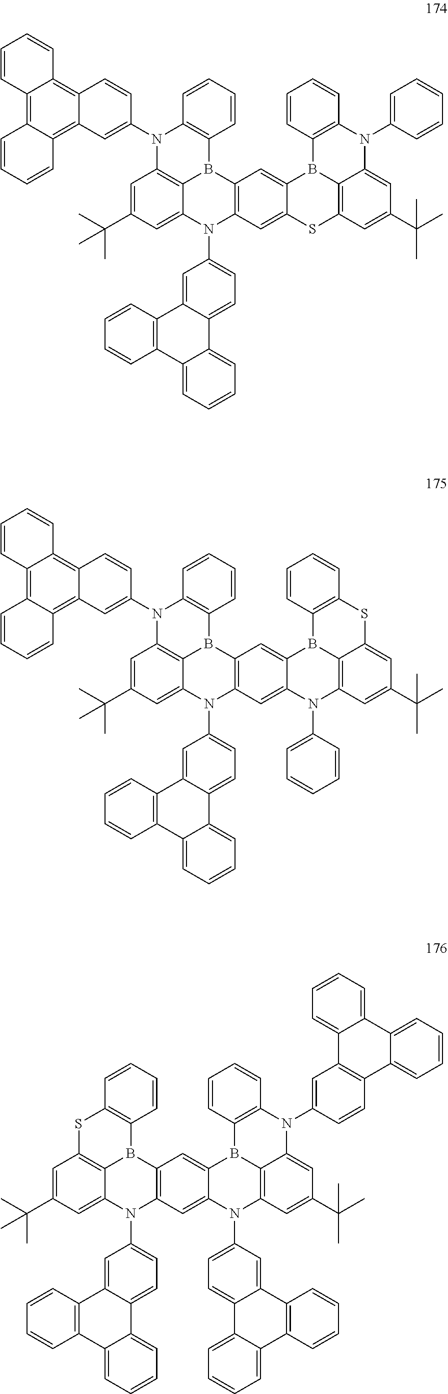

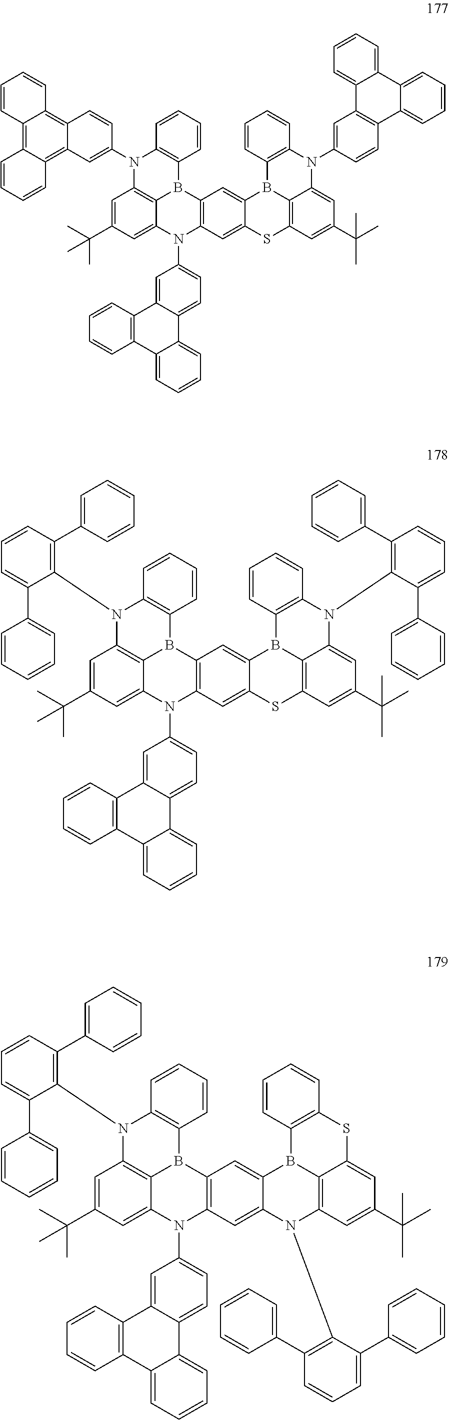 [SMILES: CC(C)(C)c1cc2c3c(c1)N(c1ccc4c5ccccc5c5ccccc5c4c1)c1ccccc1B3c1cc3c(cc1S2)N(c1ccc2c4ccccc4c4ccccc4c2c1)c1cc(C(C)(C)C)cc2c1B3c1ccccc1N2c1ccc2c3ccccc3c3ccccc3c2c1 ; CC(C)(C)c1cc2c3c(c1)N(c1c(-c4ccccc4)cccc1-c1ccccc1)c1ccccc1B3c1cc3c(cc1S2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1S2)B1c2ccccc2N(c2c(-c3ccccc3)cccc2-c2ccccc2)c2cc(C(C)(C)C)cc(c21)N4c1ccc2c3ccccc3c3ccccc3c2c1]

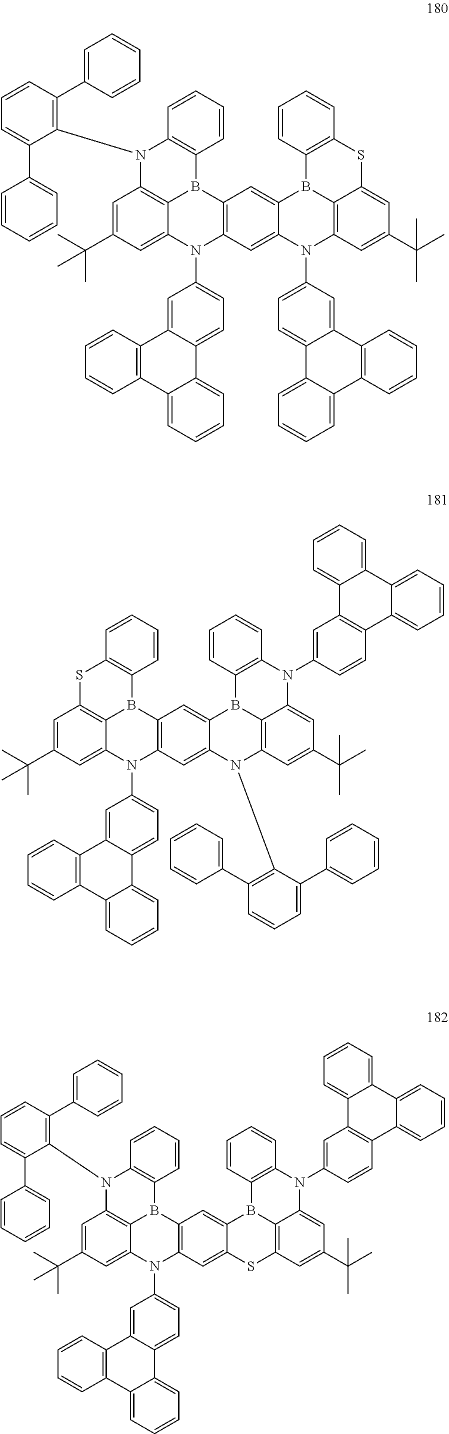

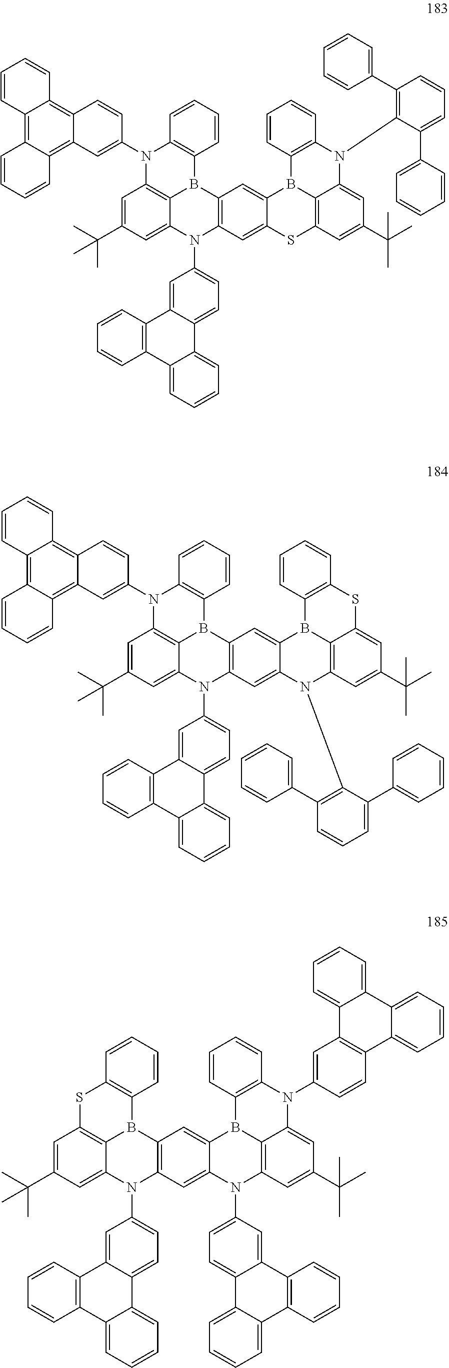 [SMILES: CC(C)(C)c1cc2c3c(c1)N(c1c(-c4ccccc4)cccc1-c1ccccc1)c1ccccc1B3c1cc3c(cc1S2)N(c1ccc2c4ccccc4c4ccccc4c2c1)c1cc(C(C)(C)C)cc2c1B3c1ccccc1N2c1ccc2c3ccccc3c3ccccc3c2c1 ; CC(C)(C)c1cc2c3c(c1)N(c1c(-c4ccccc4)cccc1-c1ccccc1)c1cc4c(cc1B3c1ccccc1S2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1S2)B1c2ccccc2N(c2ccc3c5ccccc5c5ccccc5c3c2)c2cc(C(C)(C)C)cc(c21)N4c1ccc2c3ccccc3c3ccccc3c2c1]

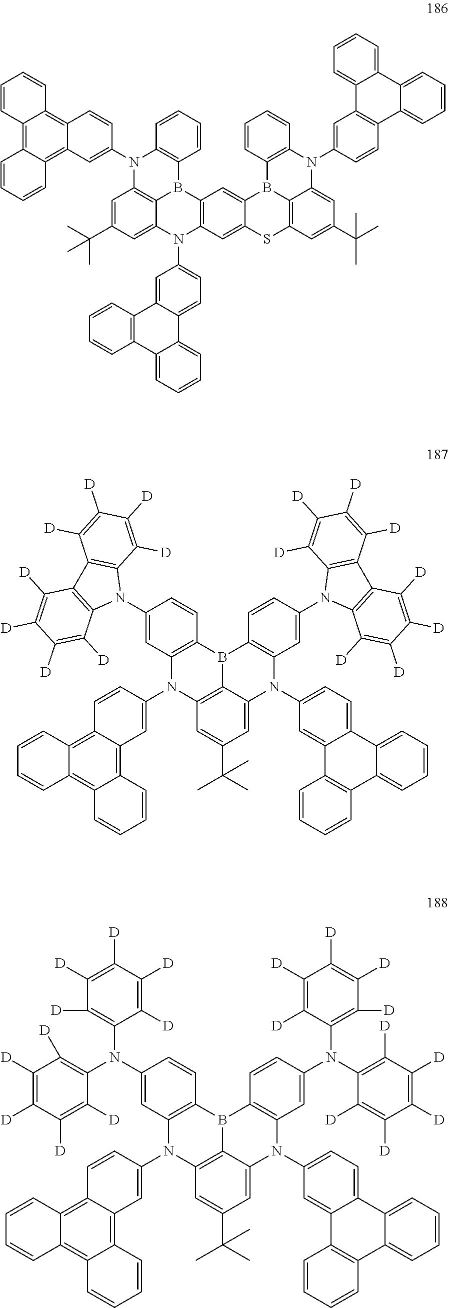

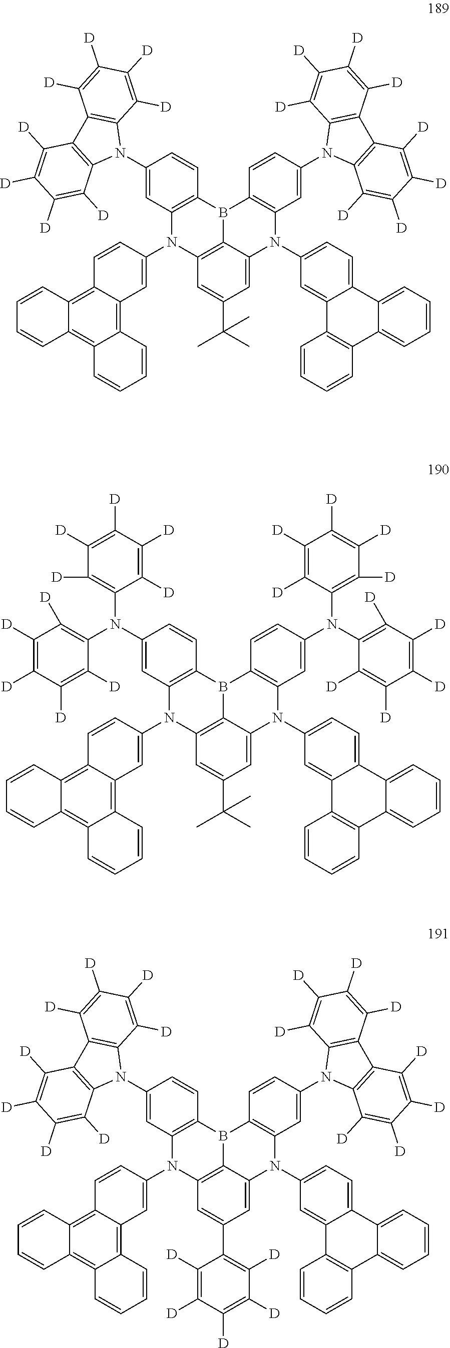

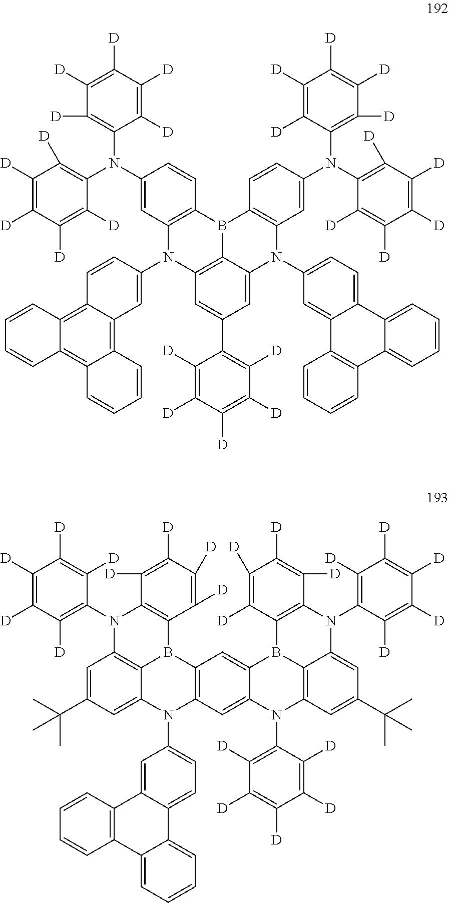

The polycyclic compound according to an embodiment may include a fused ring core moiety that includes a boron atom as a ring-forming atom and at least one triphenylenyl group as a substituent or as a fused ring moiety, and thus have a steric shielding effect, thereby exhibiting excellent stability characteristics. The polycyclic compound according to an embodiment may be used as a material for a light emitting element, thereby improving service life characteristics of the light emitting element.

The polycyclic compound according to embodiments may be included in the emission layer EML. The polycyclic compound according to embodiments may be included as a dopant material in the emission layer EML. The polycyclic compound according to embodiments may be a thermally activated delayed fluorescence material. The polycyclic compound according to embodiments may serve as a thermally activated delayed fluorescence dopant. For example, in the light emitting element ED according to an embodiment, the emission layer EML may include, as a thermally activated delayed fluorescence dopant, at least one polycyclic each independently selected from Compound Group 1 as described herein. However, a use of the polycyclic compound according to embodiments is not limited thereto.

The polycyclic compound according to an embodiment may emit blue light, and may have a maximum emission wavelength around 460 nm. The polycyclic compound according to an embodiment may emit pure blue light having a maximum emission wavelength around 460 nm.

In an embodiment, the emission layer EML may include: the first compound represented by Formula 1; and at least one of the second compound represented by Formula HT-1, the third compound represented by Formula ET-1, or the fourth compound represented by Formula M-b.

For example, the second compound according to an embodiment may serve as a hole transport host material of the emission layer EML.

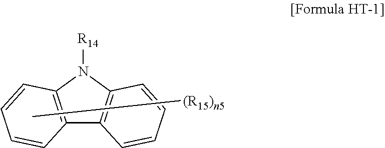

In Formula HT-1, R₁₄ and R₁₅ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, in an embodiment, R₁₄ may be a substituted phenyl group, an unsubstituted dibenzofuran group, or a substituted fluorenyl group. In an embodiment, R₁₅ may be a substituted or unsubstituted carbazole group.

In Formula HT-1, n5 may be an integer from 0 to 8. When n5 is 2 or more, multiple R₁₅ groups may be the same as each other or at least one may be different from the others.

The second compound may be selected from Compound Group 2. The light emitting element ED according to an embodiment may include any compound selected from Compound Group 2:

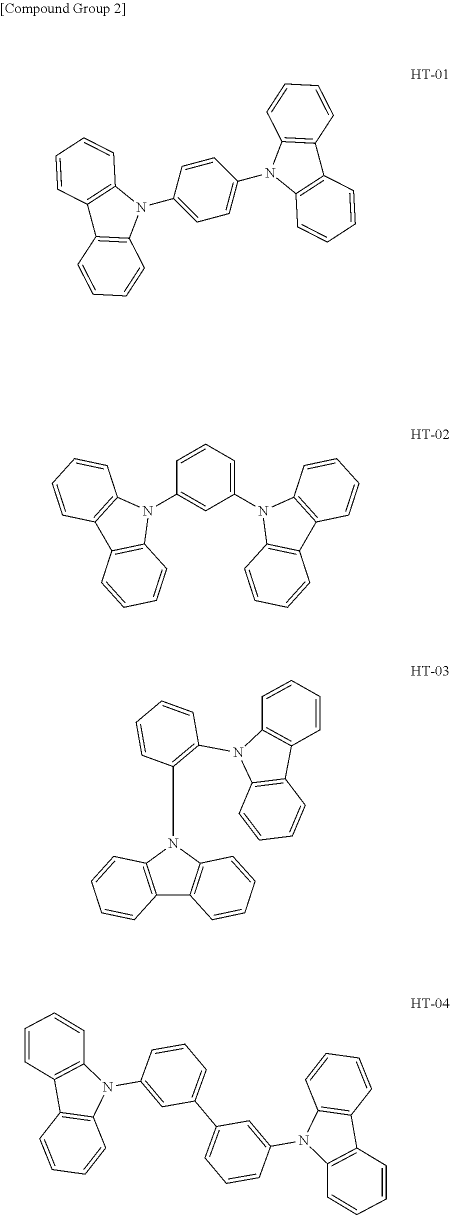 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc(-n2c3ccccc3c3ccccc32)c(-n2c3ccccc3c3ccccc32)c1 ; c1cc(-c2cccc(-n3c4ccccc4c4ccccc43)c2)cc(-n2c3ccccc3c3ccccc32)c1]

In an embodiment, the emission layer EML may include the third compound represented by Formula ET-1. For example, the third compound may serve as an electron transport host material of the emission layer EML.

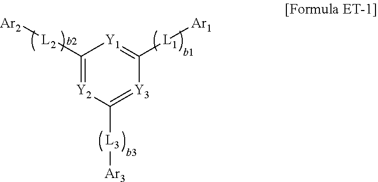

In Formula ET-1, at least one of Yi to Y₃ may be N, and the remainder of Yi to Y₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, A₁ to Ar₃ may each independently be a substituted or unsubstituted phenyl group, or a substituted or unsubstituted carbazole group.

The third compound may be selected from Compound Group 3. The light emitting element ED according to an embodiment may include any of Compounds ET22 to ET36 in Compound Group 3:

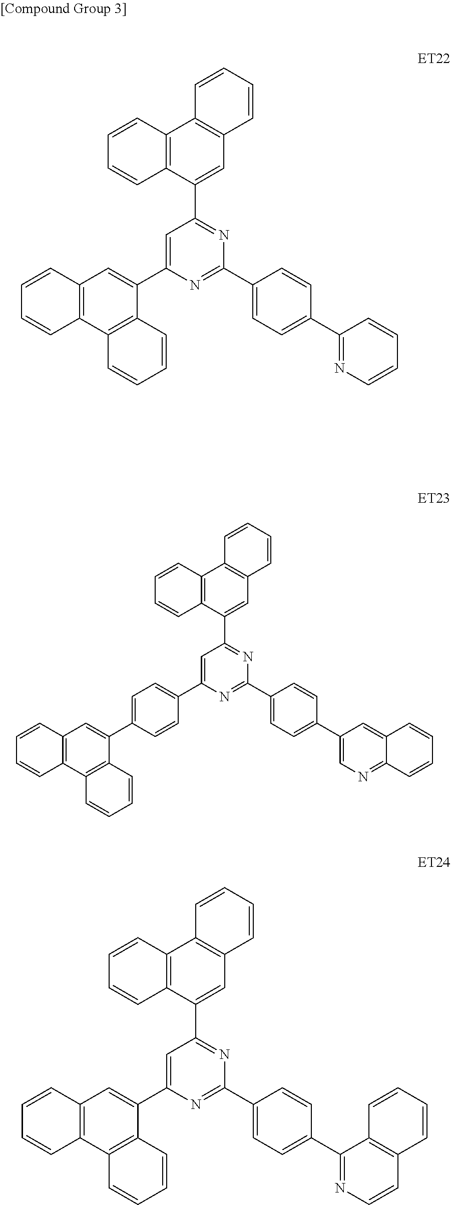 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

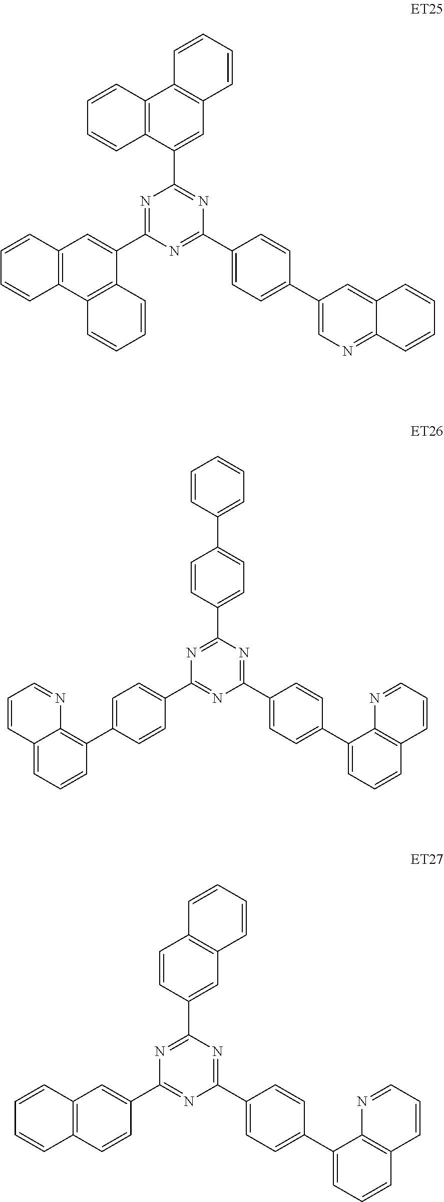 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

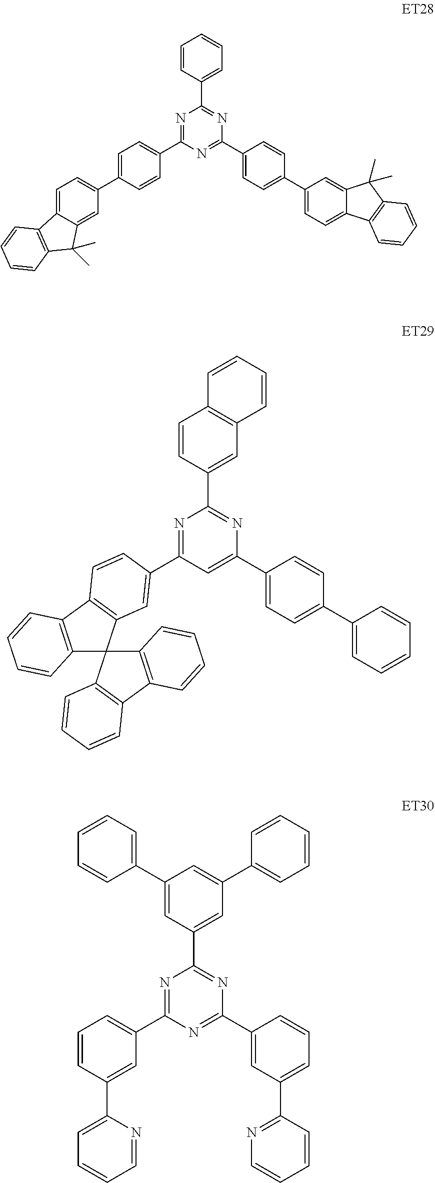 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

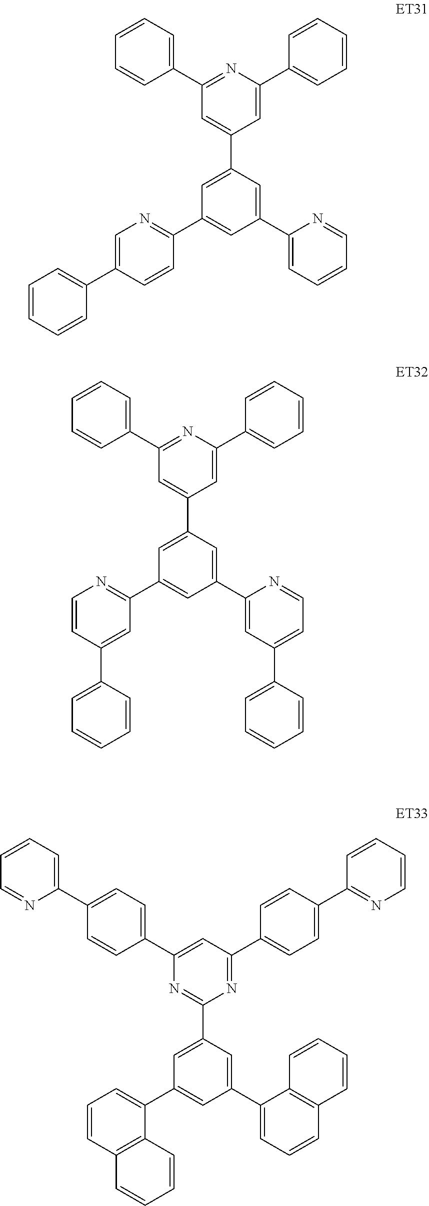 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

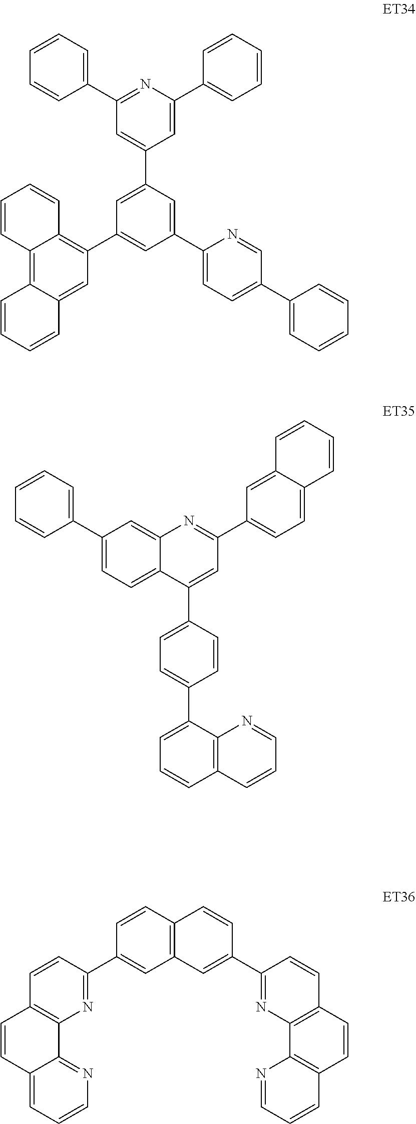 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

For example, the emission layer EML may include the second compound and the third compound, and the second compound and the third compound may form an exciplex. In the emission layer EML, an exciplex may be formed by a hole transport host and an electron transport host. In an embodiment, a triplet energy of the exciplex formed by the hole transport host and the electron transport host may correspond to a difference between a lowest unoccupied molecular orbital (LUMO) energy level of the electron transport host and a highest occupied molecular orbital (HOMO) energy level of the hole transport host.

For example, an absolute value of the triplet energy (T1) of the exciplex formed by the hole transport host and the electron transport host may be in a range of about 2.4 eV to about 3.0 eV. The triplet energy of the exciplex may be a value that is smaller than an energy gap of each host material. The exciplex may have a triplet energy equal to or less than about 3.0 eV that is smaller than an energy gap between the hole transport host and the electron transport host.

In an embodiment, the emission layer EML may include the fourth compound represented by Formula M-b. For example, the fourth compound may serve as a phosphorescent sensitizer of the emission layer EML. Energy may be transferred from the fourth compound to the first compound, thereby emitting light.

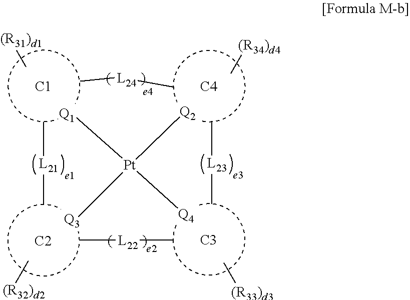

In Formula M-b, Q₁ to Q₄ may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

In Formula M-b, e1 to e4 may each independently be 0 or 1; and L21 to L24 may each independently be a direct linkage,

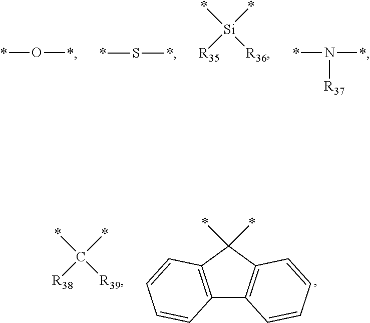

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. When d1 is 2 or more, multiple R₃₁ groups may be the same as each other or at least one may be different from the others. When d2 is 2 or more, multiple R₃₂ groups may be the same as each other or at least one may be different from the others. When d3 is 2 or more, multiple R₃₃ groups may be the same as each other or at least one may be different from the others. When d4 is 2 or more, multiple R₃₄ groups may be the same as each other or at least one may be different from the others.

In Formula M-b, R₃₁ to R₃₉ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

The fourth compound may be selected from Compound Group 4. The light emitting element ED according to an embodiment may include any compound selected from Compound Group 4:

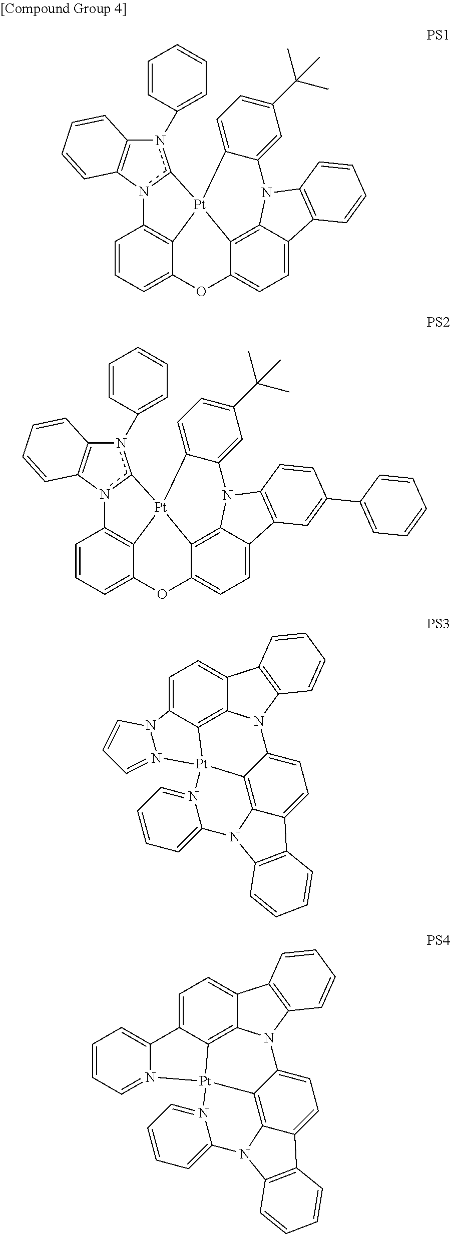

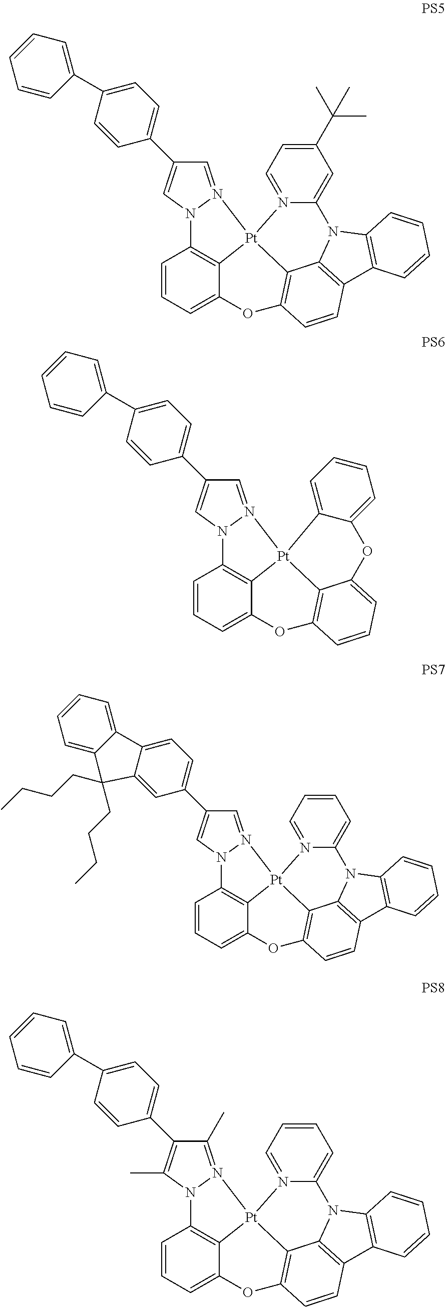

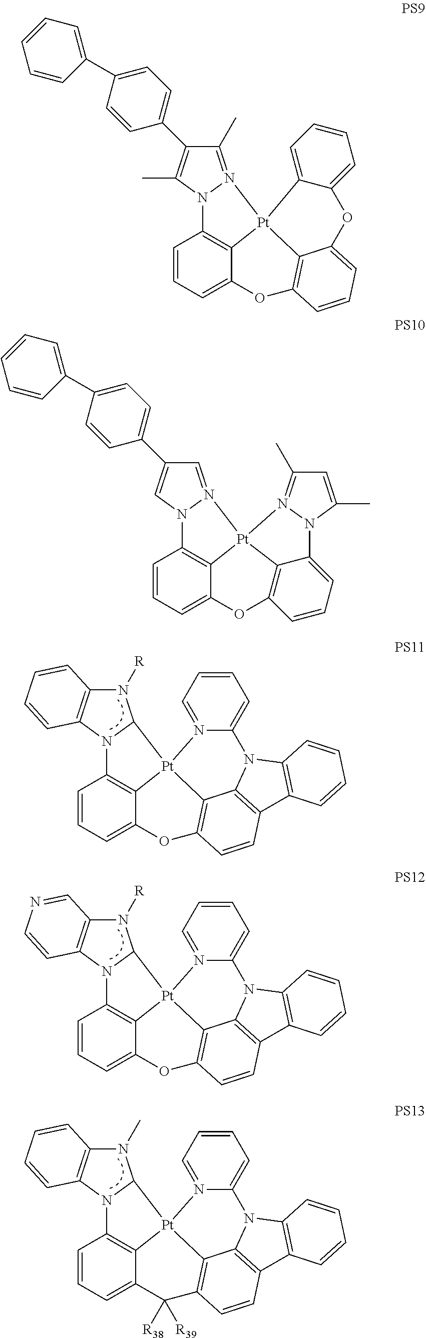

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML according to an embodiment may include the first compound, and at least one of the second to fourth compounds. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. The fourth compound may serve as a phosphorescent sensitizer. The fourth compound may emit phosphorescence or may transfer energy to the first compound as an auxiliary dopant. However, the functions of the fourth compound presented herein are only examples, and embodiments are not limited thereto.

The emission layer EML may further include a material of the related art in the emission layer, in addition to the first to fourth compounds described above. In the light emitting element ED according to an embodiment, the emission layer EML may further include an anthracene derivative, a pyrene derivative, a fluoranthene derivative, a chrysene derivative, a dihydrobenzanthracene derivative, a triphenylene derivative, or the like. For example, the emission layer EML may further include an anthracene derivative or a pyrene derivative.

In each light emitting element ED according to embodiments illustrated in FIGS. 3 to 6, the emission layer EML may include a compound represented by Formula E-1. The compound represented by Formula E-1 may be used as a fluorescent host material.

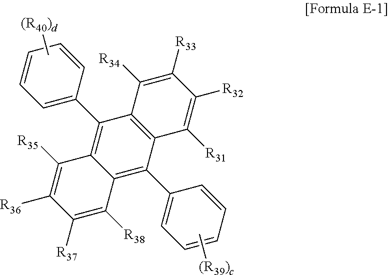

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

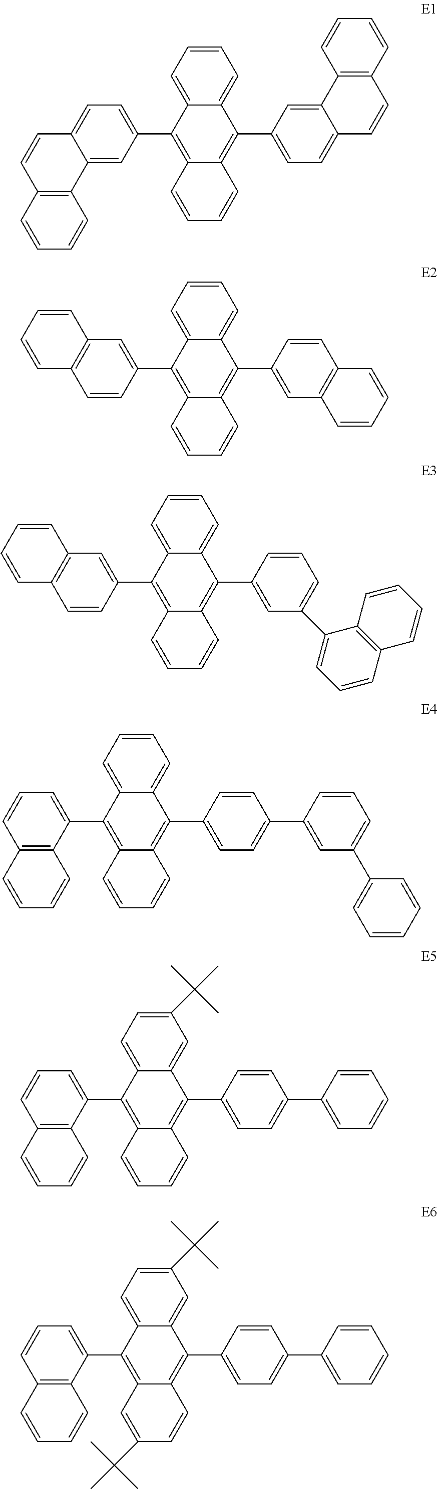

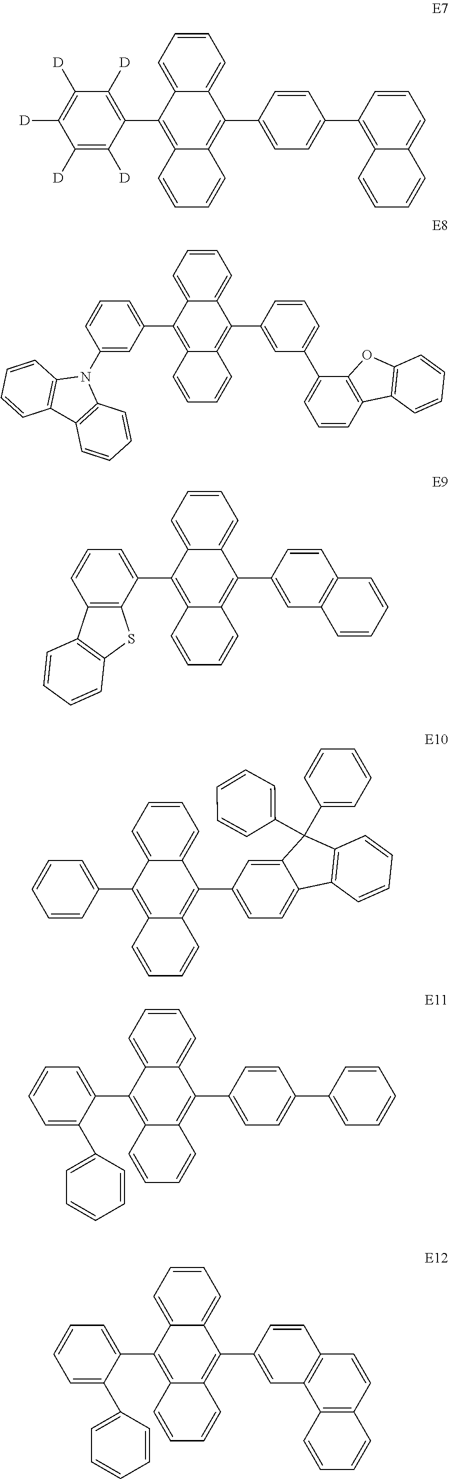

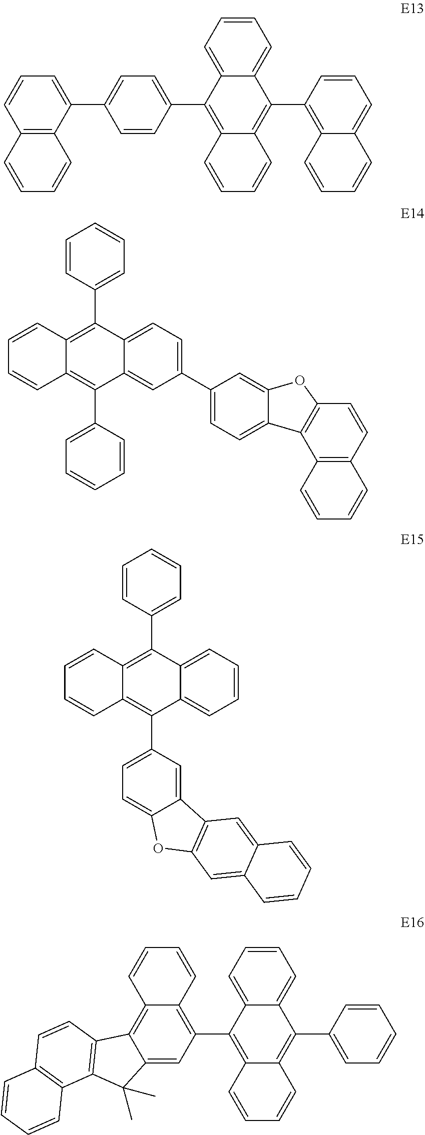

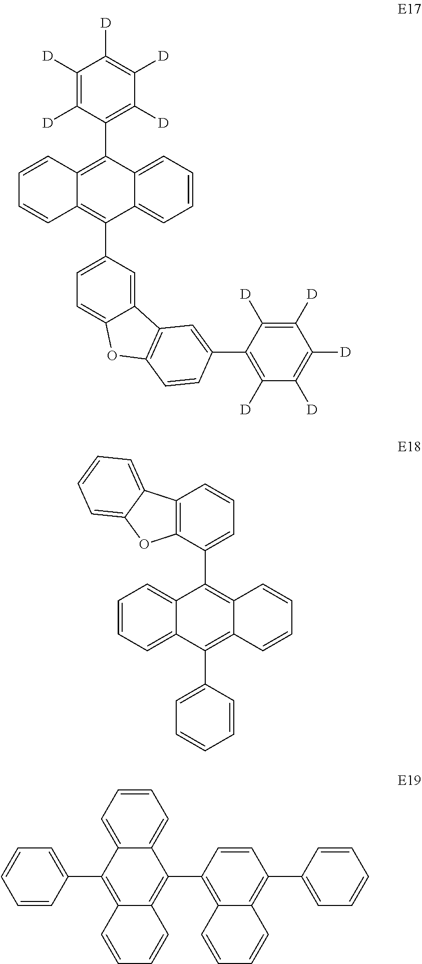

In an embodiment, the emission layer EML may include a compound represented by Formula E-2a or Formula E-2b. The compound represented by Formula E-2a or Formula E-2b may be used as a phosphorescent host material.

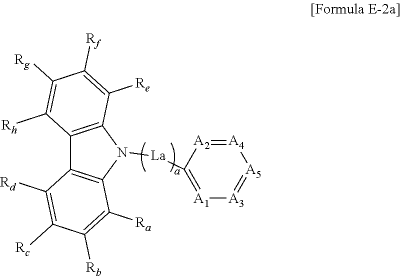

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle including N, O, S, etc. as a ring-forming atom.

In Formula E-2a, two or three of A₁ to A5 may each be N, and the remainder of A₁ to A5 may each independently be C(Rᵢ).

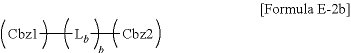

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

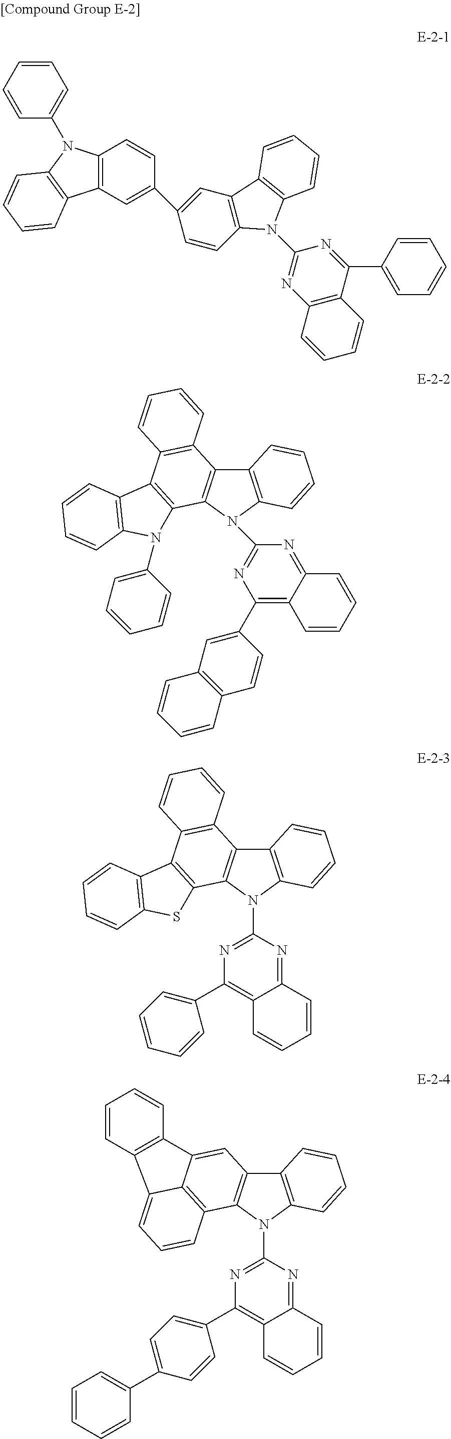

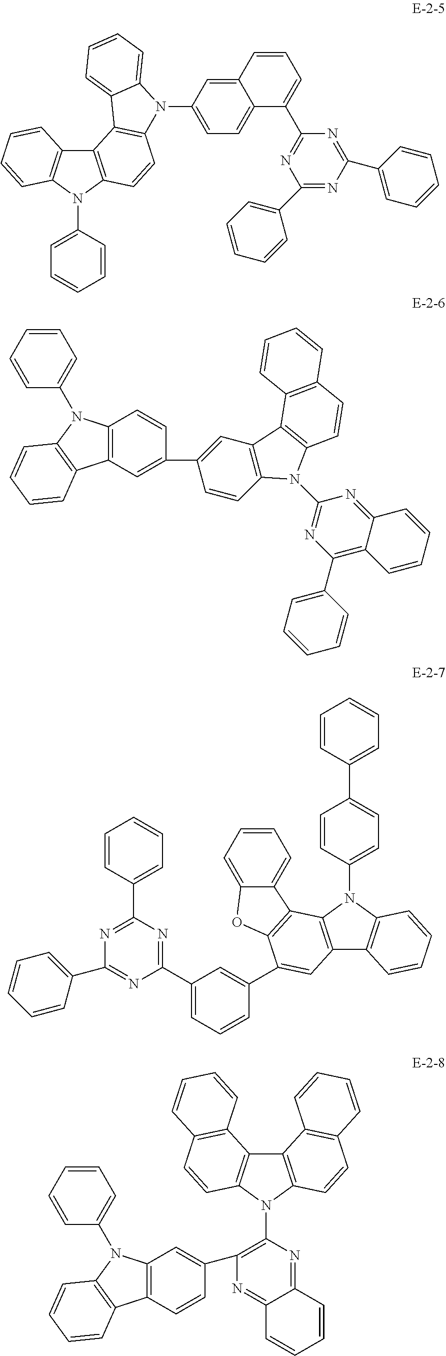

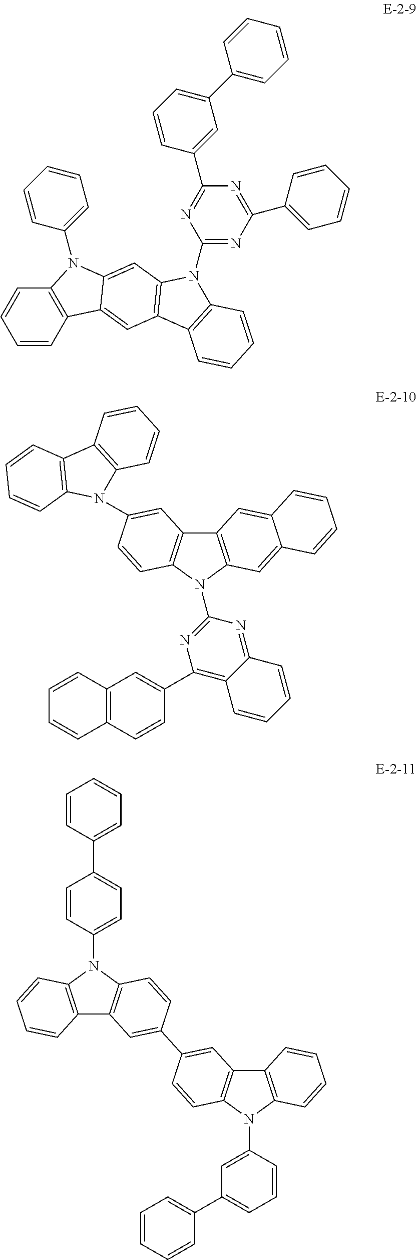

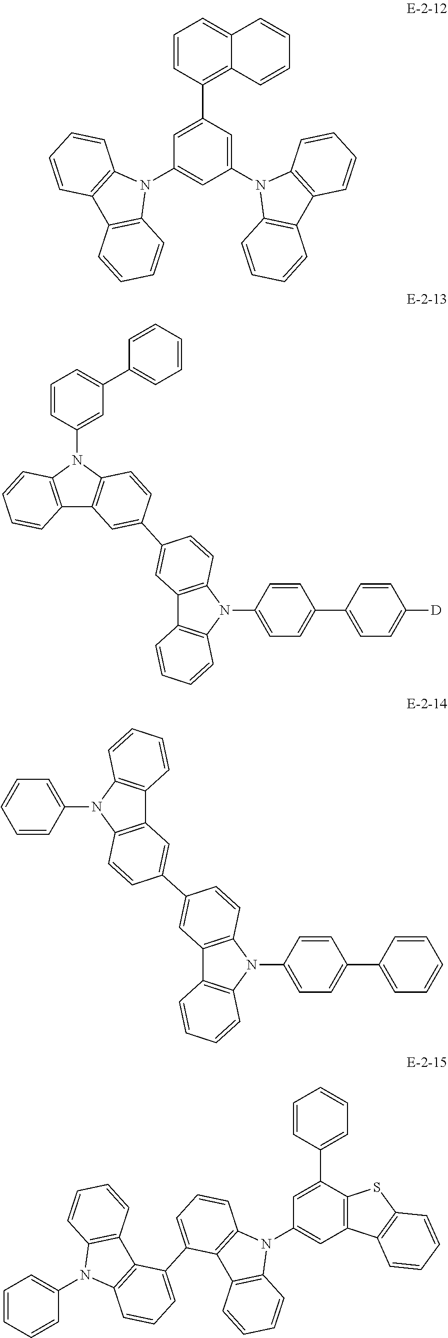 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

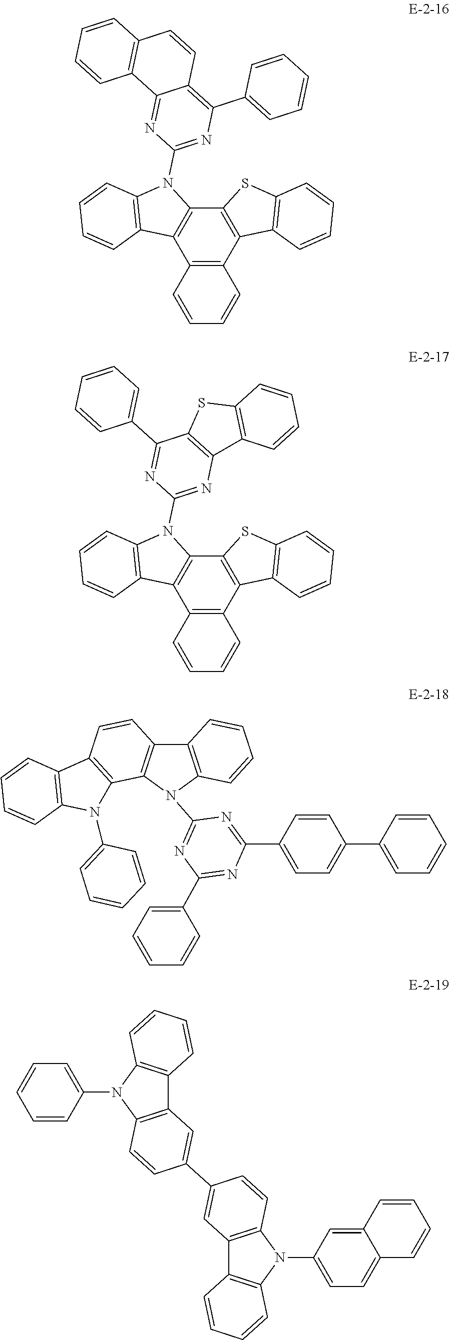

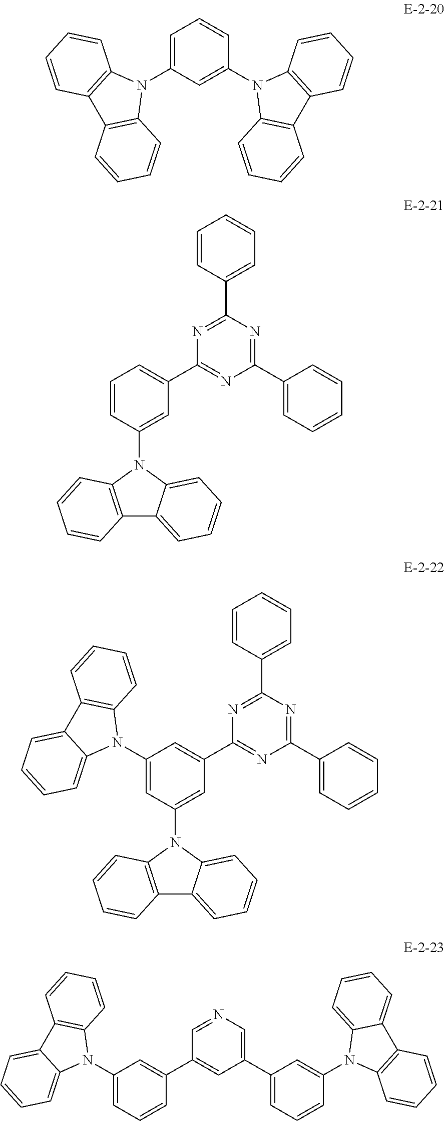

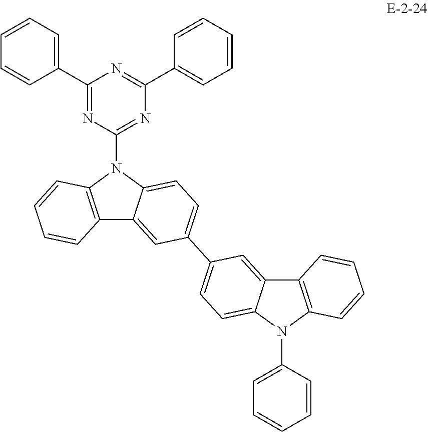 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2, 8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9, 10-di(naphth-2-yl)anthracene (TBADN), distyrylarylene (DSA), 4,4′-bis(9-carbazolyl)-2,2′-dimethyl-biphenyl (CDBP), 2-methyl-9, 10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DP SiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material. In an embodiment, the compound represented by Formula M-a may be used as an auxiliary dopant material.

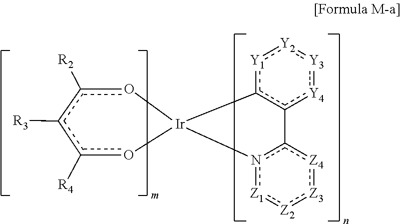

In Formula M-a, Y₁ to Y₄ and Z₁ to Z₄ may each independently be C(Ri) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

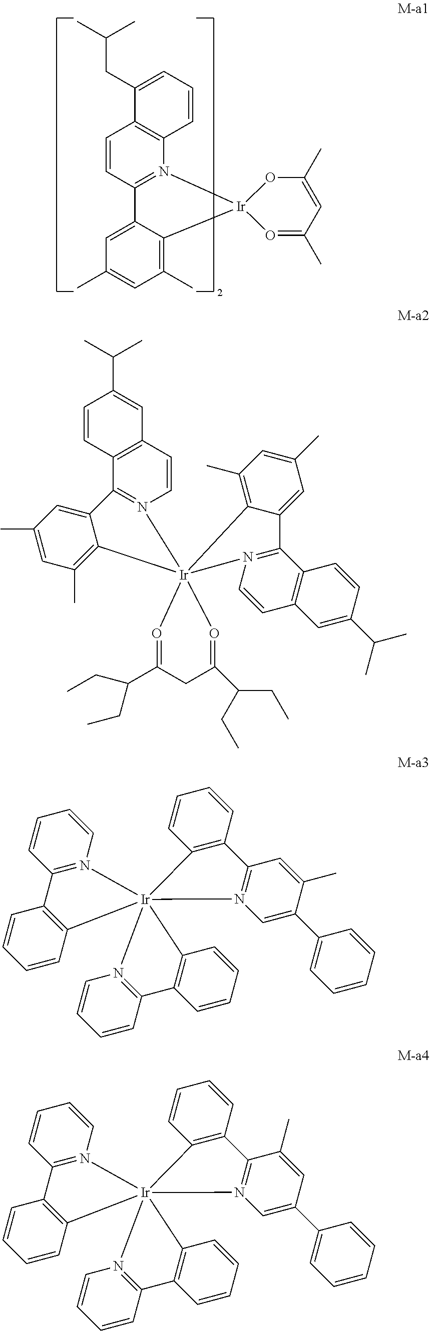

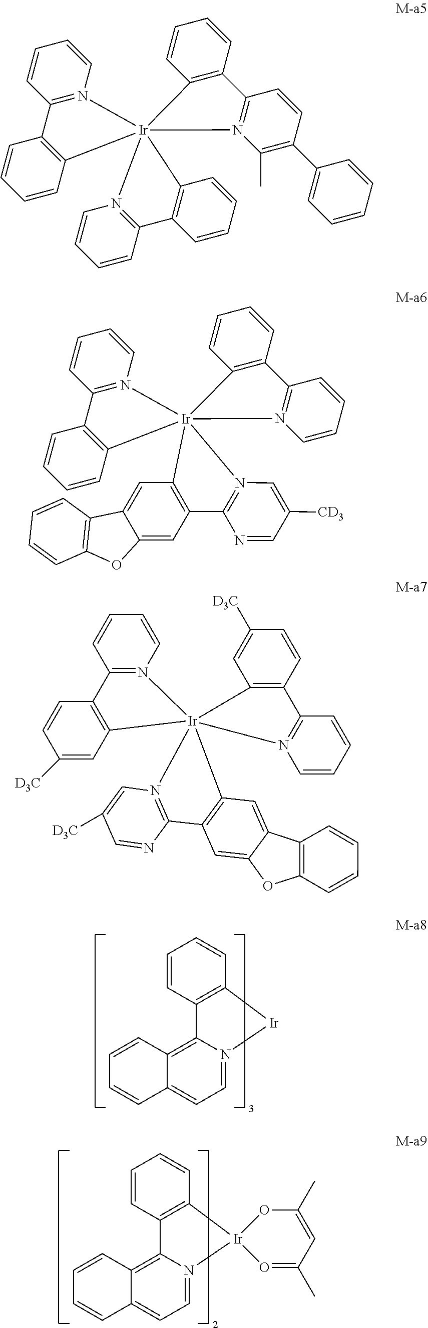

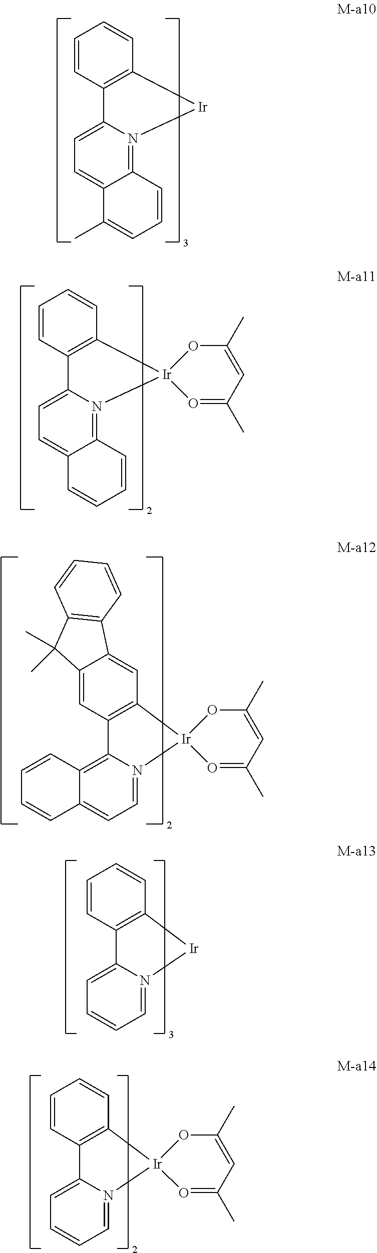

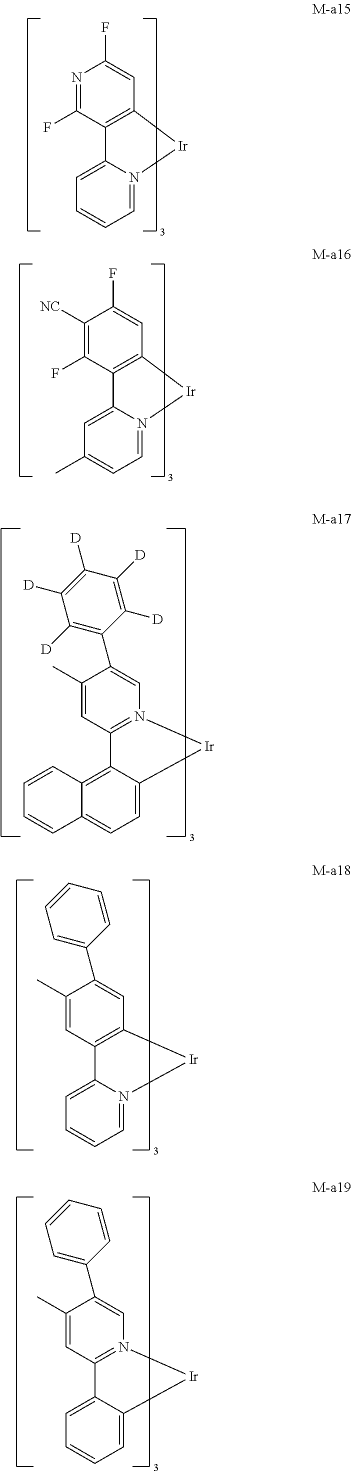

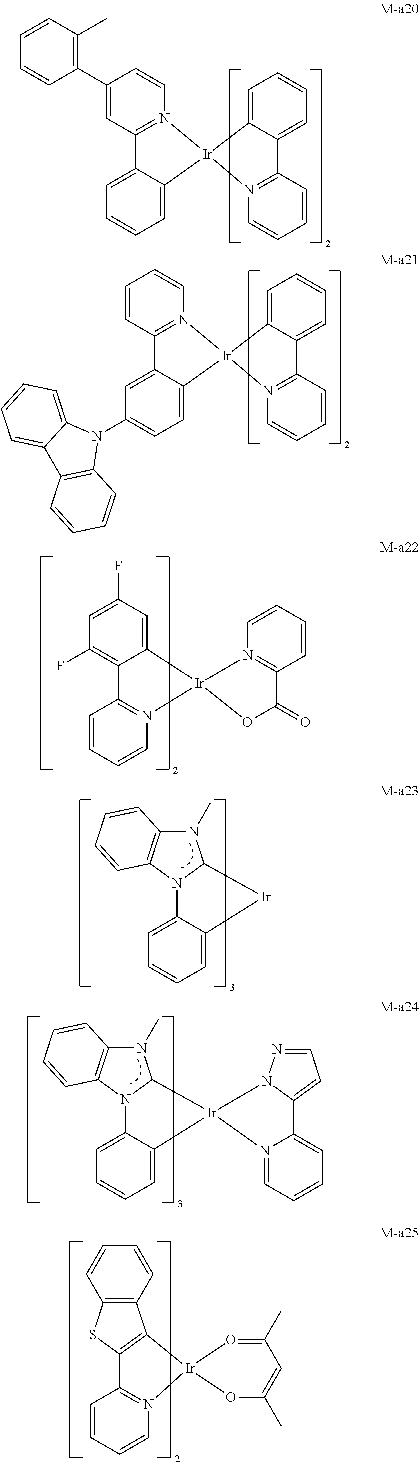

Compound M-a1 and Compound M-a2 may each be used as a red dopant material, and Compound M-a3 to Compound M-a7 may each be used as a green dopant material.

The emission layer EML may further include a compound represented by one of Formula F-a to Formula F-c. The compound represented by one of Formula F-a to Formula F-c may be used as a fluorescence dopant material.

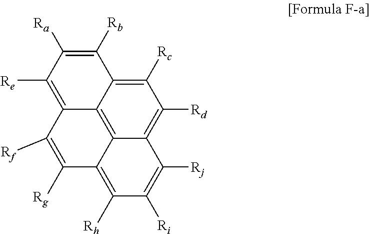

In Formula F-a, two of Rₐ to may each independently be substituted with a group represented by [symbol] NAr₁Ar₂. In Formula F-a, the remainder of Rₐ to Rⱼ which are not substituted with the group represented by [symbol] NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the group represented by [symbol] NAr₁Ar₂ Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group including O or S as a ring-forming atom.

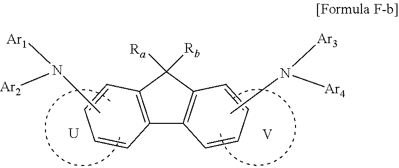

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

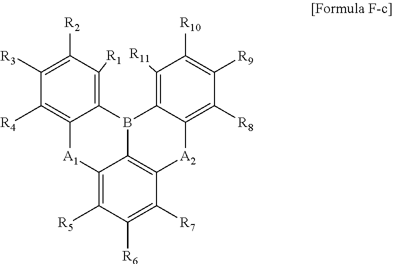

In Formula F-c, A₁ and A₂ may each independently be O, S, Se, or N(Rm); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a condensed ring. For example, when A₁ and A2 are each independently N(Rm), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl] stilbene (DPAVB), and N-(4-((E)-2-(6-((E)-4-(diphenylamino)styryl)naphthalen-2-yl)vinyl)phenyl)-N-phenylbenzena mine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

In an embodiment, when a light emitting element ED includes multiple emission layers EML, at least one emission layer EML may include a phosphorescence dopant material of the related art. For example, a metal complex including iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, bis(4,6-difluorophenylpyridinato- C²N)(picolinate) iridium(III) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, at least one emission layer EML may include a quantum dot. The quantum dot may be a Group II-VI compound, a Group III-VI compound, a Group compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

The Group III-VI compound may include: a binary compound such as In2S3 or In2Se3; a ternary compound such as InGaS₃ or InGaSe3; or any combination thereof.

The Group compound may include: a ternary compound selected from the group consisting of AgInS, AgInS2, CuInS, CuInS₂, AgGaS2, CuGaS₂ CuGaO₂, AgGaO₂, AgAlO₂, and a mixture thereof; a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AINAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. The Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. The Group IV element may be selected from the group consisting of Si, Ge, and a mixture thereof. The Group IV compound may be a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which a quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core so as to maintain semiconductor properties, and/or may serve as a charging layer to impart electrophoretic properties to the quantum dot. The shell may be a single layer or a multilayer. An example of the shell of the quantum dot may include a metal oxide, a non-metal oxide, a semiconductor compound, or any combination thereof.

Examples of the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound such as MgAl₂O₄, CoFe₂O₄, NiFe₂O₄, and CoMn₂O₄, but embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in the above ranges. Light emitted through a quantum dot may be emitted in all directions, so that a wide viewing angle may be improved.

The form of the quantum dot is not limited and may be any form that is used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

The quantum dot may control the color of emitted light according to a particle size thereof. Accordingly, the quantum dot may have various light emission colors such as blue, red, and green.

In each of the light emitting elements ED according to embodiments as illustrated in FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure including multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula EE-1. The compound represented by Formula EE-1 may be the above-described third compound:

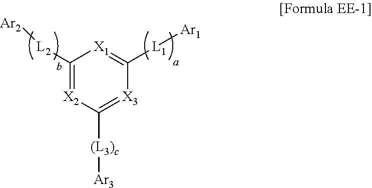

In Formula EE-1, at least one of X₁ to X₃ may be N, and the remainder of X₁ to X₃ may each independently be C(Rₐ). In Formula EE-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula EE-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula EE-1, a to c may each independently be an integer from 0 to 10. In Formula EE-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are 2 or more, multiple groups of L₁ to L3 may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9, 10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl -4H- 1,2,4-triazole (NTAZ), 2-(4-biphenylyl)-5-(4-tert-butylphenyl)-1,3,4-oxadiazole (tBu-PBD), bis(2-methyl-8-quinolinolato-N1, O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The electron transport region ETR may include at least one of Compound ET1 to Compound ET36:

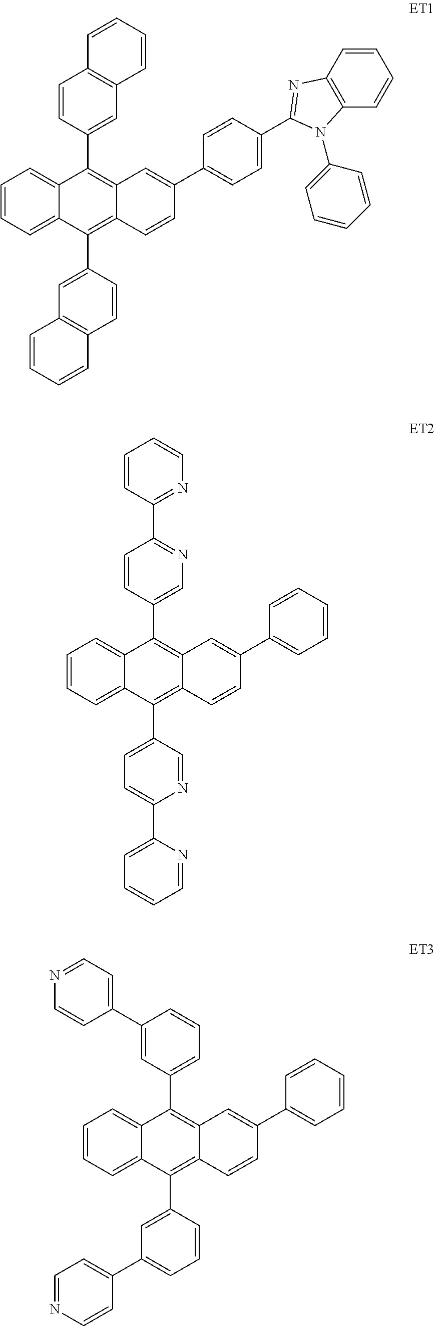 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

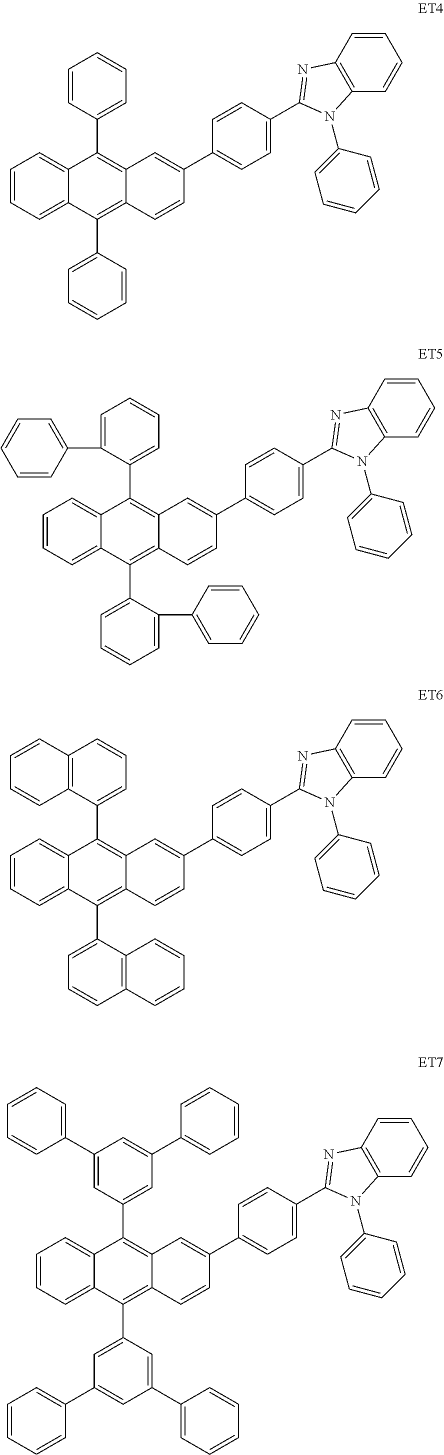 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

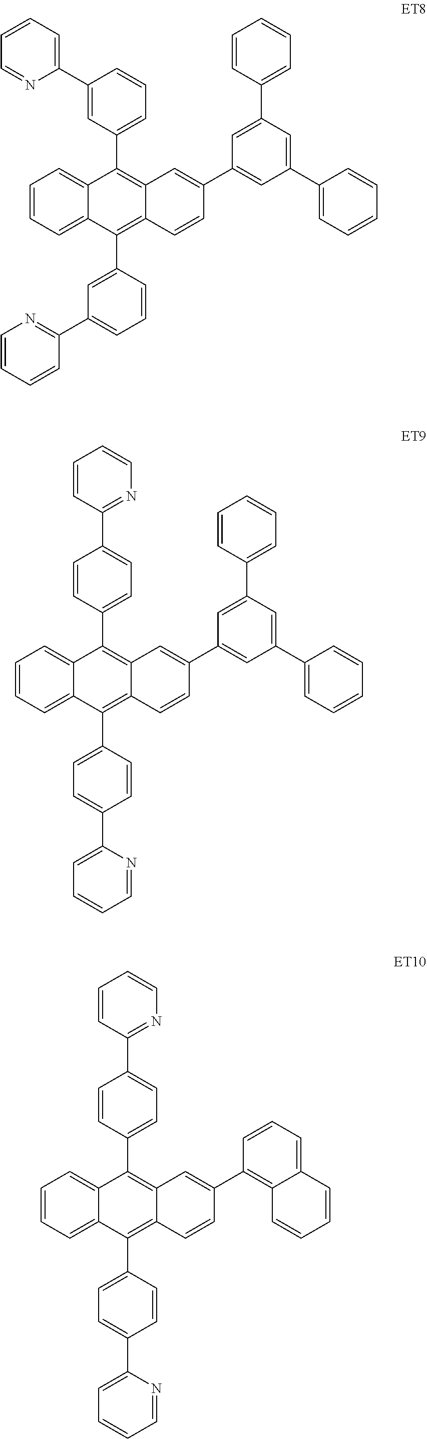 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

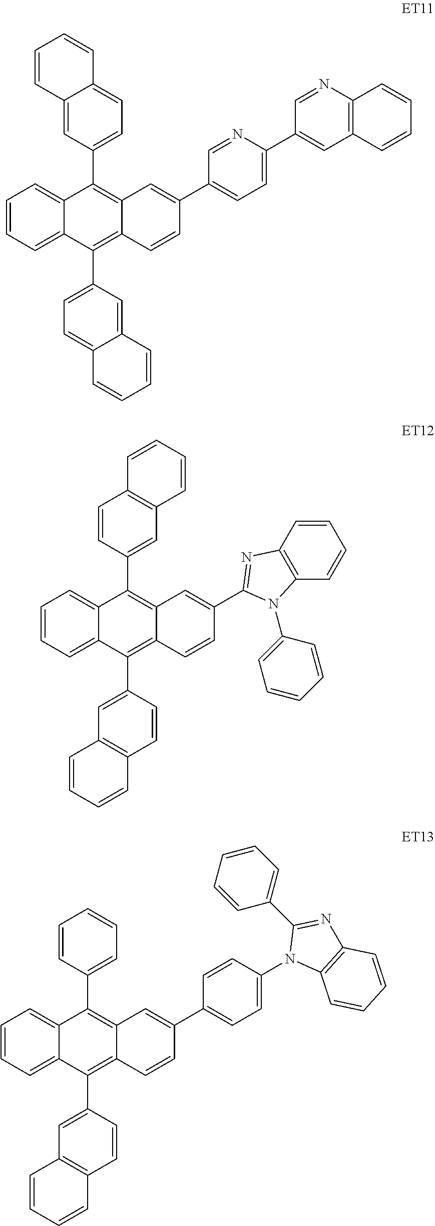 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

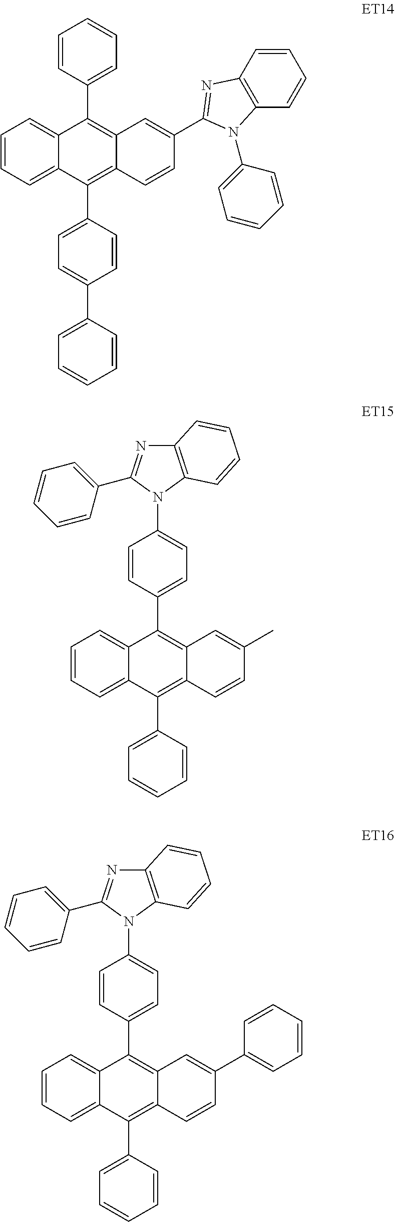 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

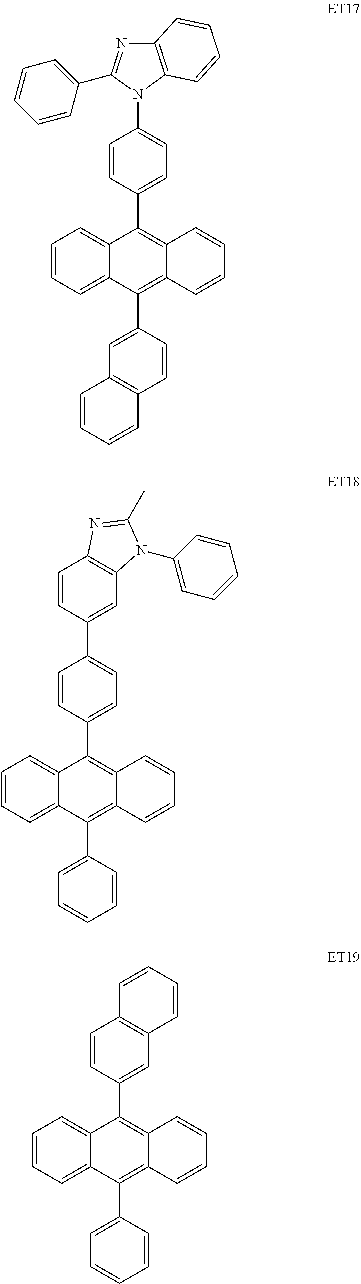

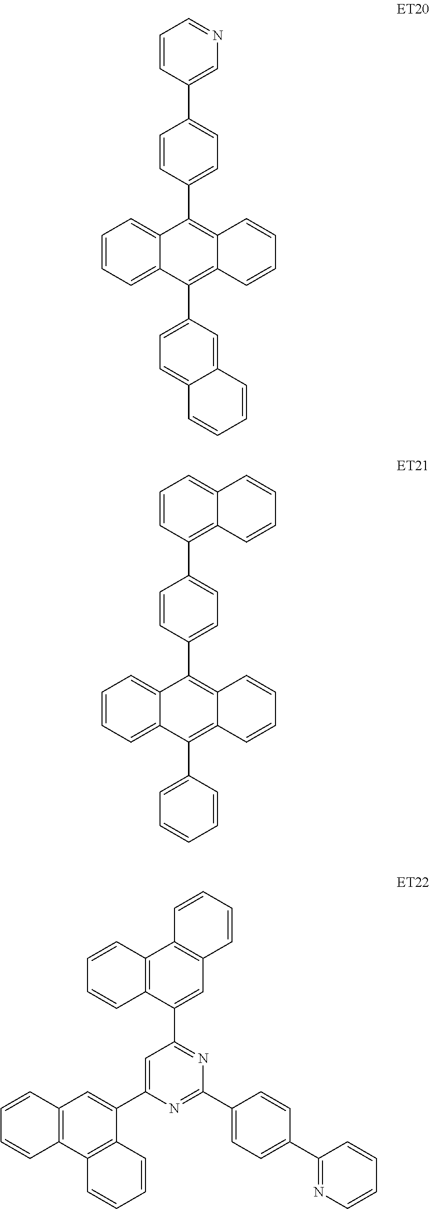

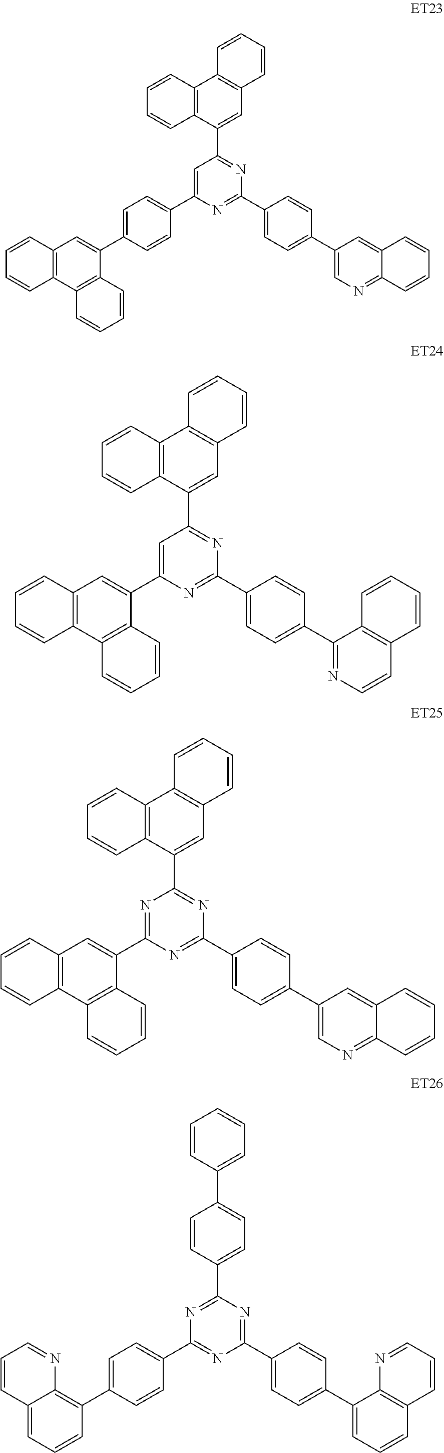 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

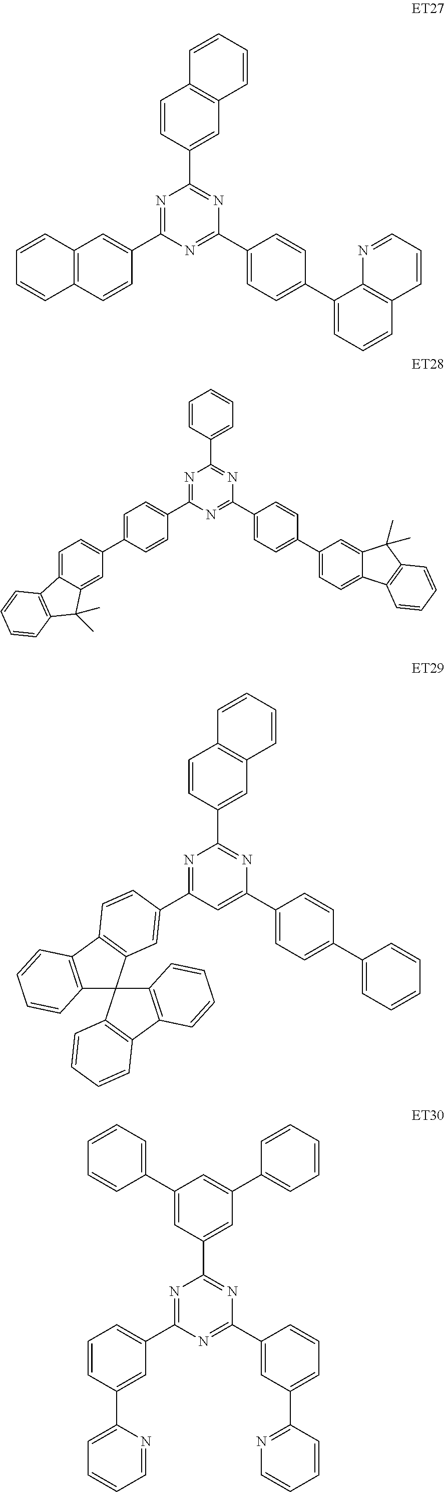

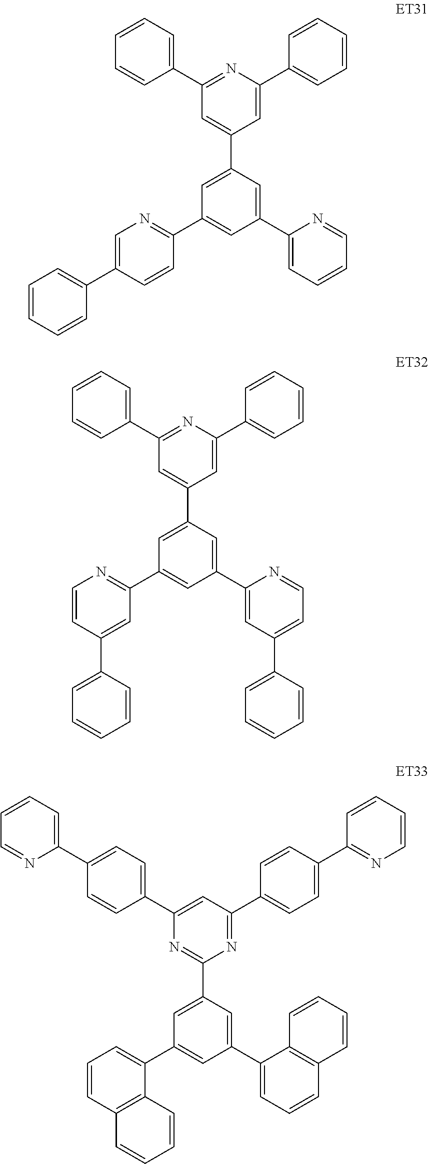 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

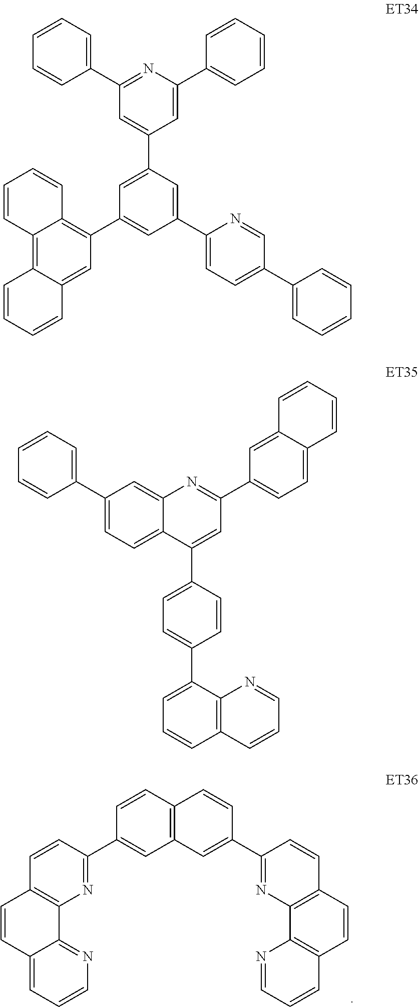

The electron transport region ETR may include: a metal halide such as LiF, NaCl, CsF, RbCl, RbI, CuI, or KI; a lanthanide metal such as Yb; or a co-deposited material of the metal halide and the lanthanide metal. For example, the electron transport region ETR may include KI:Yb, RbI:Yb, LiF:Yb, etc. as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenyl silyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to the auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (for example, LiF), an alkaline earth metal compound (for example, MgF₂), SiON, SiNₓ, SiOy, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD 15), 4,4′,4″-tri s(carbazol sol-9-yl)triphenylamine (TCTA), etc., or may include an epoxy resin, or an acrylate such as a methacrylate. However, embodiments are not limited thereto, and the capping layer CPL may include at least one of Compounds P1 to P5:

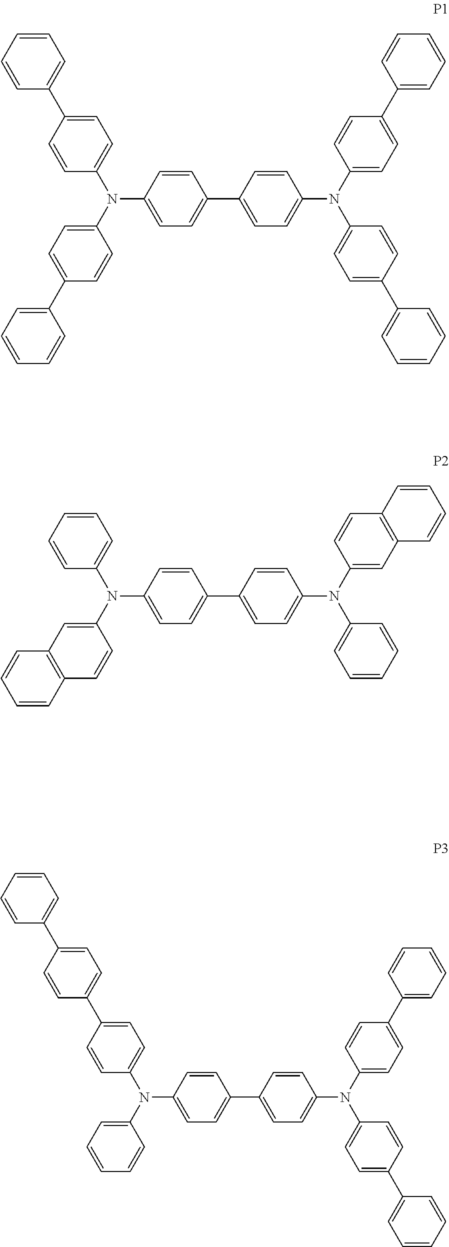 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

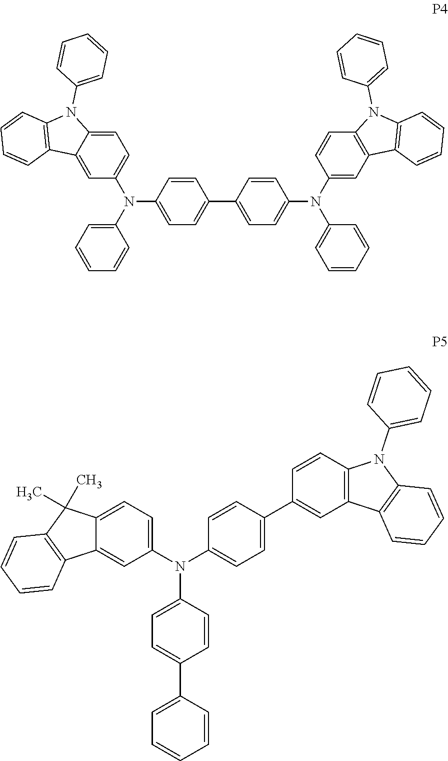 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6 with respect to light in a wavelength range of about 550 nm to about 660 nm.

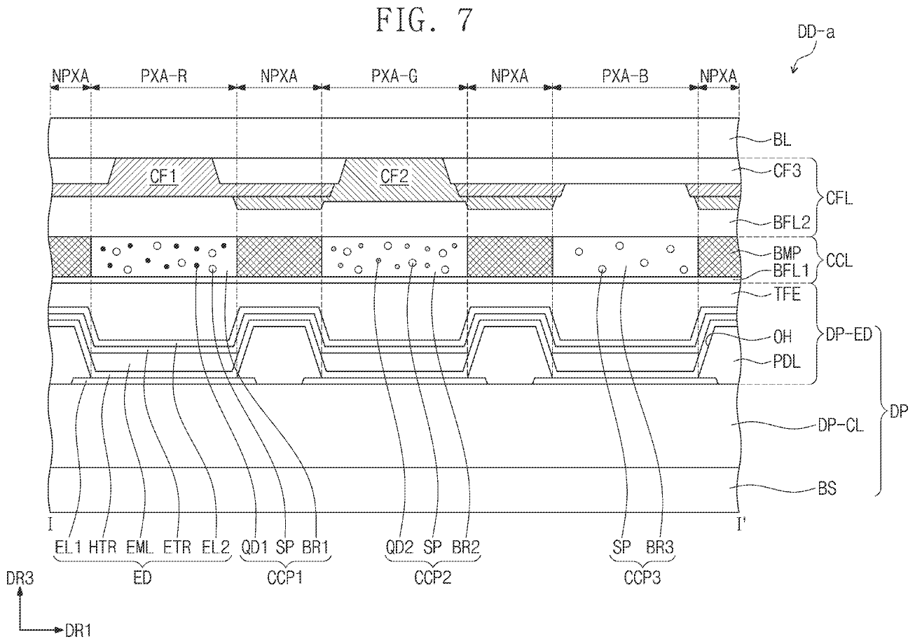

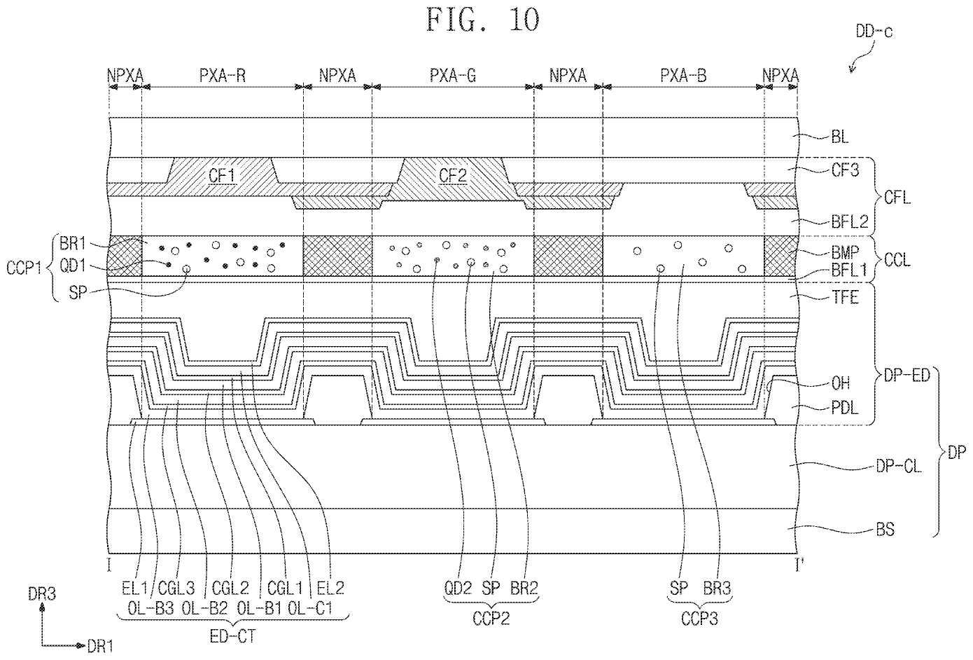

FIGS. 7 to 10 are each a schematic cross-sectional view of a display device according to an embodiment. In the descriptions of display devices according to embodiments with reference to FIGS. 7 to 10, the features which have been described with respect to FIGS. 1 to 6 will not be described again, disclosure will describe the differing features.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. A structure of the light emitting element ED shown in FIG. 7 may be the same as a structure of a light emitting element according to one of FIGS. 3 to 6 as described above.

The emission layer EML of the light emitting element ED included in the display device DD-a according to an embodiment may include the above-described polycyclic compound according to an embodiment.

Referring to FIG. 7, the emission layer EML may be disposed in an opening OH defined in a pixel defining film PDL. For example, the emission layer EML, which is separated by the pixel defining film PDL and provided corresponding to each of the light emitting regions PXA-R, PXA-G, and PXA-B, may emit light in a same wavelength range. In the display device DD-a according to an embodiment, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light, and may emit the resulting light. For example, the light control layer CCL may be a layer that includes a quantum dot or may be a layer that includes a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. FIG. 7 illustrates that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 which converts first color light provided from the light emitting element ED into second color light, a second light control part CCP2 including a second quantum dot QD2 which converts the first color light into third color light, and a third light control part CCP3 which transmits the first color light.

In an embodiment, the first light control part CCP1 may provide red light which is the second color light, and the second light control part CCP2 may provide green light which is the third color light. The third light control part CCP3 may transmit and provide blue light, which is the first color light provided from the light emitting element ED. For example, the first quantum dot QD1 may be a red quantum dot, and the second quantum dot QD2 may be a green quantum dot. The quantum dots QD1 and QD2 may be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow silica. The scatterer SP may include any one of TiO2, ZnO, A1203, SiO2, or hollow silica, or the scatterer SP may be a mixture of at least two materials selected from among TiO₂, ZnO, Al₂O₃, SiO2, and hollow silica.

The first light control part CCP1, the second light control part CCP2, and the third light control part CCP3 may each include base resins BR₁, BR₂, and BR₃ in which the quantum dots QD1 and QD2 and the scatterer SP are dispersed. In an embodiment, the first light control part CCP1 may include the first quantum dot QD1 and the scatterer SP dispersed in a first base resin BR₁, the second light control part CCP2 may include the second quantum dot QD2 and the scatterer SP dispersed in a second base resin BR₂, and the third light control part CCP3 may include the scatterer SP dispersed in a third base resin BR_{3.} The base resins BR₁, BR₂, and BR₃ are media in which the quantum dots QD1 and QD2 and the scatterer SP are dispersed, and may be formed of various resin compositions, which may be generally referred to as a binder. For example, the base resins BR₁, BR₂, and BR₃ may be acrylic-based resins, urethane-based resins, silicone-based resins, epoxy-based resins, etc. The base resins BR₁, BR₂, and BR₃ may be transparent resins. In an embodiment, the first base resin BR₁, the second base resin BR₂, and the third base resin BR₃ may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from being exposed to moisture/oxygen. The barrier layer BFL1 may cover the light control parts CCP1, CCP2, and CCP3. A barrier layer BFL2 may be provided between the light control parts CCP1, CCP2, and CCP3 and color filters CF1, CF2, and CF3.

The barrier layers BFL1 and BFL2 may each independently include at least one inorganic layer. For example, the barrier layers BFL1 and BFL2 may each include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may further include an organic film. The barrier layers BFL1 and BFL2 may each independently be formed of a single layer or of multiple layers.

In the display device DD-a according to an embodiment, a color filter layer CFL may be disposed on the light control layer CCL. In an embodiment, the color filter layer CFL may be directly disposed on the light control layer CCL. For example, the barrier layer BFL2 may be omitted.

The color filter layer CFL may include color filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The color filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated from each other and may be provided as one filter.

The first to third filters CF1, CF2, and CF3 may be disposed corresponding to the red light emitting region PXA-R, the green light emitting region PXA-G, and the blue light emitting region PXA-B, respectively.

Although not shown in the drawings, the color filter layer CFL may include a light shielding part (not shown). The color filter layer CFL may include a light shielding part (not shown) that is disposed to overlap the boundaries between neighboring filters CF1, CF2, and CF3. The light shielding part (not shown) may be a black matrix. The light shielding part (not shown) may include an organic light shielding material or an inorganic light shielding material including a black pigment or dye. The light shielding part (not shown) may separate boundaries between the adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

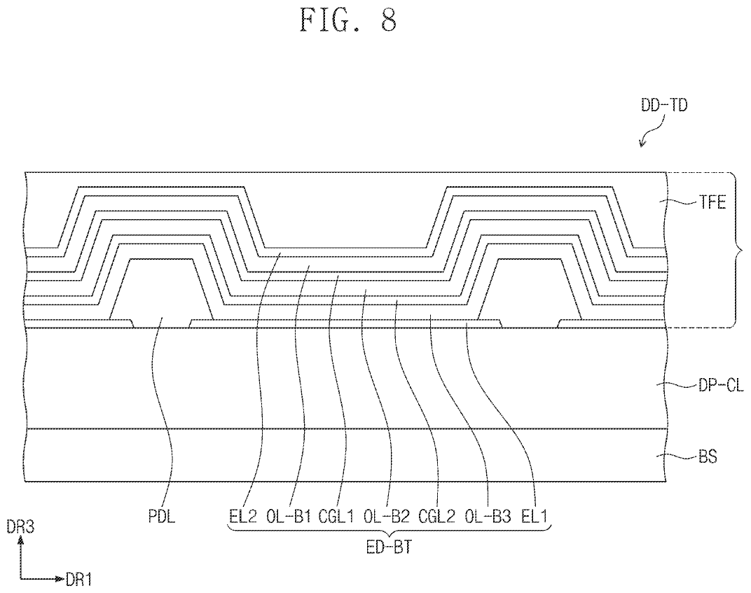

FIG. 8 is a schematic cross-sectional view illustrating a portion of a display device according to an embodiment. In the display device DD-TD according to an embodiment, a light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting element ED-BT included in the display device DD-TD of an embodiment may be a light emitting element having a tandem structure and including multiple emission layers.

In an embodiment illustrated in FIG. 8, light emitted from each of the light emitting structures OL-B1, OL-B2, and OL-B3 may all be blue light. However, embodiments are not limited thereto, and the light emitted from the light emitting structures OL-B1, OL-B2, and OL-B3 may have wavelength ranges that are different from each other. For example, the light emitting element ED-BT including the light emitting structures OL-B1, OL-B2, and OL-B3 which emit light having wavelength ranges that are different from each other may emit white light.

Charge generation layers CGL1 and CGL2 may be respectively disposed between two of the neighboring light emitting structures OL-B1, OL-B2, and OL-B3. The charge generation layers CGL1 and CGL2 may each independently include a p-type charge generation layer and/or an n-type charge generation layer.

At least one of the light emitting structures OL-B1, OL-B2, and OL-B3 included in the display device DD-TD according to an embodiment may include the above-described polycyclic compound according to an embodiment. For example, at least one of the emission layers included in the light emitting element ED-BT may include the polycyclic compound according to an embodiment.

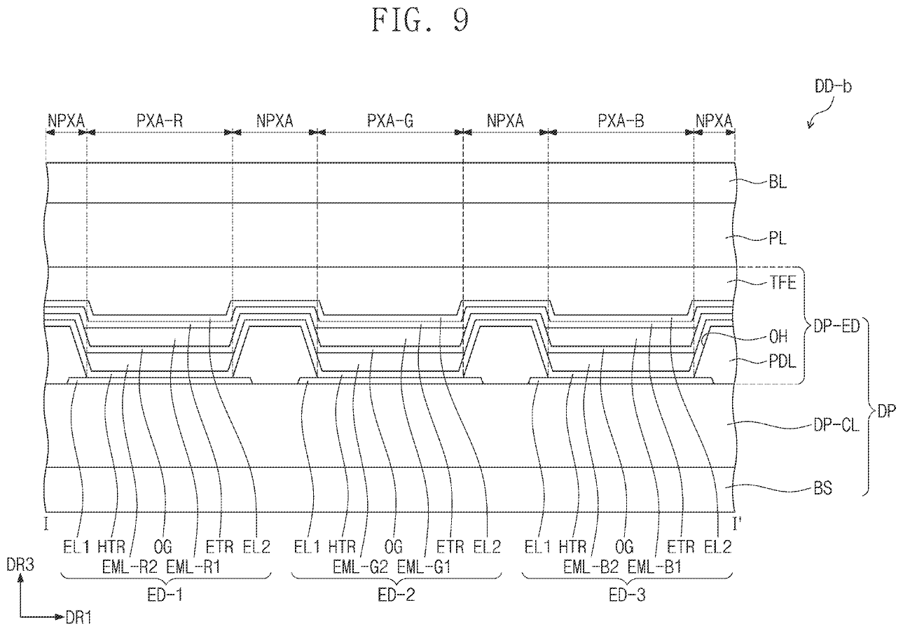

Referring to FIG. 9, a display device DD-b according to an embodiment may include light emitting elements ED-1, ED-2, and ED-3 which may each include two emission layers that are stacked. In contrast to the display device DD illustrated in FIG. 2, the embodiment illustrated in FIG. 9 is different at least in that the first to third light emitting elements ED-1, ED-2, and ED-3 each include two emission layers stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or may be a multilayer. The emission auxiliary part OG may include a charge generation layer. For example, the emission auxiliary part OG may include an electron transport region, a charge generation layer, and a hole transport region that are stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R₁, the first green emission layer EML-G1, and the first blue emission layer EML-B1 may each be disposed between the electron transport region ETR and the emission auxiliary part OG. The second red emission layer EML-R₂, the second green emission layer EML-G2, and the second blue emission layer EML-B2 may each be disposed between the emission auxiliary part OG and the hole transport region HTR.

For example, the first light emitting element ED-1 may include the first electrode ELL the hole transport region HTR, the second red emission layer EML-R₂, the emission auxiliary part OG, the first red emission layer EML-R₁, the electron transport region ETR, and the second electrode EL2, stacked in that order. The second light emitting element ED-2 may include the first electrode ELL the hole transport region HTR, the second green emission layer EML-G2, the emission auxiliary part OG, the first green emission layer EML-G1, the electron transport region ETR, and the second electrode EL2, stacked in that order. The third light emitting element ED-3 may include the first electrode ELL the hole transport region HTR, the second blue emission layer EML-B2, the emission auxiliary part OG, the first blue emission layer EML-B1, the electron transport region ETR, and the second electrode EL2, stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

At least one emission layer included in the display device DD-b according to an embodiment illustrated in FIG. 9 may include the above-described polycyclic compound according to an embodiment. For example, in an embodiment, at least one of the first blue emission layer EML-B 1 or the second blue emission layer EML-B2 may include the polycyclic compound according to an embodiment.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in different wavelength regions from one another.

The charge generation layers CGL1, CGL2, and CGL3 disposed between adjacent light emitting structures OL-B1, OL-B2, OL-B3, and OL-C1 may each independently include a p-type charge generation layer and/or an n-type charge generation layer.

At least one of the light emitting structures OL-B1, OL-B2, OL-B3, and OL-C1 included in the display device DD-c according to an embodiment may include the above-described polycyclic compound according to an embodiment. For example, in an embodiment, at least one of the first to third light emitting elements OL-B1, OL-B2, and OL-B3 may include the described-above polycyclic compound according to an embodiment.

The light emitting element ED according to an embodiment may include the above-described polycyclic compound according to an embodiment in at least one functional layer disposed between the first electrode EL1 and the second electrode EL2, thereby exhibiting an improved service life characteristic. For example, the polycyclic compound according to an embodiment may be included in the emission layer EML of the light emitting element ED of an embodiment, and the light emitting element of an embodiment may exhibit a long service life characteristic.

The above-described polycyclic compound of an embodiment includes, as a substituent, at least one triphenylenyl group having a steric shielding effect and high stability and rigid characteristics in the excited state, and thus has high stability, thereby exhibiting an increased service life characteristic. The polycyclic compound according to an embodiment includes a fused ring including at least one boron atom and at least one nitrogen atom, and thus may be used as a thermally activated delayed fluorescence dopant material, thereby increasing efficiency.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

1. Synthesis of Polycyclic Compound

A synthesis method of a polycyclic compound according to embodiments will be described in detail by illustrating synthesis methods of Compounds 1, 2, 48, 51, 63, 78, 116, and 159. In the following descriptions, the synthesis methods of the polycyclic compounds are provided only as examples, and thus, the synthesis method according to embodiments is not limited to the Examples below.

(1) Synthesis of Compound 1

Compound 1 according to an example may be synthesized by, for example, the steps shown in Reaction Scheme 1 below:

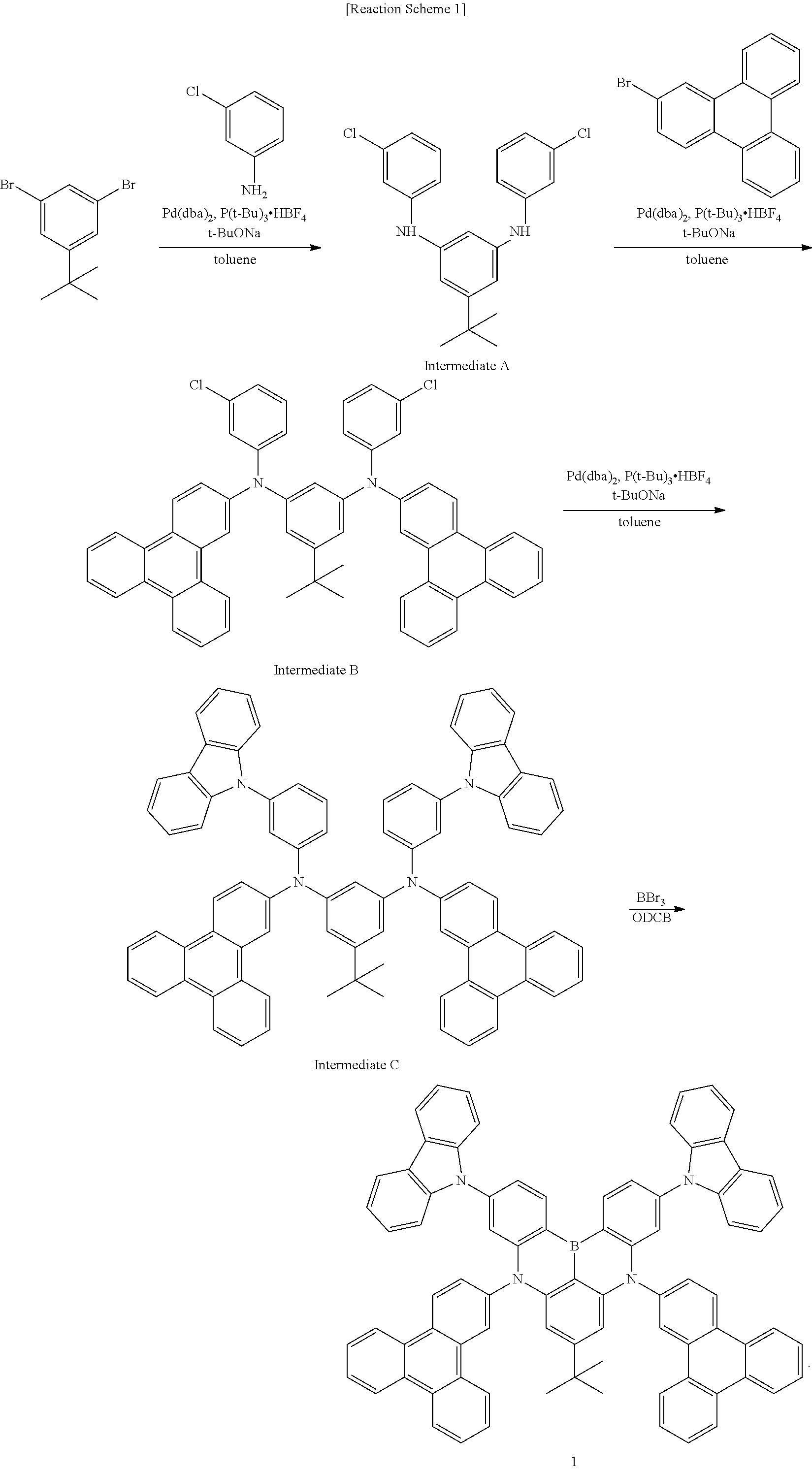

<Synthesis of Intermediate A>

In an argon (Ar) atmosphere, 1,3-dibromo-5-(tert-butyl)benzene (15.0 g, 51.4 mmol), 3-chloroaniline (13.4 g, 105.3 mmol), Pd(dba)₂ (2.95 g, 5.14 mmol), P(t-Bu)₃HBF₄ (2.98 g, 10.3 mmol), and t-BuONa (11.4 g, 118.15 mmol) were added to 260 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate A (17.2 g, yield 87%).

By measuring FAB-MS, a mass number of m/z=385 was observed by molecular ion peak, thereby identifying Intermediate A.

<Synthesis of Intermediate B>

In an Ar atmosphere, Intermediate A (15.0 g, 38.9 mmol), 2-bromotriphenylene (14.3 g, 46.7 mmol), Pd(dba)₂ (2.24 g, 3.89 mmol), P(t-Bu)₃HBF₄ (2.26 g, 7.79 mmol), and t-BuONa (8.60 g, 89.5 mmol) were added to 195 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate B (31.0 g, yield 95%).

By measuring FAB-MS, a mass number of m/z=87 was observed by molecular ion peak, thereby identifying Intermediate B.

<Synthesis of Intermediate C>

In an Ar atmosphere, Intermediate B (15.0 g, 17.9 mmol), carbazole (8.98 g, 53.7 mmol), Pd(dba)₂ (1.03 g, 1.79 mmol), P(t-Bu)₃HBF₄ (1.04 g, 3.58 mmol), and t-BuONa (3.96 g, 41.2 mmol) were added to 90 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate C (13.8 g, yield 70%).

By measuring FAB-MS, a mass number of m/z=1099 was observed by molecular ion peak, thereby identifying Intermediate C.

<Synthesis of Compound 1>

In an Ar atmosphere, Intermediate C (12.0g, 10.9 mmol) was dissolved in 1,2-dichlorobenzene (ODCB, 100 mL), BBr₃ (6.84 g, 27.3 mmol) was added thereto, and the resulting mixture was heated and stirred at about 170° C. for about 10 hours. The resulting mixture was cooled to room temperature, N,N-diisopropylethylamine (16.9 g, 131 mmol) was added thereto and water was added thereto, and the resultant mixture was subjected to celite filtering and liquid separation to concentrate an organic layer. The concentrated organic layer was purified by silica gel column chromatography to obtain Compound 1 (9.67 g, yield 80%).

By measuring FAB-MS, a mass number of m/z=1107 was observed by molecular ion peak, thereby identifying Compound 1. Sublimation purification (380° C., 2.1×10⁻³ Pa) was conducted and element evaluation was performed.

(2) Synthesis of Compound 2

Compound 2 according to an example may be synthesized by, for example, the steps shown in Reaction Scheme 2 below:

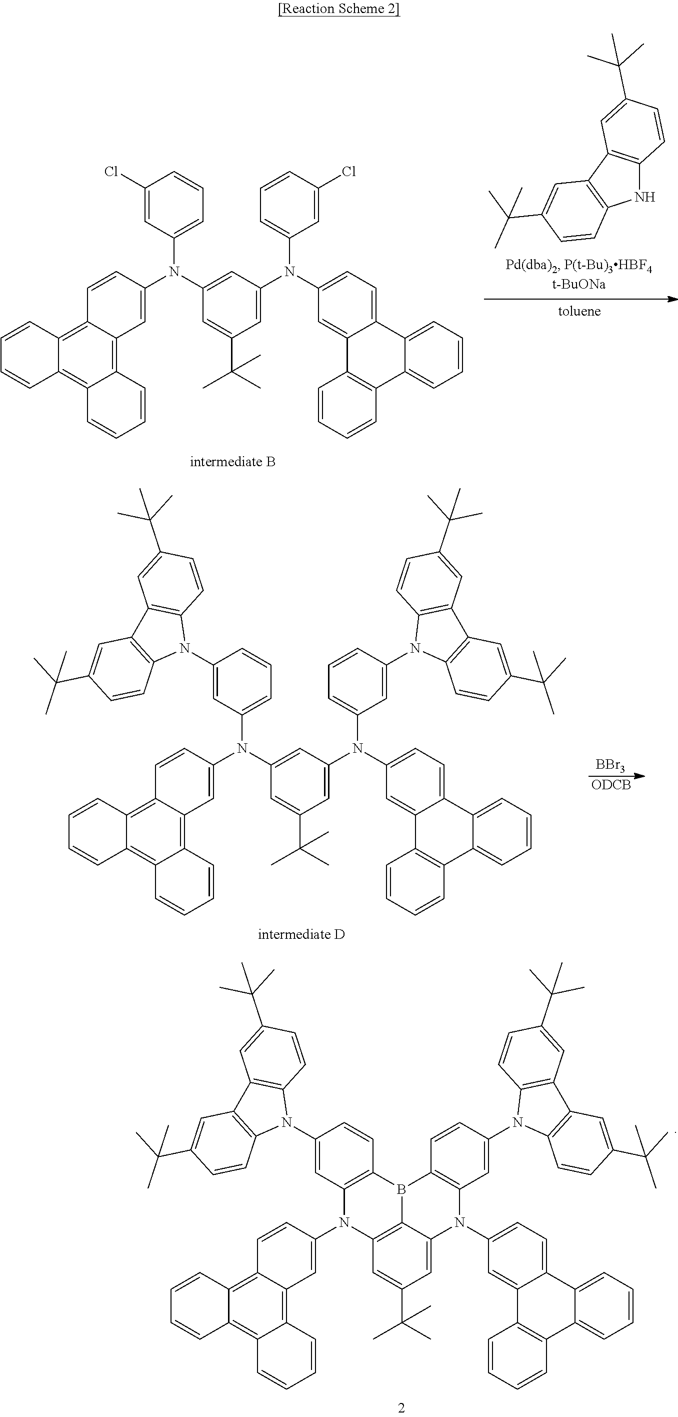

<Synthesis of Intermediate D>

In an Ar atmosphere, Intermediate B (15.0 g, 17.9 mmol), 3,6-di-tert-butyl-9H-carbazole (15.0 g, 53.7 mmol), Pd(dba)₂ (1.03 g, 1.79 mmol), P(t-Bu)₃HBF₄ (1.04 g, 3.58 mmol), and t-BuONa (3.96 g, 41.2 mmol) were added to 90 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate D (15.4 g, yield 65%).

By measuring FAB-MS, a mass number of m/z=1323 was observed by molecular ion peak, thereby identifying Intermediate D.

<Synthesis of Compound 2>

In an Ar atmosphere, Intermediate D (12.0 g, 9.06 mmol) was dissolved in 1,2-dichlorobenzene (ODCB, 91 mL), BBr₃ (5.68 g, 22.7 mmol) was added thereto, and the resulting mixture was heated and stirred at about 170° C. for about 10 hours. The resulting mixture was cooled to room temperature, N,N-diisopropylethylamine (14.0 g, 109 mmol) was added thereto and water was added thereto, and the resultant mixture was subjected to celite filtering and liquid separation to concentrate an organic layer. The concentrated organic layer was purified by silica gel column chromatography to obtain Compound 2 (9.17 g, yield 76%).

By measuring FAB-MS, a mass number of m/z=1331 was observed by molecular ion peak, thereby identifying Compound 2. Sublimation purification (360° C., 2.5×10⁻³ Pa) was conducted and element evaluation was performed.

(3) Synthesis of Compound 48

Compound 48 according to an example may be synthesized by, for example, the steps shown in Reaction Scheme 3 below:

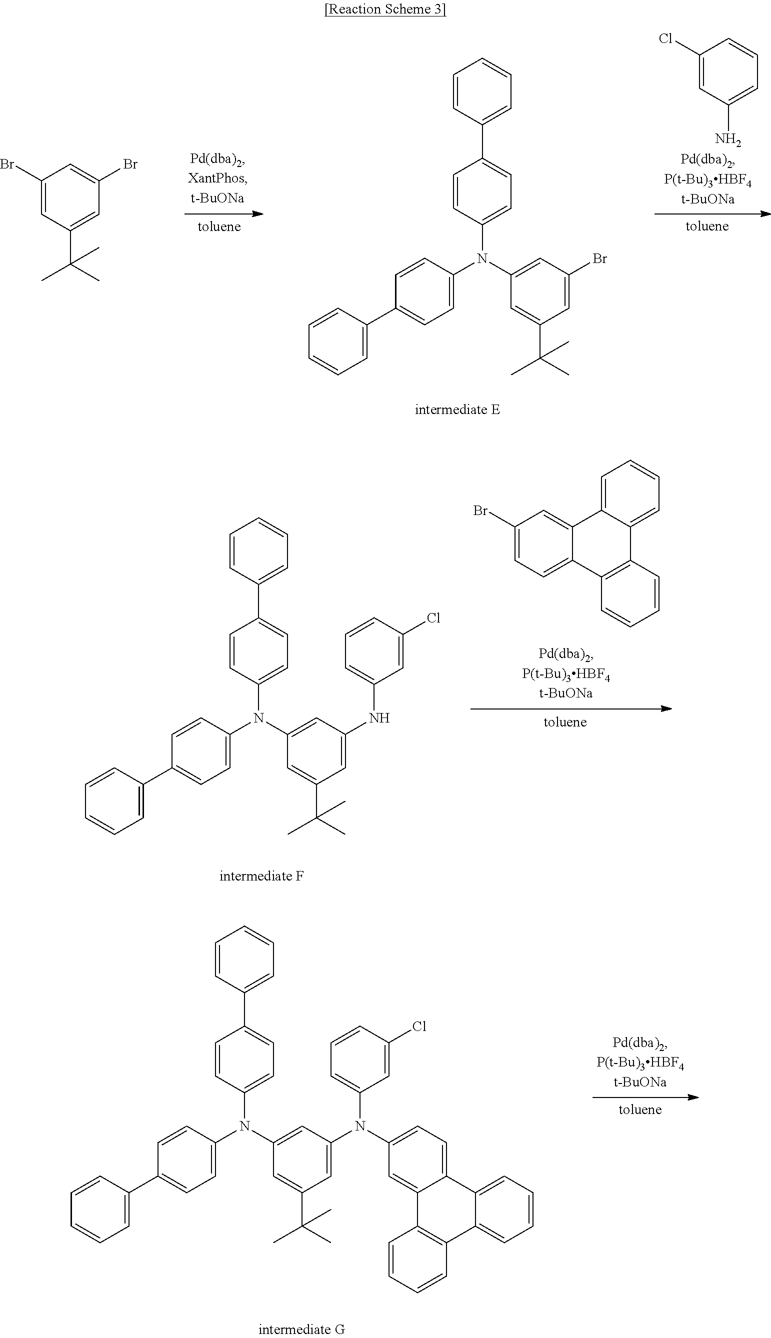 [SMILES: CC(C)(C)c1cc(Br)cc(Br)c1 ; CC(C)(C)c1cc(Br)cc(N(c2ccc(-c3ccccc3)cc2)c2ccc(-c3ccccc3)cc2)c1 ; Nc1cccc(Cl)c1 ; CC(C)(C)c1cc(Nc2cccc(Cl)c2)cc(N(c2ccc(-c3ccccc3)cc2)c2ccc(-c3ccccc3)cc2)c1 ; Brc1ccc2c3ccccc3c3ccccc3c2c1 ; CC(C)(C)c1cc(N(c2ccc(-c3ccccc3)cc2)c2ccc(-c3ccccc3)cc2)cc(N(c2cccc(Cl)c2)c2ccc3c4ccccc4c4ccccc4c3c2)c1]

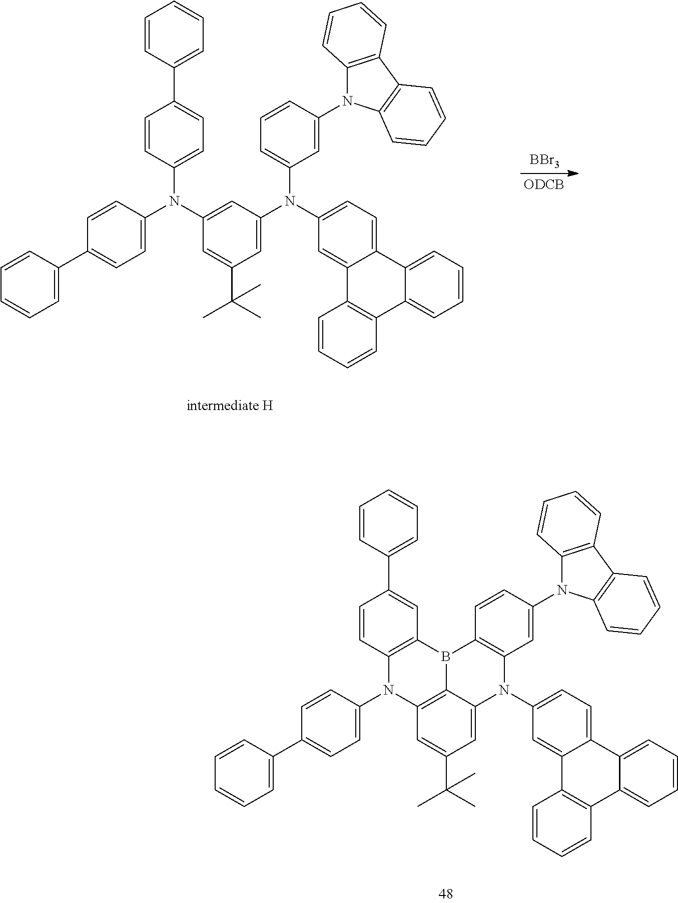 [SMILES: CC(C)(C)c1cc(N(c2ccc(-c3ccccc3)cc2)c2ccc(-c3ccccc3)cc2)cc(N(c2cccc(-n3c4ccccc4c4ccccc43)c2)c2ccc3c4ccccc4c4ccccc4c3c2)c1 ; "ODCB" ; "BBr3" ; CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc(-c2ccccc2)cc1]

<Synthesis of Intermediate E>

In an Ar atmosphere, 1,3-dibromo-5-(tert-butyl)benzene (15.0 g, 51.4 mmol), bisbiphenylamine (16.8 g, 52.4 mmol), Pd(dba)₂ (0.738 g, 1.28 mmol), xantphos(4,5-bis(diphenylphosphino)-9,9-dimethylxanthene (1.06 g, 1.83 mmol), and t-BuONa (5.92 g, 61.6 mmol) were added to 114 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate E (23.3 g, yield 85%).

By measuring FAB-MS, a mass number of m/z=532 was observed by molecular ion peak, thereby identifying Intermediate E.

<Synthesis of Intermediate F>

In an Ar atmosphere, Intermediate E (15.0 g, 28.2 mmol), 3-chloroaniline (3.77 g, 29.6 mmol), Pd(dba)₂ (1.62 g, 2.82 mmol), P(t-Bu)₃HBF₄ (1.63 g, 5.63 mmol), and t-BuONa (6.23 g, 64.8 mmol) were added to 140 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate F (13.7 g, yield 84%).

By measuring FAB-MS, a mass number of m/z=579 was observed by molecular ion peak, thereby identifying Intermediate F.

<Synthesis of Intermediate G>

In an Ar atmosphere, Intermediate F (13.0 g, 22.5 mmol), 2-bromotriphenylene (8.27 g, 26.9 mmol), Pd(dba)₂ (1.29 g, 2.24 mmol), P(t-Bu)₃HBF₄ (1.30 g, 4.49 mmol), and t-BuONa (4.96 g, 51.6 mmol) were added to 110 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate G (16.5 g, yield 91%).

By measuring FAB-MS, a mass number of m/z=805 was observed by molecular ion peak, thereby identifying Intermediate G.

<Synthesis of Intermediate H>

In an Ar atmosphere, Intermediate G (15.0 g, 18.6 mmol), carbazole (6.22 g, 37.3 mmol), Pd(dba)₂ (1.07 g, 1.86 mmol), P(t-Bu)₃HBF₄ (1.08 g, 3.72 mmol), and t-BuONa (7.16 g, 74.5 mmol) were added to 90 mL of toluene, and the resulting mixture was heated and stirred at about 80° C. for about 10 hours. Water was added thereto, and the resultant mixture was subjected to celite filtering and liquid separation to concentrate an organic layer.

The concentrated organic layer was purified by silica gel column chromatography to obtain Intermediate H (13.9 g, yield 80%).

By measuring FAB-MS, a mass number of m/z=936 was observed by molecular ion peak, thereby identifying Intermediate H.

<Synthesis of Compound 48>

In an Ar atmosphere, Intermediate H (12.0 g, 12.8 mmol) was dissolved in 1,2-dichlorobenzene (ODCB, 130 mL), BBr₃ (8.02 g, 32.0 mmol) was added thereto, and the resulting mixture was heated and stirred at about 170° C. for about 10 hours. The resulting mixture was cooled to room temperature, N,N-diisopropylethylamine (19.8 g, 154 mmol) was added thereto and water was added thereto, and the resultant mixture was subjected to celite filtering and liquid separation to concentrate an organic layer. The concentrated organic layer was purified by silica gel column chromatography to obtain Compound 48 (9.07 g, yield 75%).

By measuring FAB-MS, a mass number of m/z=944 was observed by molecular ion peak, thereby identifying Compound 48. Sublimation purification (360° C., 2.3×10⁻³ Pa) was conducted and element evaluation was performed.

(4) Synthesis of Compound 51

Compound 51 according to an example may be synthesized by, for example, the steps shown in Reaction Scheme 4 below:

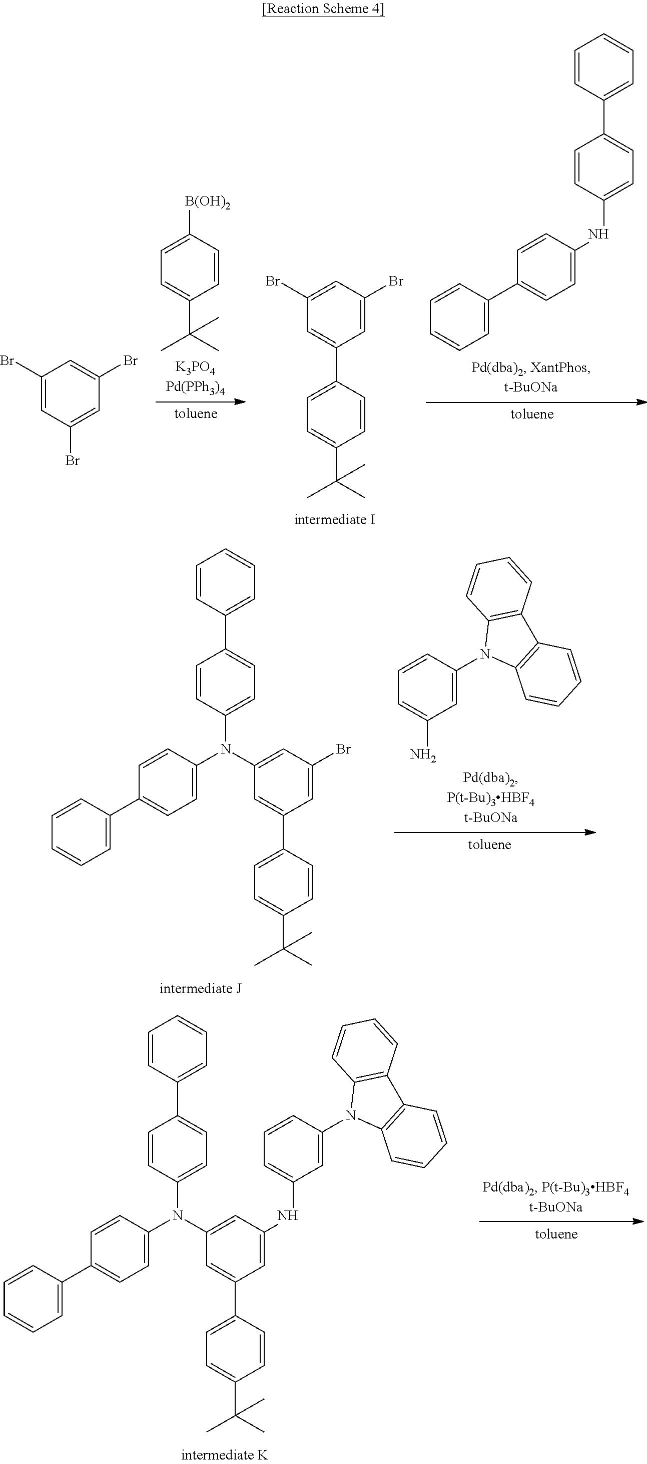

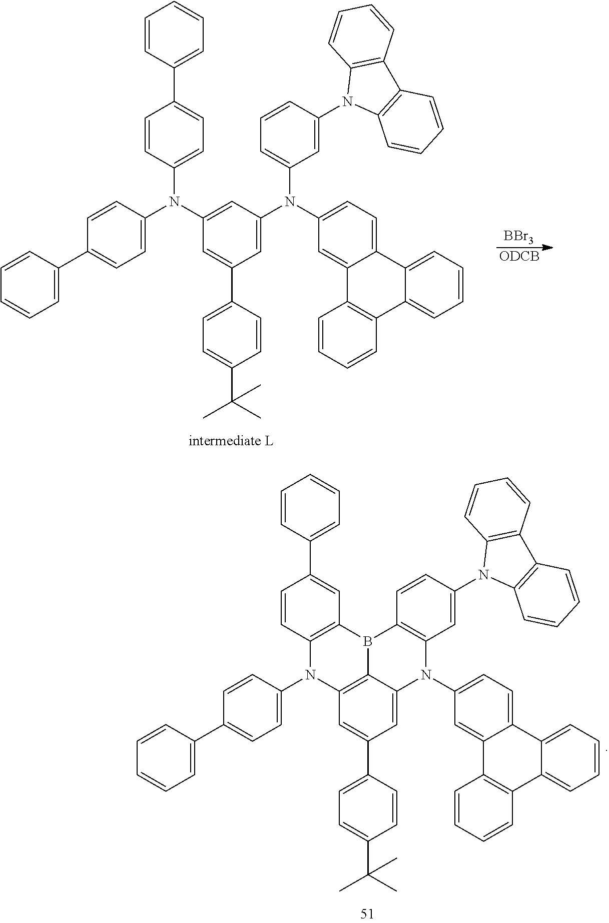

<Synthesis of Intermediate I>

In an Ar atmosphere, 1,3,5-tribromobenzene (15.0g, 47.7 mmol eq), 4-(tert-butyl)phenyl)boronic acid (12.7 g, 71.5 mmol), Pd(PPh3)4 (5.51 g, 4.77 mmol), and K₃PO₄ (20.2 g, 95.2 mmol) were added to 120 mL of Toluene, and the resulting mixture was reacted at about 80° C. for about 6 hours. The resulting mixture was cooled and water was added thereto, and the resultant mixture was subjected to celite filtering and filtering and liquid separation to concentrate an organic layer. The concentrated organic layer was purified by silica gel column chromatography to obtain Intermediate I (12.3 g, yield 70%).

By measuring FAB-MS, a mass number of m/z=368 was observed by molecular ion peak, thereby identifying Intermediate I.

<Synthesis of Intermediate J>

In an Ar atmosphere, Intermediate I (12.0 g, 32.6 mmol), bisbiphenylamine (10.7 g, 33.3 mmol), Pd(dba)₂ (469 mg, 0.81 mmol), xantphos (673 mg, 1.16 mmol), and t-BuONa (3.76 g, 39.1 mmol) were added to 70 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate J (16.9 g, yield 85%).

By measuring FAB-MS, a mass number of m/z=608 was observed by molecular ion peak, thereby identifying Intermediate J.

<Synthesis of Intermediate K>

In an Ar atmosphere, Intermediate J (15.0 g, 24.7 mmol), 3-(9H-carbazol-9-yl)aniline (12.7 g, 49.3 mmol), Pd(dba)₂ (1.42 g, 2.46 mmol), P(t-Bu)₃HBF₄ (1.43 g, 4.93 mmol), and t-BuONa (9.47 g, 98.6 mmol) were added to 130 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate K (17.4 g, yield 90%).

By measuring FAB-MS, a mass number of m/z=786 was observed by molecular ion peak, thereby identifying Intermediate K.

<Synthesis of Intermediate L>

In an Ar atmosphere, Intermediate K (15.01 g, 19.09 mmol), 2-bromotriphenylene (11.73 g, 38.19 mmol), Pd(dba)₂ (1.098 g, 1.909 mmol), P(t-Bu)₃HBF₄ (1.108 g, 3.819 mmol), and t-BuONa (7.340 g, 76.38 mmol) were added to 130 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate L (17.39 g, yield 90%).

By measuring FAB-MS, a mass number of m/z=1012 was observed by molecular ion peak, thereby identifying Intermediate L.

<Synthesis of Compound 51>

In an Ar atmosphere, Intermediate L (12.00 g, 11.74 mmol) was dissolved in 1,2-dichlorobenzene (117 mL), BBr₃ (7.35 g, 29.3 mmol) was added thereto, and the resulting mixture was heated and stirred at about 170° C. for about 10 hours. The resulting mixture was cooled to room temperature, N,N-diisopropylethylamine (18.1g, 140.9 mmol) was added thereto and water was added thereto, and the resultant mixture was subjected to celite filtering and liquid separation to concentrate an organic layer. The concentrated organic layer was purified by silica gel column chromatography to obtain Compound 51 (8.390 g, yield 70%).

By measuring FAB-MS, a mass number of m/z=1020 was observed by molecular ion peak, thereby identifying Compound 51. Sublimation purification (280° C., 2.7×10⁻³ Pa) was conducted and element evaluation was performed.

(5) Synthesis of Compound 63

Compound 63 according to an example may be synthesized by, for example, the steps shown in Reaction Scheme 5 below:

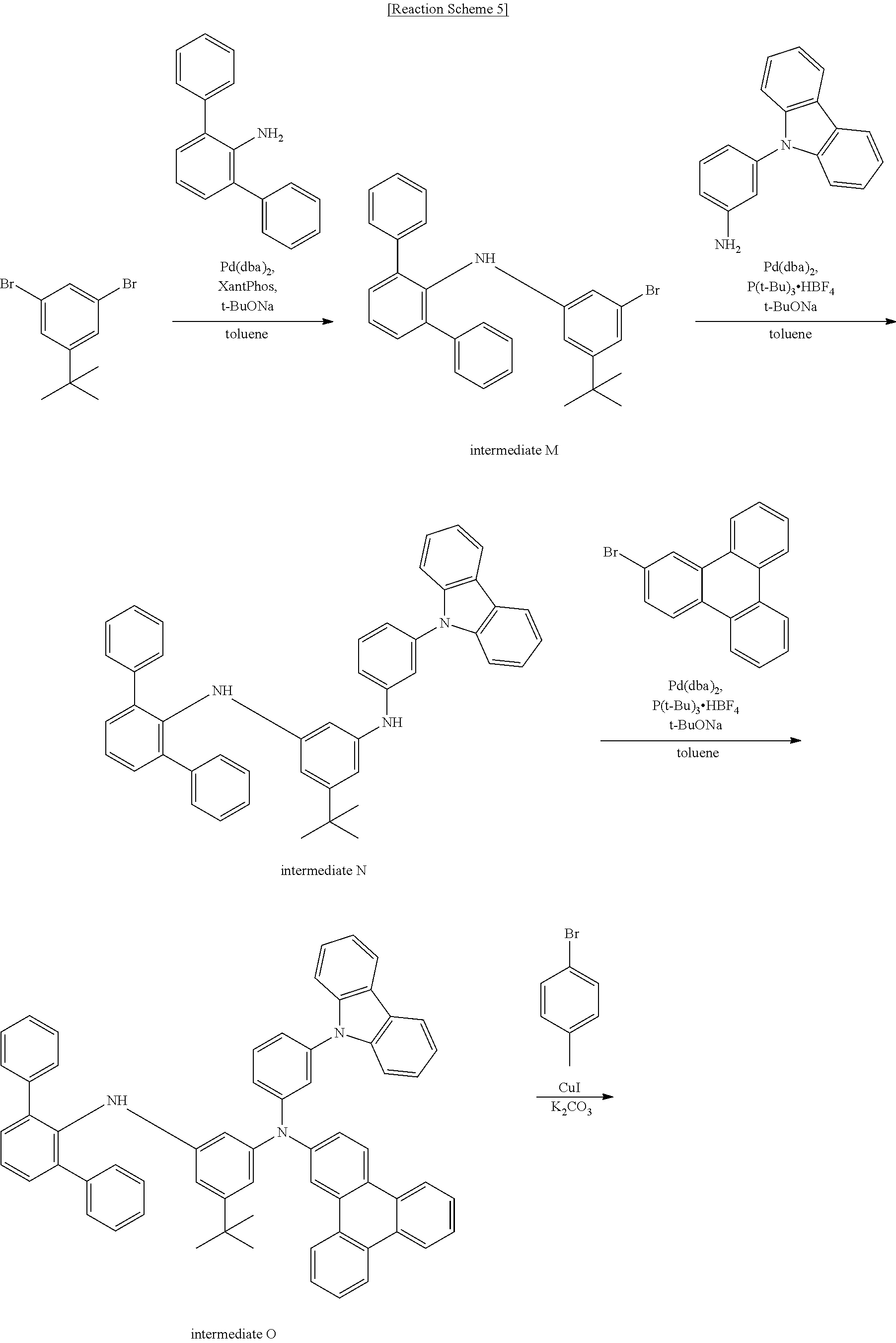

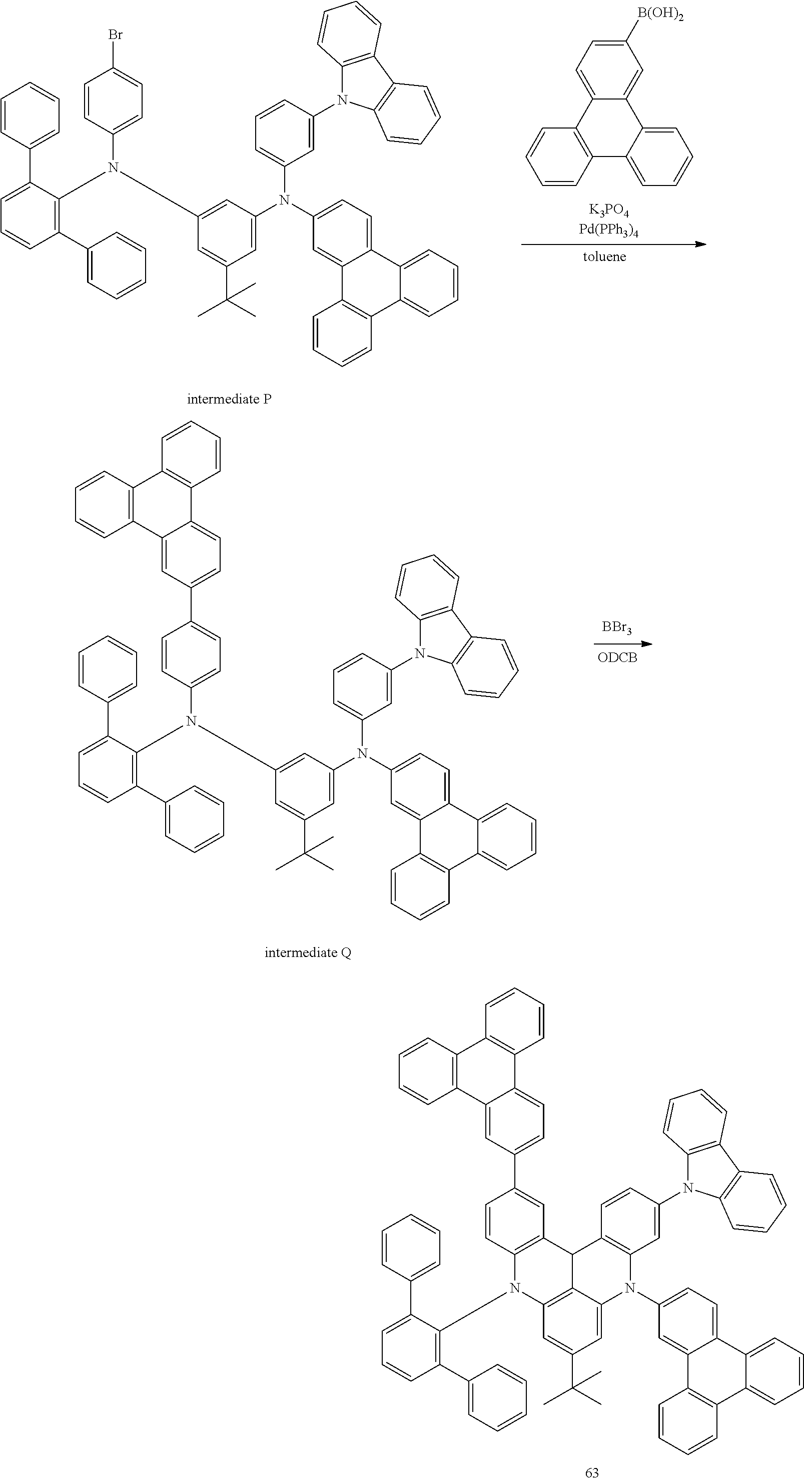 [SMILES: CC(C)(C)c1cc(N(c2cccc(-n3c4ccccc4c4ccccc43)c2)c2ccc3c4ccccc4c4ccccc4c3c2)cc(N(c2ccc(Br)cc2)c2c(-c3ccccc3)cccc2-c2ccccc2)c1 ; OB(O)c1ccc2c3ccccc3c3ccccc3c2c1 ; CC(C)(C)c1cc(N(c2cccc(-n3c4ccccc4c4ccccc43)c2)c2ccc3c4ccccc4c4ccccc4c3c2)cc(N(c2ccc(-c3ccc4c5ccccc5c5ccccc5c4c3)cc2)c2c(-c3ccccc3)cccc2-c2ccccc2)c1 ; "ODCB" ; "BBr3" ; CC(C)(C)c1cc2c3c(c1)N(c1c(-c4ccccc4)cccc1-c1ccccc1)c1ccc(-c4ccc5c6ccccc6c6ccccc6c5c4)cc1C3c1ccc(-n3c4ccccc4c4ccccc43)cc1N2c1ccc2c3ccccc3c3ccccc3c2c1]

<Synthesis of Intermediate M>

In an Ar atmosphere, 1,3-dibromo-5-(tert-butyl)benzene (15.0 g, 51.4 mmol), [1,1′:3′,1″-terphenyl]-2′-amine (12.8 g, 52.4 mmol), Pd(dba)₂ (0.738 g, 1.28 mmol), xantphos (1.06 g, 1.83 mmol), and t-BuONa (5.92 g, 61.6 mmol) were added to 114 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate M (20.6 g, yield 88%).

By measuring FAB-MS, a mass number of m/z=456 was observed by molecular ion peak, thereby identifying Intermediate M.

<Synthesis of Intermediate N>

In an Ar atmosphere, Intermediate M (18 g, 39.43 mmol), 2-bromotriphenylene (21.56 g, 78.87 mmol), Pd(dba)₂ (2.267 g, 3.943 mmol), P(t-Bu)₃HBF₄ (2.288 g, 7.887 mmol), and t-BuONa (15.15 g, 157.7 mmol) were added to 197 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate N (21.74 g, yield 87%).

By measuring FAB-MS, a mass number of m/z=633 was observed by molecular ion peak, thereby identifying Intermediate N.

<Synthesis of Intermediate O>

In an Ar atmosphere, Intermediate N (18 g, 28.39 mmol), 2-bromotriphenylene (13.08 g, 42.59 mmol), Pd(dba)₂ (1.632 g, 2.839 mmol), P(t-Bu)₃HBF₄ (1.647 g, 5.679 mmol), and t-BuONa (10.91 g, 113.5 mmol) were added to 141 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate 0 (22.47 g, yield 92%).

By measuring FAB-MS, a mass number of m/z=860 was observed by molecular ion peak, thereby identifying Intermediate O.

<Synthesis of Intermediate P>

In an Ar atmosphere, a small amount of toluene was added to Intermediate 0 (22.0 g, 25.6 mmol), 1-bromo-4-iodobenzene (108 g, 384 mmol), CuI (10.2 g, 52.7 mmol), and K₂CO₃ (28.3 g, 205 mmol), and the resulting mixture was heated for about 24 hours while the exterior temperature is maintained at about 215° C. The mixture was diluted with CH₂Cl₂, water was added thereto, and the resultant mixture was subjected to celite filtering and liquid separation to concentrate an organic layer. The concentrated organic layer was purified by silica gel column chromatography to obtain Intermediate P (16.1 g, yield 62%).

By measuring FAB-MS, a mass number of m/z=1015 was observed by molecular ion peak, thereby identifying Intermediate P.

<Synthesis of Intermediate Q>

In an Ar atmosphere, Intermediate P (15.0g, 14.8 mmol), triphenylen-2-ylboronic acid (6.03 g, 22.2 mmol), Pd(PPh3)₄ (1.71 g, 1.48 mmol), and K₃PO₄ (9.41 g, 44.3 mmol) were added to 120 mL of toluene, and the resulting mixture was reacted at about 80° C. for about 6 hours. The resulting mixture was cooled and water was added thereto, and the resultant mixture was subjected to celite filtering and filtering and liquid separation to concentrate an organic layer. The concentrated organic layer was purified by silica gel column chromatography to obtain Intermediate Q (13.7 g, yield 80%).

By measuring FAB-MS, a mass number of m/z=1162 was observed by molecular ion peak, thereby identifying Intermediate Q.

<Synthesis of Compound 63>

In an Ar atmosphere, Intermediate Q (12.00 g, 10.32 mmol) was dissolved in 1,2-dichlorobenzene (103 mL), BBr₃ (6.46 g, 25.8 mmol) was added thereto, and the resulting mixture was heated and stirred at about 170° C. for about 10 hours. The resulting mixture was cooled to room temperature, N,N-diisopropylethylamine (15.9 g, 123.8 mmol) was added thereto and water was added thereto, and the resultant mixture was subjected to celite filtering and liquid separation to concentrate an organic layer. The concentrated organic layer was purified by silica gel column chromatography to obtain Compound 63 (8.456 g, yield 70%).

By measuring FAB-MS, a mass number of m/z=1170 was observed by molecular ion peak, thereby identifying Compound 63. Sublimation purification (400° C., 2.2×10⁻³ Pa) was conducted and element evaluation was performed.

(6) Synthesis of Compound 78

Compound 78 according to an example may be synthesized by, for example, the steps shown in Reaction Scheme 6 below:

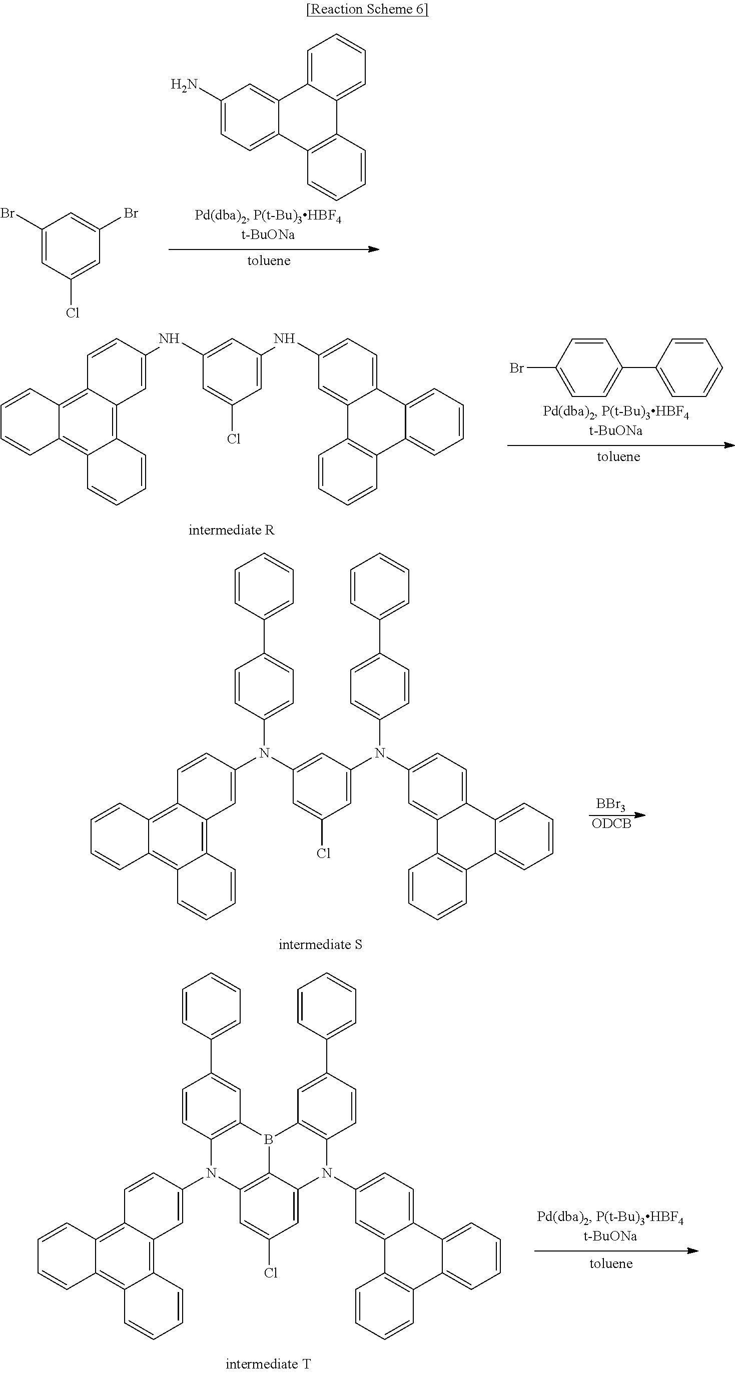

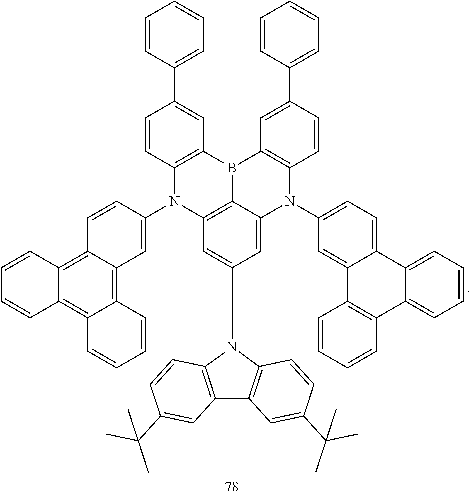 [SMILES: CC(C)(C)c1ccc2c(c1)c1cc(C(C)(C)C)ccc1n2-c1cc2c3c(c1)N(c1ccc4c5ccccc5c5ccccc5c4c1)c1ccc(-c4ccccc4)cc1B3c1cc(-c3ccccc3)ccc1N2c1ccc2c3ccccc3c3ccccc3c2c1]

<Synthesis of Intermediate R>

In an Ar atmosphere, 1,3-dibromo-5-chlorobenzene (15.00 g, 55.48 mmol), 2-bromotriphenylene (29.69 g, 122.0 mmol), Pd(dba)₂ (3.190 g, 5.548 mmol), P(t-Bu)₃HBF₄ (3.219 g, 11.09 mmol), and t-BuONa (21.32 g, 221.9 mmol) were added to 277 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate R (27.07 g, yield 82%).

By measuring FAB-MS, a mass number of m/z=595 was observed by molecular ion peak, thereby identifying Intermediate R.

<Synthesis of Intermediate S>

In an Ar atmosphere, Intermediate R (25 g, 42.00 mmol), 2-bromobiphenyl (21.54 g, 92.41 mmol), Pd(dba)₂ (2.415 g, 4.200 mmol), P(t-Bu)₃HBF₄ (2.437 g, 8.401 mmol), and t-BuONa (16.14 g, 168.0 mmol) were added to 210 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate S (31.30 g, yield 80%).

By measuring FAB-MS, a mass number of m/z=931 was observed by molecular ion peak, thereby identifying Intermediate S.

<Synthesis of Intermediate T>

In an Ar atmosphere, Intermediate S (30 g, 33.35 mmol) was dissolved in 1,2-dichlorobenzene (300 mL), BBr₃ (20.8 g, 83.3 mmol) was added thereto, and the resulting mixture was heated and stirred at about 170° C. for about 10 hours. The resulting mixture was cooled to room temperature, N,N-diisopropylethylamine (51.6 g, 400.2 mmol) was added thereto and water was added thereto, and the resultant mixture was subjected to celite filtering and liquid separation to concentrate an organic layer. The concentrated organic layer was purified by silica gel column chromatography to obtain Intermediate T (7.564 g, yield 25%).

By measuring FAB-MS, a mass number of m/z=907 was observed by molecular ion peak, thereby identifying Intermediate T.

<Synthesis of Compound 78>

In an Ar atmosphere, Intermediate T (7 g, 7.715 mmol), 3,6-di-tert-butyl-9H-carbazole (4.742 g, 16.97 mmol), Pd(dba)₂ (0.443 g, 0.771 mmol), P(t-Bu)₃HBF₄ (0.447 g, 1.543 mmol), and t-BuONa (2.965 g, 30.86 mmol) were added to 38 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Compound 78 (6.833 g, yield 77%)

By measuring FAB-MS, a mass number of m/z=1150 was observed by molecular ion peak, thereby identifying Compound 78. Sublimation purification (380° C., 2.3×10⁻³ Pa) was conducted and element evaluation was performed.

(7) Synthesis of Compound 116

Compound 116 according to an example may be synthesized by, for example, the steps shown in Reaction Scheme 7 below:

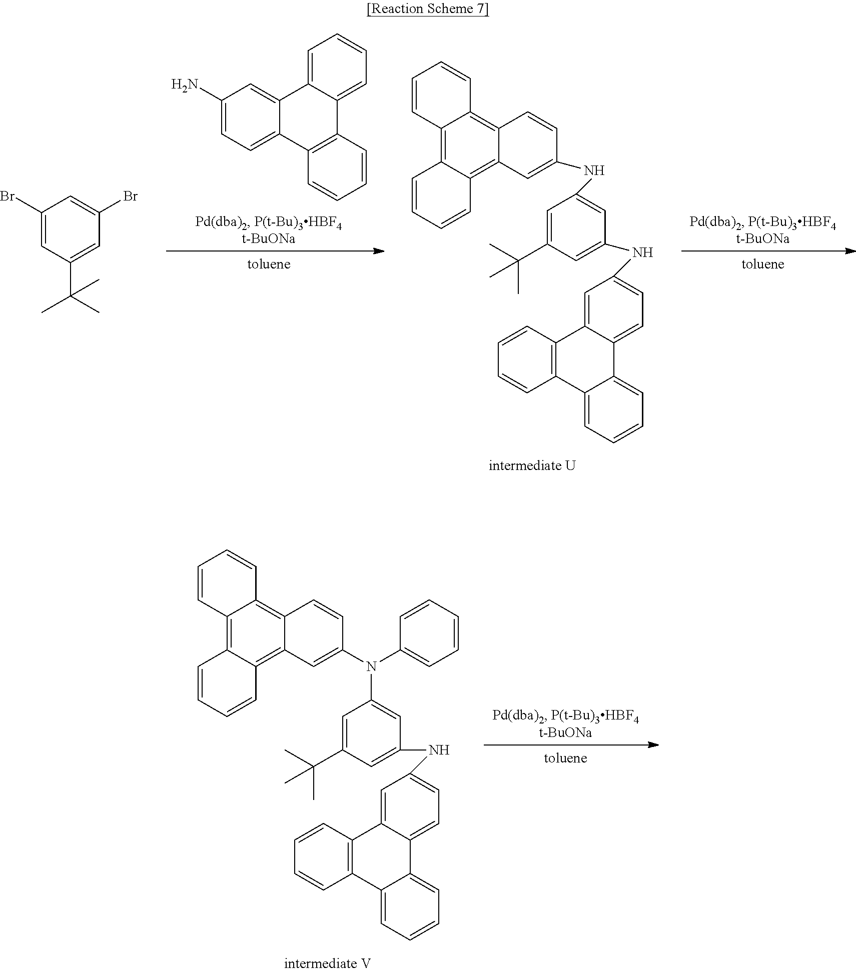

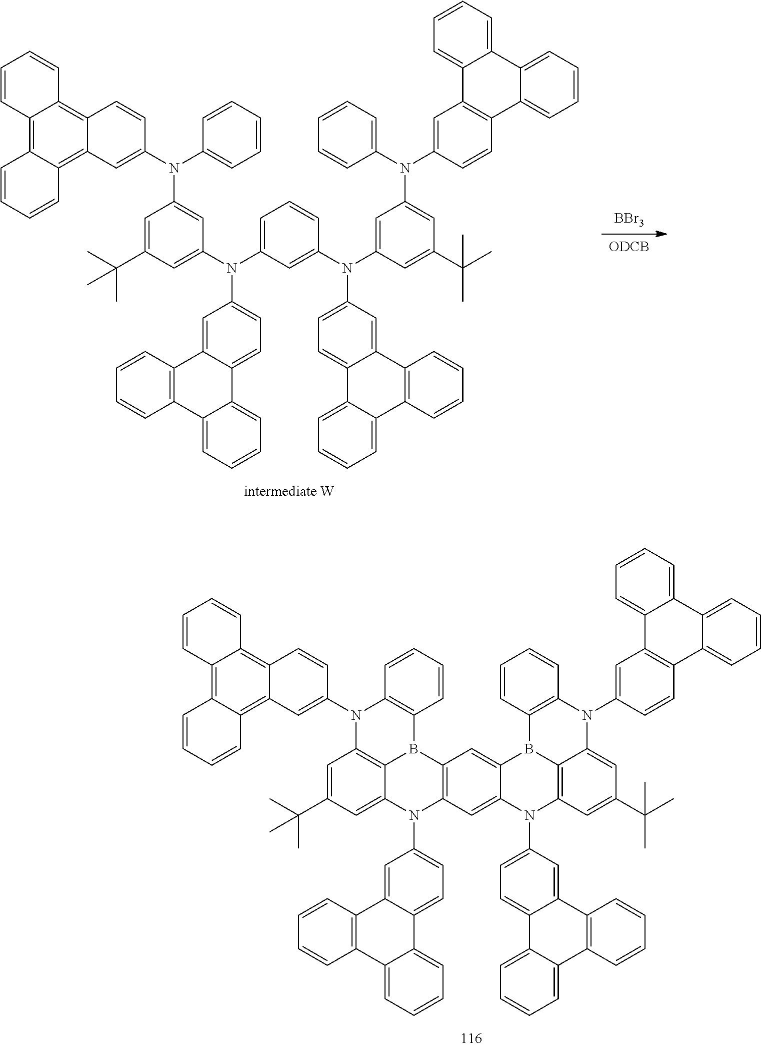 [SMILES: CC(C)(C)c1cc(N(c2ccccc2)c2ccc3c4ccccc4c4ccccc4c3c2)cc(N(c2cccc(N(c3cc(N(c4ccccc4)c4ccc5c6ccccc6c6ccccc6c5c4)cc(C(C)(C)C)c3)c3ccc4c5ccccc5c5ccccc5c4c3)c2)c2ccc3c4ccccc4c4ccccc4c3c2)c1 ; "ODCB" ; "BBr3" ; CC(C)(C)c1cc2c3c(c1)N(c1ccc4c5ccccc5c5ccccc5c4c1)c1cc4c(cc1B3c1ccccc1N2c1ccc2c3ccccc3c3ccccc3c2c1)B1c2ccccc2N(c2ccc3c5ccccc5c5ccccc5c3c2)c2cc(C(C)(C)C)cc(c21)N4c1ccc2c3ccccc3c3ccccc3c2c1]

<Synthesis of Intermediate U>

In an Ar atmosphere, 1,3-dibromo-5-(tert-butyl)benzene (15 g, 51.36 mmol), triphenylen-2-amine (27.49 g, 113.0 mmol), Pd(dba)₂ (2.953 g, 5.136 mmol), P(t-Bu)₃HBF₄ (2.980 g, 10.27 mmol), and t-BuONa (19.74 g, 205.4 mmol) were added to 256 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate U (27.24 g, yield 86%).

By measuring FAB-MS, a mass number of m/z=616 was observed by molecular ion peak, thereby identifying Intermediate U.

<Synthesis of Intermediate V>

In an Ar atmosphere, Intermediate U (25.00 g, 85.61 mmol), bromobenzene (29.57 g, 188.3 mmol), Pd(dba)₂ (4.922 g, 8.561 mmol), P(t-Bu)₃HBF₄ (4.967 g, 17.12 mmol), and t-BuONa (32.90 g, 342.4 mmol) were added to 428 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate V (41.52 g, yield 70%).

By measuring FAB-MS, a mass number of m/z=692 was observed by molecular ion peak, thereby identifying Intermediate V.

<Synthesis of Intermediate W>

In an Ar atmosphere, 1,3-dibromobenzene (2.00 g, 8.477 mmol), Intermediate V (12.92 g, 18.65 mmol), Pd(dba)₂ (0.487 g, 0.847 mmol), P(t-Bu)₃HBF₄ (0.491 g, 1.695 mmol), and t-BuONa (3.258 g, 33.91 mmol) were added to 100 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate W (10.76 g, yield 86%).

By measuring FAB-MS, a mass number of m/z=1475 was observed by molecular ion peak, thereby identifying Intermediate W.

<Synthesis of Compound 116>

In an Ar atmosphere, Intermediate W (10.00 g, 6.775 mmol) was dissolved in 1,2-dichlorobenzene (67 mL), BBr₃ (4.24 g, 16.9 mmol) was added thereto, and the resulting mixture was heated and stirred at about 170° C. for about 10 hours. The resulting mixture was cooled to room temperature, N,N-diisopropylethylamine (10.4 g, 81.30 mmol) was added thereto and water was added thereto, and the resultant mixture was subjected to celite filtering and liquid separation to concentrate an organic layer. The concentrated organic layer was purified by silica gel column chromatography to obtain Compound 116 (1.52 g, yield 15%). By measuring FAB-MS, the molecular weight of Compound 116 was about 1491. Sublimation purification (410° C., 2.9×10⁻³ Pa) was conducted and element evaluation was performed.

(8) Synthesis of Compound 159

Compound 159 according to an example may be synthesized by, for example, the steps shown in Reaction Scheme 8 below:

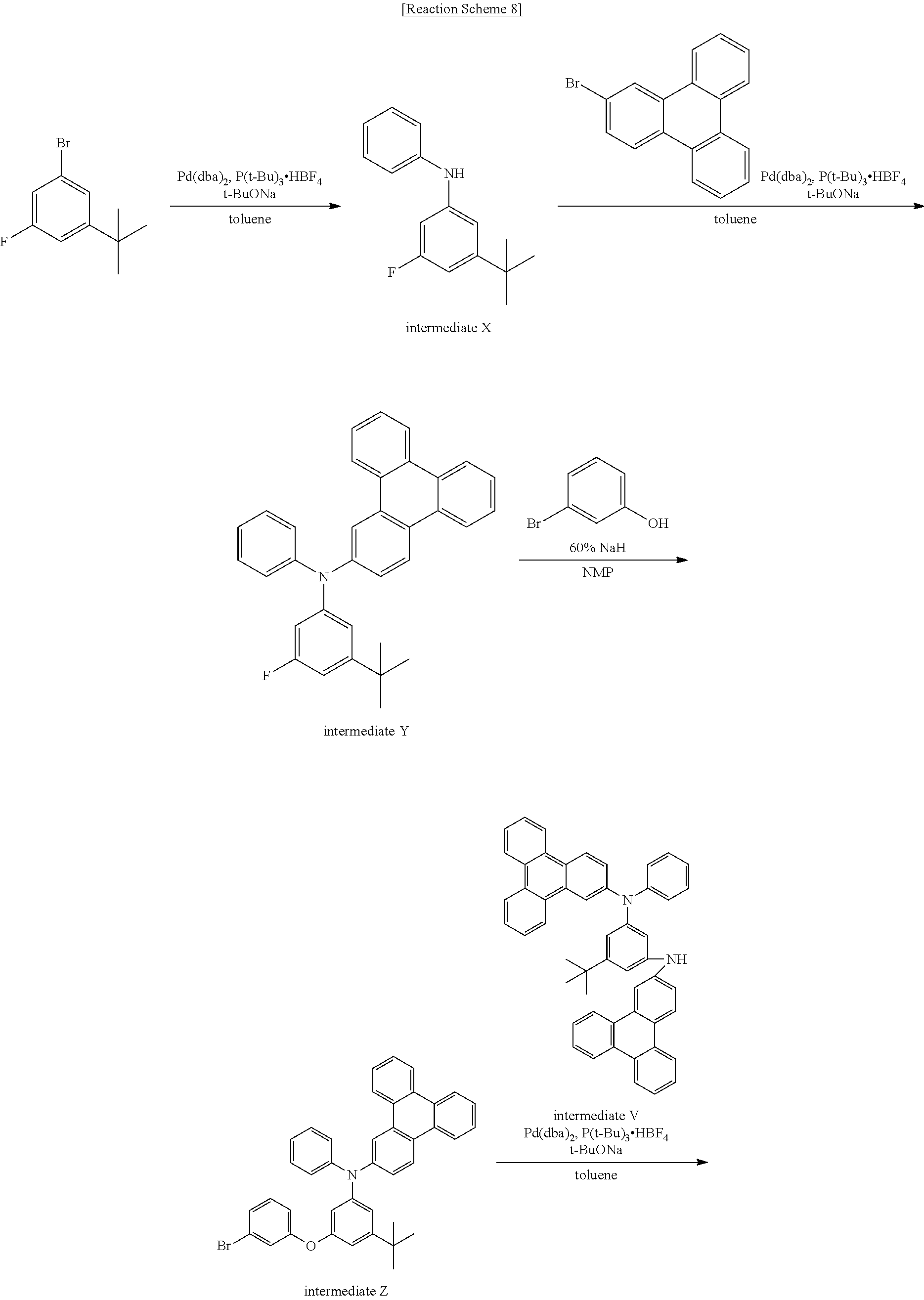

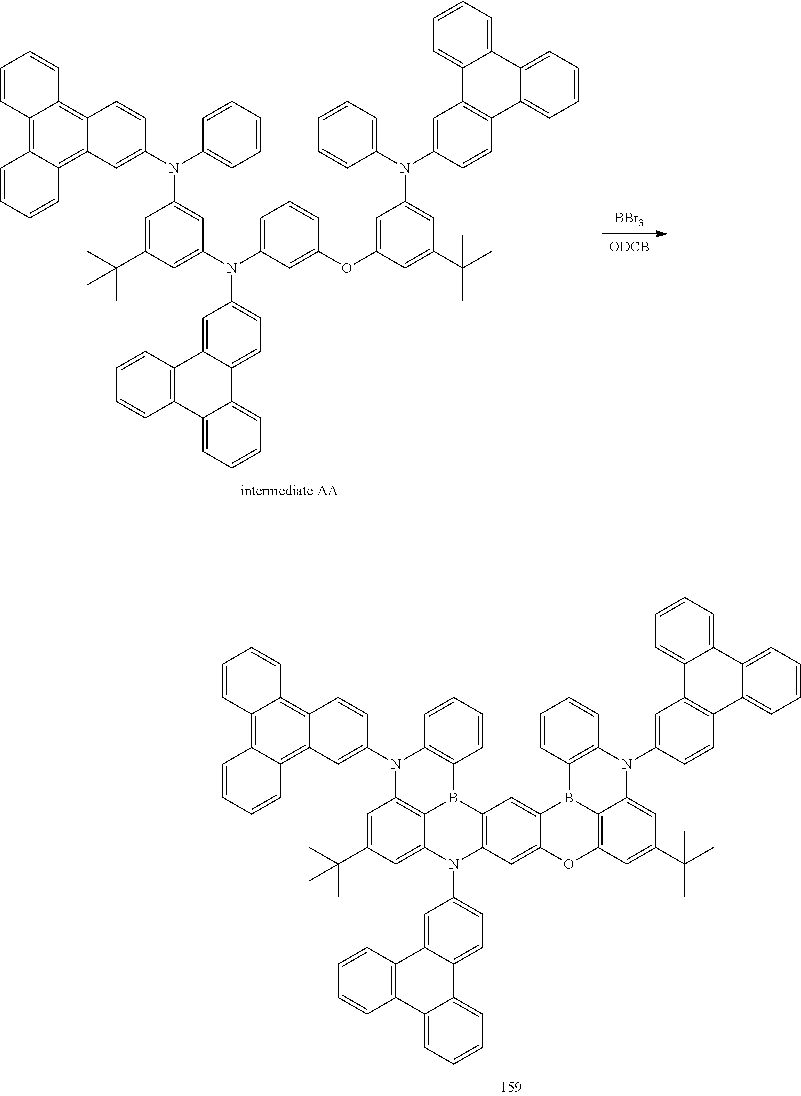 [SMILES: CC(C)(C)c1cc(Oc2cccc(N(c3cc(N(c4ccccc4)c4ccc5c6ccccc6c6ccccc6c5c4)cc(C(C)(C)C)c3)c3ccc4c5ccccc5c5ccccc5c4c3)c2)cc(N(c2ccccc2)c2ccc3c4ccccc4c4ccccc4c3c2)c1 ; "ODCB" ; "BBr3" ; CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1]

<Synthesis of Intermediate X>

In an Ar atmosphere, 1-bromo-3-(tert-butyl)-5-fluorobenzene (15.00 g, 64.90 mmol), aniline (13.15 g, 142.7 mmol), Pd(dba)₂ (3.732 g, 6.490 mmol), P(t-Bu)₃HBF₄ (3.766 g, 12.98 mmol), and t-BuONa (24.94 g, 259.6 mmol) were added to 324 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate X (13.10 g, yield 83%).

By measuring FAB-MS, a mass number of m/z=243 was observed by molecular ion peak, thereby identifying Intermediate X.

<Synthesis of Intermediate Y>

In an Ar atmosphere, Intermediate X (12.00 g, 49.31 mmol), 2-bromotriphenylene (18.17 g, 59.17 mmol), Pd(dba)₂ (2.835 g, 4.931 mmol), P(t-Bu)₃HBF₄ (2.861 g, 9.863 mmol), and t-BuONa (18.95 g, 197.2 mmol) were added to 250 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate Y (20.61 g, yield 89%).

By measuring FAB-MS, a mass number of m/z=469 was observed by molecular ion peak, thereby identifying Intermediate Y.

<Synthesis of Intermediate Z>

In an Ar atmosphere, Intermediate Y (20.0 g, 42.6 mmol), 3-bromophenol (8.84 g, 51.1 mmol), and 1-methyl-2-pyrrolidone (NMP, 150 mL) were added and maintained at about 0° C., and 60% NaH (3.41 g, 85.2 mmol) was added thereto, and the resulting mixture was stirred for about 30 minutes and stirred at about 100° C. for about 6 hours. Water and toluene were added thereto, and the resultant mixture was stirred for about 1 hour and subjected to celite filtering and liquid separation to concentrate an organic layer. The concentrated organic layer was purified by silica gel column chromatography to obtain Intermediate Z (26.5 g, yield 70%).

By measuring FAB-MS, a mass number of m/z=622 was observed by molecular ion peak, thereby identifying Intermediate Z.

<Synthesis of Intermediate AA>

In an Ar atmosphere, Intermediate Z (10.00 g, 16.06 mmol), Intermediate V (13.16 g, 19.27 mmol), Pd(dba)₂ (0.923 g, 1.606 mmol), P(t-Bu)₃HBF₄ (0.931 g, 3.212 mmol), and t-BuONa (6.174 g, 64.24 mmol) were added to 80 mL of toluene, and the resulting mixture was heated and stirred at about 80° C. for about 10 hours. Water was added thereto, and the resultant mixture was subjected to celite filtering and liquid separation to concentrate an organic layer. The concentrated organic layer was purified by silica gel column chromatography to obtain Intermediate AA (16.06 g, yield 81%).

By measuring FAB-MS, a mass number of m/z=1234 was observed by molecular ion peak, thereby identifying Intermediate AA.

<Synthesis of Compound 159>

In an Ar atmosphere, Intermediate AA (15.00 g, 12.14 mmol) was dissolved in 1,2-dichlorobenzene (120 mL), BBr₃ (7.60 g, 30.3 mmol) was added thereto, and the resulting mixture was heated and stirred at about 170° C. for about 10 hours. The resulting mixture was cooled to room temperature, N,N-diisopropylethylamine (18.8 g, 145.7 mmol) was added thereto and water was added thereto, and the resultant mixture was subjected to celite filtering and liquid separation to concentrate an organic layer. The concentrated organic layer was purified by silica gel column chromatography to obtain Intermediate 159 (2.58 g, yield 17%).

By measuring FAB-MS, a mass number of m/z=1250 was observed by molecular ion peak, thereby identifying Compound 159. Sublimation purification (390° C., 3.5×10⁻³ Pa) was conducted and element evaluation was performed.

2. Manufacture and Evaluation of Light Emitting Element

Evaluation of the light emitting elements including compounds of Examples and Comparative Examples was performed as follows. The method for manufacturing the light emitting element for the evaluation of the element is described below.

(1) Manufacture of Light Emitting Elements

A glass substrate on which a 150 nm-thick ITO had been patterned was ultrasonically washed by using isopropyl alcohol and pure water for about 5 minutes each. After ultrasonic washing, the glass substrate was irradiated with UV rays for about 30 minutes and treated with ozone. HAT-CN was deposited to a thickness of about 10 nm, α-NPD was deposited to a thickness of about 80 nm, and mCP was deposited to a thickness of about 5 nm in this order to form a hole transport region.

An Example Compound or a Comparative Example Compound and mCBP were co-deposited to form a 20 nm-thick emission layer. The Example Compound or the Comparative Example Compound and mCBP were co-deposited in a weight ratio of about 1:99. In the manufacture of the light emitting element, the Example Compound or the Comparative Example Compound was used as a dopant material.

TPBi was deposited to a thickness of about 30 nm and LiF was deposited to a thickness of about 0.5 nm in this order to form an electron transport region.

Al was deposited to form a 100 nm-thick second electrode.

In the Examples, the hole transport region, the emission layer, the electron transport region, and the second electrode were formed using a vacuum deposition apparatus.

The Example Compounds and Comparative Example Compounds which were used to manufacture the light emitting elements are as follows:

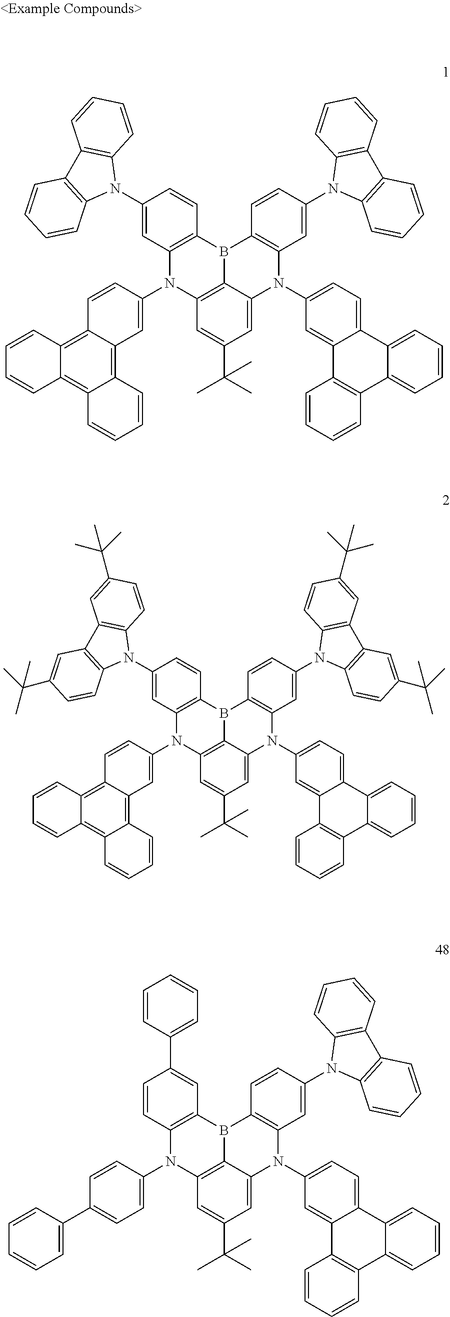 [SMILES: CC(C)(C)c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc(-c2ccccc2)cc1]

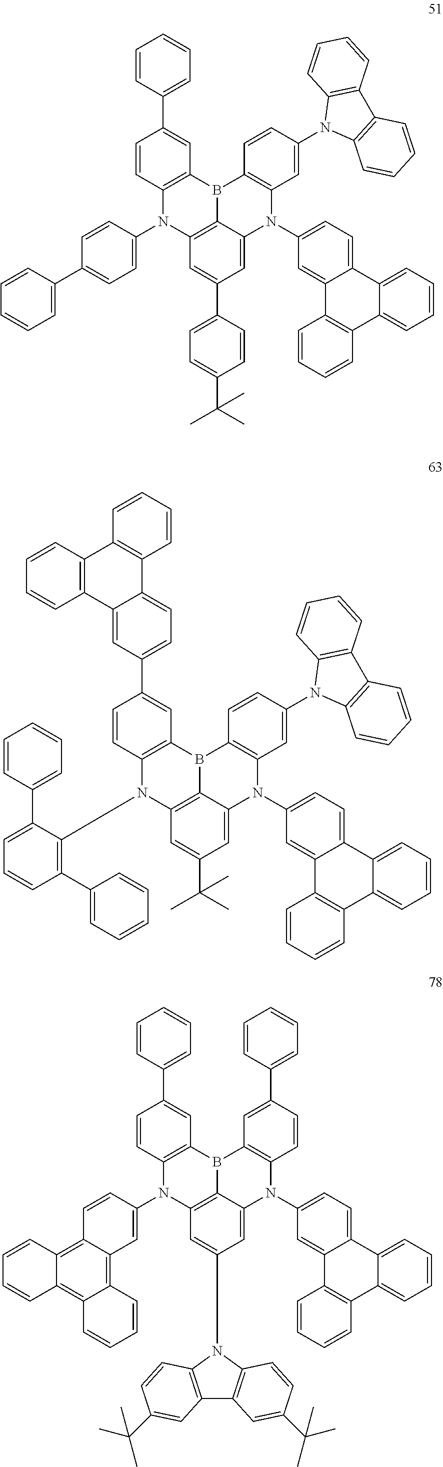 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc(-c3ccccc3)cc2)cc1 ; CC(C)(C)c1cc2c3c(c1)N(c1c(-c4ccccc4)cccc1-c1ccccc1)c1ccc(-c4ccc5c6ccccc6c6ccccc6c5c4)cc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1cc2c3c(c1)N(c1ccc4c5ccccc5c5ccccc5c4c1)c1ccc(-c4ccccc4)cc1B3c1cc(-c3ccccc3)ccc1N2c1ccc2c3ccccc3c3ccccc3c2c1]

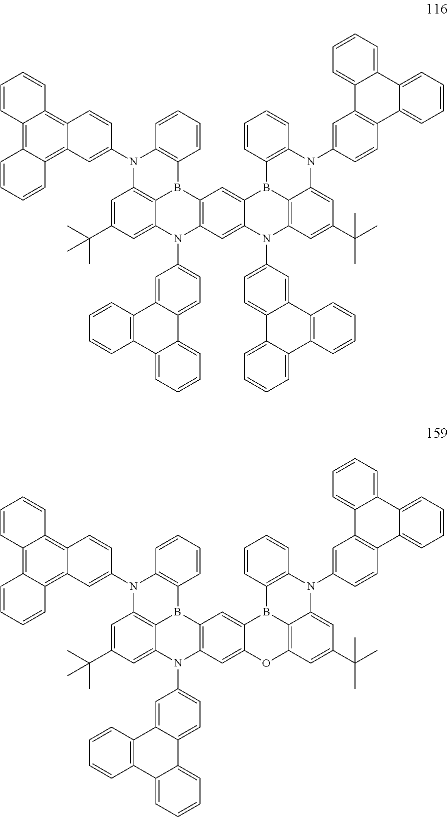 [SMILES: CC(C)(C)c1cc2c3c(c1)N(c1ccc4c5ccccc5c5ccccc5c4c1)c1cc4c(cc1B3c1ccccc1N2c1ccc2c3ccccc3c3ccccc3c2c1)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1]

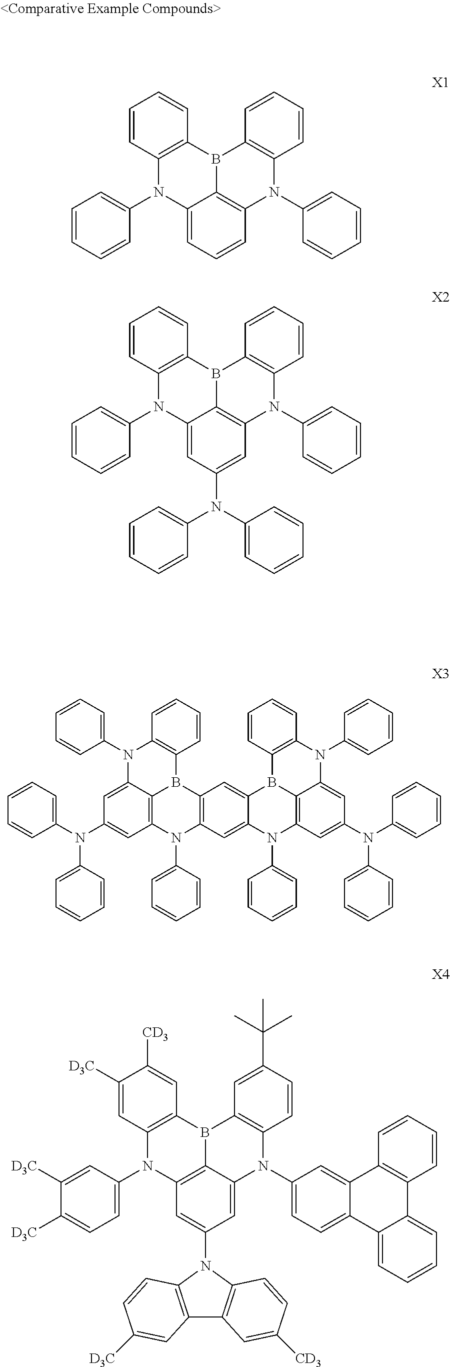 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; [2H]C([2H])([2H])c1ccc2c(c1)c1cc(C([2H])([2H])[2H])ccc1n2-c1cc2c3c(c1)N(c1ccc(C([2H])([2H])[2H])c(C([2H])([2H])[2H])c1)c1cc(C([2H])([2H])[2H])c(C([2H])([2H])[2H])cc1B3c1cc(C(C)(C)C)ccc1N2c1ccc2c3ccccc3c3ccccc3c2c1]

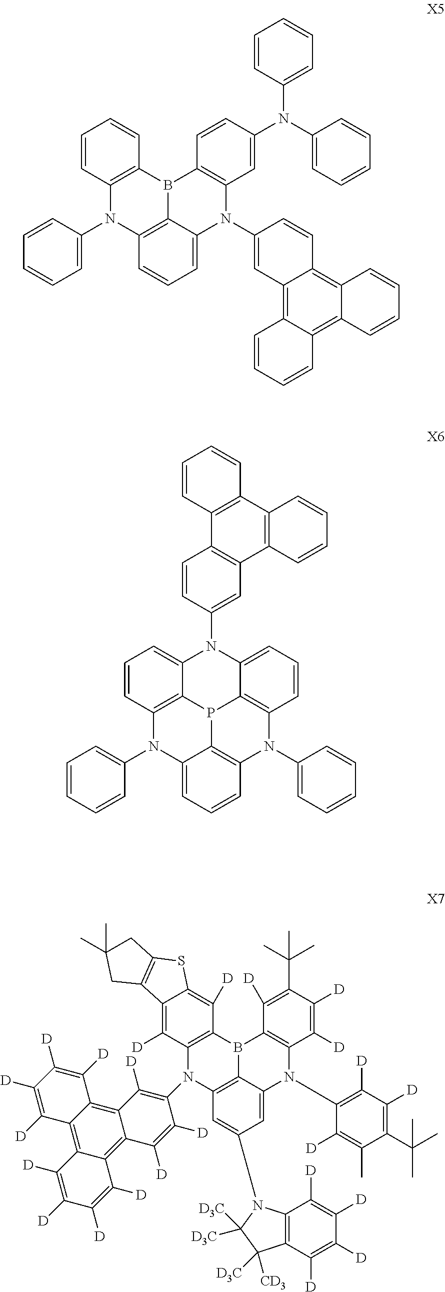

(2) Evaluation of Light Emitting Elements

Evaluation results of the light emitting elements of Examples 1 to 8, and Comparative Examples 1 to 7 are listed in Table 1. A maximum emission wavelength (λₘₐₓ), a delayed fluorescence service life, roll-off, and a half service life (LT50) in the manufactured light emitting elements are listed for comparison in Table 1.

In the characteristic evaluation results of the Examples and the Comparative Examples listed in Table 1, the roll-off is represented by [[(external quantum efficiency at 1 cd/m³)−(1000 cd/m³)]/(external quantum efficiency at 1 cd/m³)]×100. The half service life is shown by evaluating a brightness half-life from an initial brightness of 100 cd/m². The half service life is shown as a relative value assuming the result of Comparative Example 3 as 100.

The delayed fluorescence service life is the value of measuring PL of a thin film having a thickness of 20 nm, in which Example Compound or Comparative Example Compound and mCBP are co-deposited in a weight ratio of 1:99.

TABLE 1

| | | | Delayed | | |
|---|---|---|---|---|---|
| | | | fluorescence | Roll- | |
| | | λₘₐₓ | service life | off | LT50 |
| Division | Dopant Material | (nm) | (μs) | (%) | (%) |
| Example 1 | Compound 1 | 457 | 90 | 20.6 | 280 |
| Example 2 | Compound 2 | 458 | 80 | 18.0 | 330 |
| Example 3 | Compound 48 | 461 | 75 | 15.3 | 300 |
| Example 4 | Compound 51 | 464 | 70 | 13.0 | 350 |
| Example 5 | Compound 63 | 461 | 82 | 12.0 | 380 |
| Example 6 | Compound 78 | 460 | 52 | 11.0 | 400 |
| Example 7 | Compound 116 | 461 | 10 | 10.0 | 420 |
| Example 8 | Compound 159 | 458 | 8 | 8.2 | 480 |
| Comparative | Comparative | 457 | 130 | 33.2 | 30 |
| Example 1 | Example | | | | |
| | Compound X1 | | | | |
| Comparative | Comparative | 446 | 11.2 | 30.5 | 20 |
| Example 2 | Example | | | | |
| | Compound X2 | | | | |
| Comparative | Comparative | 467 | 5.5 | 13.5 | 100 |
| Example 3 | Example | | | | |
| | Compound X3 | | | | |
| Comparative | Comparative | 455 | 125 | 28.3 | 25 |
| Example 4 | Example | | | | |
| | Compound X4 | | | | |
| Comparative | Comparative | 458 | 95 | 32.3 | 30 |
| Example 5 | Example | | | | |
| | Compound X5 | | | | |
| Comparative | Comparative | 450 | 300 | 52.3 | 10 |
| Example 6 | Example | | | | |
| | Compound X6 | | | | |
| Comparative | Comparative | 455 | 100 | 32.8 | 20 |
| Example 7 | Example | | | | |
| | Compound X7 | | | | |

Referring to the results of Table 1, Examples 1 to 8 according to embodiments exhibit long service life characteristics compared with Comparative Examples 1 to 7. It is thought that the light emitting elements of Examples 1 to 8 include a core moiety including a boron atom as a ring-forming atom and at least one triphenylenyl group substituted at the core part, and include, as a material for an emission layer, the polycyclic compound satisfying a combination of specific substituents of R₃, R₄, R₇, and R₈ as described above, and thus exhibit long service life characteristics compared with the light emitting elements of Comparative Examples that exclude triphenylenyl group or include, as a material for an emission layer, Comparative Example Compound which does not satisfy a combination of specific sub stituents of R₃, R₄, R₇, and R_{8.}

The maximum emission wavelength (max) for Examples 1 to 8 is about 460 nm, which exhibits color purity close to pure blue as compared with the Comparative Examples. All of Examples 1 to 8 exhibit improved characteristics in the half service life as compared with Comparative Examples 1 to 7.

When Examples 1 to 6 including one boron atom (B) in the polycyclic compound are compared with Comparative Examples 1, 2, 4, 5, and 7, Examples 1 to 6 including the polycyclic compound in which any one of R₃ and R₄ and any one of R₇ and R₈ are each independently an amine group, an aryl group, or a heteroaryl group exhibit lower roll-off values. Accordingly, it is thought that Examples 1 to 6 have significant improvement in the half service life as compared with Comparative Examples 1, 2, 4, 5, and 7. Examples 1 to 6 exhibit a delayed fluorescence service life equal to or less than about 90 μs.

When the light emitting elements of Examples 1 to 6 including the polycyclic compounds having a similar compound structure are compared with the light emitting element of Comparative Example 5, it may be confirmed that the light emitting elements of the Examples have significant improvement in service life compared with that of the Comparative Examples. It is thought that this is because when one boron atom is present in the polycyclic compound, the structure of Example Compound in which any one of R₃ and R₄ and any one of R₇ and R₈ are each independently an amine group, an aryl group, or a heteroaryl group has greater molecular stability than that of the Comparative Example Compounds in which only one among R₃, R₄, R₇, and R₈ is an amine group, an aryl group, or a heteroaryl group.

Referring to the results of element evaluation of Examples 3 and 5, for Example Compound 63 included in the element of Example 5, R₄ is an unsubstituted triphenylenyl group, and thus the element of Example 5 has greater improvement in service life than that of Example 3 including Example Compound 48 in which R₄ is an unsubstituted phenyl group.

Therefore, it is thought that the polycyclic compound according to embodiments includes a fused ring including a boron atom as a core moiety and at least one triphenylenyl group substituted at the fused ring, and thus has an increase in excitation stability of the molecule and a decrease in intermolecular interaction due to the increase of the molecular volume, thereby significantly improving the service life of the light emitting element including the fused ring and triphenylenyl group.

When the elements of Examples 7 and 8 including an Example Compound that includes two boron atoms (B) in the polycyclic compound are compared with the element of Comparative Example 3, it may be seen that Examples 7 and 8 including at least one triphenylenyl group as a substituent exhibit lower roll-off values. Accordingly, it is thought that Examples 7 and 8 exhibit the results of significantly improved half service life as compared with Comparative Example 3. Examples 7 and 8 exhibit a delayed fluorescence service life equal to or less than about 10 μs.

It is thought that the Example Compounds used in Examples 7 and 8 include three or four triphenylenyl groups, and thus have a greater steric shielding effect that protects the compound molecule, and accordingly, the stability of the compounds is increased, and the effect of improving the service lives of the light emitting elements including the Example Compounds is exhibited.

For Comparative Example Compound X6 included in the light emitting element of Comparative Example 6, the fused ring of the core includes three nitrogen atoms surrounding a phosphorus atom (P), and has a skeleton in which each of the three nitrogen atoms forms a bridge. It is believed that reverse intersystem crossing (RISC) for generating thermally activated delayed fluorescence (TADF) emission is not readily achieved, external quantum efficiency (EQE) is reduced, driving voltage is increased, and thus the service life characteristic is reduced. The Example Compound according to embodiments includes a boron atom in a core moiety, and two nitrogen atoms surrounding the boron atom, and has a skeleton including two bridge structures. Accordingly, multiple resonance effects may be enhanced, and external quantum efficiency may increase, thereby increasing element service life characteristics.

It is believed that Comparative Example Compound X₇ included in the light emitting element of Comparative Example 7 includes benzothiophene included in the fused ring of a core moiety, and thus the service life is reduced. Furthermore, Comparative Example Compound X₇ does not satisfy the condition wherein “when neither of R₃, R₄, R₇, and R₈ is a substituted or unsubstituted boron group, any one of R₃ and R₄ and any one of R₇ and R₈ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms.” Accordingly, it is thought that the core moiety including a boron atom as a ring-forming atom is not stable and the service life characteristic is significantly reduced.

The polycyclic compound according to an embodiment includes a core moiety including a boron atom as a ring-forming atom, and includes at least one triphenylenyl group which is a substituent of the core moiety, thereby exhibiting the effect of improving the stability of the whole compound. The light emitting element including a polycyclic compound of an Example may exhibit a long service life characteristic.

The light emitting element according to an embodiment may include the polycyclic compound according to an embodiment in the emission layer, thereby exhibiting a long service life characteristic.

The polycyclic compound of an embodiment may include the polycyclic group having a great steric effect, thereby contributing to improving the service life of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
at least one functional layer disposed between the first electrode and the second electrode, wherein
the at least one functional layer comprises:
a first compound represented by Formula 1; and
at least one of a second compound represented by Formula HT-1, a third compound represented by Formula ET-1, or a fourth compound represented by Formula M-b: 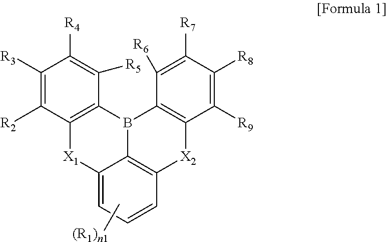
wherein in Formula 1,
X₁ and X₂ are each independently N(R₁₀), O, or S,
R₁ to R₁₀ are each independently:
a hydrogen atom, a deuterium atom, a halogen atom, a substituted or unsubstituted amine group, a substituted or unsubstituted boron group, a substituted or unsubstituted alkyl group 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
n1 is an integer from 0 to 3,
at least one of R₁ to R₁₀ is each independently a group represented by Formula 2,
when R₃ or R₄ is a substituted or unsubstituted boron group, R₃ and R₄ are bonded to each other to form a ring,
when R₇ or R₈ is a substituted or unsubstituted boron group, R₇ and R₈ are bonded to each other to form a ring, and
when neither of R₃, R₄, R₇, and R₈ is a substituted or unsubstituted boron group, one of R₃ and R₄ and one of R₇ and R₈ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms: 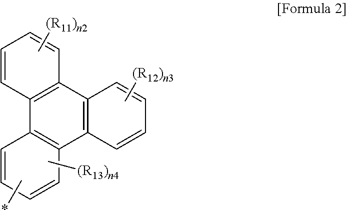
wherein in Formula 2,
R₁₁ to R₁₃ are each independently a hydrogen atom, a deuterium atom, a halogen atom, a substituted or unsubstituted amine group, substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n2 and n3 are each independently an integer from 0 to 4,
n4 is an integer from 0 to 3, and [symbol]
represents a binding site to Formula 1: 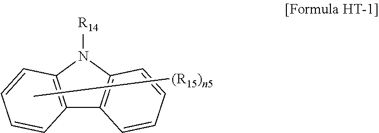
wherein in Formula HT-,
R₁₄ and R₁₅ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms,
n5 is an integer from 0 to 8: 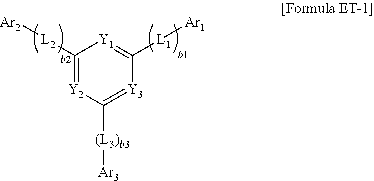
wherein in Formula ET-1,
at least one of Y₁ to Y₃ is N,
the remainder of Y₁ to Y₃ are each independently C(Rₐ),
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b 1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms: 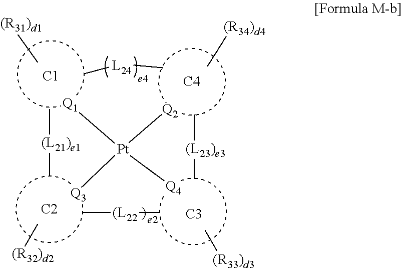
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heteroaryl group having 2 to 30 ring-forming carbon atoms,
e1 to e4 are each independently 0 or 1,
L₂₁ to L24 are each independently a direct linkage, 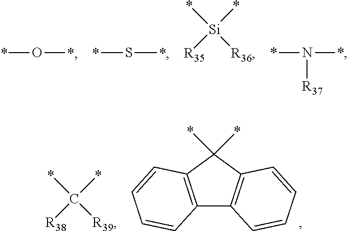
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

2. The light emitting element of claim 1, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound, the third compound, or the fourth compound.

3. The light emitting element of claim 1, wherein the first compound represented by Formula 1 is represented by Formula 1-1 or Formula 1-2: 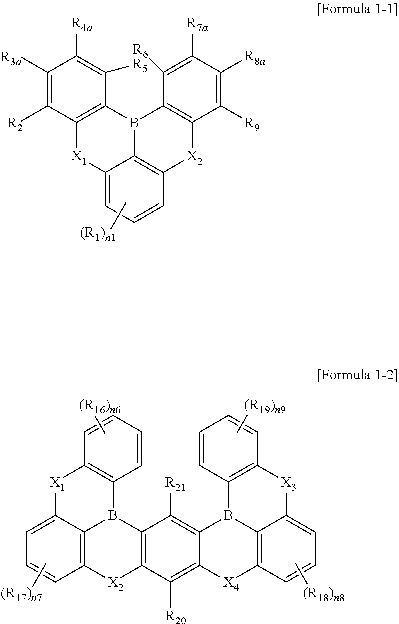
wherein in Formula 1-1,
R₃ₐ, R₄ₐ, R₇ₐ, and R₈ₐ are each independently:
a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁, R₂, R₅, R₆, R₉, R₁₀, R₃ₐ, R₄ₐ, R₇ₐ, or R₈ₐ is a group represented by Formula 2, and
one of R₃, and R₄ₐ and one of R₇, and R₈ₐ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms,
wherein in Formula 1-2,
X₃ and X₄ are each independently N(R₂₂), O, or S,
R₁₆ to R₂₂ are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁₆ to R₂₂ is a group represented by Formula 2,
n6 and n9 are each independently an integer from 0 to 4,
n7 and n8 are each independently an integer from 0 to 3, and
wherein in Formula 1-1 and Formula 1-2,
X₁, X₂, R₁, R₂, R₅, R₆, R₉, R₁₀, and n1 are each the same as defined in Formula 1.

4. The light emitting element of claim 3, wherein the first compound represented by Formula 1-1 is represented by Formula 1-1a: 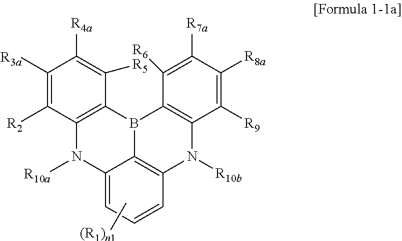
wherein in Formula 1-1a,
R₁₀ₐ and R_{10b} are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁, R₂, R₅, R₆, R₉, R₃ₐ, R₄ₐ, R₇ₐ, R₈ₐ, R₁₀ₐ or R_{10b} is a group represented by Formula 2,
R₃ₐ, R₄ₐ, R₇ₐ, and R₈ are each the same as defined in Formula 1-1, and
R₁, R₂, R₅, R₆, R₉, and n1 are each the same as defined in Formula 1.

5. The light emitting element of claim 3, wherein the first compound represented by Formula 1-2 is represented by one of Formulae 1-2a to 1-2e: 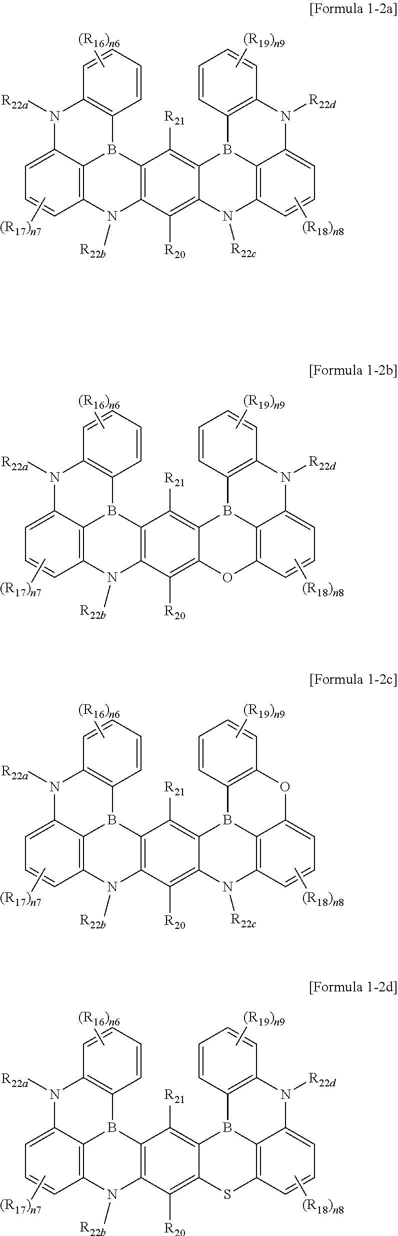 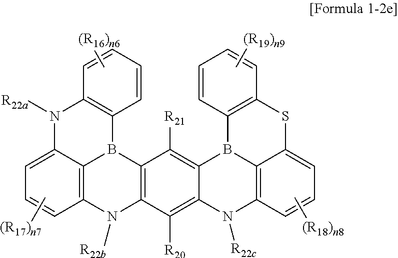
wherein in Formulae 1-2a to 1-2e,
R₂₂ₐ to R_{22d} are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁₆ to R₂₁ and R₂₂ₐ to R_{22d} is a group represented by Formula 2, and
R₁₆ to R₂₁ and n6 to n9 are each the same as defined in Formula 1-2.

6. The light emitting element of claim 1, wherein the first compound represented by Formula 1 is represented by Formula 1-3: 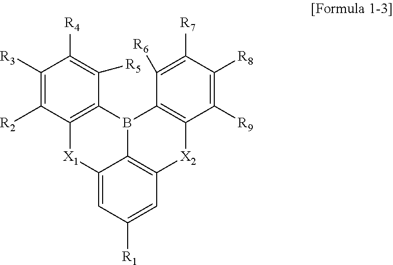
wherein in Formula 1-3,
X₁, X₂, and R₁ to R₉ are each the same as defined in Formula 1.

7. The light emitting element of claim 1, wherein the group represented by Formula 2 is represented by Formula 2-1: 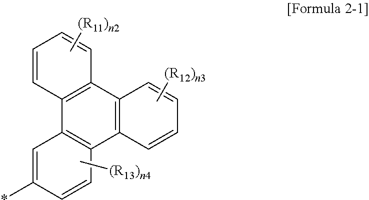
wherein in Formula 2-1,
R₁₁, R₁₂, R₁₃, n2 to n4, and [symbol] are each the same as defined in Formula 2.

8. The light emitting element of claim 1, wherein R₁ is a hydrogen atom, a substituted or unsubstituted t-butyl group, a substituted or unsubstituted phenyl group, a substituted or unsubstituted diphenylamine group, a substituted or unsubstituted triphenylenyl group, a substituted or unsubstituted carbazole group, a substituted or unsubstituted dibenzofuran group, or a substituted or unsubstituted dibenzothiophene group.

9. The light emitting element of claim 1, wherein R₂, R₅, R₆, and R₉ are each independently a hydrogen atom or a deuterium atom.

10. The light emitting element of claim 1, wherein R₃, R₄, R₇, and R₈ are each independently a hydrogen atom, a deuterium atom, a substituted or unsubstituted boron group, a substituted or unsubstituted phenyl group, a substituted or unsubstituted triphenylenyl group, a substituted or unsubstituted carbazole group, or a substituted or unsubstituted diphenylamine group.

11. The light emitting element of claim 1, wherein R₁₀ is a substituted or unsubstituted phenyl group, a substituted or unsubstituted biphenyl group, a substituted or unsubstituted terphenyl group, or a substituted or unsubstituted triphenylenyl group.

12. The light emitting element of claim 1, wherein R₁₁, R₁₂, and R₁₃ are each a hydrogen atom.

13. The light emitting element of claim 1, wherein the at least one functional layer comprises the first compound, the second compound, and the third compound.

14. The light emitting element of claim 1, wherein the at least one functional layer comprises the first compound, the second compound, the third compound, and the fourth compound.

15. The light emitting element of claim 1, wherein the first compound is selected from Compound Group 1: 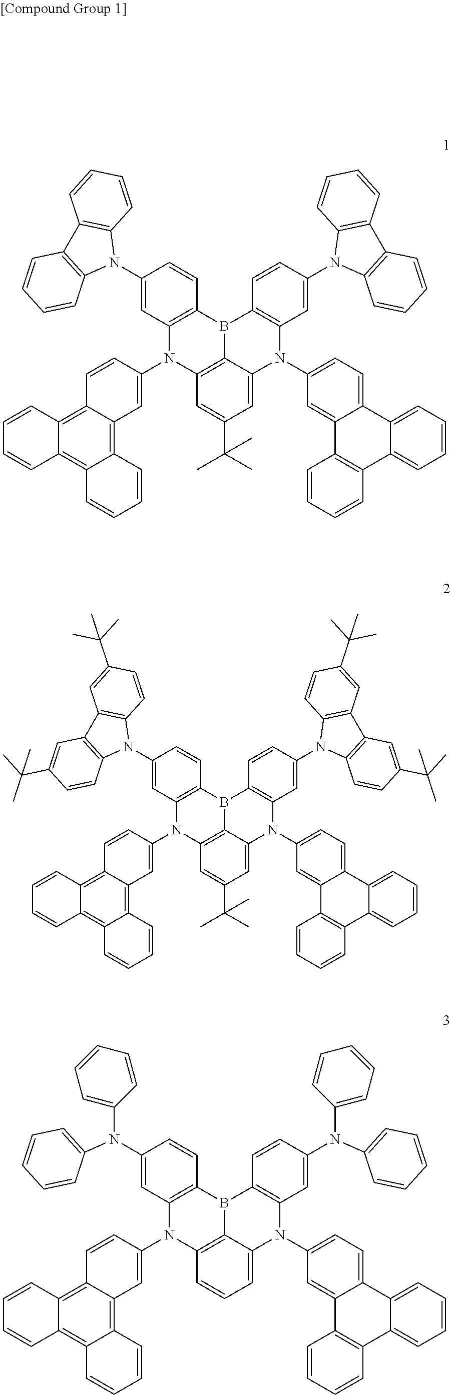 [SMILES: CC(C)(C)c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1ccc2c3ccccc3c3ccccc3c2c1 ; c1ccc(N(c2ccccc2)c2ccc3c(c2)N(c2ccc4c5ccccc5c5ccccc5c4c2)c2cccc4c2B3c2ccc(N(c3ccccc3)c3ccccc3)cc2N4c2ccc3c4ccccc4c4ccccc4c3c2)cc1] 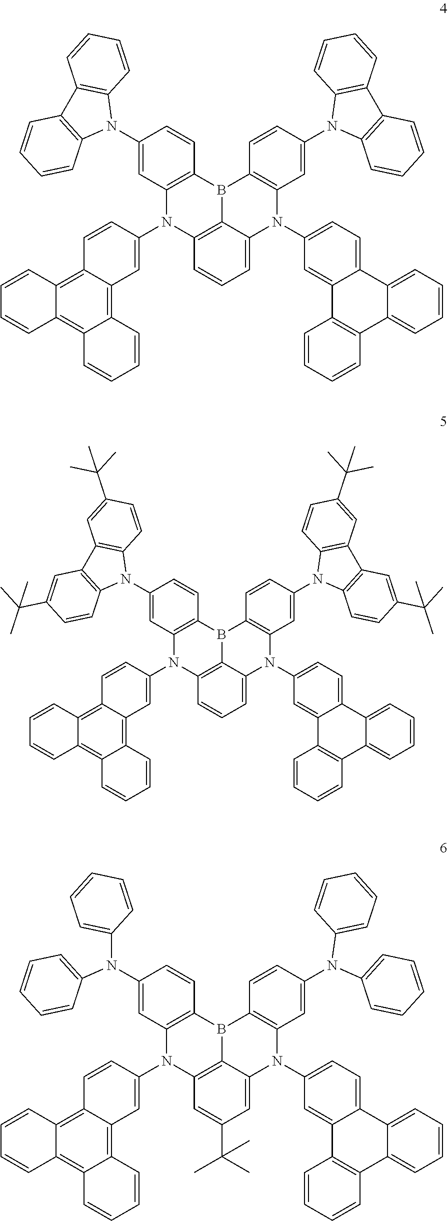 [SMILES: c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1ccc(-n2c4ccc(C(C)(C)C)cc4c4cc(C(C)(C)C)ccc42)cc1N3c1ccc2c3ccccc3c3ccccc3c2c1 ; CC(C)(C)c1cc2c3c(c1)N(c1ccc4c5ccccc5c5ccccc5c4c1)c1cc(N(c4ccccc4)c4ccccc4)ccc1B3c1ccc(N(c3ccccc3)c3ccccc3)cc1N2c1ccc2c3ccccc3c3ccccc3c2c1] 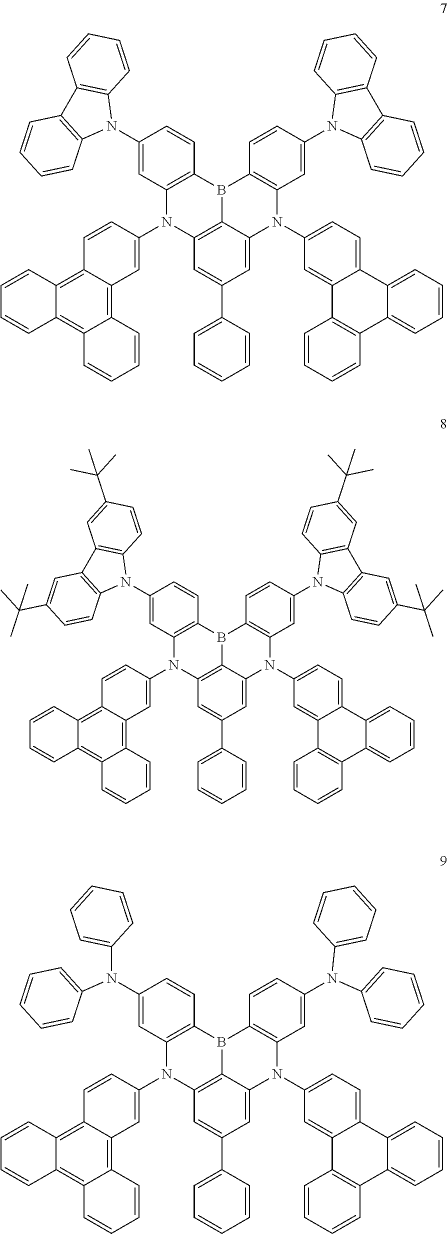 [SMILES: c1ccc(-c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1ccc(-n2c4ccc(C(C)(C)C)cc4c4cc(C(C)(C)C)ccc42)cc1N3c1ccc2c3ccccc3c3ccccc3c2c1 ; c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1] 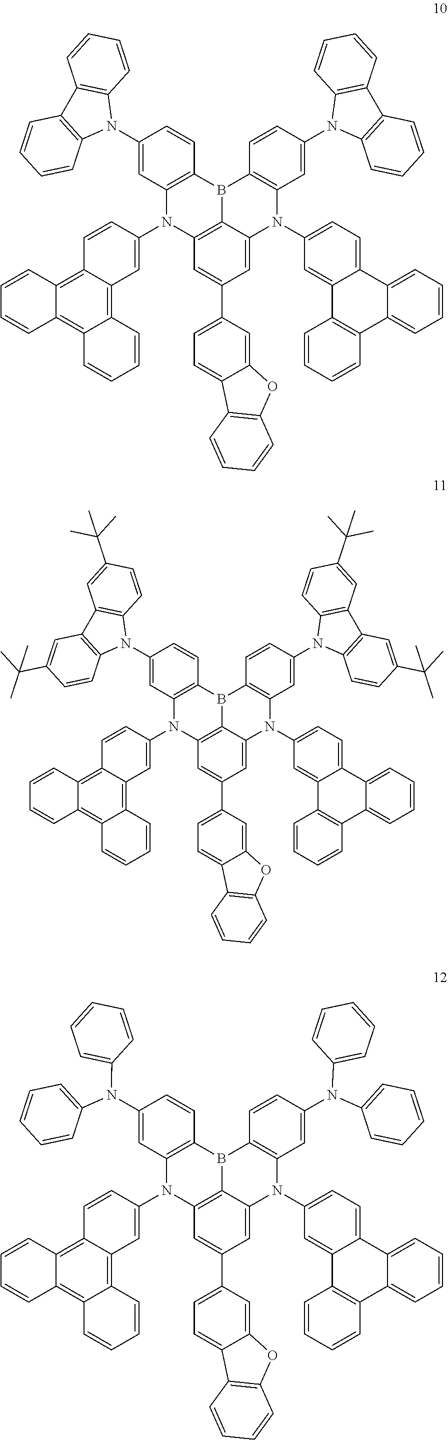 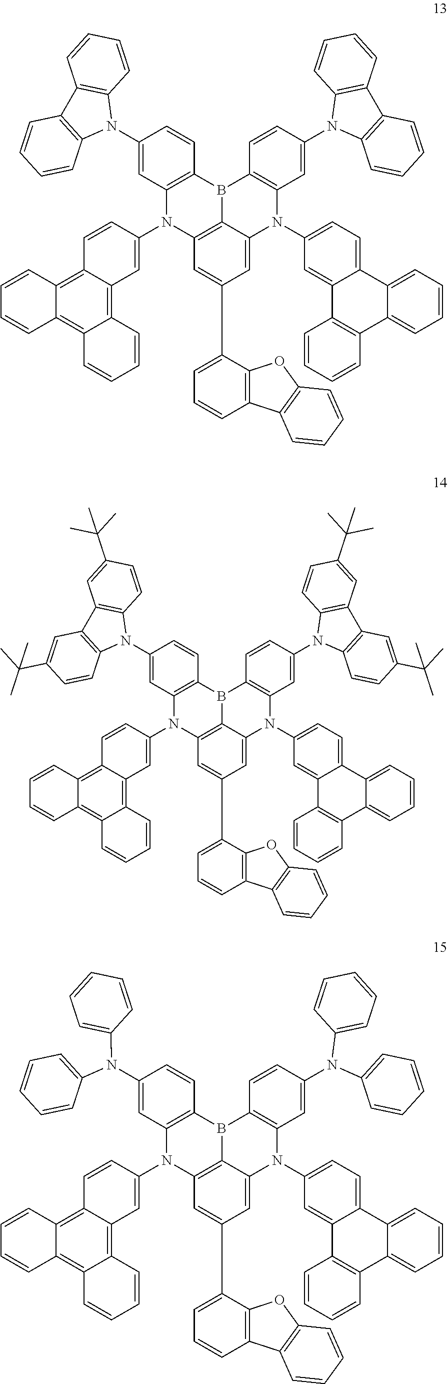 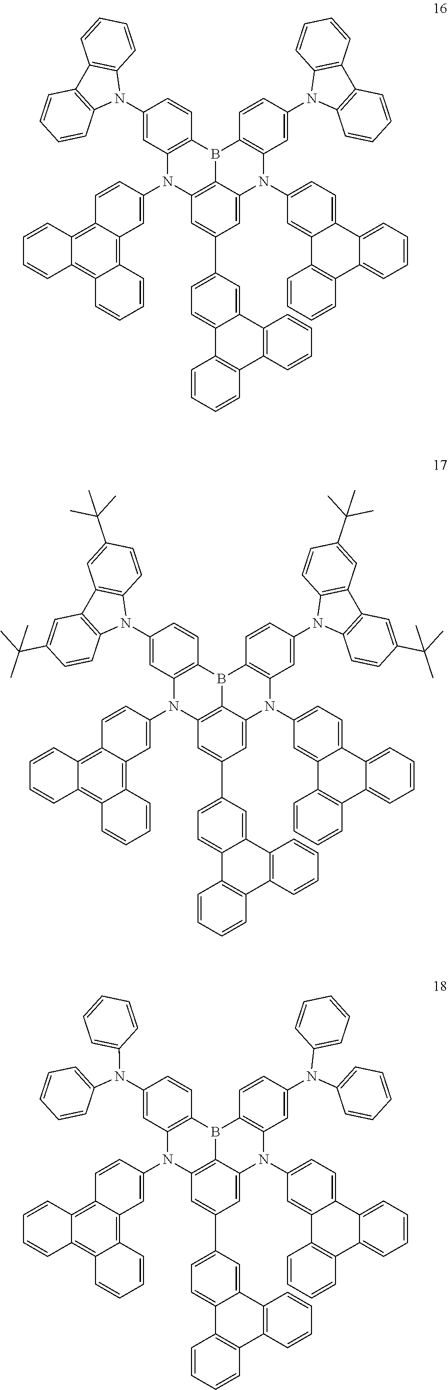 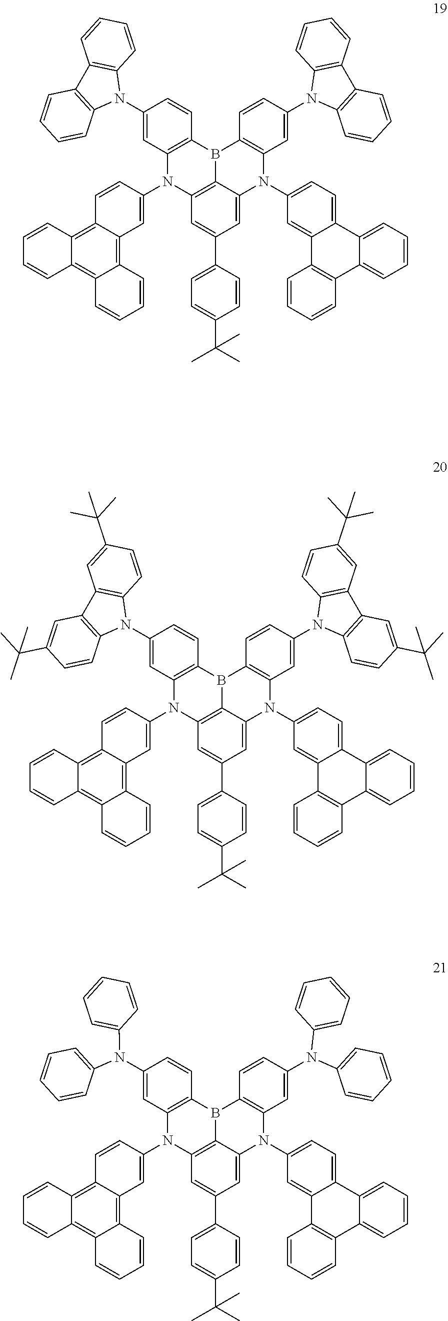 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1] 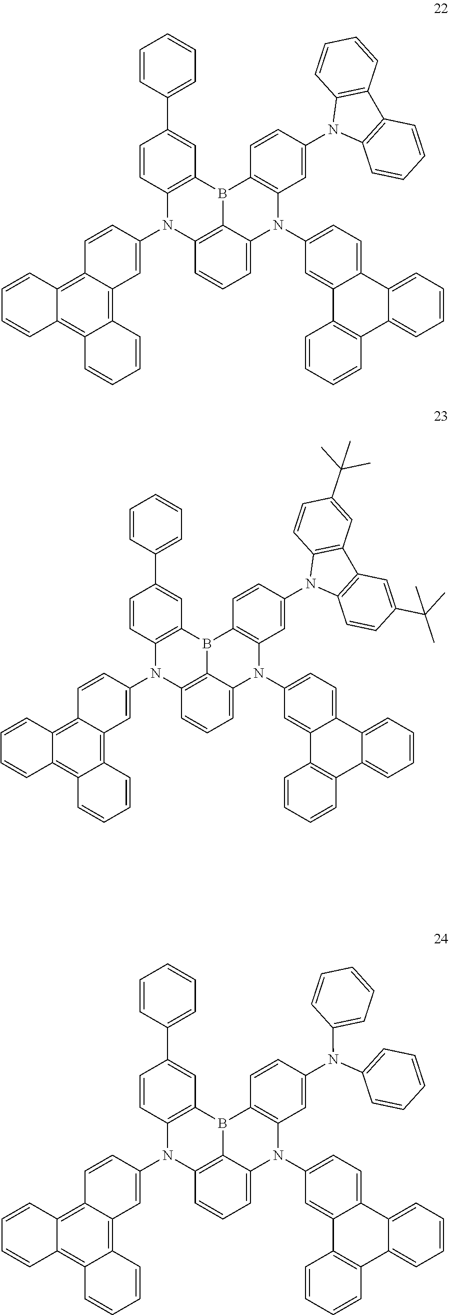 [SMILES: c1ccc(-c2ccc3c(c2)B2c4ccc(-n5c6ccccc6c6ccccc65)cc4N(c4ccc5c6ccccc6c6ccccc6c5c4)c4cccc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cccc(c42)N3c2ccc3c4ccccc4c4ccccc4c3c2)cc1] 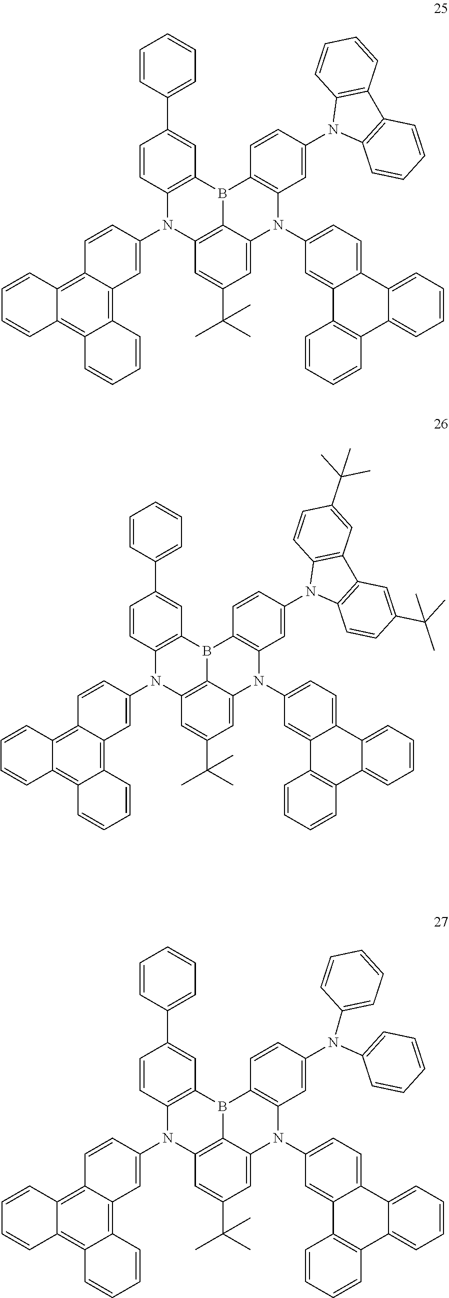 [SMILES: CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1cc(-c3ccccc3)ccc1N2c1ccc2c3ccccc3c3ccccc3c2c1 ; CC(C)(C)c1cc2c3c(c1)N(c1ccc4c5ccccc5c5ccccc5c4c1)c1cc(N(c4ccccc4)c4ccccc4)ccc1B3c1cc(-c3ccccc3)ccc1N2c1ccc2c3ccccc3c3ccccc3c2c1] 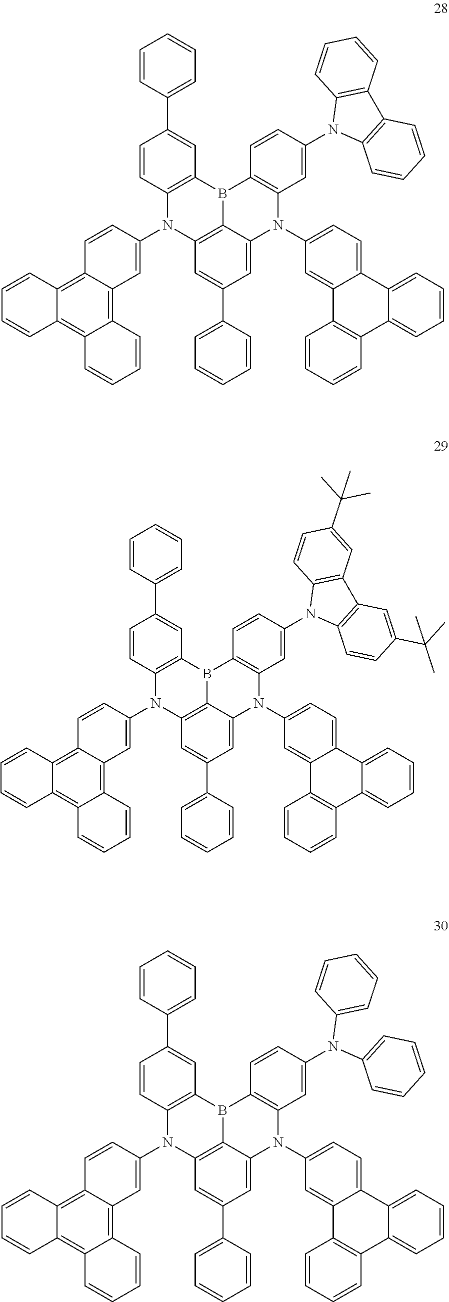 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-c5ccccc5)cc(c42)N3c2ccc3c4ccccc4c4ccccc4c3c2)cc1] 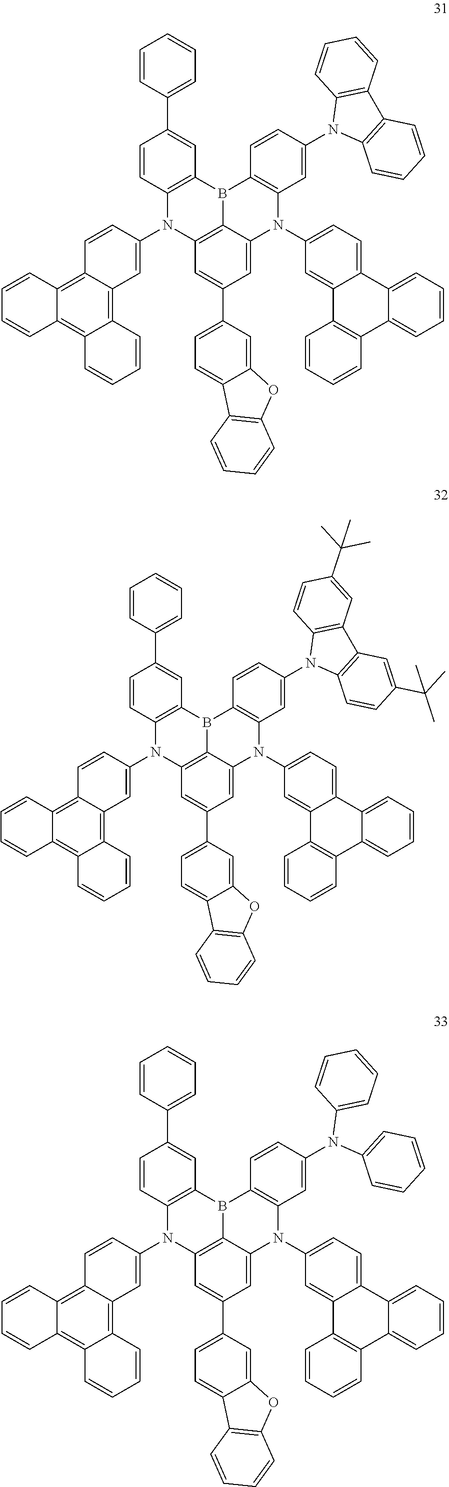 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1] 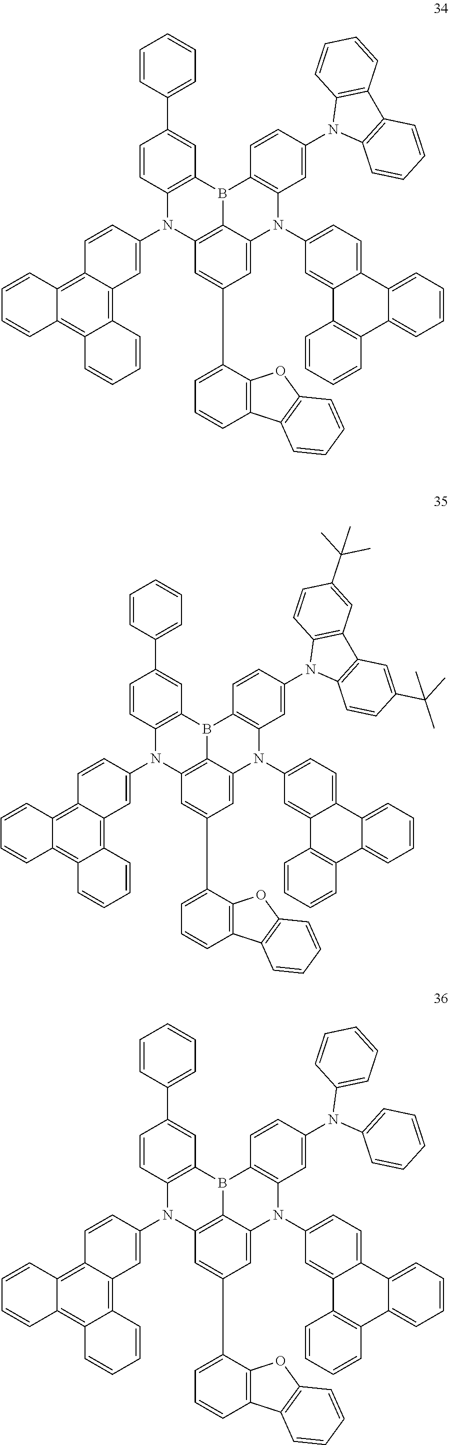 [SMILES: c1ccc(-c2ccc3c(c2)B2c4ccc(-n5c6ccccc6c6ccccc65)cc4N(c4ccc5c6ccccc6c6ccccc6c5c4)c4cc(-c5cccc6c5oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3cccc4c3oc3ccccc34)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(-c5cccc6c5oc5ccccc56)cc(c42)N3c2ccc3c4ccccc4c4ccccc4c3c2)cc1] 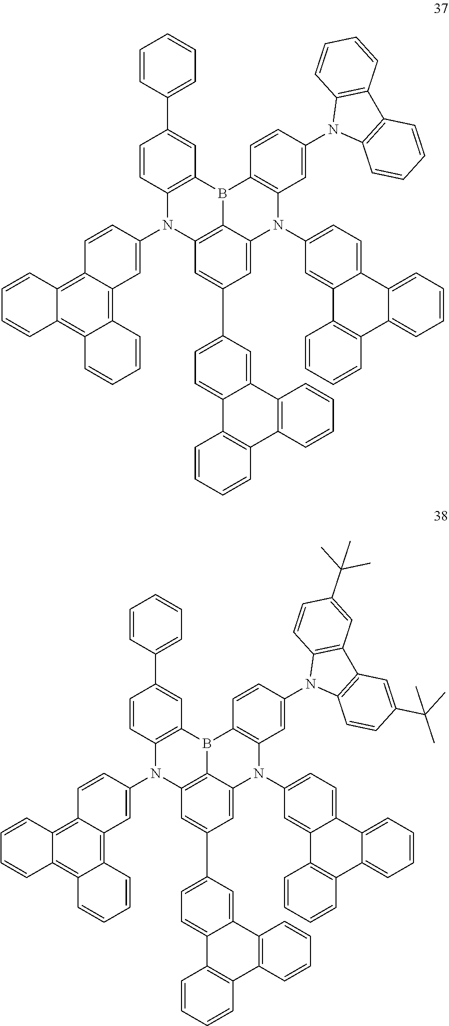 [SMILES: c1ccc(-c2ccc3c(c2)B2c4ccc(-n5c6ccccc6c6ccccc65)cc4N(c4ccc5c6ccccc6c6ccccc6c5c4)c4cc(-c5ccc6c7ccccc7c7ccccc7c6c5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c5ccccc5c5ccccc5c4c3)cc3c1B2c1cc(-c2ccccc2)ccc1N3c1ccc2c3ccccc3c3ccccc3c2c1] 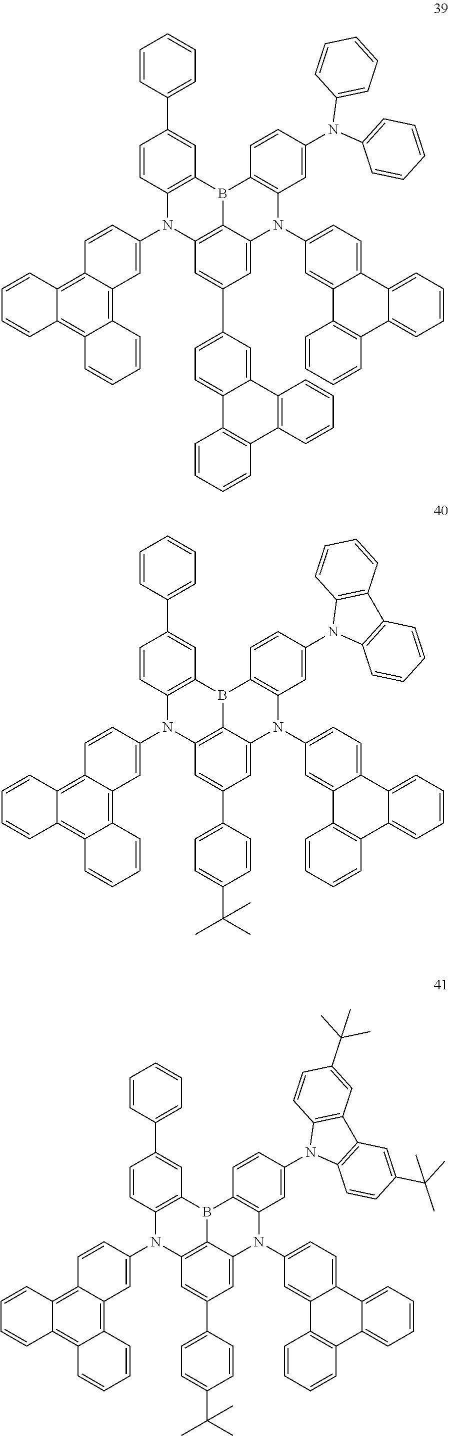 [SMILES: c1ccc(-c2ccc3c(c2)B2c4ccc(N(c5ccccc5)c5ccccc5)cc4N(c4ccc5c6ccccc6c6ccccc6c5c4)c4cc(-c5ccc6c7ccccc7c7ccccc7c6c5)cc(c42)N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2cc(-c4ccccc4)ccc2N3c2ccc3c4ccccc4c4ccccc4c3c2)cc1] 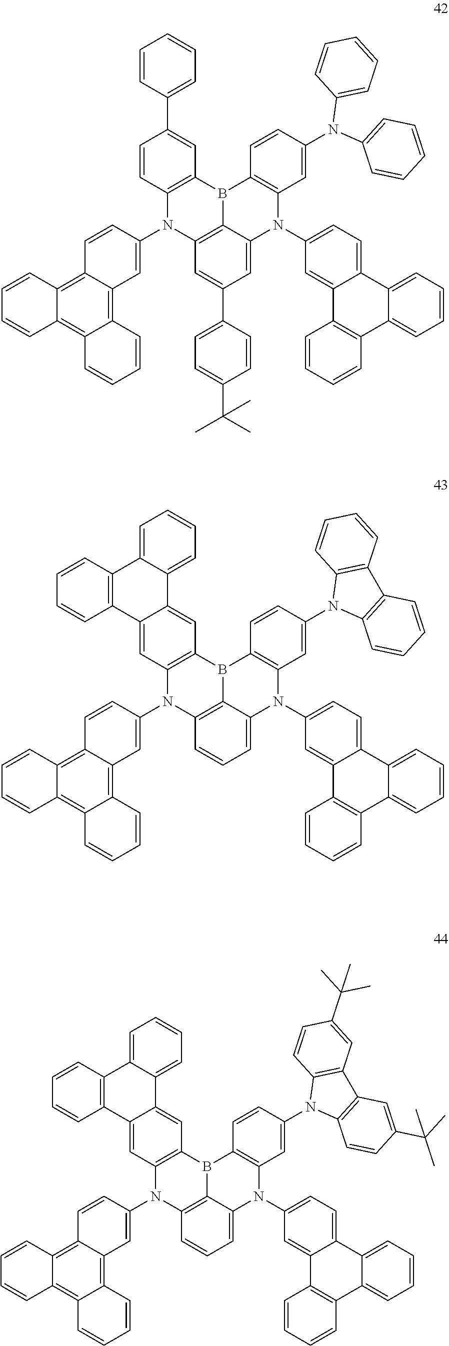 [SMILES: CC(C)(C)c1ccc(-c2cc3c4c(c2)N(c2ccc5c6ccccc6c6ccccc6c5c2)c2cc(N(c5ccccc5)c5ccccc5)ccc2B4c2cc(-c4ccccc4)ccc2N3c2ccc3c4ccccc4c4ccccc4c3c2)cc1 ; c1cc2c3c(c1)N(c1ccc4c5ccccc5c5ccccc5c4c1)c1cc4c5ccccc5c5ccccc5c4cc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1cc2c4ccccc4c4ccccc4c2cc1N3c1ccc2c3ccccc3c3ccccc3c2c1] 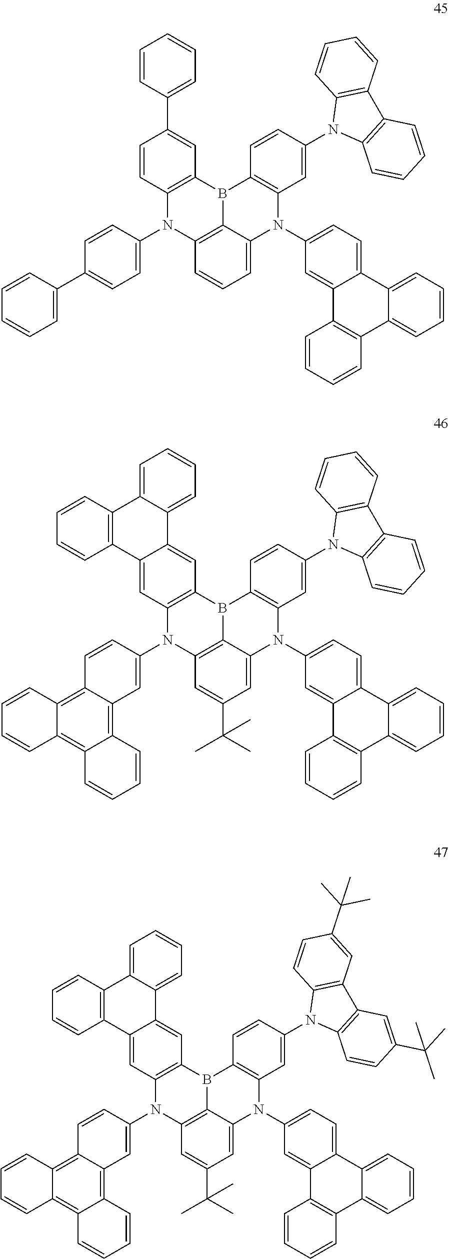 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cccc3c54)cc2)cc1 ; CC(C)(C)c1cc2c3c(c1)N(c1ccc4c5ccccc5c5ccccc5c4c1)c1cc4c5ccccc5c5ccccc5c4cc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc4c5ccccc5c5ccccc5c4cc1B3c1ccc(-n3c4ccc(C(C)(C)C)cc4c4cc(C(C)(C)C)ccc43)cc1N2c1ccc2c3ccccc3c3ccccc3c2c1] 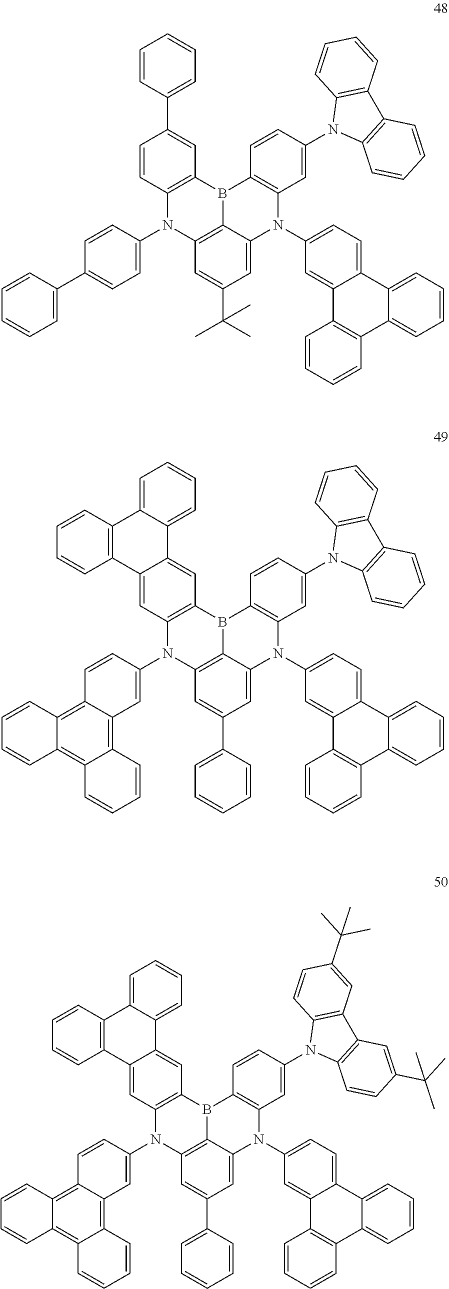 [SMILES: CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc(-c2ccccc2)cc1 ; c1ccc(-c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1cc2c4ccccc4c4ccccc4c2cc1N3c1ccc2c3ccccc3c3ccccc3c2c1] 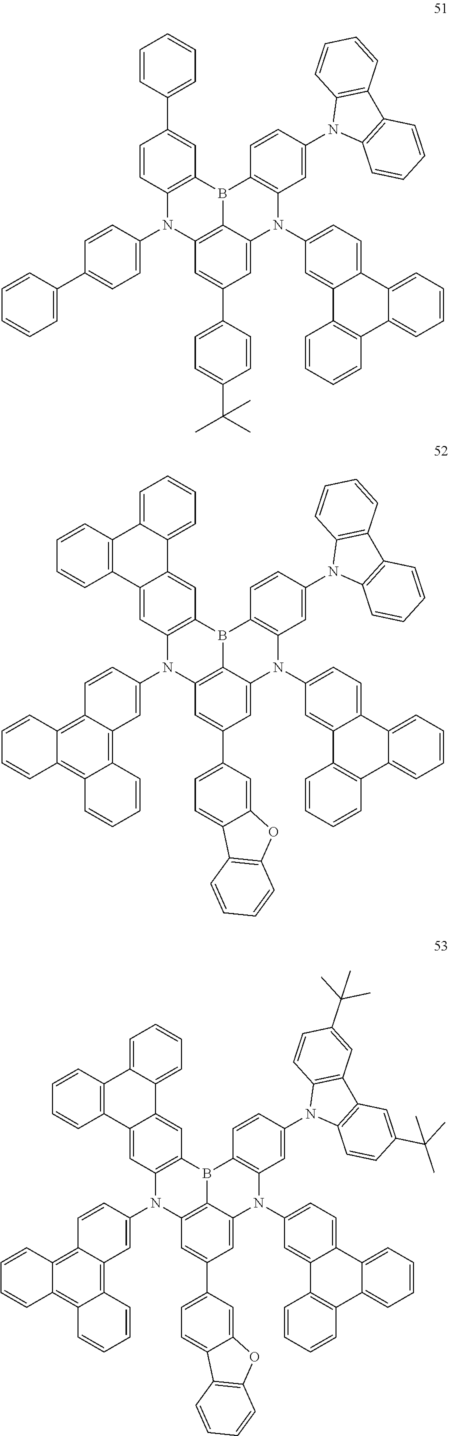 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc(-c3ccccc3)cc2)cc1 ; c1ccc2c(c1)oc1cc(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc2c4ccccc4c4ccccc4c2cc1N3c1ccc2c3ccccc3c3ccccc3c2c1] 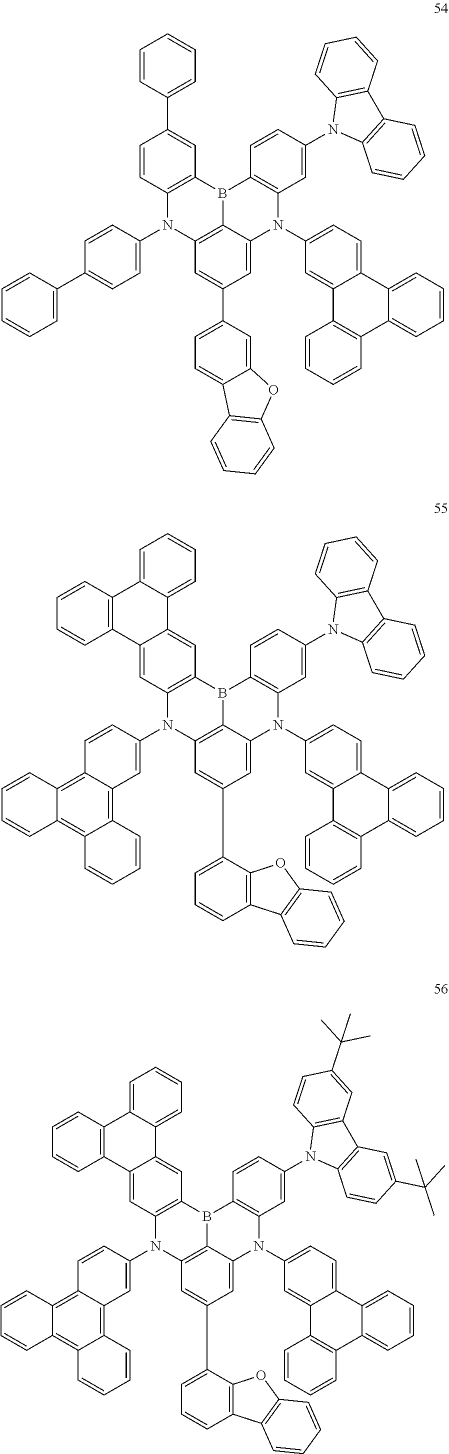 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6ccc7c(c6)oc6ccccc67)cc3c54)cc2)cc1 ; c1ccc2c(c1)oc1c(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)cccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3cccc4c3oc3ccccc34)cc3c1B2c1cc2c4ccccc4c4ccccc4c2cc1N3c1ccc2c3ccccc3c3ccccc3c2c1] 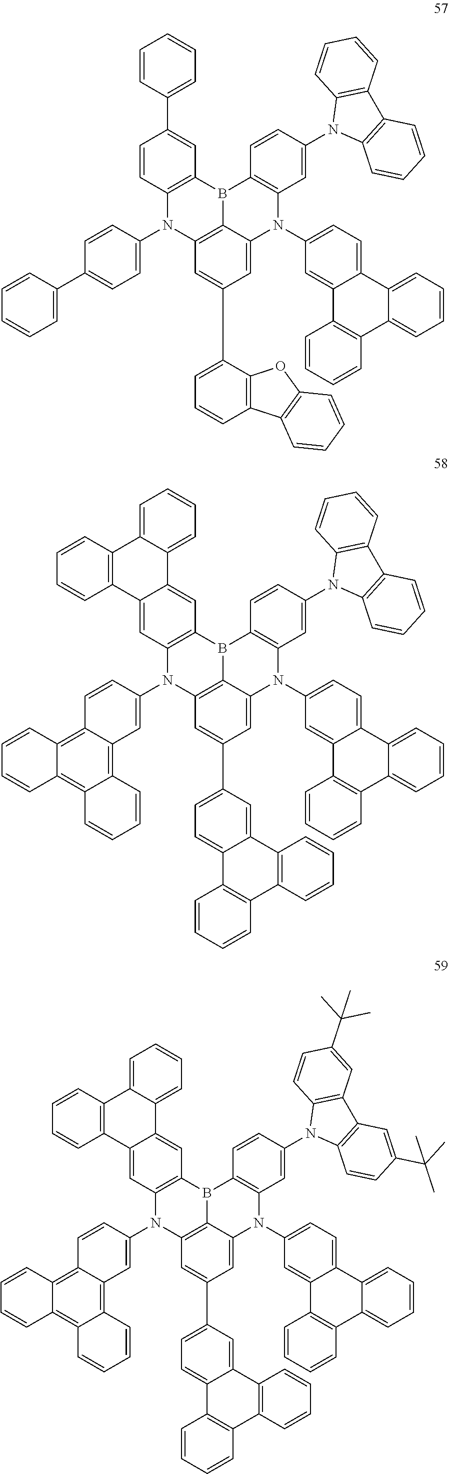 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6cccc7c6oc6ccccc67)cc3c54)cc2)cc1 ; c1ccc2c(c1)c1ccccc1c1cc(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c5ccccc5c5ccccc5c4c3)cc3c1B2c1cc2c4ccccc4c4ccccc4c2cc1N3c1ccc2c3ccccc3c3ccccc3c2c1] 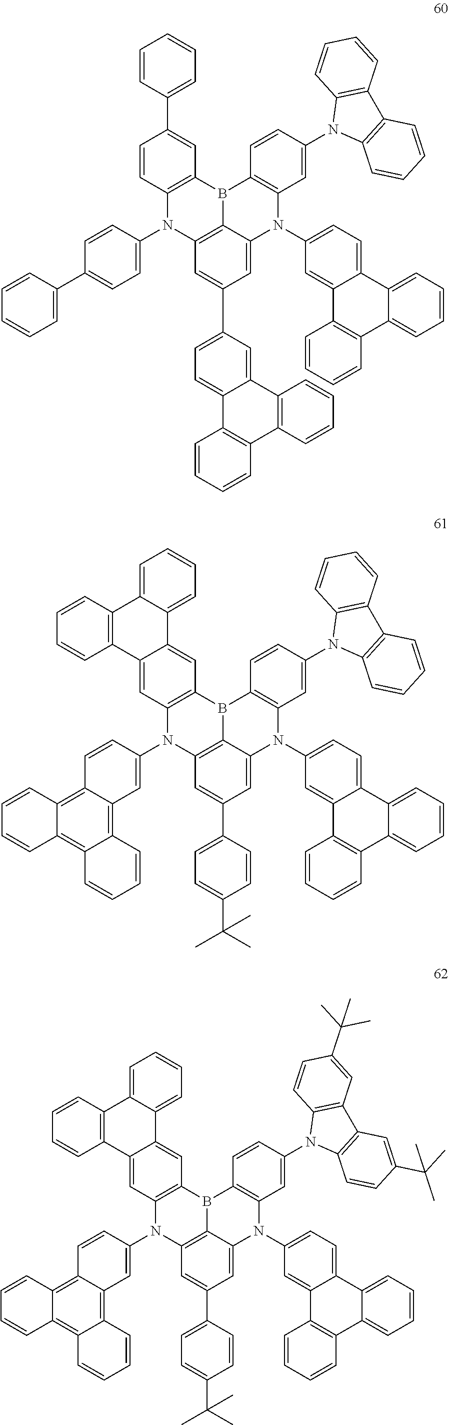 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6ccc7c8ccccc8c8ccccc8c7c6)cc3c54)cc2)cc1 ; CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccc(C(C)(C)C)cc5c5cc(C(C)(C)C)ccc54)cc2N3c2ccc3c4ccccc4c4ccccc4c3c2)cc1] 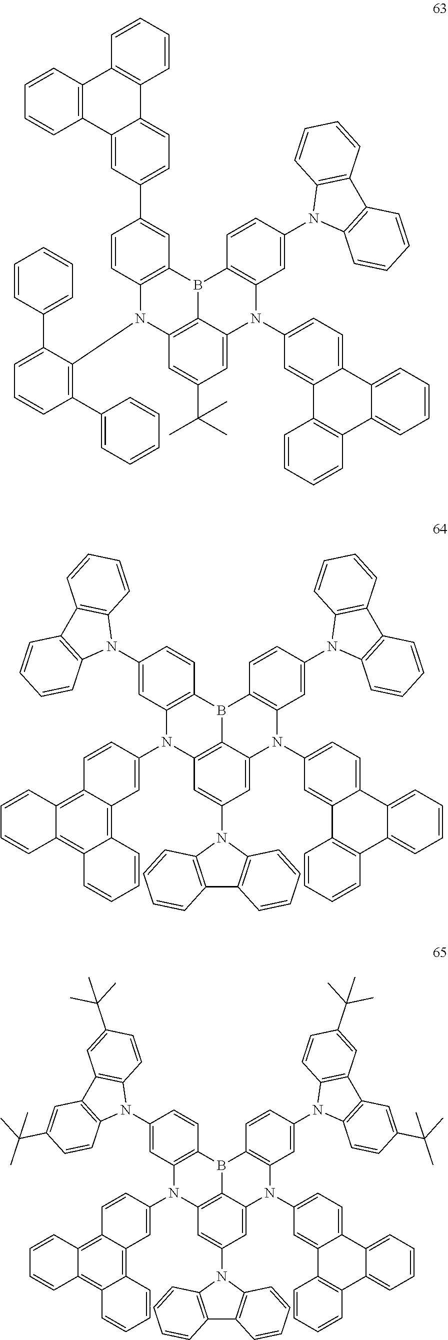 [SMILES: CC(C)(C)c1cc2c3c(c1)N(c1c(-c4ccccc4)cccc1-c1ccccc1)c1ccc(-c4ccc5c6ccccc6c6ccccc6c5c4)cc1B3c1ccc(-n3c4ccccc4c4ccccc43)cc1N2c1ccc2c3ccccc3c3ccccc3c2c1 ; c1ccc2c(c1)c1ccccc1c1cc(N3c4cc(-n5c6ccccc6c6ccccc65)ccc4B4c5ccc(-n6c7ccccc7c7ccccc76)cc5N(c5ccc6c7ccccc7c7ccccc7c6c5)c5cc(-n6c7ccccc7c7ccccc76)cc3c54)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1ccc(-n2c4ccc(C(C)(C)C)cc4c4cc(C(C)(C)C)ccc42)cc1N3c1ccc2c3ccccc3c3ccccc3c2c1] 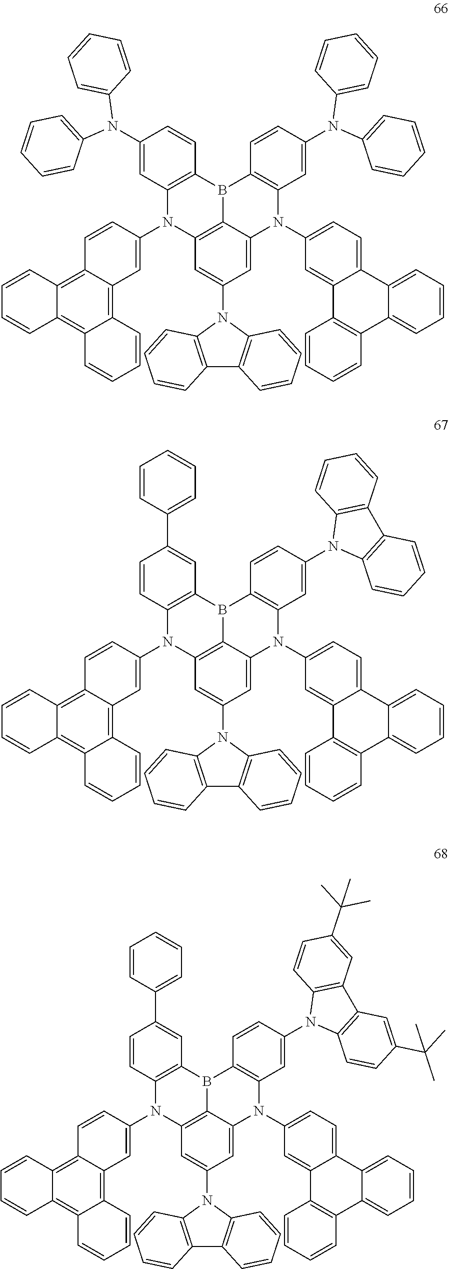 [SMILES: c1ccc(N(c2ccccc2)c2ccc3c(c2)N(c2ccc4c5ccccc5c5ccccc5c4c2)c2cc(-n4c5ccccc5c5ccccc54)cc4c2B3c2ccc(N(c3ccccc3)c3ccccc3)cc2N4c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc(-c2ccccc2)ccc1N3c1ccc2c3ccccc3c3ccccc3c2c1] 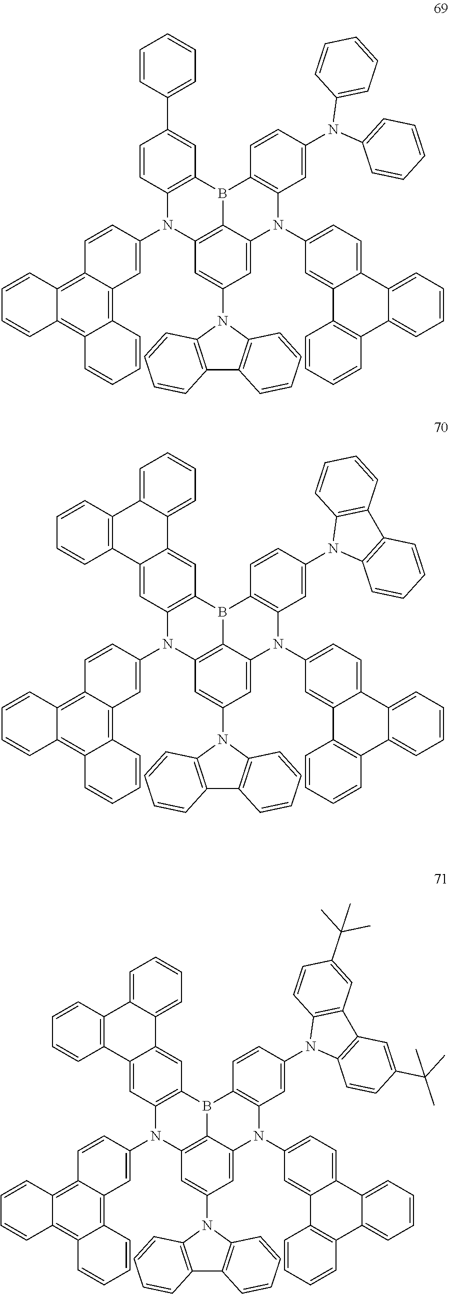 [SMILES: c1ccc(-c2ccc3c(c2)B2c4ccc(N(c5ccccc5)c5ccccc5)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1 ; c1ccc2c(c1)c1ccccc1c1cc(N3c4cc(-n5c6ccccc6c6ccccc65)ccc4B4c5cc6c7ccccc7c7ccccc7c6cc5N(c5ccc6c7ccccc7c7ccccc7c6c5)c5cc(-n6c7ccccc7c7ccccc76)cc3c54)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc2c4ccccc4c4ccccc4c2cc1N3c1ccc2c3ccccc3c3ccccc3c2c1] 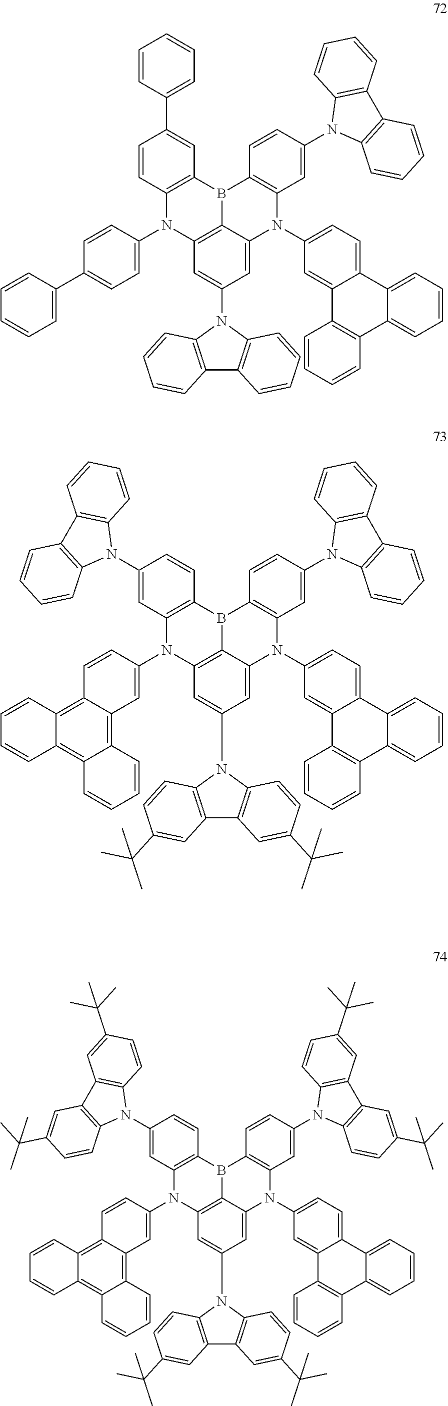 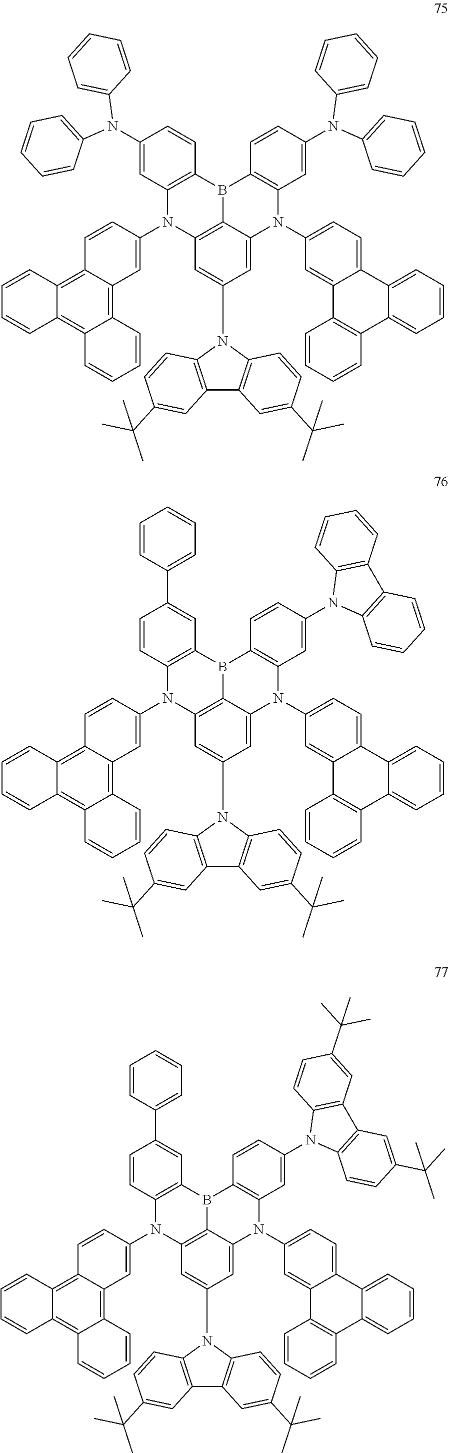 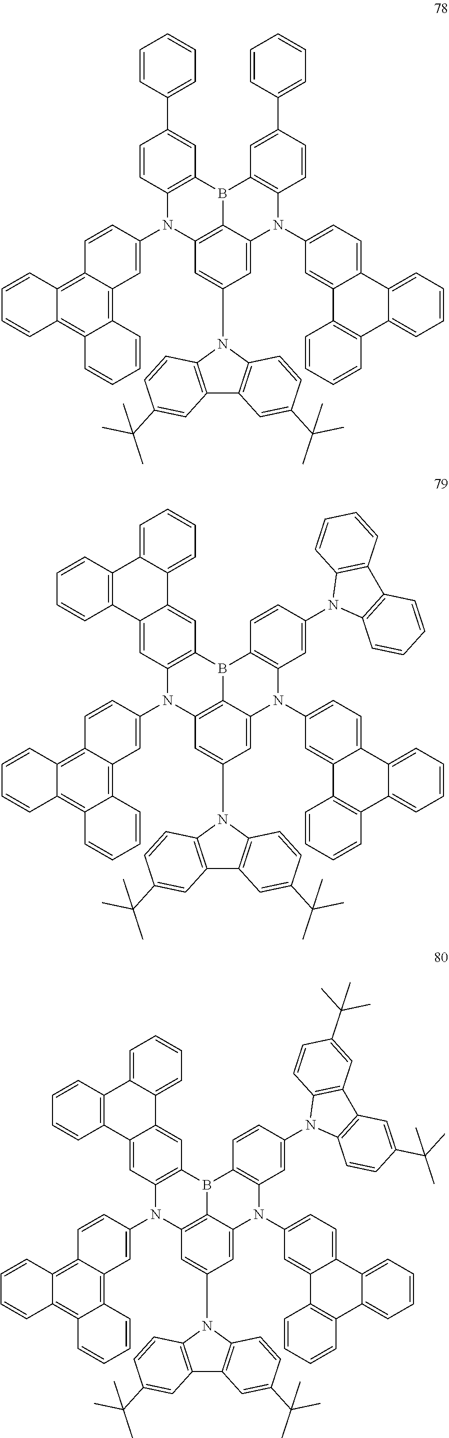 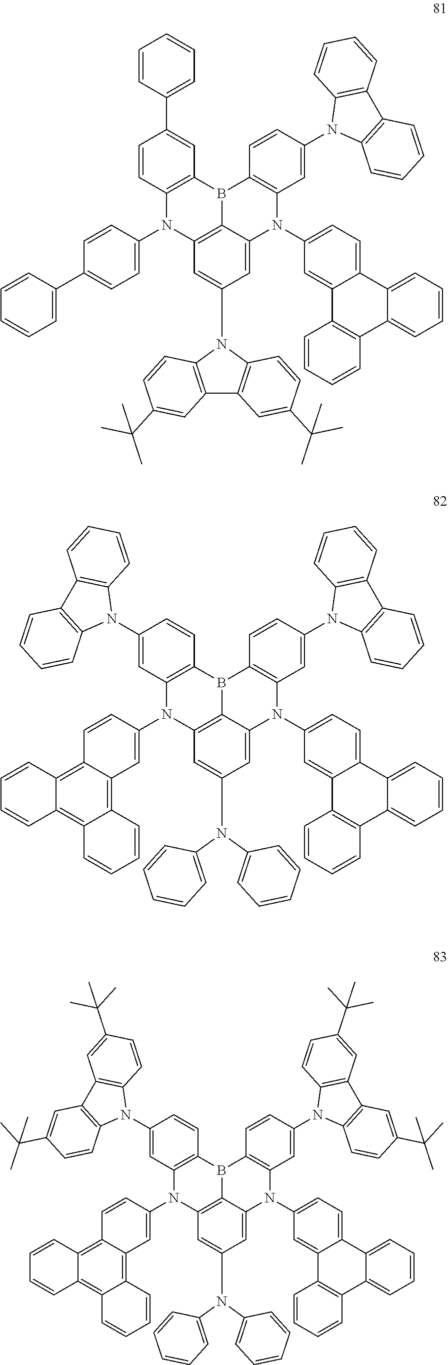 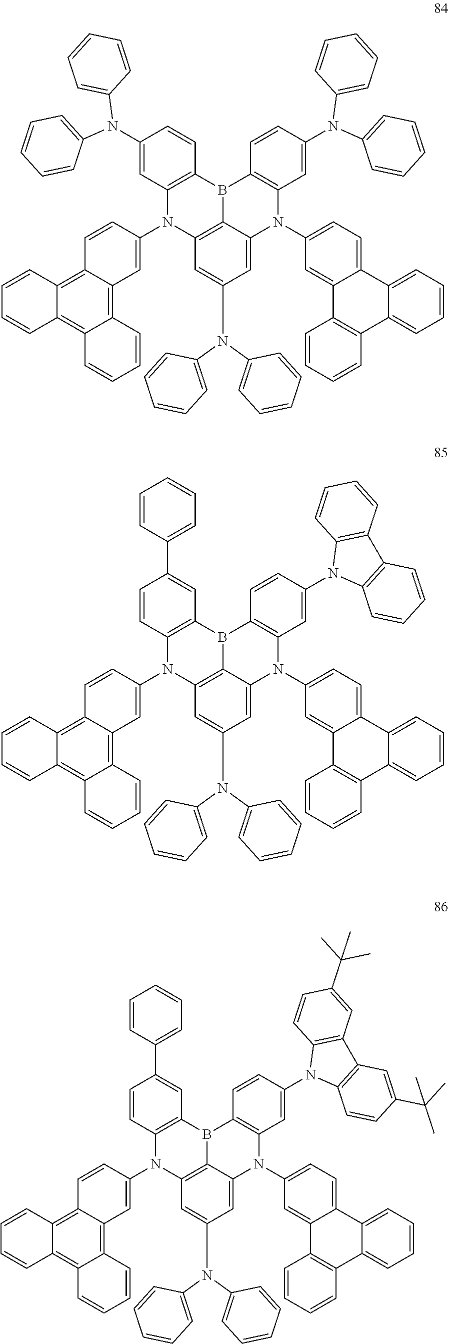 [SMILES: c1ccc(N(c2ccccc2)c2ccc3c(c2)N(c2ccc4c5ccccc5c5ccccc5c4c2)c2cc(N(c4ccccc4)c4ccccc4)cc4c2B3c2ccc(N(c3ccccc3)c3ccccc3)cc2N4c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc(-c2ccccc2)ccc1N3c1ccc2c3ccccc3c3ccccc3c2c1] 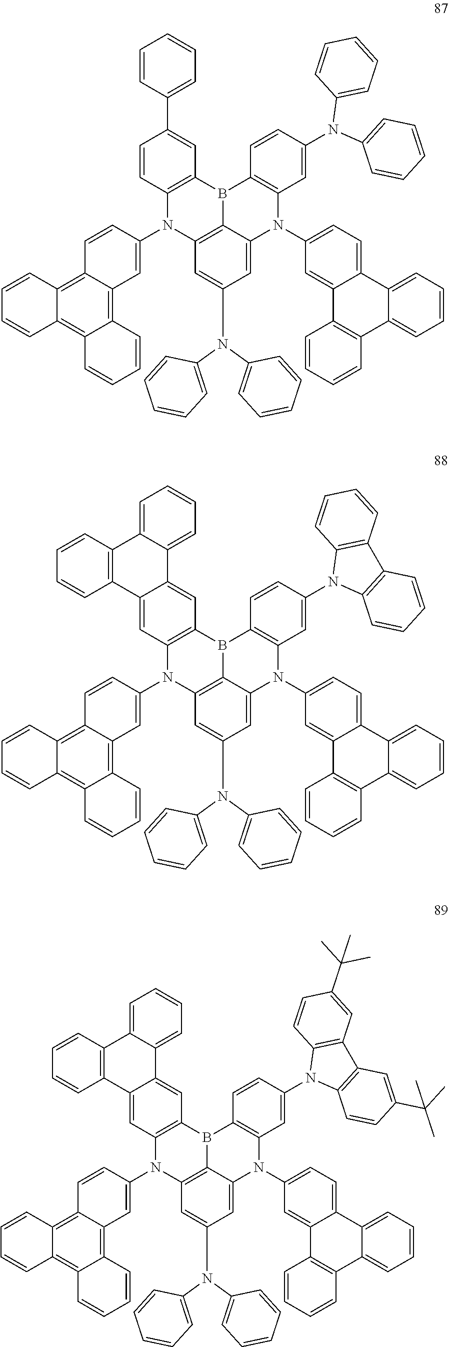 [SMILES: c1ccc(-c2ccc3c(c2)B2c4ccc(N(c5ccccc5)c5ccccc5)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1 ; c1ccc(N(c2ccccc2)c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc2c4ccccc4c4ccccc4c2cc1N3c1ccc2c3ccccc3c3ccccc3c2c1] 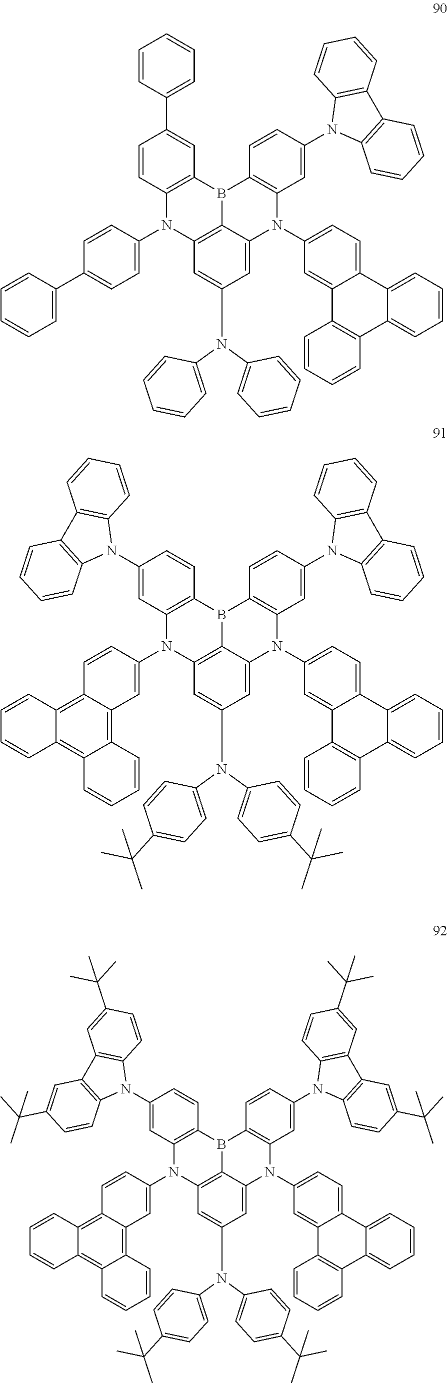 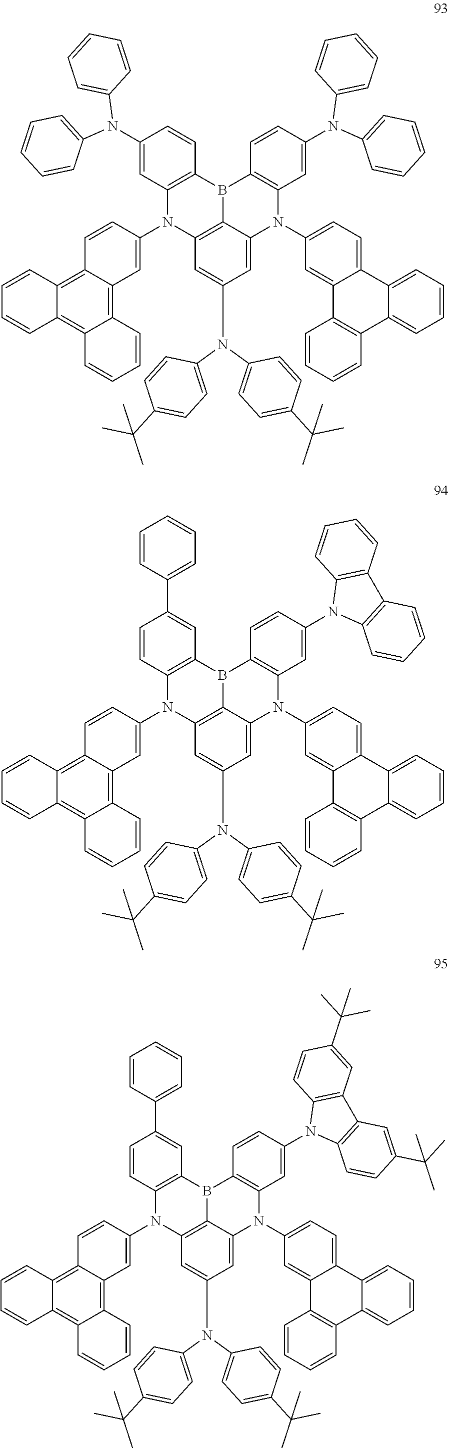 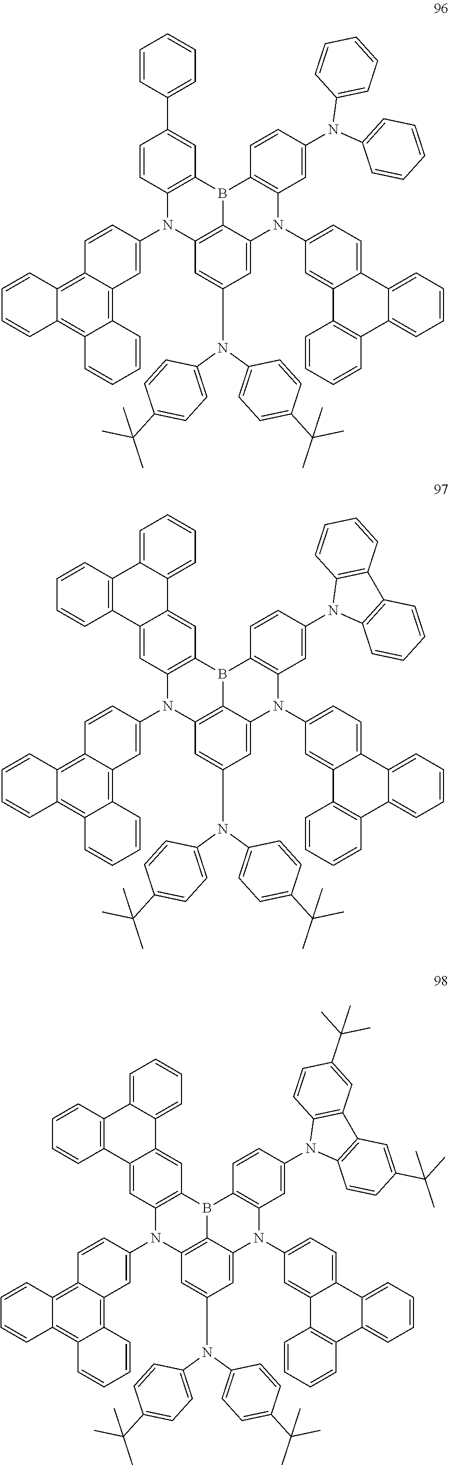 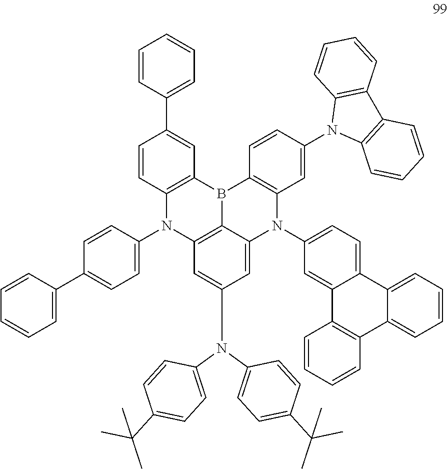 [SMILES: CC(C)(C)c1ccc(N(c2ccc(C(C)(C)C)cc2)c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc(-c3ccccc3)cc2)cc1] 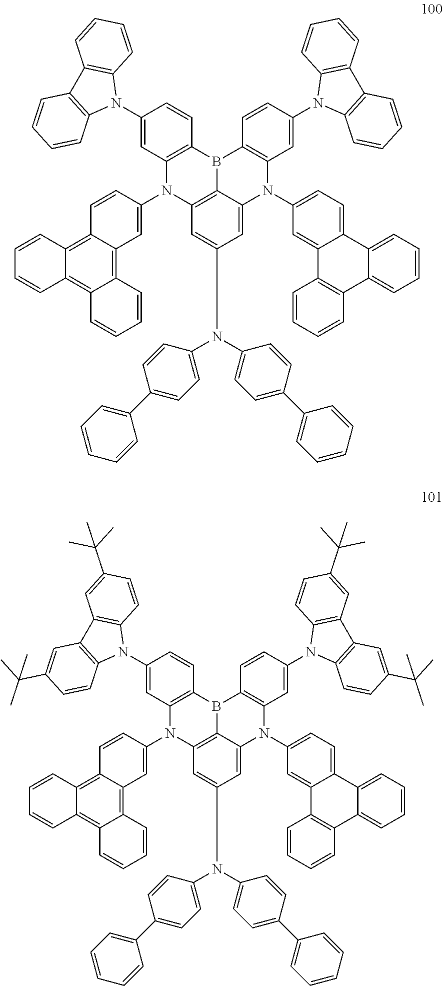 [SMILES: c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3ccc(-n5c6ccccc6c6ccccc65)cc3N4c3ccc4c5ccccc5c5ccccc5c4c3)cc2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1ccc(-n2c4ccc(C(C)(C)C)cc4c4cc(C(C)(C)C)ccc42)cc1N3c1ccc2c3ccccc3c3ccccc3c2c1] 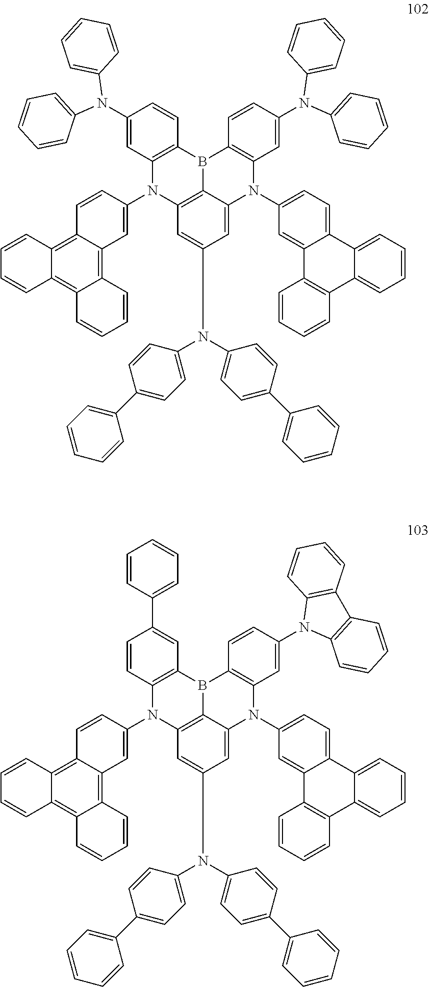 [SMILES: c1ccc(-c2ccc(N(c3ccc(-c4ccccc4)cc3)c3cc4c5c(c3)N(c3ccc6c7ccccc7c7ccccc7c6c3)c3cc(N(c6ccccc6)c6ccccc6)ccc3B5c3ccc(N(c5ccccc5)c5ccccc5)cc3N4c3ccc4c5ccccc5c5ccccc5c4c3)cc2)cc1 ; c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3cc(-c5ccccc5)ccc3N4c3ccc4c5ccccc5c5ccccc5c4c3)cc2)cc1] 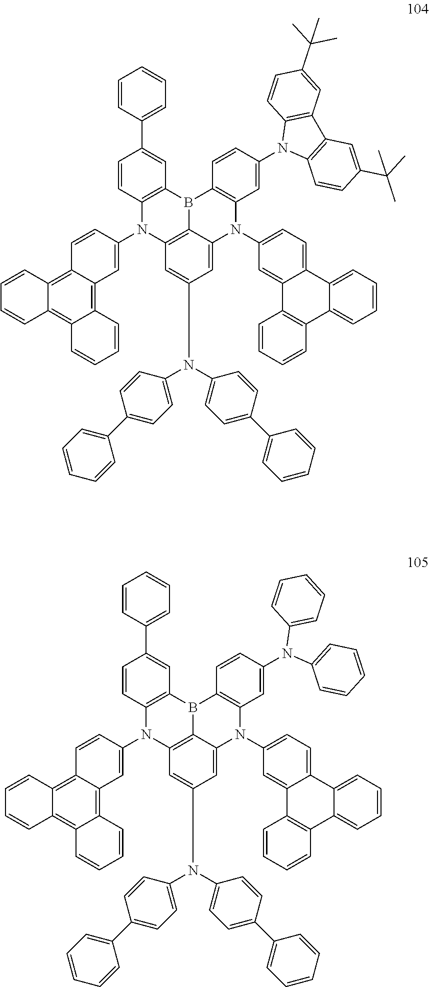 [SMILES: CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1cc(-c2ccccc2)ccc1N3c1ccc2c3ccccc3c3ccccc3c2c1 ; c1ccc(-c2ccc(N(c3ccc(-c4ccccc4)cc3)c3cc4c5c(c3)N(c3ccc6c7ccccc7c7ccccc7c6c3)c3cc(N(c6ccccc6)c6ccccc6)ccc3B5c3cc(-c5ccccc5)ccc3N4c3ccc4c5ccccc5c5ccccc5c4c3)cc2)cc1] 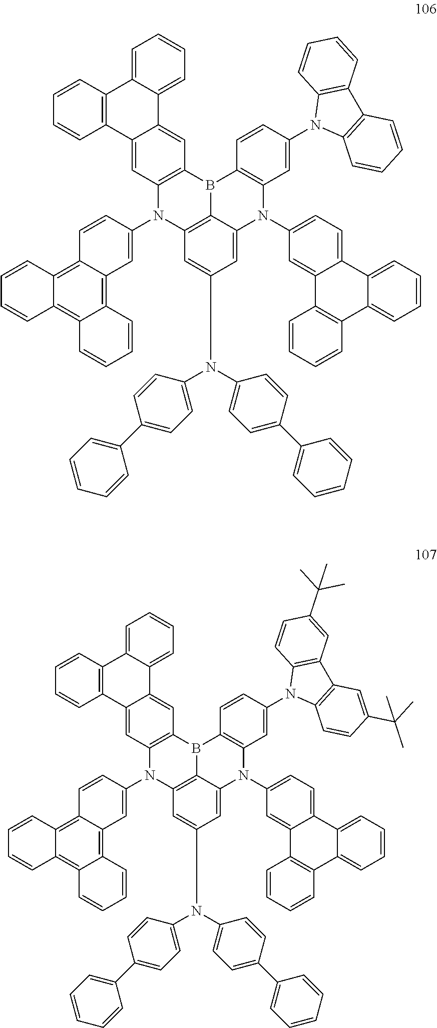 [SMILES: c1ccc(-c2ccc(N(c3ccc(-c4ccccc4)cc3)c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)cc2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccc(-c4ccccc4)cc3)c3ccc(-c4ccccc4)cc3)cc3c1B2c1cc2c4ccccc4c4ccccc4c2cc1N3c1ccc2c3ccccc3c3ccccc3c2c1] 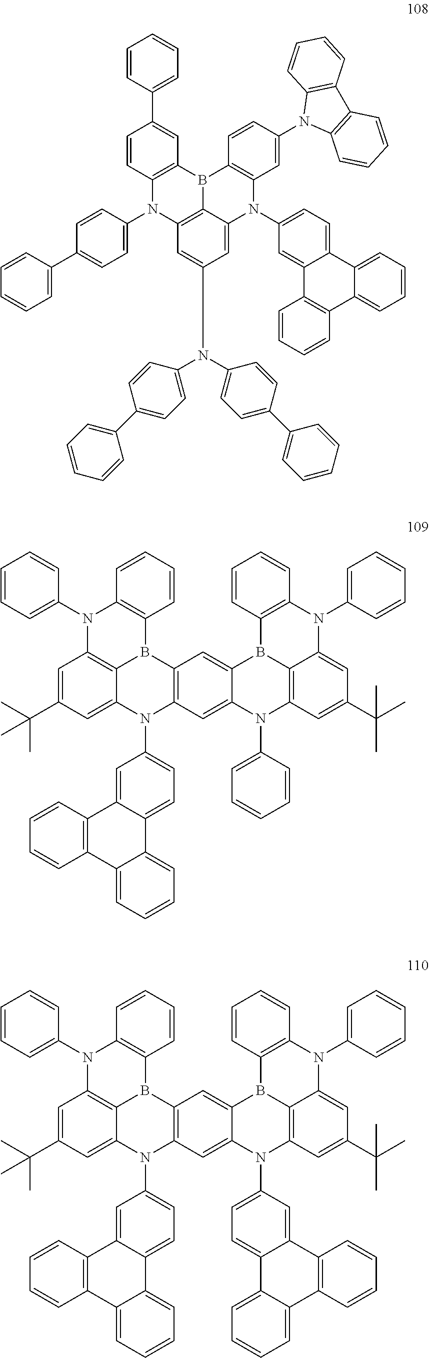 [SMILES: c1ccc(-c2ccc(N(c3ccc(-c4ccccc4)cc3)c3cc4c5c(c3)N(c3ccc6c7ccccc7c7ccccc7c6c3)c3cc(-n6c7ccccc7c7ccccc76)ccc3B5c3cc(-c5ccccc5)ccc3N4c3ccc(-c4ccccc4)cc3)cc2)cc1 ; CC(C)(C)c1cc2c3c(c1)N(c1ccccc1)c1cc4c(cc1B3c1ccccc1N2c1ccccc1)B1c2ccccc2N(c2ccccc2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1N2c1ccccc1)B1c2ccccc2N(c2ccccc2)c2cc(C(C)(C)C)cc(c21)N4c1ccc2c3ccccc3c3ccccc3c2c1] 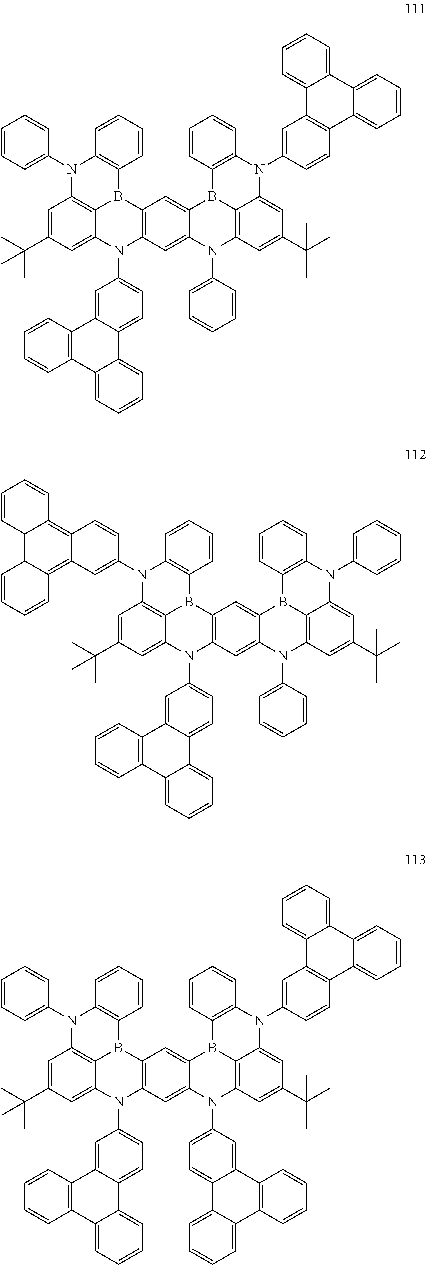 [SMILES: CC(C)(C)c1cc2c3c(c1)N(c1ccccc1)c1cc4c(cc1B3c1ccccc1N2c1ccc2c3ccccc3c3ccccc3c2c1)B1c2ccccc2N(c2ccccc2)c2cc(C(C)(C)C)cc(c21)N4c1ccc2c3ccccc3c3ccccc3c2c1 ; CC(C)(C)c1cc2c3c(c1)N(c1ccccc1)c1cc4c(cc1B3c1ccccc1N2c1ccccc1)B1c2ccccc2N(c2ccc3c(c2)=C2C=CC=CC2C2C=CC=CC=32)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1N2c1ccccc1)B1c2ccccc2N(c2ccc3c5ccccc5c5ccccc5c3c2)c2cc(C(C)(C)C)cc(c21)N4c1ccc2c3ccccc3c3ccccc3c2c1] 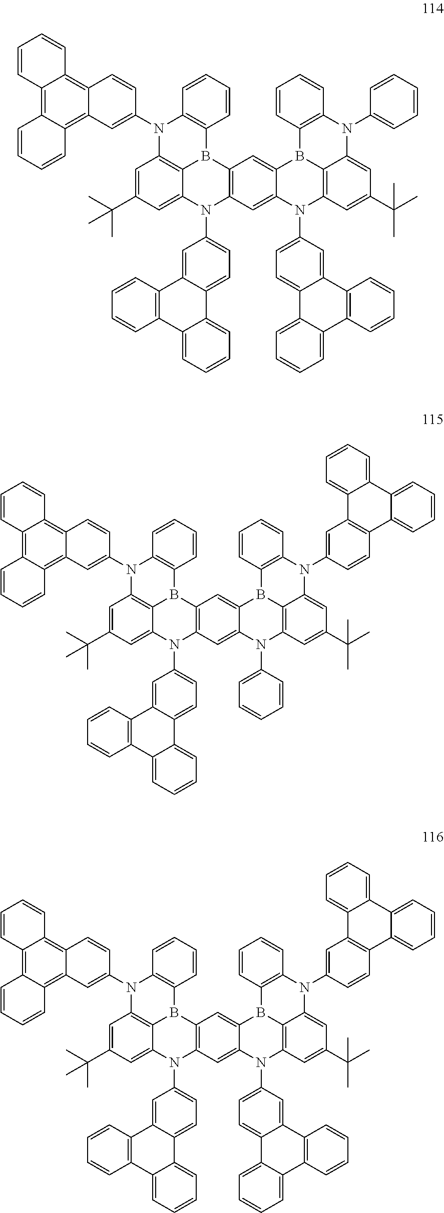 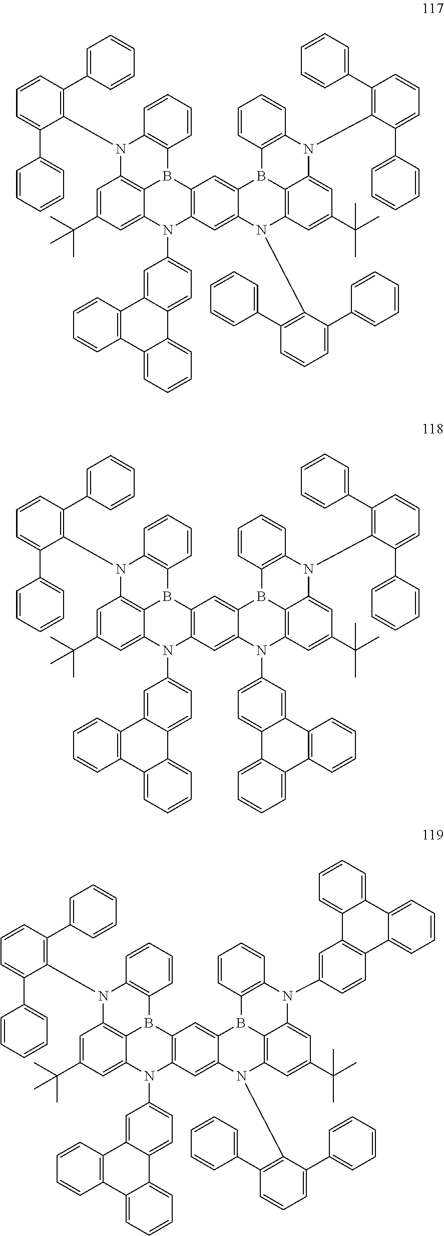 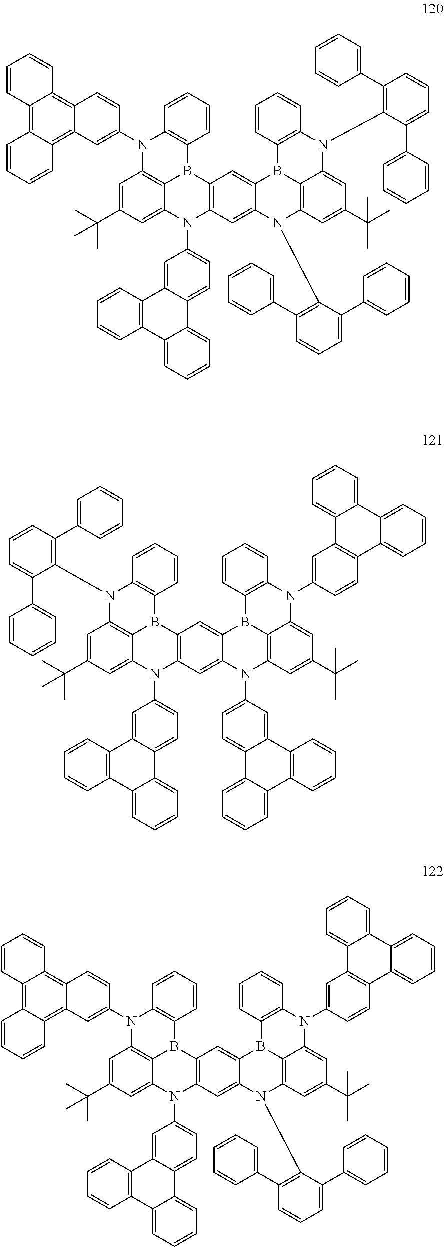 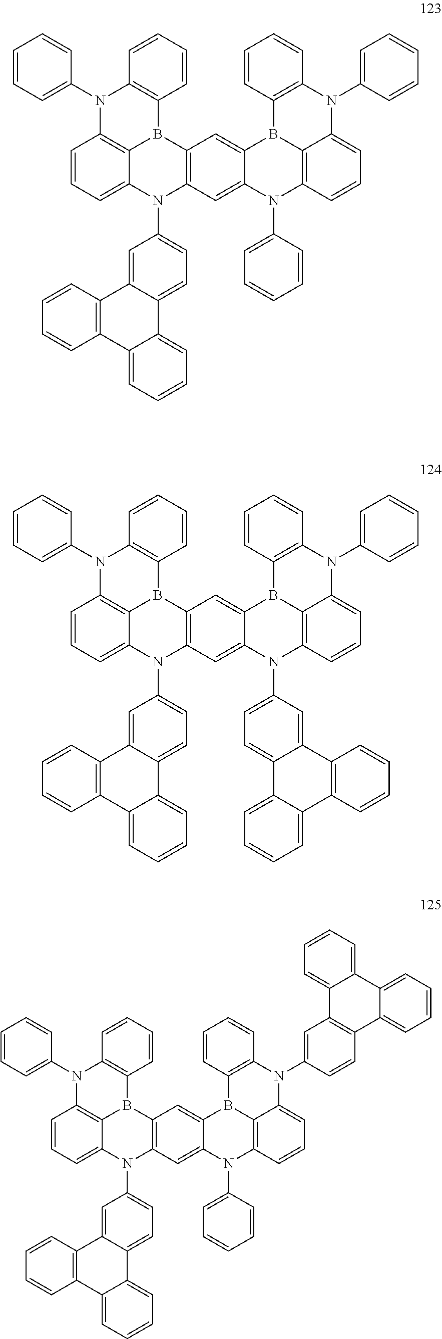 [SMILES: c1ccc(N2c3ccccc3B3c4cc5c(cc4N(c4ccccc4)c4cccc2c43)N(c2ccc3c4ccccc4c4ccccc4c3c2)c2cccc3c2B5c2ccccc2N3c2ccccc2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccccc2)cc1 ; c1ccc(N2c3ccccc3B3c4cc5c(cc4N(c4ccc6c7ccccc7c7ccccc7c6c4)c4cccc2c43)N(c2ccccc2)c2cccc3c2B5c2ccccc2N3c2ccc3c4ccccc4c4ccccc4c3c2)cc1] 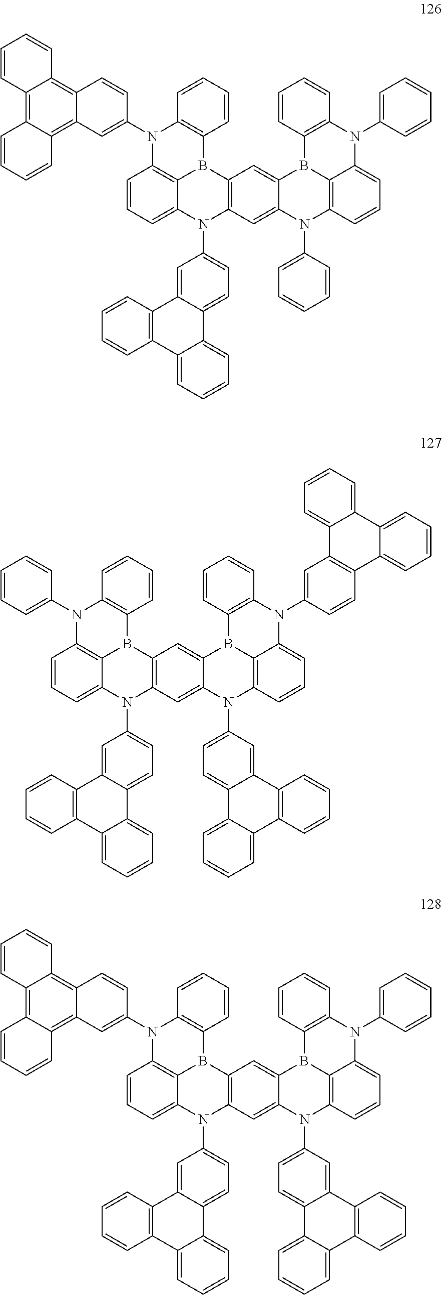 [SMILES: c1ccc(N2c3ccccc3B3c4cc5c(cc4N(c4ccccc4)c4cccc2c43)N(c2ccc3c4ccccc4c4ccccc4c3c2)c2cccc3c2B5c2ccccc2N3c2ccc3c4ccccc4c4ccccc4c3c2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccc3c4ccccc4c4ccccc4c3c2)cc1 ; c1ccc(N2c3ccccc3B3c4cc5c(cc4N(c4ccc6c7ccccc7c7ccccc7c6c4)c4cccc2c43)N(c2ccc3c4ccccc4c4ccccc4c3c2)c2cccc3c2B5c2ccccc2N3c2ccc3c4ccccc4c4ccccc4c3c2)cc1] 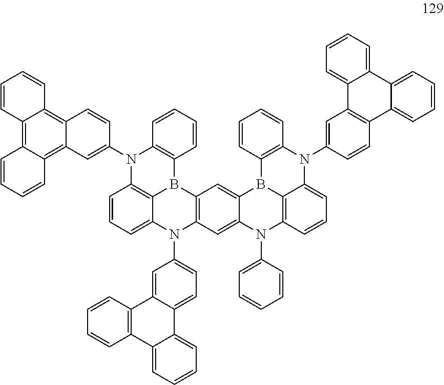 [SMILES: c1ccc(N2c3cc4c(cc3B3c5ccccc5N(c5ccc6c7ccccc7c7ccccc7c6c5)c5cccc2c53)B2c3ccccc3N(c3ccc5c6ccccc6c6ccccc6c5c3)c3cccc(c32)N4c2ccc3c4ccccc4c4ccccc4c3c2)cc1] 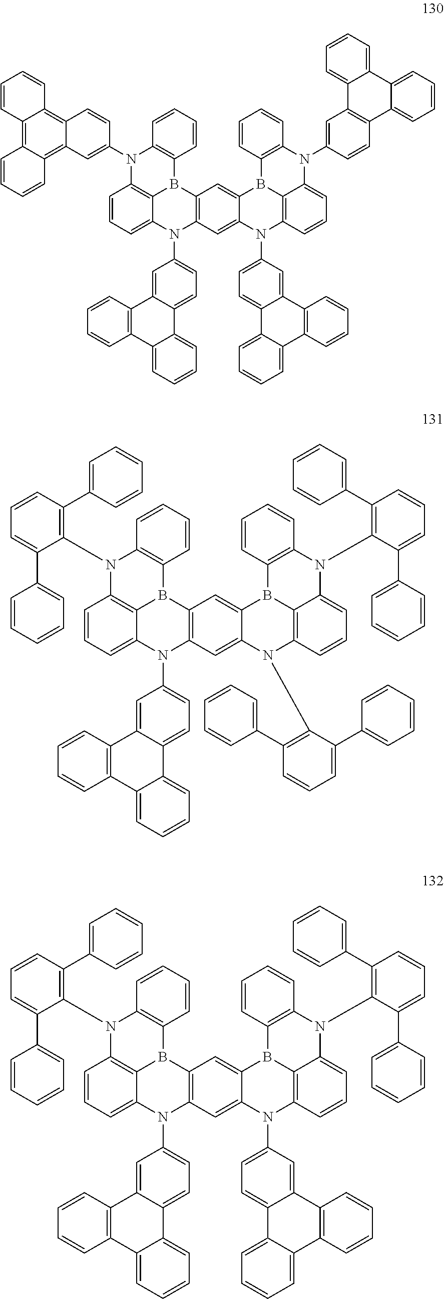 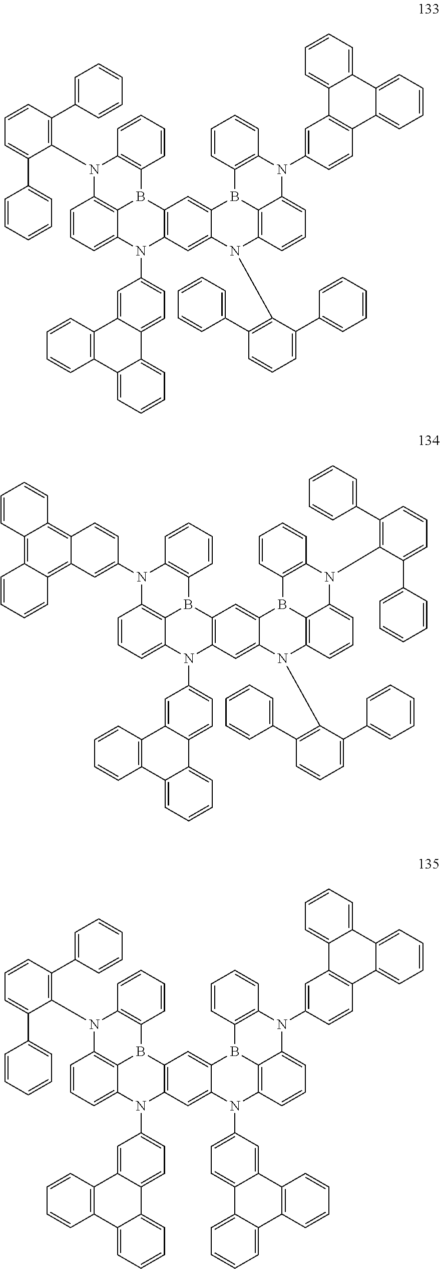 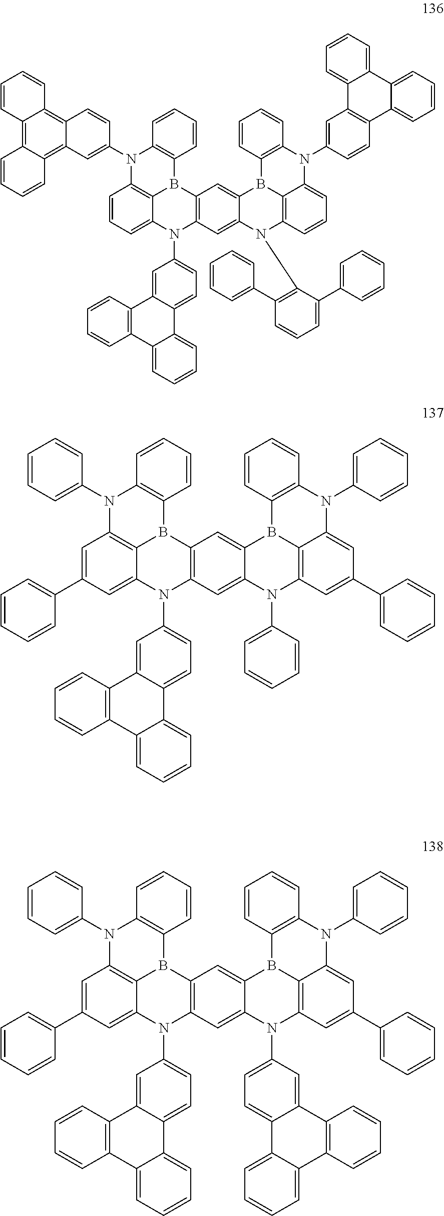 [SMILES: c1ccc(-c2cccc(-c3ccccc3)c2N2c3cc4c(cc3B3c5ccccc5N(c5ccc6c7ccccc7c7ccccc7c6c5)c5cccc2c53)B2c3ccccc3N(c3ccc5c6ccccc6c6ccccc6c5c3)c3cccc(c32)N4c2ccc3c4ccccc4c4ccccc4c3c2)cc1 ; c1ccc(-c2cc3c4c(c2)N(c2ccccc2)c2cc5c(cc2B4c2ccccc2N3c2ccccc2)B2c3ccccc3N(c3ccccc3)c3cc(-c4ccccc4)cc(c32)N5c2ccc3c4ccccc4c4ccccc4c3c2)cc1 ; c1ccc(-c2cc3c4c(c2)N(c2ccc5c6ccccc6c6ccccc6c5c2)c2cc5c(cc2B4c2ccccc2N3c2ccccc2)B2c3ccccc3N(c3ccccc3)c3cc(-c4ccccc4)cc(c32)N5c2ccc3c4ccccc4c4ccccc4c3c2)cc1] 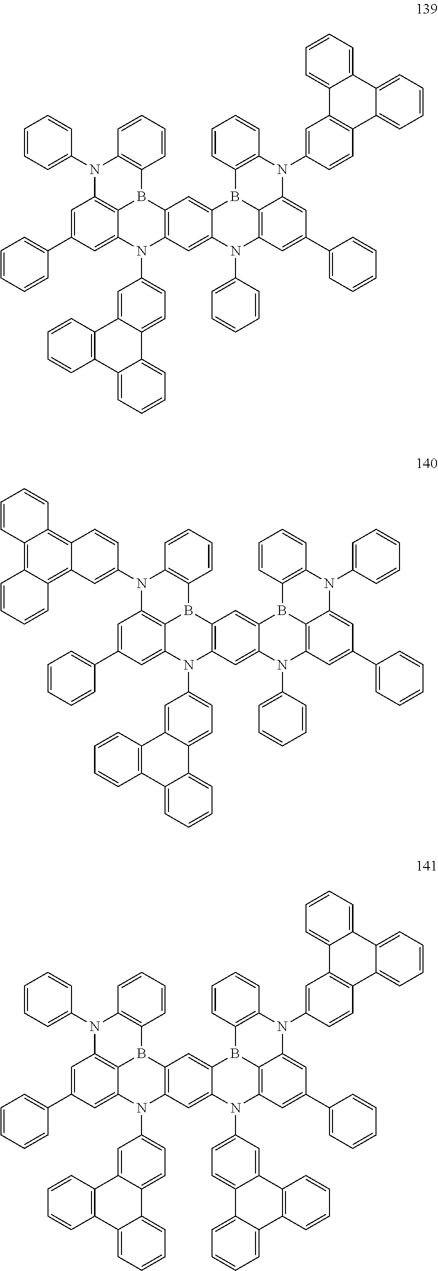 [SMILES: c1ccc(-c2cc3c4c(c2)N(c2ccccc2)c2cc5c(cc2B4c2ccccc2N3c2ccc3c4ccccc4c4ccccc4c3c2)B2c3ccccc3N(c3ccccc3)c3cc(-c4ccccc4)cc(c32)N5c2ccc3c4ccccc4c4ccccc4c3c2)cc1 ; c1ccc(-c2cc3c4c(c2)N(c2ccccc2)c2cc5c(cc2B4c2ccccc2N3c2ccccc2)B2c3ccccc3N(c3ccc4c6ccccc6c6ccccc6c4c3)c3cc(-c4ccccc4)cc(c32)N5c2ccc3c4ccccc4c4ccccc4c3c2)cc1 ; c1ccc(-c2cc3c4c(c2)N(c2ccc5c6ccccc6c6ccccc6c5c2)c2cc5c(cc2B4c2ccccc2N3c2ccccc2)B2c3ccccc3N(c3ccc4c6ccccc6c6ccccc6c4c3)c3cc(-c4ccccc4)cc(c32)N5c2ccc3c4ccccc4c4ccccc4c3c2)cc1] 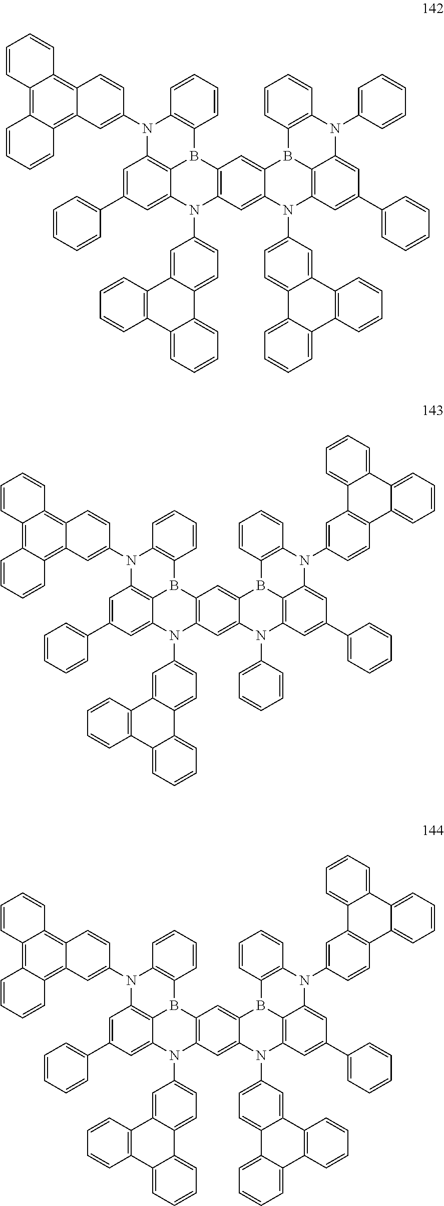 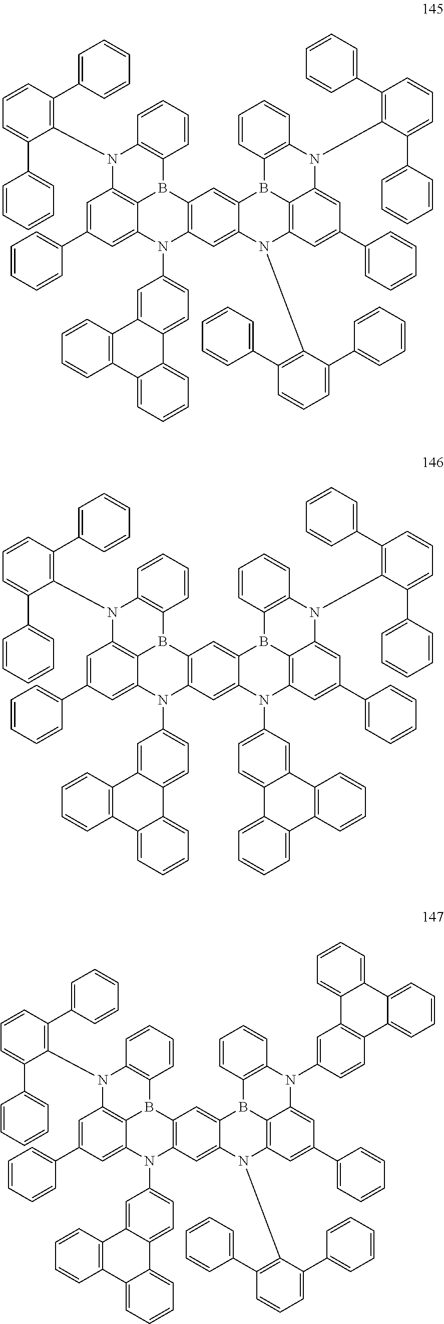 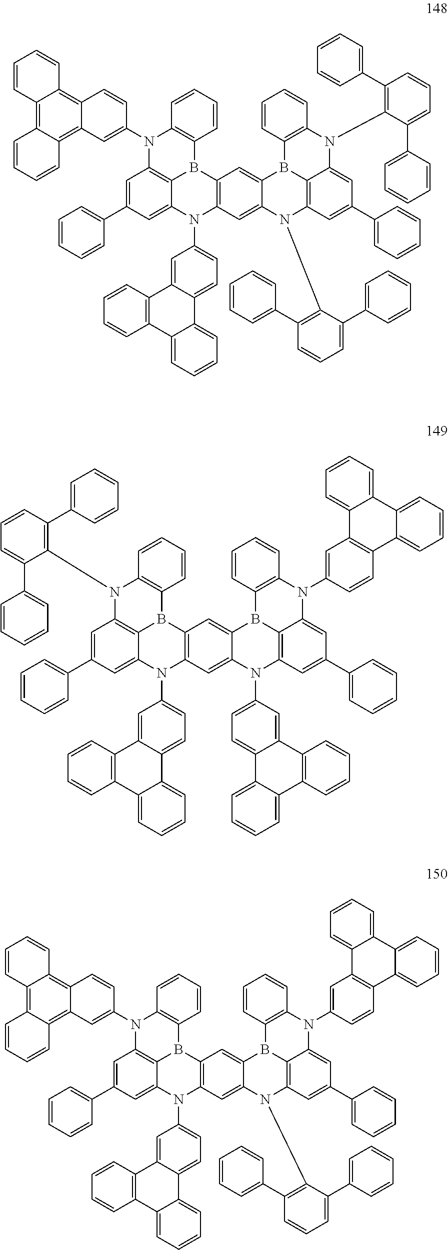 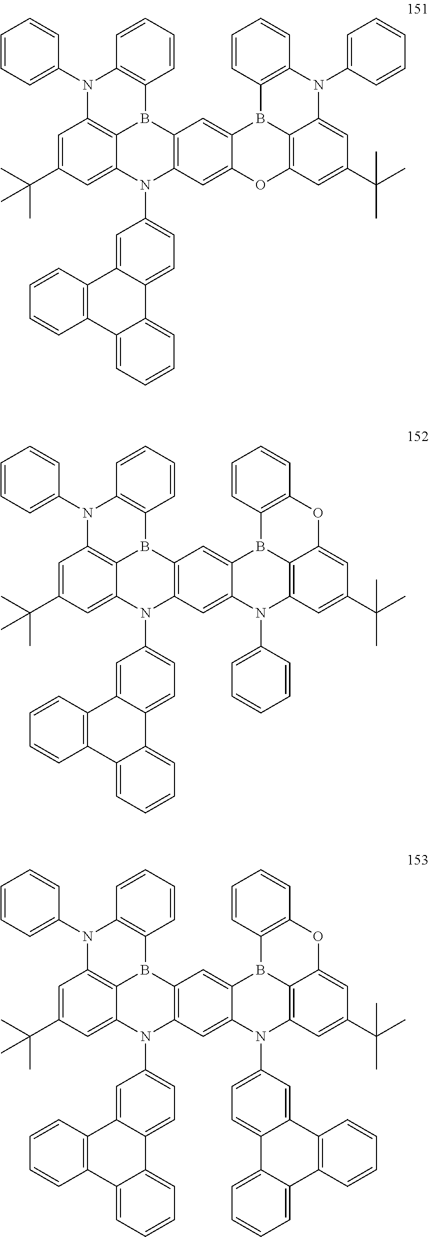 [SMILES: CC(C)(C)c1cc2c3c(c1)N(c1ccccc1)c1ccccc1B3c1cc3c(cc1O2)N(c1ccc2c4ccccc4c4ccccc4c2c1)c1cc(C(C)(C)C)cc2c1B3c1ccccc1N2c1ccccc1 ; CC(C)(C)c1cc2c3c(c1)N(c1ccccc1)c1cc4c(cc1B3c1ccccc1O2)B1c2ccccc2N(c2ccccc2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1O2)B1c2ccccc2N(c2ccccc2)c2cc(C(C)(C)C)cc(c21)N4c1ccc2c3ccccc3c3ccccc3c2c1] 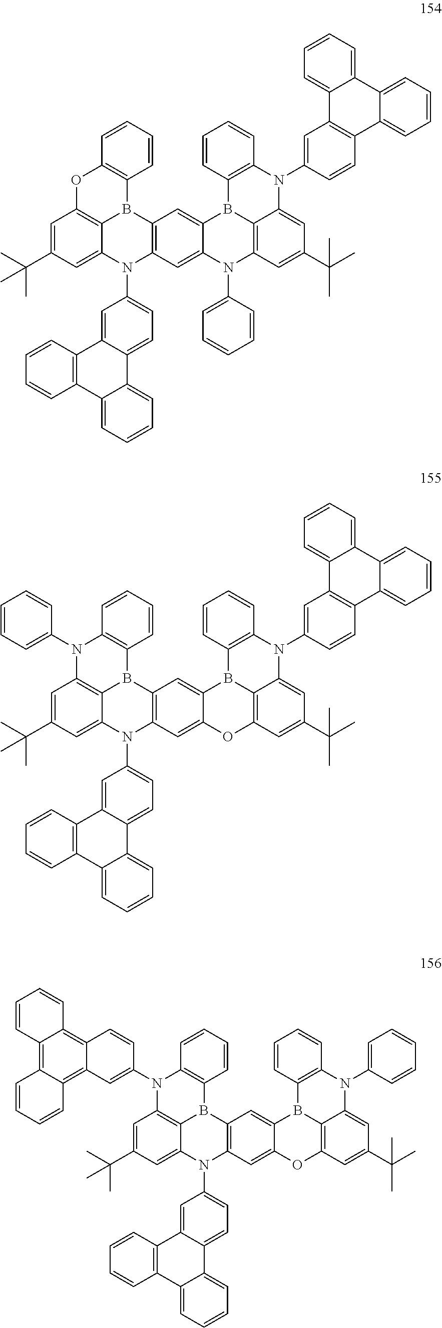 [SMILES: CC(C)(C)c1cc2c3c(c1)N(c1ccc4c5ccccc5c5ccccc5c4c1)c1cc4c(cc1B3c1ccccc1O2)B1c2ccccc2N(c2ccc3c5ccccc5c5ccccc5c3c2)c2cc(C(C)(C)C)cc(c21)N4c1ccccc1 ; CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccccc1 ; CC(C)(C)c1cc2c3c(c1)N(c1ccccc1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1] 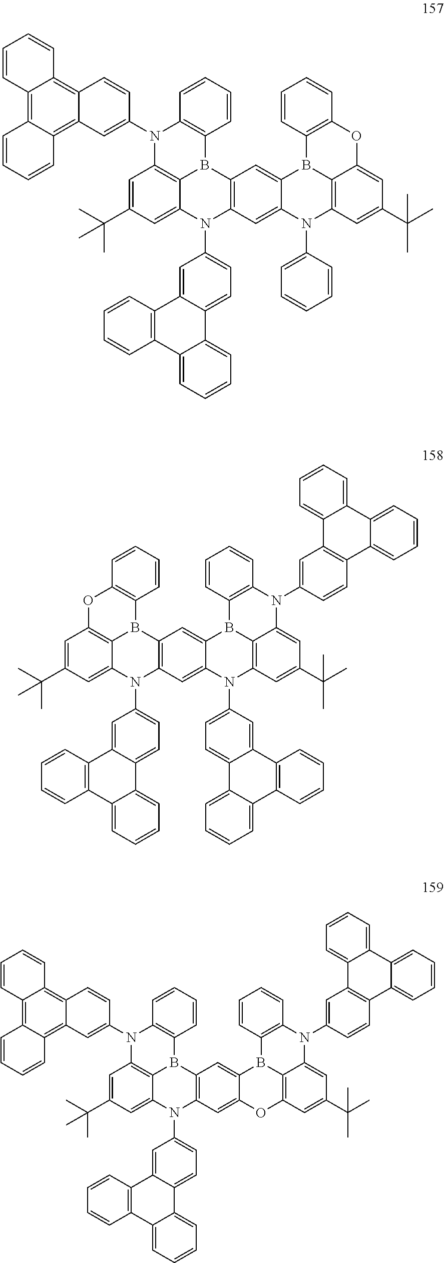 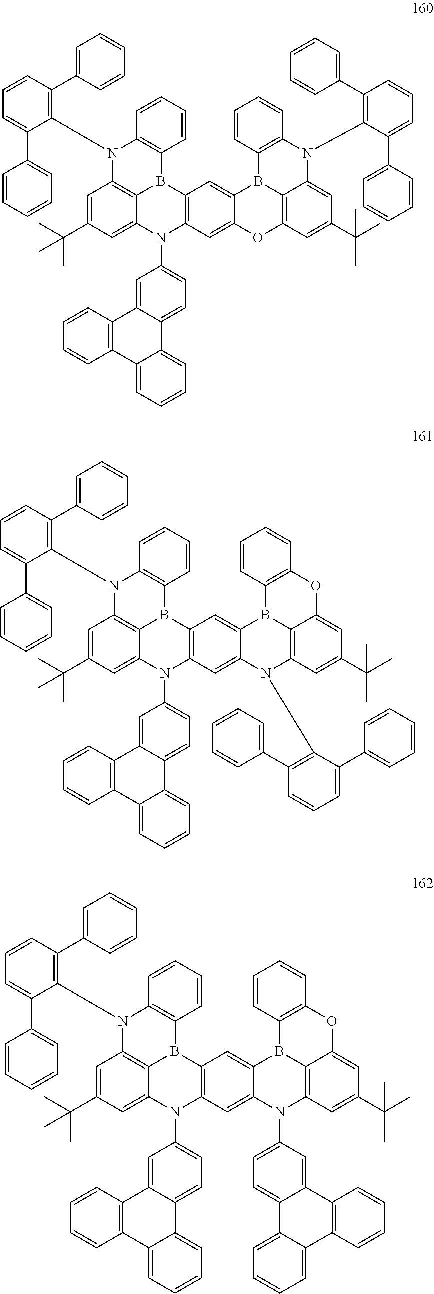 [SMILES: CC(C)(C)c1cc2c3c(c1)N(c1c(-c4ccccc4)cccc1-c1ccccc1)c1ccccc1B3c1cc3c(cc1O2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1O2)B1c2ccccc2N(c2c(-c3ccccc3)cccc2-c2ccccc2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1O2)B1c2ccccc2N(c2c(-c3ccccc3)cccc2-c2ccccc2)c2cc(C(C)(C)C)cc(c21)N4c1ccc2c3ccccc3c3ccccc3c2c1] 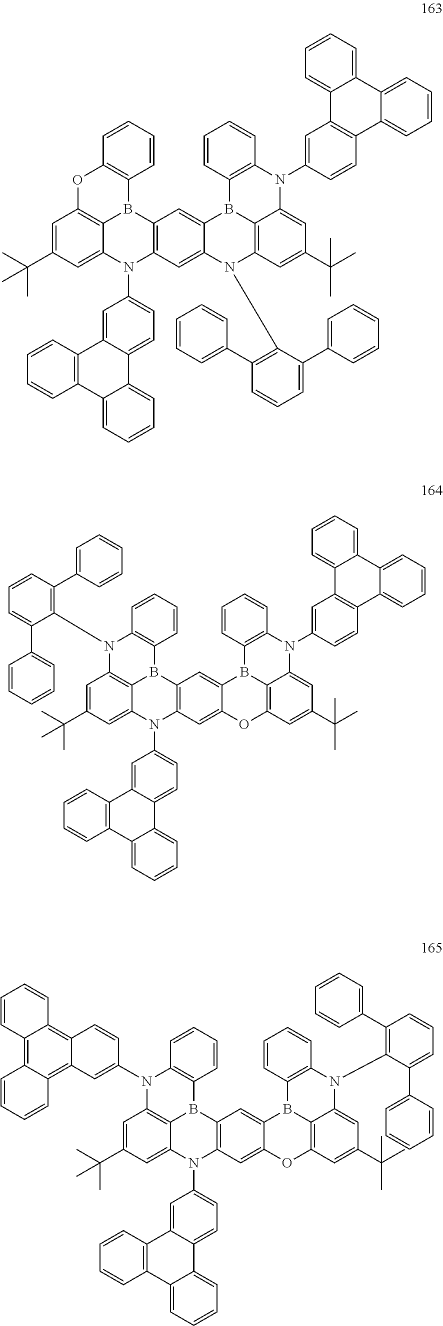 [SMILES: CC(C)(C)c1cc2c3c(c1)N(c1ccc4c5ccccc5c5ccccc5c4c1)c1cc4c(cc1B3c1ccccc1O2)B1c2ccccc2N(c2ccc3c5ccccc5c5ccccc5c3c2)c2cc(C(C)(C)C)cc(c21)N4c1c(-c2ccccc2)cccc1-c1ccccc1 ; CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1] 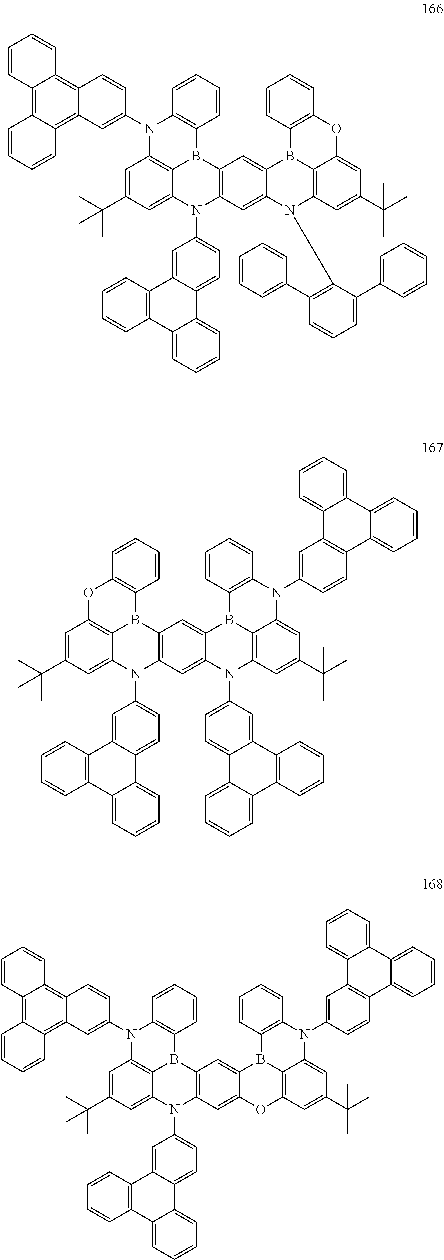 [SMILES: CC(C)(C)c1cc2c3c(c1)N(c1c(-c4ccccc4)cccc1-c1ccccc1)c1cc4c(cc1B3c1ccccc1O2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1O2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1ccccc1B3c1cc3c(cc1O2)N(c1ccc2c4ccccc4c4ccccc4c2c1)c1cc(C(C)(C)C)cc2c1B3c1ccccc1N2c1ccc2c3ccccc3c3ccccc3c2c1] 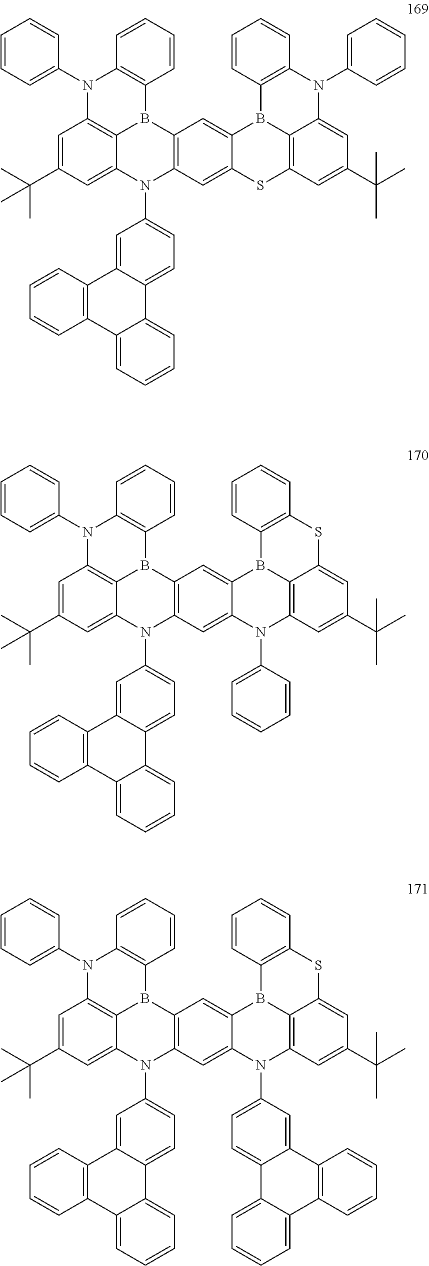 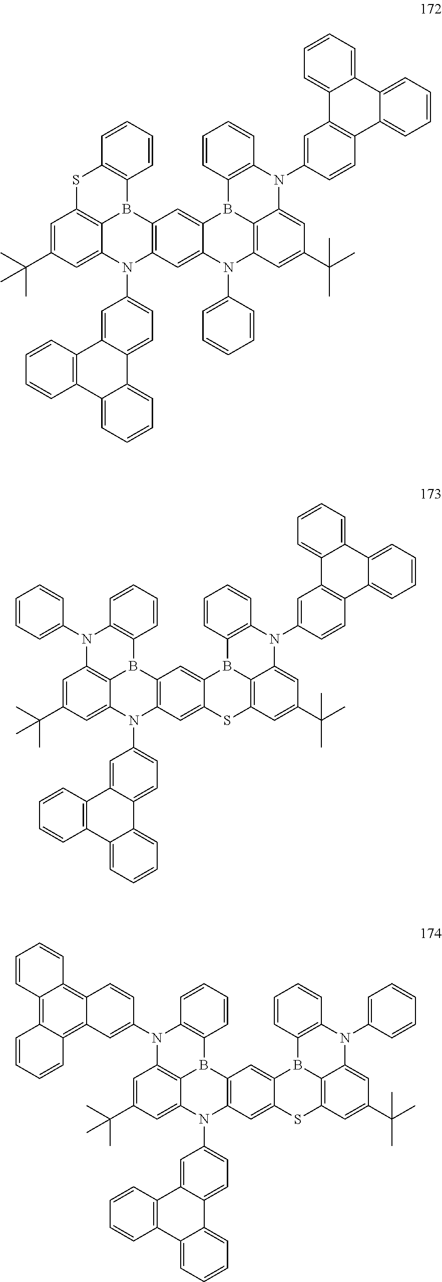 [SMILES: CC(C)(C)c1cc2c3c(c1)N(c1ccc4c5ccccc5c5ccccc5c4c1)c1cc4c(cc1B3c1ccccc1S2)B1c2ccccc2N(c2ccc3c5ccccc5c5ccccc5c3c2)c2cc(C(C)(C)C)cc(c21)N4c1ccccc1 ; CC(C)(C)c1cc2c3c(c1)N(c1ccc4c5ccccc5c5ccccc5c4c1)c1ccccc1B3c1cc3c(cc1S2)N(c1ccc2c4ccccc4c4ccccc4c2c1)c1cc(C(C)(C)C)cc2c1B3c1ccccc1N2c1ccccc1 ; CC(C)(C)c1cc2c3c(c1)N(c1ccccc1)c1ccccc1B3c1cc3c(cc1S2)N(c1ccc2c4ccccc4c4ccccc4c2c1)c1cc(C(C)(C)C)cc2c1B3c1ccccc1N2c1ccc2c3ccccc3c3ccccc3c2c1] 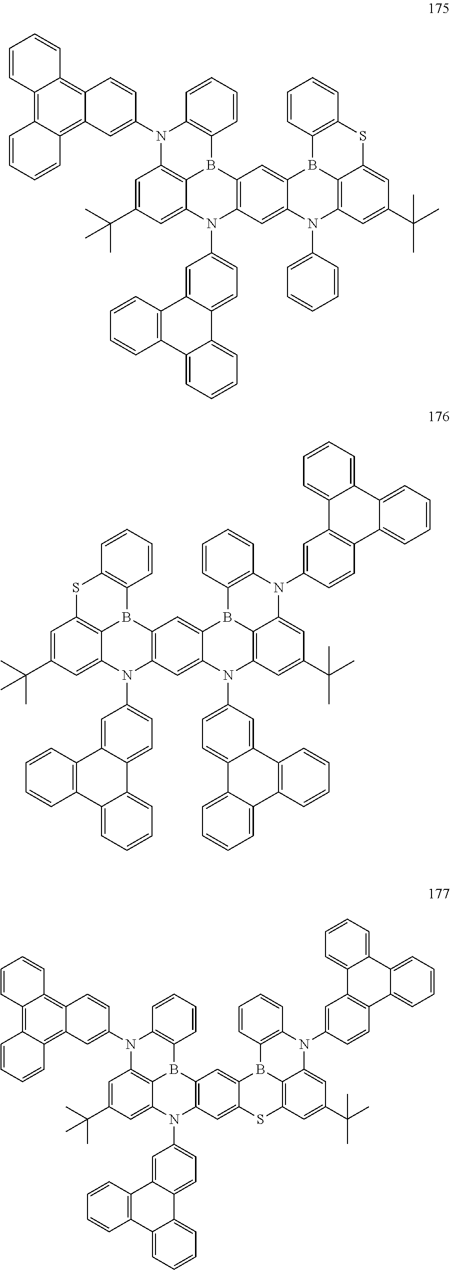 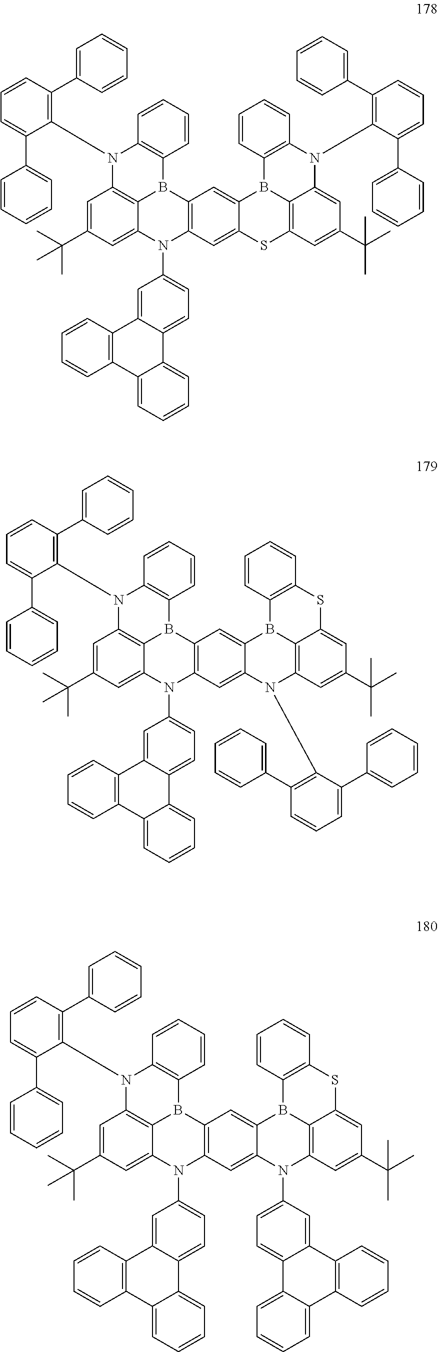 [SMILES: CC(C)(C)c1cc2c3c(c1)N(c1c(-c4ccccc4)cccc1-c1ccccc1)c1ccccc1B3c1cc3c(cc1S2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1S2)B1c2ccccc2N(c2c(-c3ccccc3)cccc2-c2ccccc2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1S2)B1c2ccccc2N(c2c(-c3ccccc3)cccc2-c2ccccc2)c2cc(C(C)(C)C)cc(c21)N4c1ccc2c3ccccc3c3ccccc3c2c1] 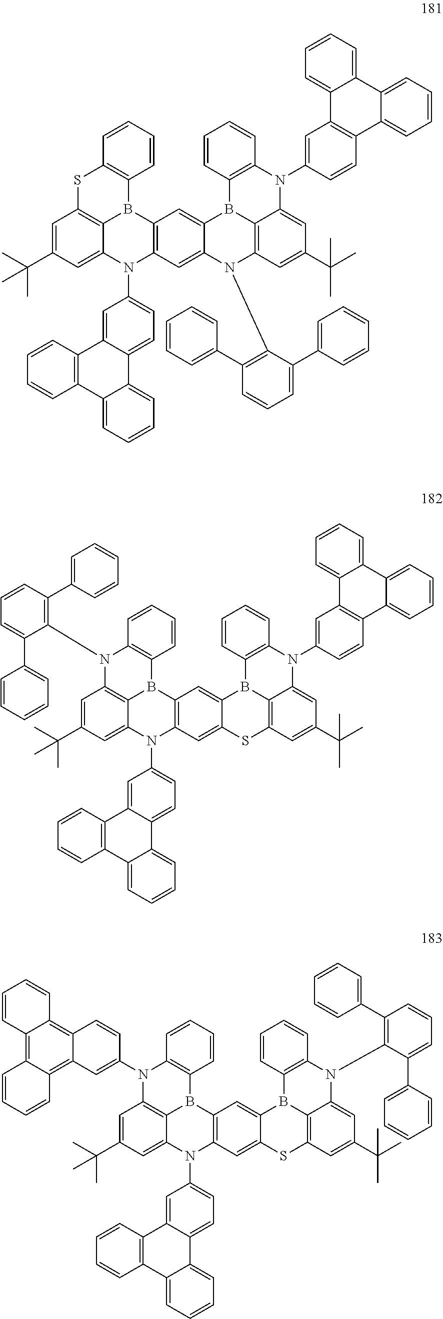 [SMILES: CC(C)(C)c1cc2c3c(c1)N(c1ccc4c5ccccc5c5ccccc5c4c1)c1cc4c(cc1B3c1ccccc1S2)B1c2ccccc2N(c2ccc3c5ccccc5c5ccccc5c3c2)c2cc(C(C)(C)C)cc(c21)N4c1c(-c2ccccc2)cccc1-c1ccccc1 ; CC(C)(C)c1cc2c3c(c1)N(c1ccc4c5ccccc5c5ccccc5c4c1)c1ccccc1B3c1cc3c(cc1S2)N(c1ccc2c4ccccc4c4ccccc4c2c1)c1cc(C(C)(C)C)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1S2)N(c1ccc2c4ccccc4c4ccccc4c2c1)c1cc(C(C)(C)C)cc2c1B3c1ccccc1N2c1ccc2c3ccccc3c3ccccc3c2c1] 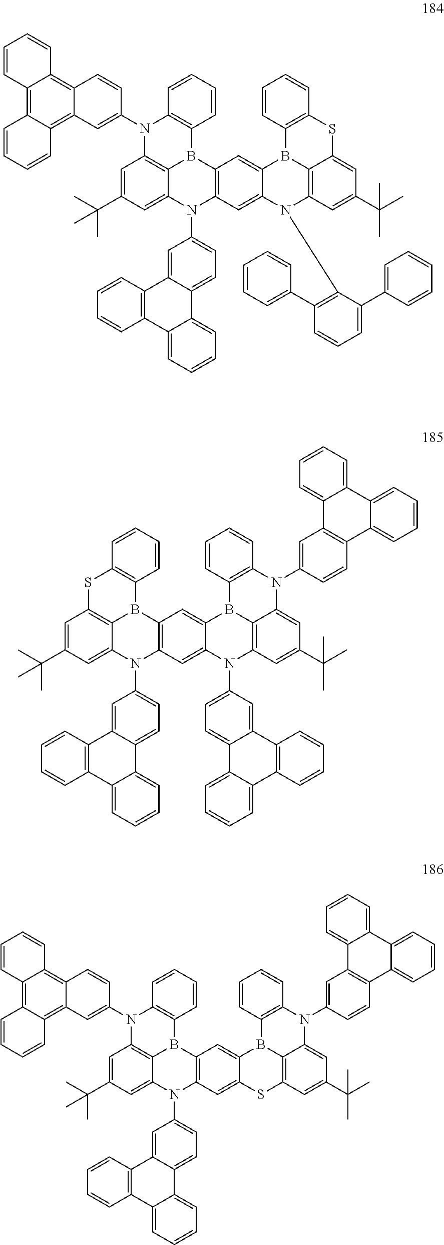 [SMILES: CC(C)(C)c1cc2c3c(c1)N(c1c(-c4ccccc4)cccc1-c1ccccc1)c1cc4c(cc1B3c1ccccc1S2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1cc4c(cc1B3c1ccccc1S2)B1c2ccccc2N(c2ccc3c5ccccc5c5ccccc5c3c2)c2cc(C(C)(C)C)cc(c21)N4c1ccc2c3ccccc3c3ccccc3c2c1 ; CC(C)(C)c1cc2c3c(c1)N(c1ccc4c5ccccc5c5ccccc5c4c1)c1ccccc1B3c1cc3c(cc1S2)N(c1ccc2c4ccccc4c4ccccc4c2c1)c1cc(C(C)(C)C)cc2c1B3c1ccccc1N2c1ccc2c3ccccc3c3ccccc3c2c1] 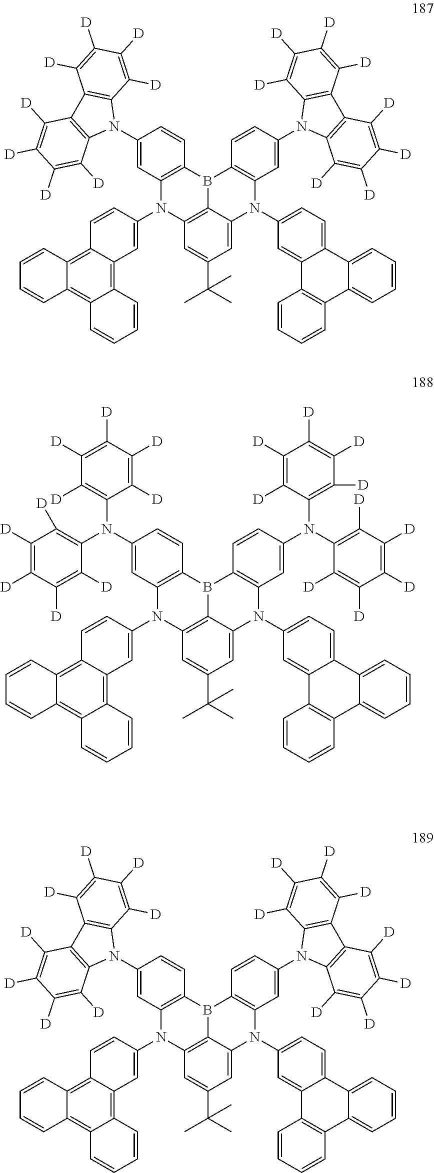 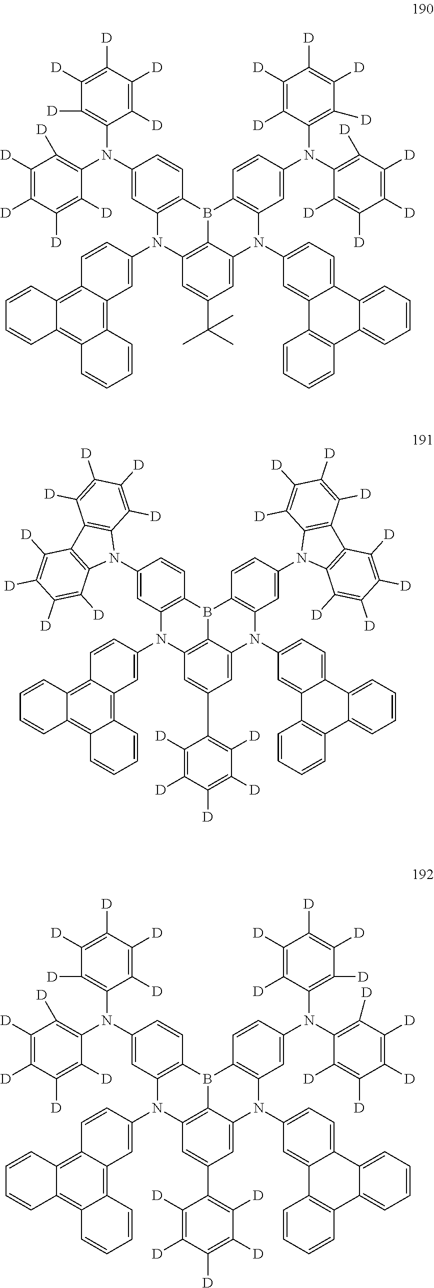 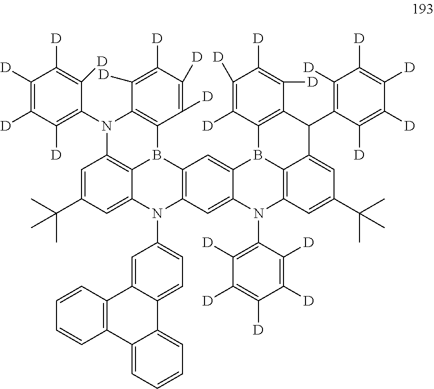 [SMILES: [2H]c1c([2H])c([2H])c(C2c3cc(C(C)(C)C)cc4c3B(c3cc5c(cc3N4c3c([2H])c([2H])c([2H])c([2H])c3[2H])N(c3ccc4c6ccccc6c6ccccc6c4c3)c3cc(C(C)(C)C)cc4c3B5c3c([2H])c([2H])c([2H])c([2H])c3N4c3c([2H])c([2H])c([2H])c([2H])c3[2H])c3c([2H])c([2H])c([2H])c([2H])c32)c([2H])c1[2H]]
wherein in Compound Group 1,
D is a deuterium atom.

16. A light emitting element comprising:
a first electrode;
a second electrode disposed on the first electrode; and
an emission layer disposed between the first electrode and the second electrode and comprising a polycyclic compound represented by Formula 1: 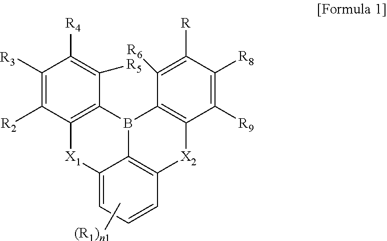
wherein in Formula 1,
X₁ and X₂ are each independently N(R₁₀), O, or S,
R₁ to R₁₀ are each independently:
a hydrogen atom, a deuterium atom, a halogen atom, a substituted or unsubstituted amine group, a substituted or unsubstituted boron group, a substituted or unsubstituted alkyl group 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
n1 is an integer from 0 to 3,
at least one of R₁ to R₁₀ is a group represented by Formula 2,
when R₃ or R₄ is a substituted or unsubstituted boron group, R₃ and R₄ are bonded to each other to form a ring,
when R₇ or R₈ is a substituted or unsubstituted boron group, R₇ and R₈ are bonded to each other to form a ring, and
when neither of R₃, R₄, R₇, and R₈ is a substituted or unsubstituted boron group, one of R₃ and R₄ and one of R₇ and R₈ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms: 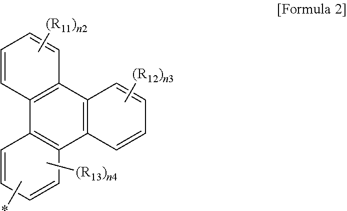
wherein in Formula 2,
R₁₁ to R₁₃ are each independently a hydrogen atom, a deuterium atom, a halogen atom, a substituted or unsubstituted amine group, substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n2 and n3 are each independently an integer from 0 to 4,
n4 is an integer from 0 to 3, and [symbol]
represents a binding site to Formula 1.

17. The light emitting element of claim 16, wherein the polycyclic compound represented by Formula 1 is represented by Formula 1-1 or Formula 1-2: 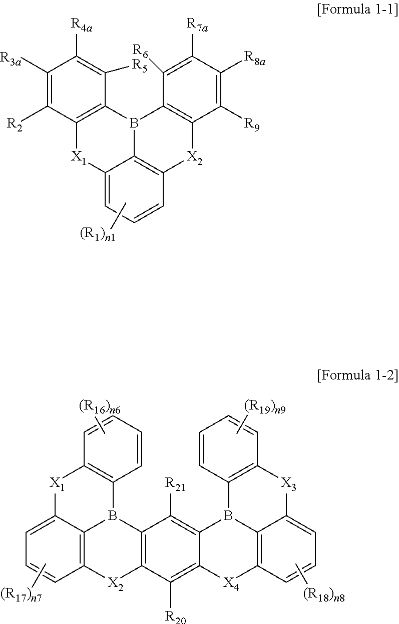
wherein in Formula 1-1,
R₃ₐ, R₄ₐ, R₇ₐ, and R₈ₐ are each independently:
a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁, R₂, R₅, R₆, R₉, R₁₀, R₃ₐ, R₄ₐ, R₇ₐ, or R₈ₐ is a group represented by Formula 2, and
one of R₃ₐ and R₄ₐ and one of R₇, and R₈ₐ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms,
wherein in Formula 1-2,
X₃ and X₄ are each independently N(R₂₂), O, or S,
R₁₆ to R₂₂ are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁₆ to R₂₂ is a group represented by Formula 2,
n6 and n9 are each independently an integer from 0 to 4,
n7 and n8 are each independently an integer from 0 to 3, and
wherein in Formula 1-1 and Formula 1-2,
X₁, X₂, R₁, R₂, R₅, R₆, R₉, R₁₀, and n1 are each the same as defined in Formula 1.

18. The light emitting element of claim 16, wherein the group represented by Formula 2 is represented by Formula 2-1: 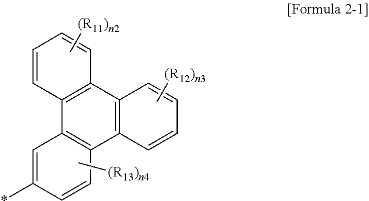
wherein in Formula 2-1,
R₁₁, R₁₂, R₁₃, n2 to n4, and [symbol] are each the same as defined in Formula 2.

19. A polycyclic compound represented by Formula 1: 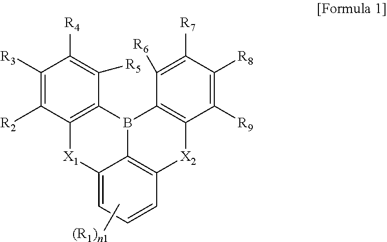
wherein in Formula 1,
X₁ and X₂ are each independently N(R₁₀), O, or S,
R₁ to R₁₀ are each independently:
a hydrogen atom, a deuterium atom, a halogen atom, a substituted or unsubstituted amine group, a substituted or unsubstituted boron group, a substituted or unsubstituted alkyl group 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
n1 is an integer from 0 to 3,
at least one of R₁ to R₁₀ is a group represented by Formula 2,
when R₃ or R₄ is a substituted or unsubstituted boron group, R₃ and R₄ are bonded to each other to form a ring,
when R₇ or R₈ is a substituted or unsubstituted boron group, R₇ and R₈ are bonded to each other to form a ring, and
when neither of R₃, R₄, R₇, and R₈ is a substituted or unsubstituted boron group, one of R₃ and R₄ and one of R₇ and R₈ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms: 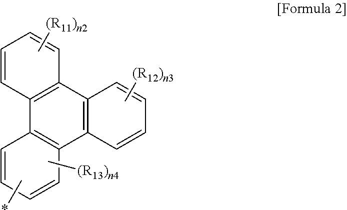
wherein in Formula 2,
R₁₁ to R₁₃ are each independently a hydrogen atom, a deuterium atom, a halogen atom, a substituted or unsubstituted amine group, substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n2 and n3 are each independently an integer from 0 to 4,
n4 is an integer from 0 to 3, and [symbol]
represents a binding site to Formula 1.

20. The polycyclic compound of claim 19, wherein the polycyclic compound represented by Formula 1 is represented by Formula 1-1 or Formula 1-2: 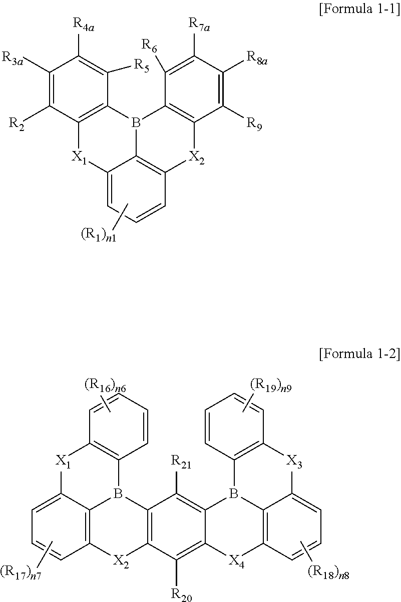
wherein in Formula 1-1,
R₃ₐ, R₄ₐ, R₇ₐ, and R₈ₐ are each independently:
a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁, R₂, R₅, R₆, R₉, R₁₀, R₃ₐ, R₄ₐ, R₇ₐ, or R₈ₐ is a group represented by Formula 2, and
one of R₃ₐ and R₄ₐ and one of R₇ₐ and R₈ₐ are each independently a substituted or unsubstituted amine group, a substituted or unsubstituted aryl group having 6 to 60 ring-forming carbon atoms, or a substituted or unsubstituted heteroaryl group having 2 to 60 ring-forming carbon atoms,
wherein in Formula 1-2,
X₃ and X₄ are each independently N(R₂₂), O, or S,
R₁₆ to R₂₂ are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁₆ to R₂₂ is a group represented by Formula 2,
n6 and n9 are each independently an integer from 0 to 4,
n7 and n8 are each independently an integer from 0 to 3, and
wherein in Formula 1-1 and Formula 1-2,
X₁, X₂, R₁, R₂, R₅, R₆, R₉, R₁₀, and n1 are each the same as defined in Formula 1.

21. The polycyclic compound of claim 20, wherein the polycyclic compound represented by Formula 1-1 is represented by Formula 1-1a: 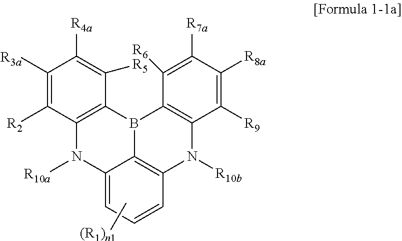
wherein in Formula 1-1a,
R₁₀ₐ and R_{10b} are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁, R₂, R₅, R₆, R₉, R₃ₐ, R₄ₐ, R₇ₐ, R₈ₐ, R₁₀ₐ, or R_{10b} is a group represented by Formula 2,
R₃ₐ, R₄ₐ, R₇ₐ, and R₈ are each the same as defined in Formula 1-1, and
R₁, R₂, R₅, R₆, R₉, and n1 are each the same as defined in Formula 1.

22. The polycyclic compound of claim 20, wherein the polycyclic compound represented by Formula 1-2 is represented by one of Formulae 1-2a to 1-2e: 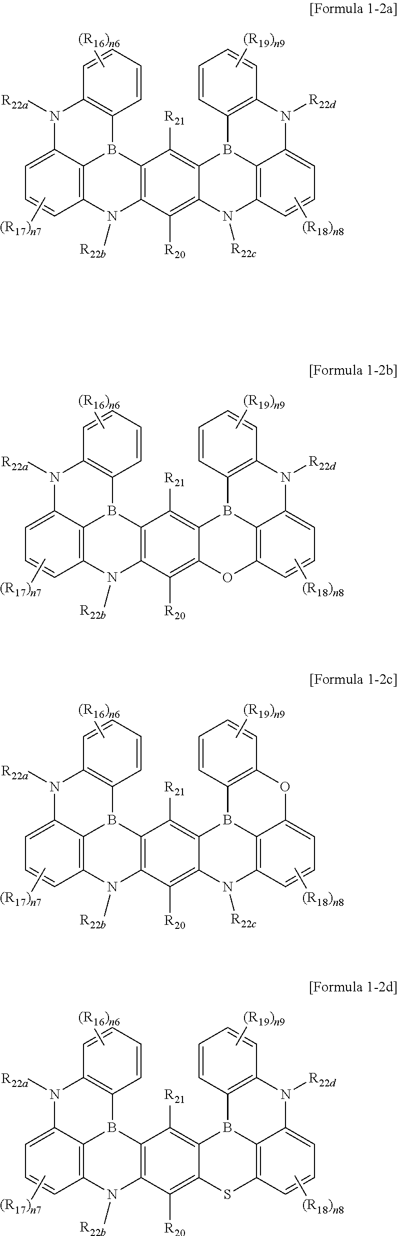 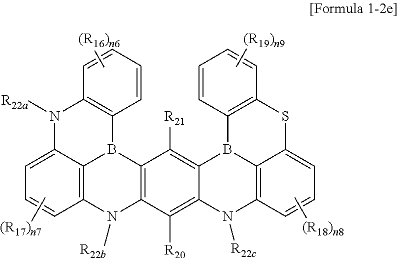
wherein in Formula 1-2a to Formula 1-2e,
R₂₂ₐ to R_{22d} are each independently:
a hydrogen atom, a deuterium atom, a halogen atom, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; or
bonded to an adjacent group to form a ring; or
a group represented by Formula 2,
at least one of R₁₆ to R₂₁ and R₂₂ₐ to R_{22d} is a group represented by Formula 2, and
R₁₆ to R₂₁ and n6 to n9 are each the same as defined in Formula 1-2.

23. The polycyclic compound of claim 19, wherein the polycyclic compound represented by Formula 1 is represented by Formula 1-3: 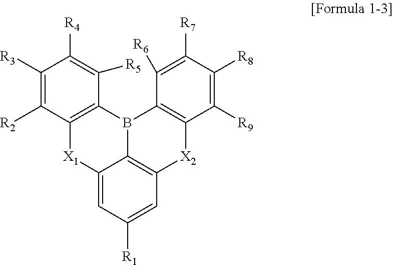
wherein in Formula 1-3,
X₁, X₂, and R₁ to R₉ are each the same as defined in Formula 1.

24. The polycyclic compound of claim 19, wherein the group represented by Formula 2 is represented by Formula 2-1: 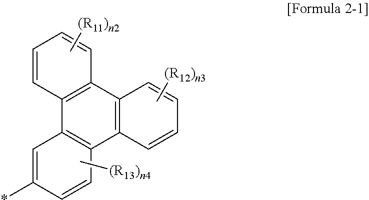
wherein in Formula 2-1,
R₁₁, R₁₂, R₁₃, n2 to n4, and [symbol] are each the same as defined in Formula 2.

25. The polycyclic compound of claim 19, wherein the polycyclic compound is selected from Compound Group 1: 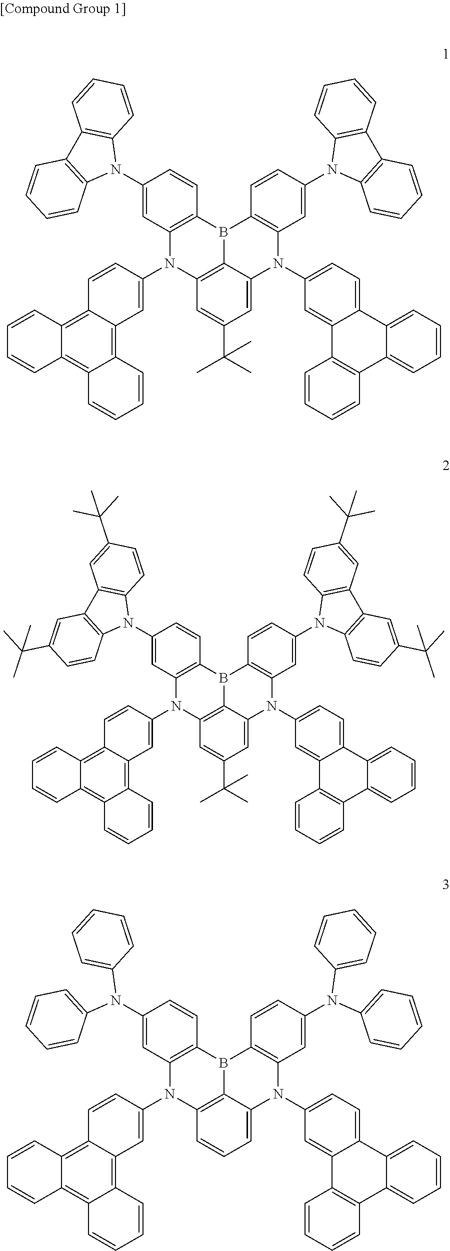 [SMILES: CC(C)(C)c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1ccc2c3ccccc3c3ccccc3c2c1 ; c1ccc(N(c2ccccc2)c2ccc3c(c2)N(c2ccc4c5ccccc5c5ccccc5c4c2)c2cccc4c2B3c2ccc(N(c3ccccc3)c3ccccc3)cc2N4c2ccc3c4ccccc4c4ccccc4c3c2)cc1] 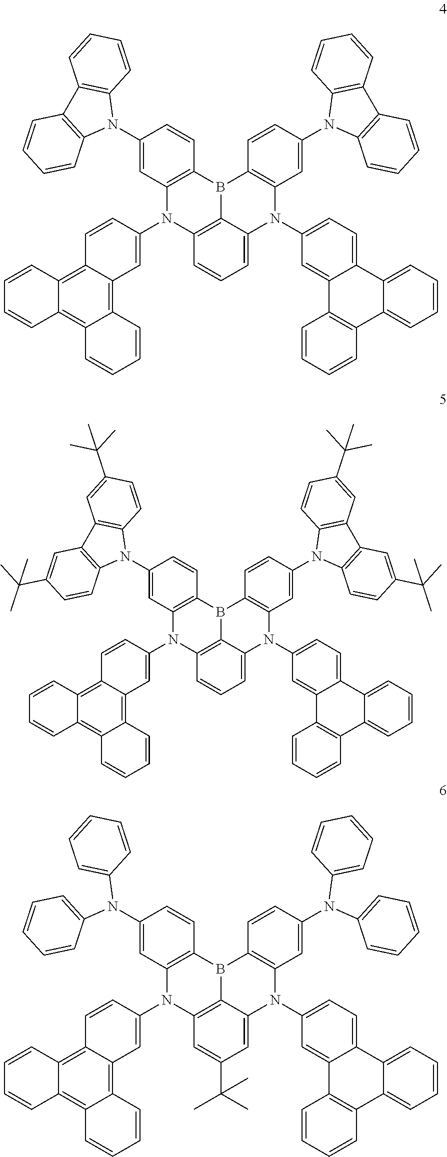 [SMILES: c1cc2c3c(c1)N(c1ccc4c5ccccc5c5ccccc5c4c1)c1cc(-n4c5ccccc5c5ccccc54)ccc1B3c1ccc(-n3c4ccccc4c4ccccc43)cc1N2c1ccc2c3ccccc3c3ccccc3c2c1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1ccc(-n2c4ccc(C(C)(C)C)cc4c4cc(C(C)(C)C)ccc42)cc1N3c1ccc2c3ccccc3c3ccccc3c2c1 ; CC(C)(C)c1cc2c3c(c1)N(c1ccc4c5ccccc5c5ccccc5c4c1)c1cc(N(c4ccccc4)c4ccccc4)ccc1B3c1ccc(N(c3ccccc3)c3ccccc3)cc1N2c1ccc2c3ccccc3c3ccccc3c2c1] 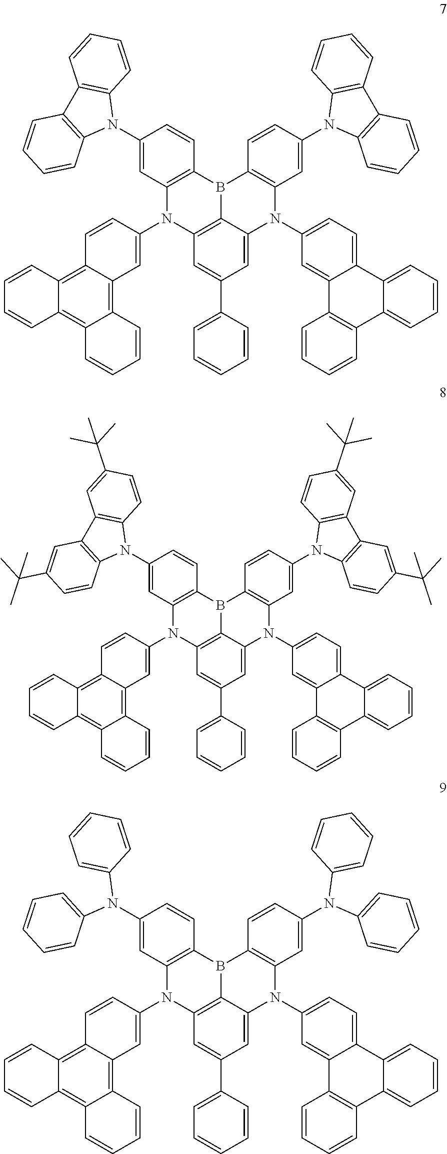 [SMILES: c1ccc(-c2cc3c4c(c2)N(c2ccc5c6ccccc6c6ccccc6c5c2)c2cc(-n5c6ccccc6c6ccccc65)ccc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1ccc(-n2c4ccc(C(C)(C)C)cc4c4cc(C(C)(C)C)ccc42)cc1N3c1ccc2c3ccccc3c3ccccc3c2c1 ; c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1] 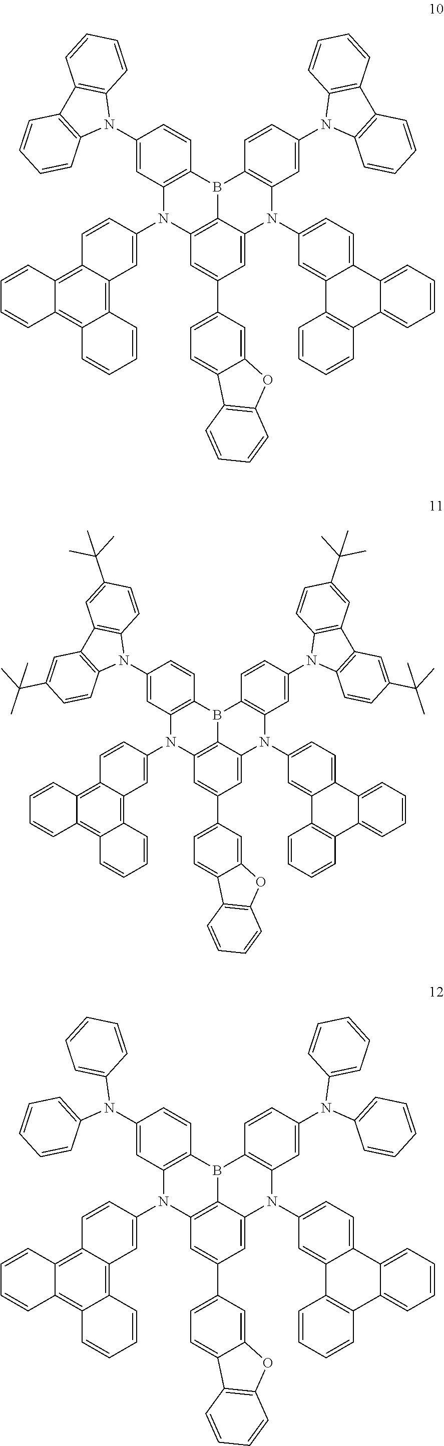 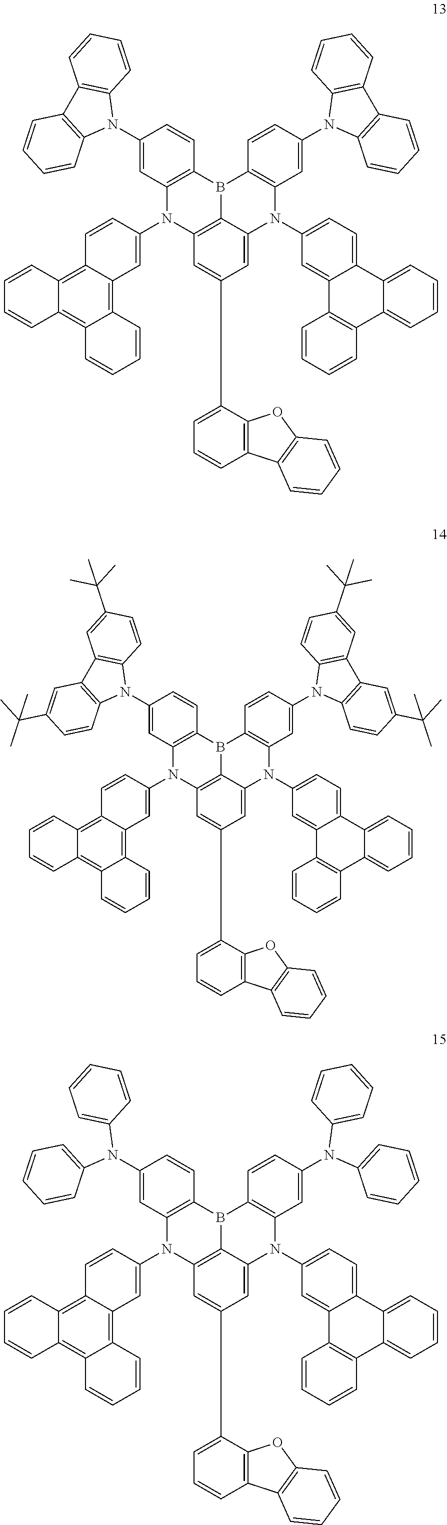 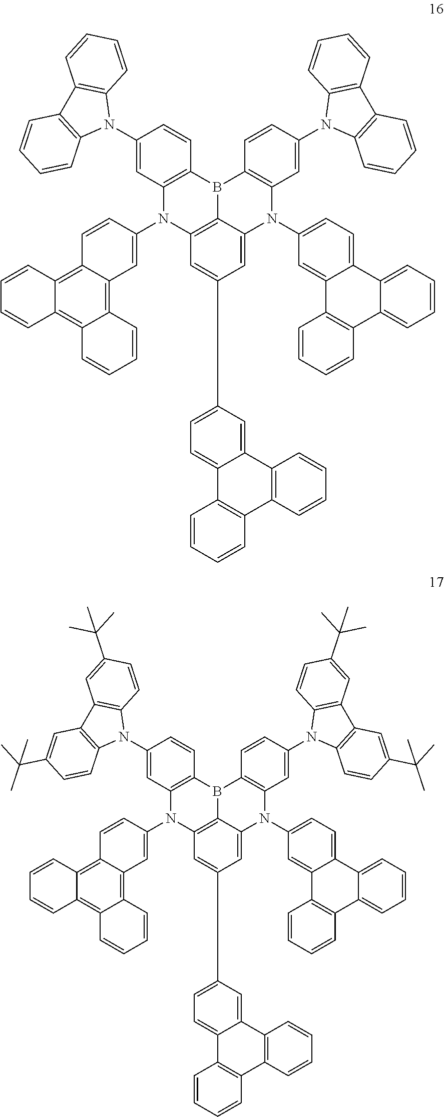 [SMILES: c1ccc2c(c1)c1ccccc1c1cc(Cc3cc4c5c(c3)N(c3ccc6c7ccccc7c7ccccc7c6c3)c3cc(-n6c7ccccc7c7ccccc76)ccc3B5c3ccc(-n5c6ccccc6c6ccccc65)cc3N4c3ccc4c5ccccc5c5ccccc5c4c3)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(Cc3ccc4c5ccccc5c5ccccc5c4c3)cc3c1B2c1ccc(-n2c4ccc(C(C)(C)C)cc4c4cc(C(C)(C)C)ccc42)cc1N3c1ccc2c3ccccc3c3ccccc3c2c1] 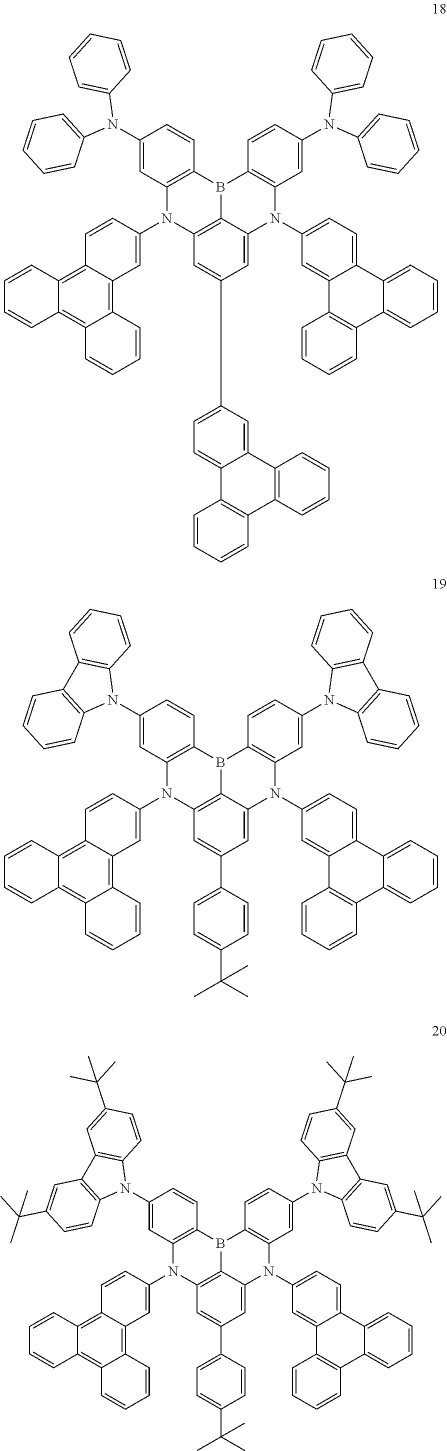 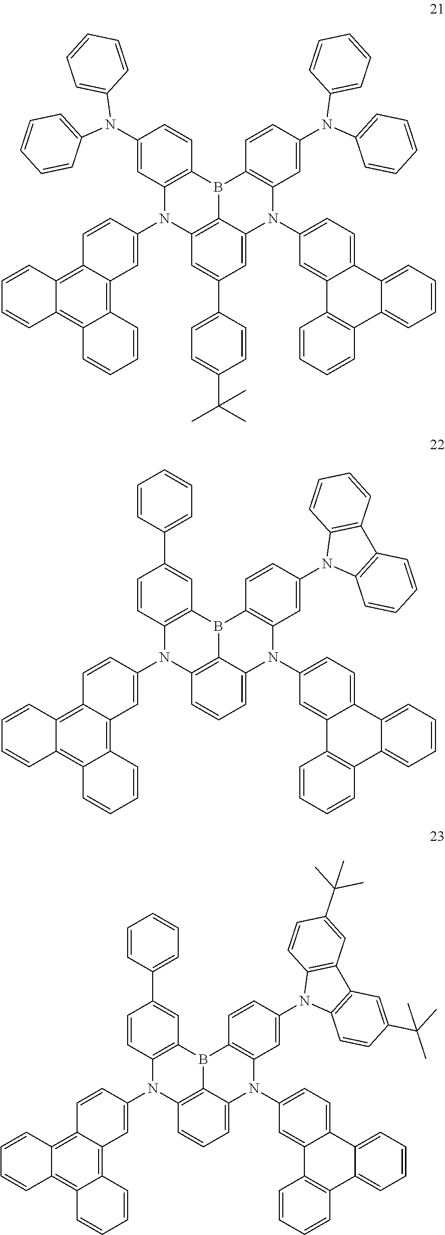 [SMILES: CC(C)(C)c1ccc(-c2cc3c4c(c2)N(c2ccc5c6ccccc6c6ccccc6c5c2)c2cc(N(c5ccccc5)c5ccccc5)ccc2B4c2ccc(N(c4ccccc4)c4ccccc4)cc2N3c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cccc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cccc3c1B2c1cc(-c2ccccc2)ccc1N3c1ccc2c3ccccc3c3ccccc3c2c1] 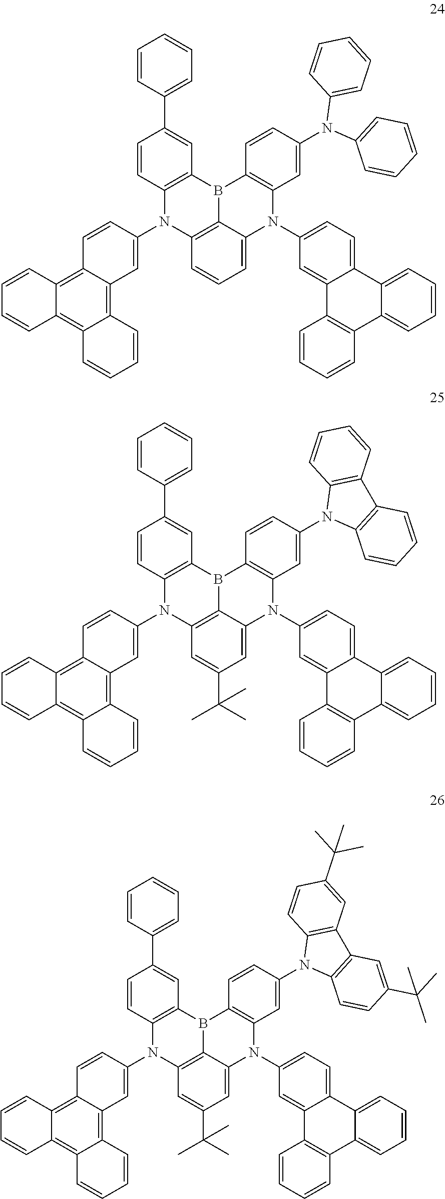 [SMILES: c1ccc(-c2ccc3c(c2)B2c4ccc(N(c5ccccc5)c5ccccc5)cc4N(c4ccc5c6ccccc6c6ccccc6c5c4)c4cccc(c42)N3c2ccc3c4ccccc4c4ccccc4c3c2)cc1 ; CC(C)(C)c1cc2c3c(c1)N(c1ccc4c5ccccc5c5ccccc5c4c1)c1cc(-n4c5ccccc5c5ccccc54)ccc1B3c1cc(-c3ccccc3)ccc1N2c1ccc2c3ccccc3c3ccccc3c2c1 ; CC(C)(C)c1cc2c3c(c1)N(c1ccc4c5ccccc5c5ccccc5c4c1)c1cc(-n4c5ccc(C(C)(C)C)cc5c5cc(C(C)(C)C)ccc54)ccc1B3c1cc(-c3ccccc3)ccc1N2c1ccc2c3ccccc3c3ccccc3c2c1] 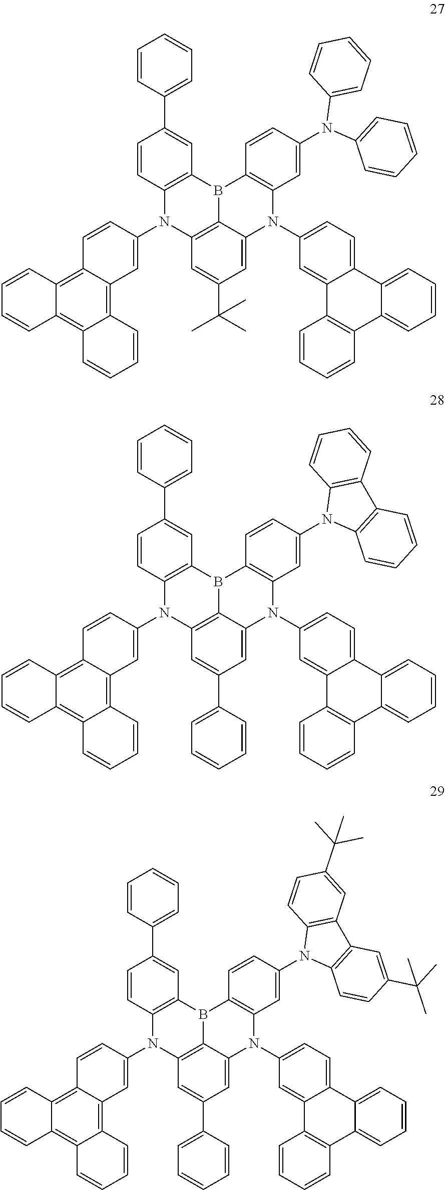 [SMILES: CC(C)(C)c1cc2c3c(c1)N(c1ccc4c5ccccc5c5ccccc5c4c1)c1cc(N(c4ccccc4)c4ccccc4)ccc1B3c1cc(-c3ccccc3)ccc1N2c1ccc2c3ccccc3c3ccccc3c2c1 ; c1ccc(-c2ccc3c(c2)B2c4ccc(-n5c6ccccc6c6ccccc65)cc4N(c4ccc5c6ccccc6c6ccccc6c5c4)c4cc(-c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccccc3)cc3c1B2c1cc(-c2ccccc2)ccc1N3c1ccc2c3ccccc3c3ccccc3c2c1] 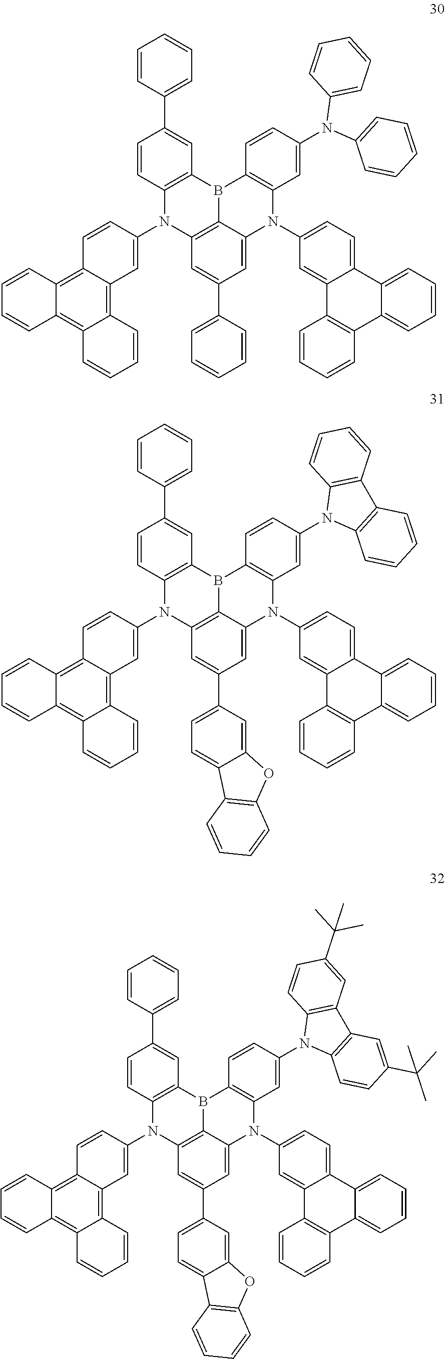 [SMILES: c1ccc(-c2ccc3c(c2)B2c4ccc(N(c5ccccc5)c5ccccc5)cc4N(c4ccc5c6ccccc6c6ccccc6c5c4)c4cc(-c5ccccc5)cc(c42)N3c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc(-c2ccccc2)ccc1N3c1ccc2c3ccccc3c3ccccc3c2c1] 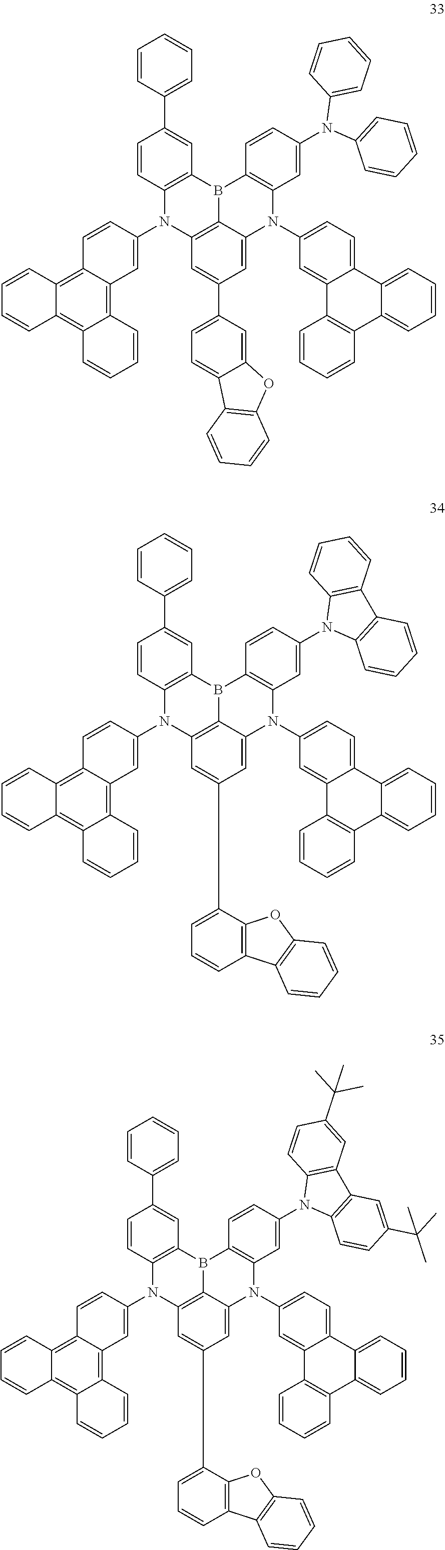 [SMILES: c1ccc(-c2ccc3c(c2)B2c4ccc(N(c5ccccc5)c5ccccc5)cc4N(c4ccc5c6ccccc6c6ccccc6c5c4)c4cc(-c5ccc6c(c5)oc5ccccc56)cc(c42)N3c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(Cc5cccc6c5oc5ccccc56)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(Cc3cccc4c3oc3ccccc34)cc3c1B2c1cc(-c2ccccc2)ccc1N3c1ccc2c3ccccc3c3ccccc3c2c1] 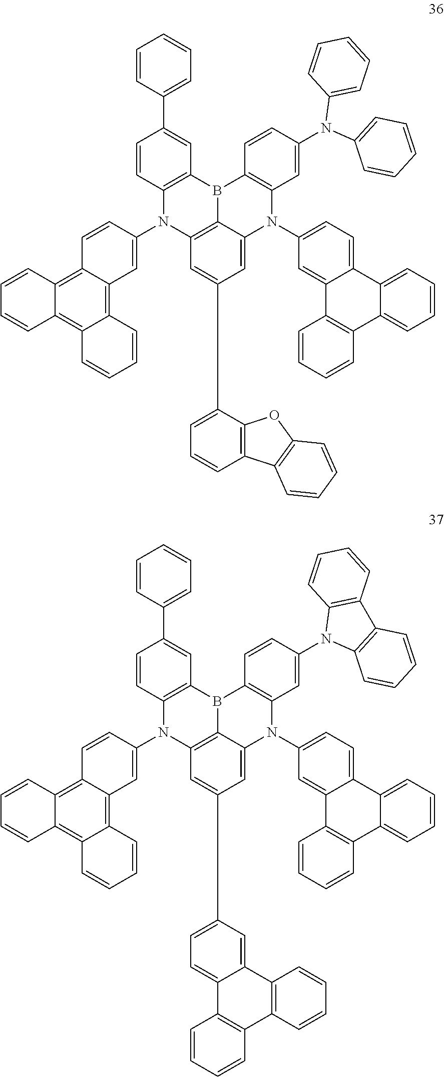 [SMILES: c1ccc(-c2ccc3c(c2)B2c4ccc(N(c5ccccc5)c5ccccc5)cc4N(c4ccc5c6ccccc6c6ccccc6c5c4)c4cc(Cc5cccc6c5oc5ccccc56)cc(c42)N3c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(Cc5ccc6c7ccccc7c7ccccc7c6c5)cc(c42)N3c2ccc3c4ccccc4c4ccccc4c3c2)cc1] 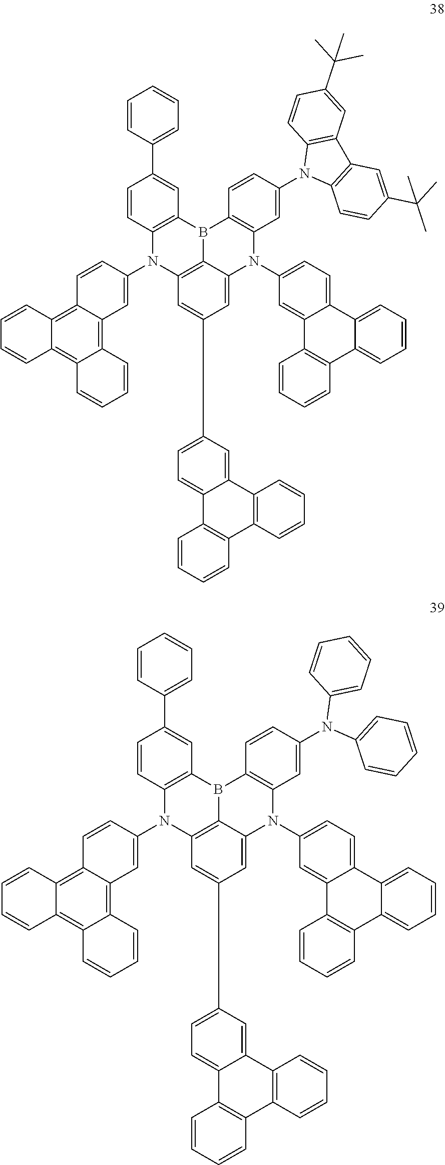 [SMILES: CC(C)(C)c1ccc2c(c1)c1cc(C(C)(C)C)ccc1n2-c1ccc2c(c1)N(c1ccc3c4ccccc4c4ccccc4c3c1)c1cc(Cc3ccc4c5ccccc5c5ccccc5c4c3)cc3c1B2c1cc(-c2ccccc2)ccc1N3c1ccc2c3ccccc3c3ccccc3c2c1 ; c1ccc(-c2ccc3c(c2)B2c4ccc(N(c5ccccc5)c5ccccc5)cc4N(c4ccc5c6ccccc6c6ccccc6c5c4)c4cc(Cc5ccc6c7ccccc7c7ccccc7c6c5)cc(c42)N3c2ccc3c4ccccc4c4ccccc4c3c2)cc1] 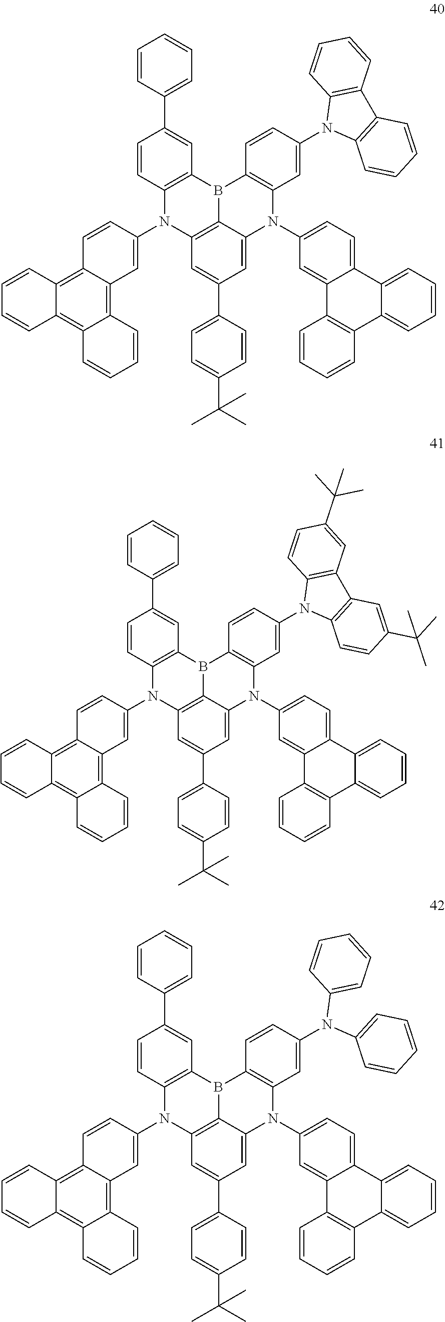 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(-n5c6ccc(C(C)(C)C)cc6c6cc(C(C)(C)C)ccc65)ccc2B4c2cc(-c4ccccc4)ccc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc(N(c5ccccc5)c5ccccc5)ccc2B4c2cc(-c4ccccc4)ccc2N3c2ccc3c4ccccc4c4ccccc4c3c2)cc1] 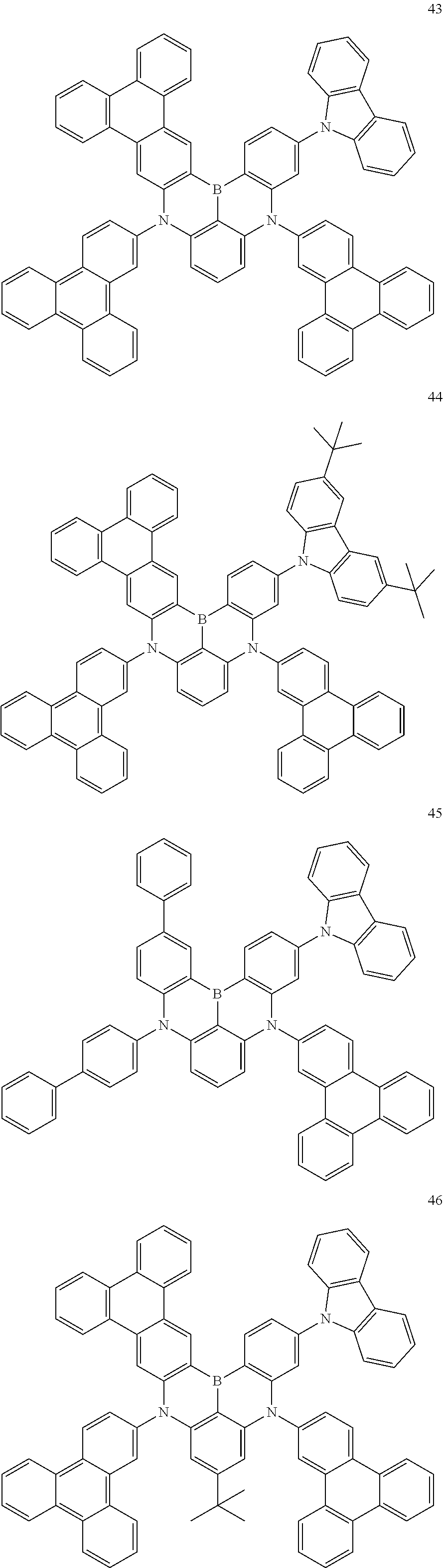 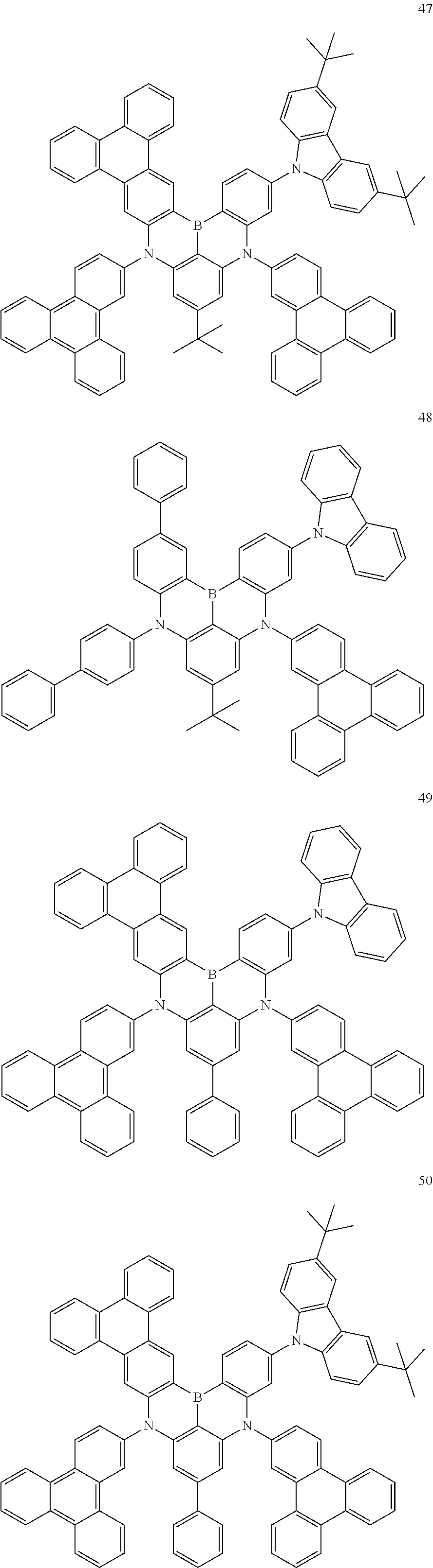 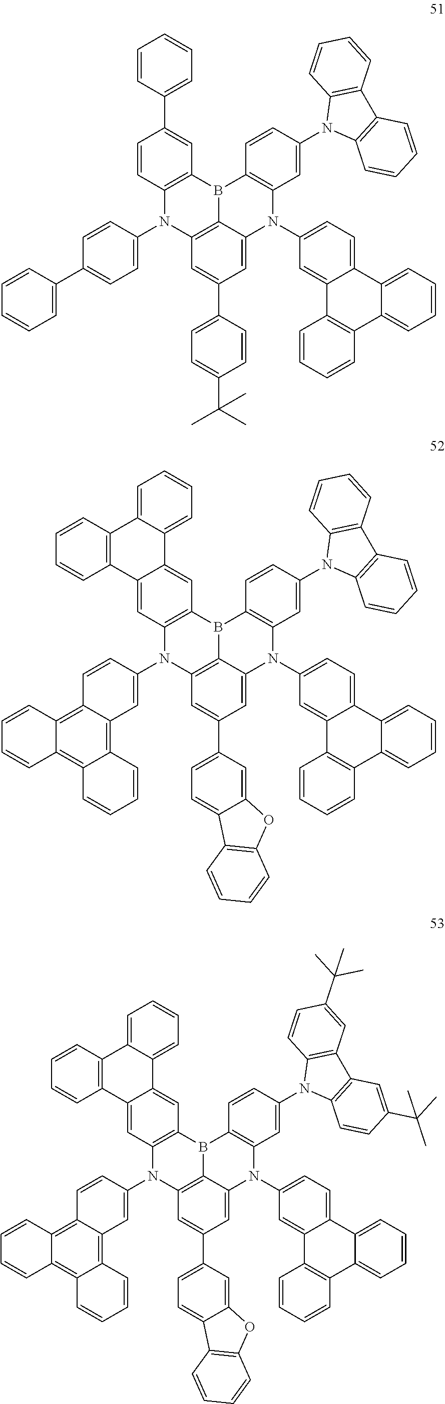 [SMILES: CC(C)(C)c1ccc(-c2cc3c4c(c2)N(c2ccc5c6ccccc6c6ccccc6c5c2)c2cc(-n5c6ccccc6c6ccccc65)ccc2B4c2cc(-c4ccccc4)ccc2N3c2ccc(-c3ccccc3)cc2)cc1 ; c1ccc2c(c1)oc1cc(-c3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc12 ; CC(C)(C)c1ccc2c(c1)c1cc(C(C)(C)C)ccc1n2-c1ccc2c(c1)N(c1ccc3c4ccccc4c4ccccc4c3c1)c1cc(-c3ccc4c(c3)oc3ccccc34)cc3c1B2c1cc2c4ccccc4c4ccccc4c2cc1N3c1ccc2c3ccccc3c3ccccc3c2c1] 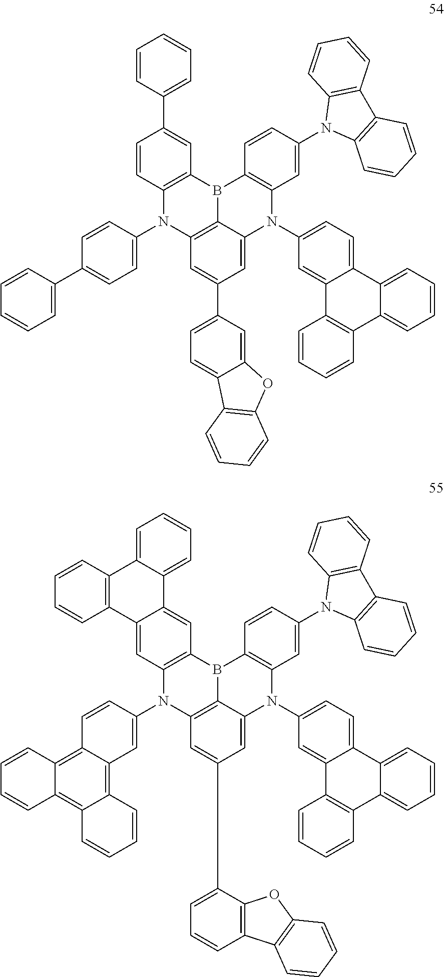 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(-c6ccc7c(c6)oc6ccccc67)cc3c54)cc2)cc1 ; c1ccc2c(c1)oc1c(Cc3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)cccc12] 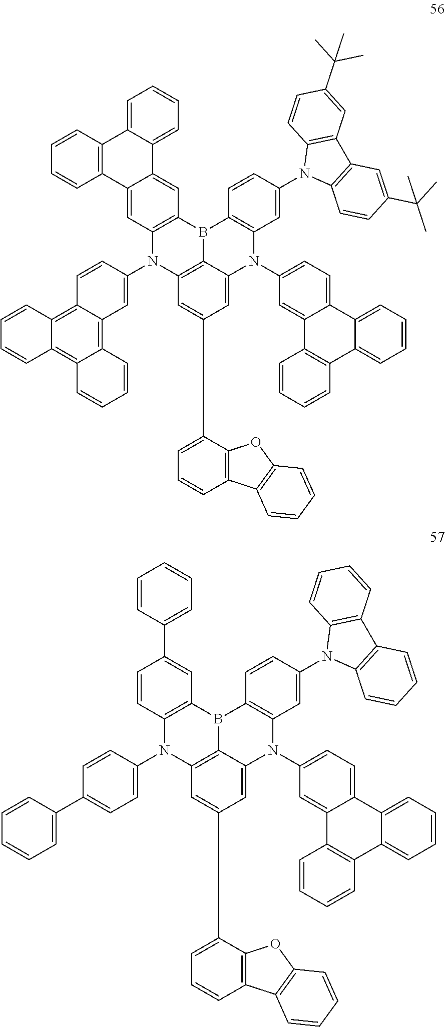 [SMILES: CC(C)(C)c1ccc2c(c1)c1cc(C(C)(C)C)ccc1n2-c1ccc2c(c1)N(c1ccc3c4ccccc4c4ccccc4c3c1)c1cc(Cc3cccc4c3oc3ccccc34)cc3c1B2c1cc2c4ccccc4c4ccccc4c2cc1N3c1ccc2c3ccccc3c3ccccc3c2c1 ; c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(Cc6cccc7c6oc6ccccc67)cc3c54)cc2)cc1] 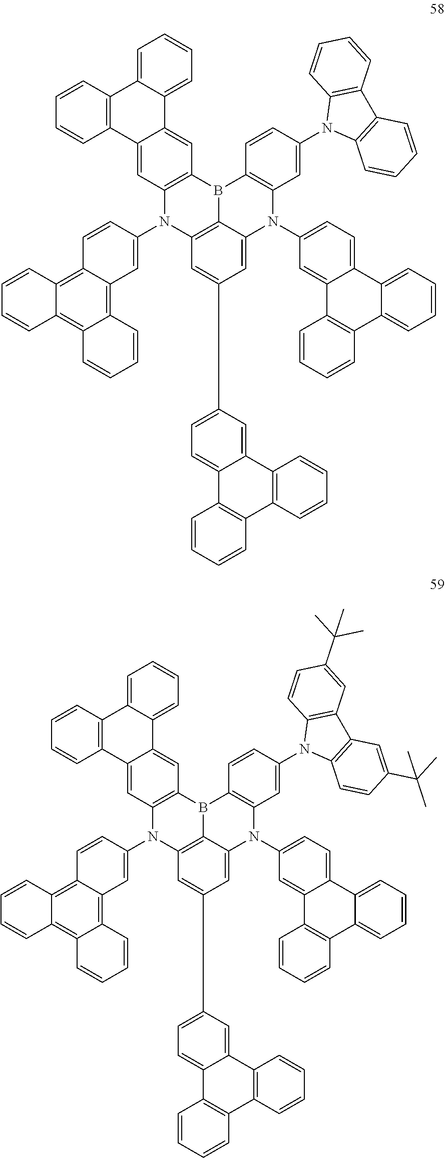 [SMILES: c1ccc2c(c1)c1ccccc1c1cc(Cc3cc4c5c(c3)N(c3ccc6c7ccccc7c7ccccc7c6c3)c3cc6c7ccccc7c7ccccc7c6cc3B5c3ccc(-n5c6ccccc6c6ccccc65)cc3N4c3ccc4c5ccccc5c5ccccc5c4c3)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(Cc3ccc4c5ccccc5c5ccccc5c4c3)cc3c1B2c1cc2c4ccccc4c4ccccc4c2cc1N3c1ccc2c3ccccc3c3ccccc3c2c1] 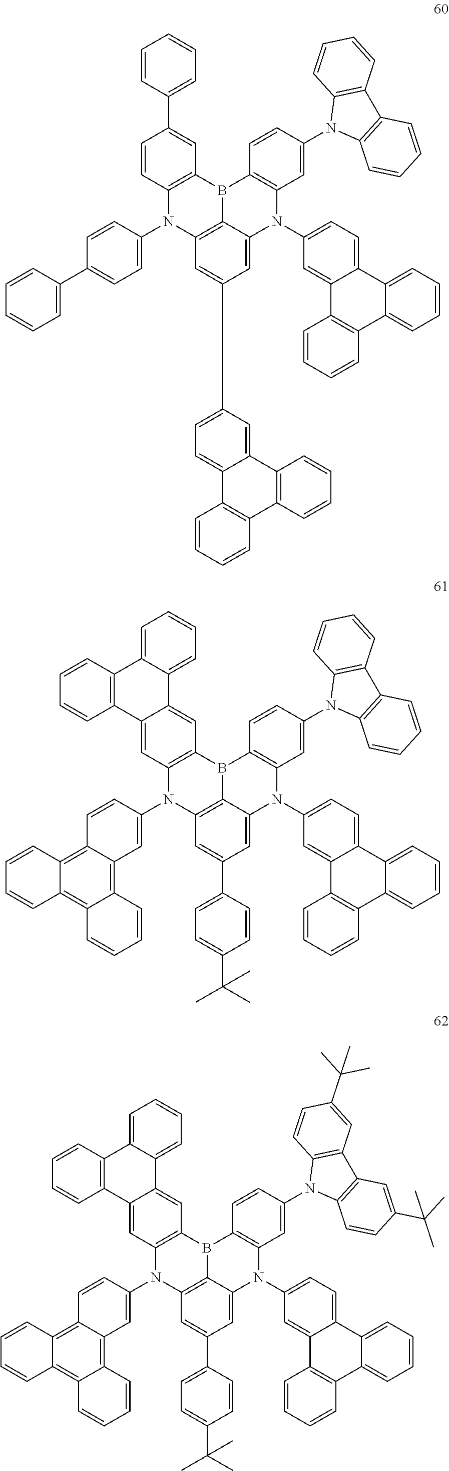 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(Cc6ccc7c8ccccc8c8ccccc8c7c6)cc3c54)cc2)cc1 ; CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc(-c2cc3c4c(c2)N(c2ccc5c6ccccc6c6ccccc6c5c2)c2cc5c6ccccc6c6ccccc6c5cc2B4c2ccc(-n4c5ccc(C(C)(C)C)cc5c5cc(C(C)(C)C)ccc54)cc2N3c2ccc3c4ccccc4c4ccccc4c3c2)cc1] 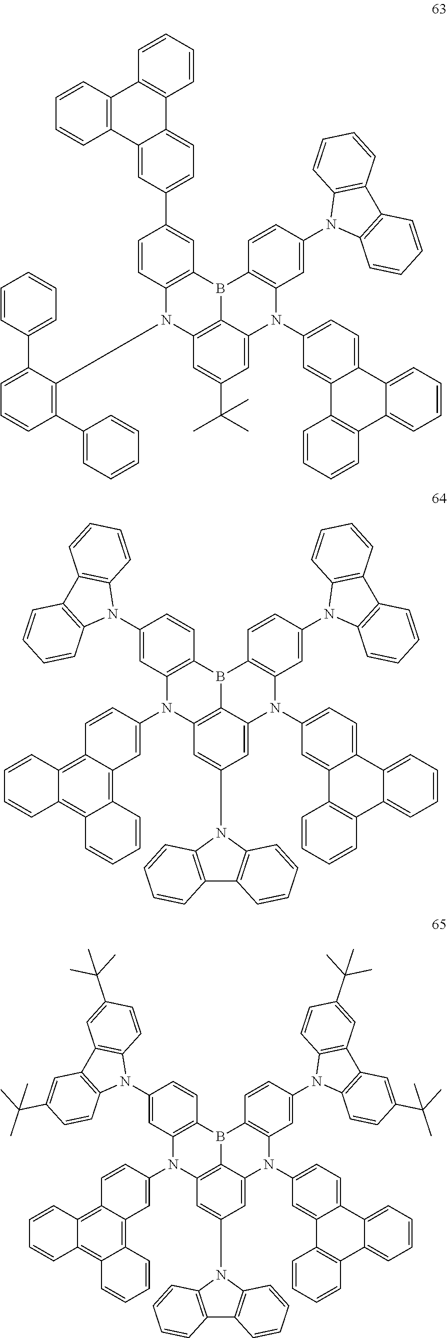 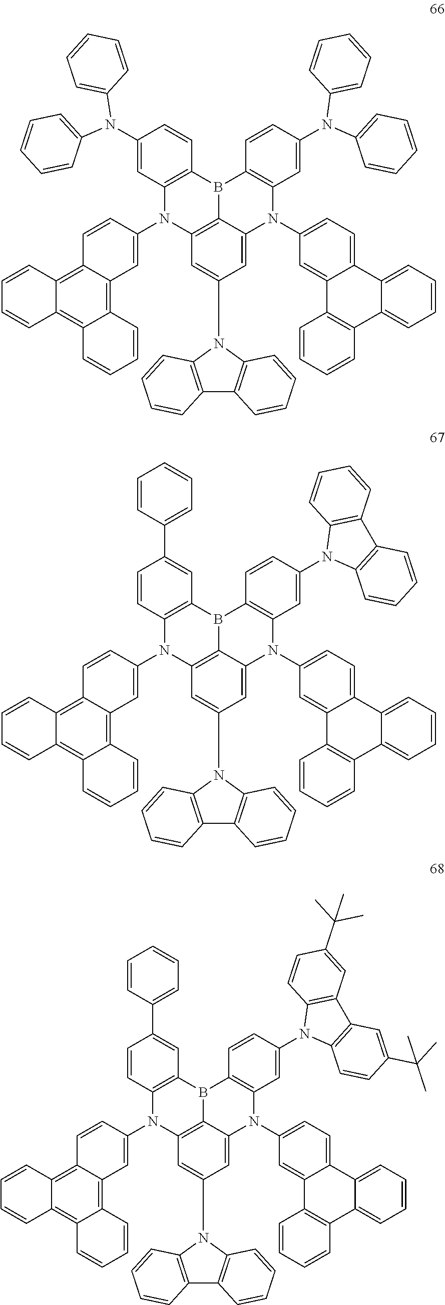 [SMILES: c1ccc(N(c2ccccc2)c2ccc3c(c2)N(c2ccc4c5ccccc5c5ccccc5c4c2)c2cc(-n4c5ccccc5c5ccccc54)cc4c2B3c2ccc(N(c3ccccc3)c3ccccc3)cc2N4c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc(-c2ccccc2)ccc1N3c1ccc2c3ccccc3c3ccccc3c2c1] 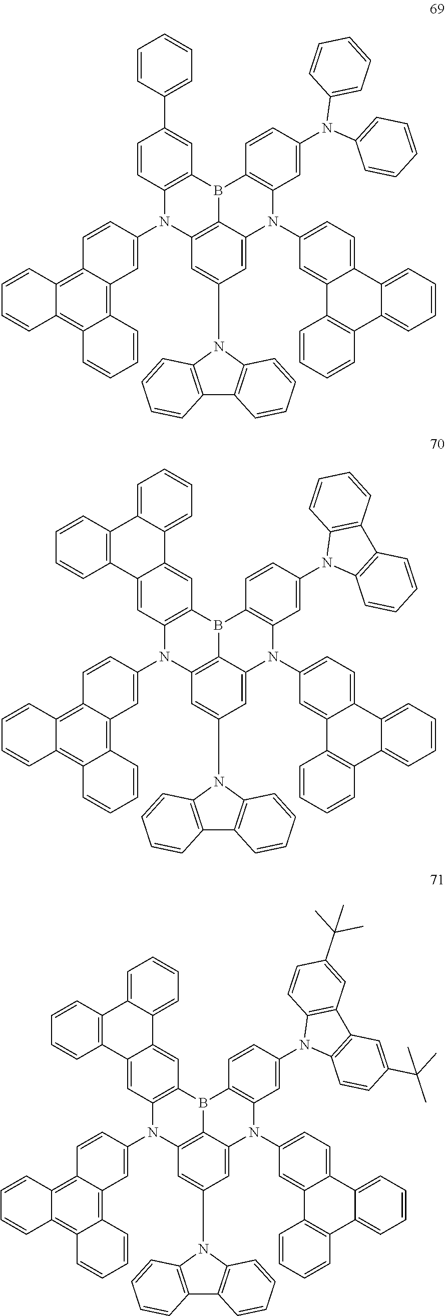 [SMILES: c1ccc(-c2ccc3c(c2)B2c4ccc(N(c5ccccc5)c5ccccc5)cc4N(c4ccc5c6ccccc6c6ccccc6c5c4)c4cc(-n5c6ccccc6c6ccccc65)cc(c42)N3c2ccc3c4ccccc4c4ccccc4c3c2)cc1 ; c1ccc2c(c1)c1ccccc1c1cc(N3c4cc(-n5c6ccccc6c6ccccc65)ccc4B4c5cc6c7ccccc7c7ccccc7c6cc5N(c5ccc6c7ccccc7c7ccccc7c6c5)c5cc(-n6c7ccccc7c7ccccc76)cc3c54)ccc21 ; CC(C)(C)c1ccc2c(c1)c1cc(C(C)(C)C)ccc1n2-c1ccc2c(c1)N(c1ccc3c4ccccc4c4ccccc4c3c1)c1cc(-n3c4ccccc4c4ccccc43)cc3c1B2c1cc2c4ccccc4c4ccccc4c2cc1N3c1ccc2c3ccccc3c3ccccc3c2c1] 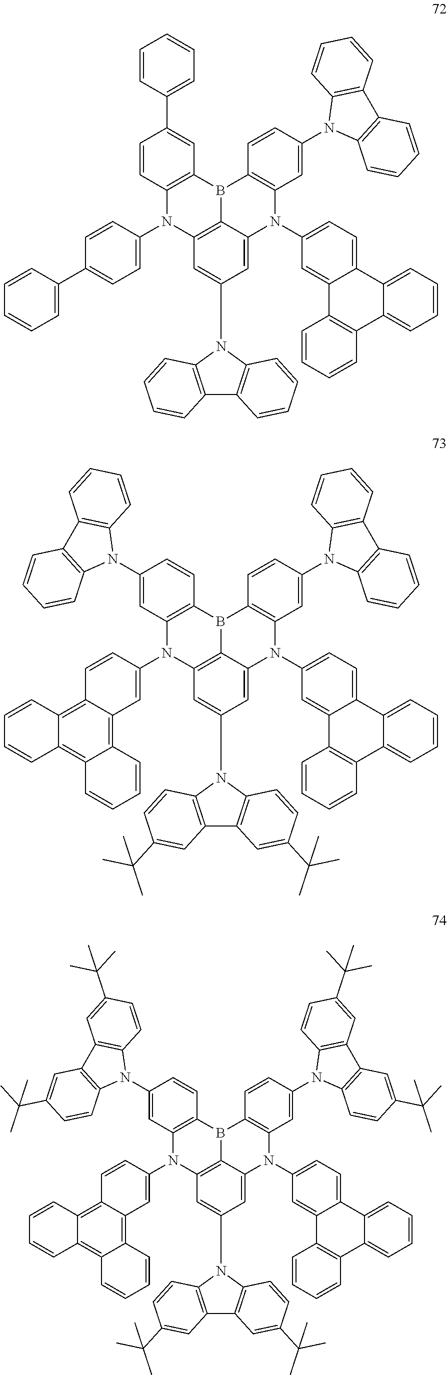 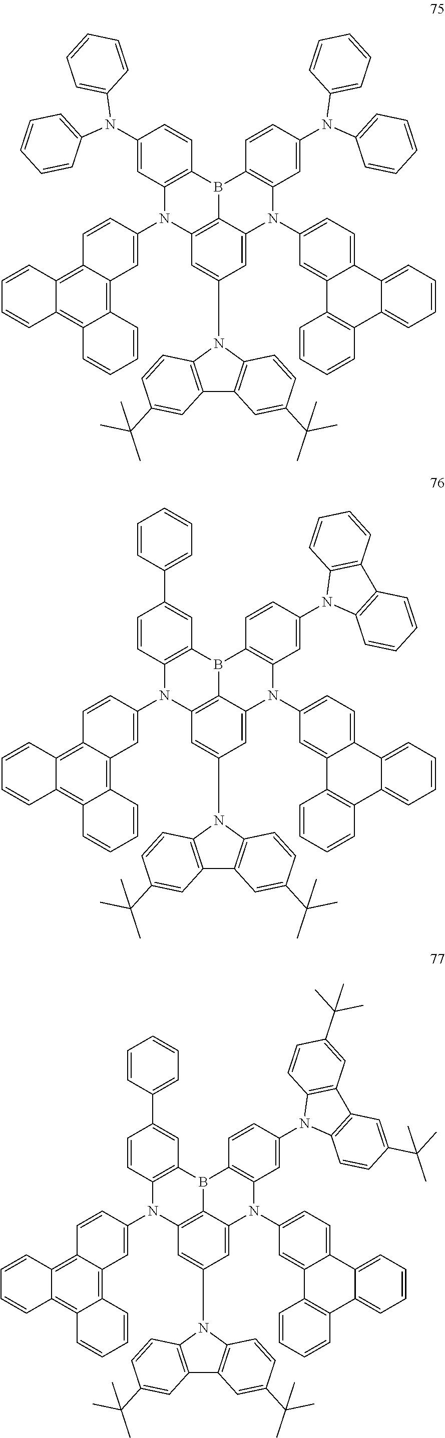 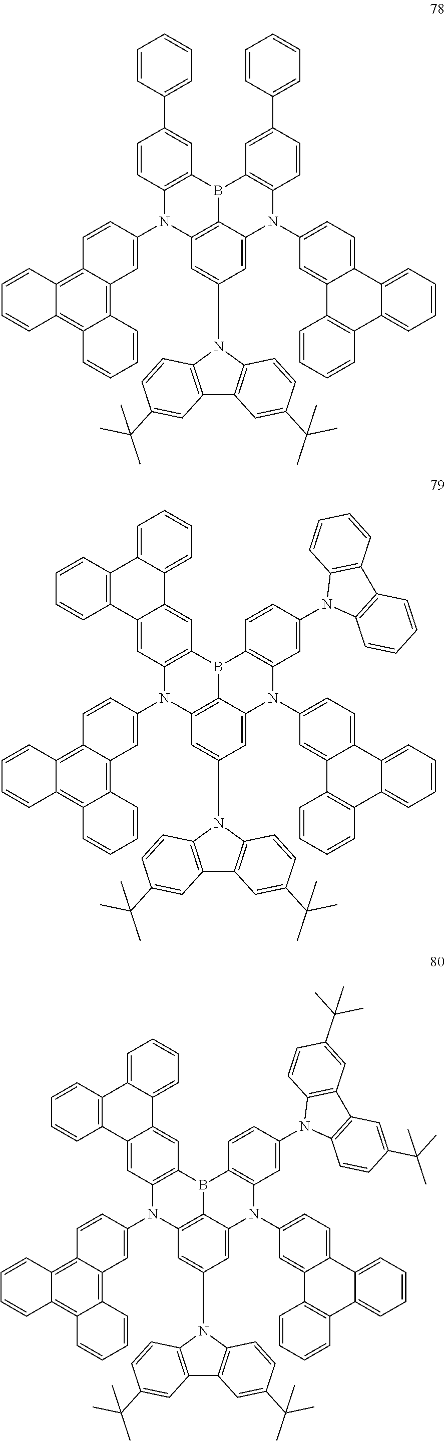 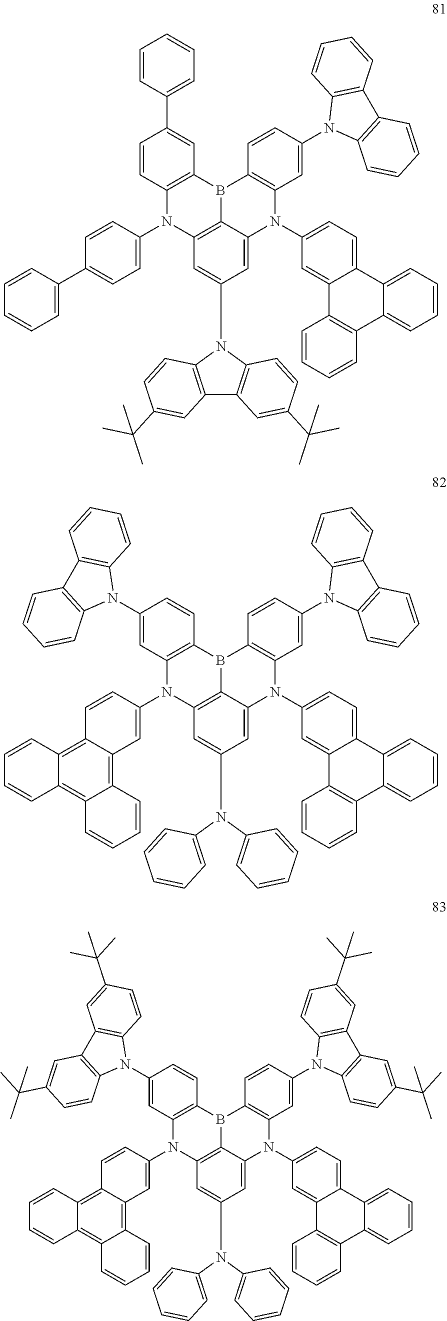 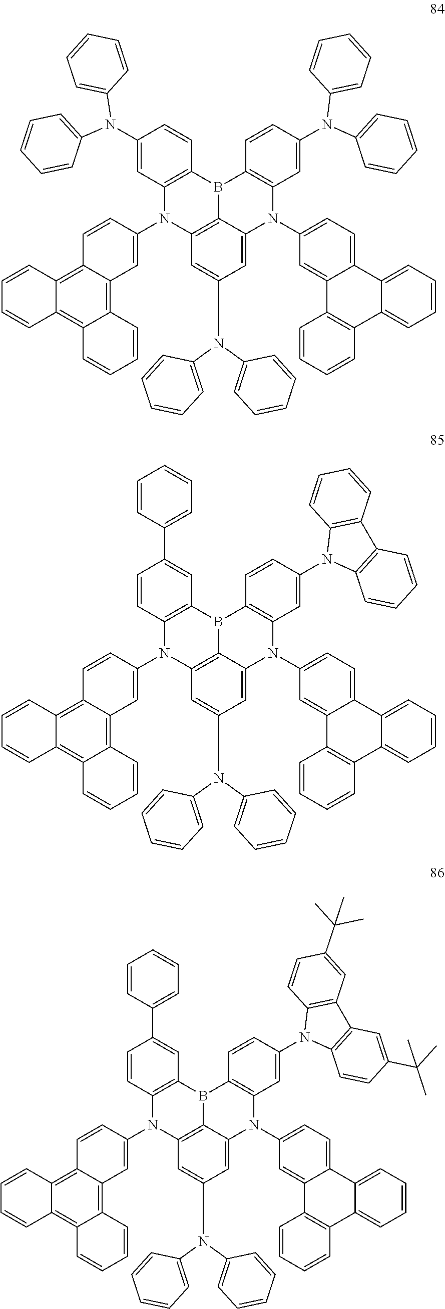 [SMILES: c1ccc(N(c2ccccc2)c2ccc3c(c2)N(c2ccc4c5ccccc5c5ccccc5c4c2)c2cc(N(c4ccccc4)c4ccccc4)cc4c2B3c2ccc(N(c3ccccc3)c3ccccc3)cc2N4c2ccc3c4ccccc4c4ccccc4c3c2)cc1 ; c1ccc(-c2ccc3c(c2)B2c4ccc(-n5c6ccccc6c6ccccc65)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc(-c2ccccc2)ccc1N3c1ccc2c3ccccc3c3ccccc3c2c1] 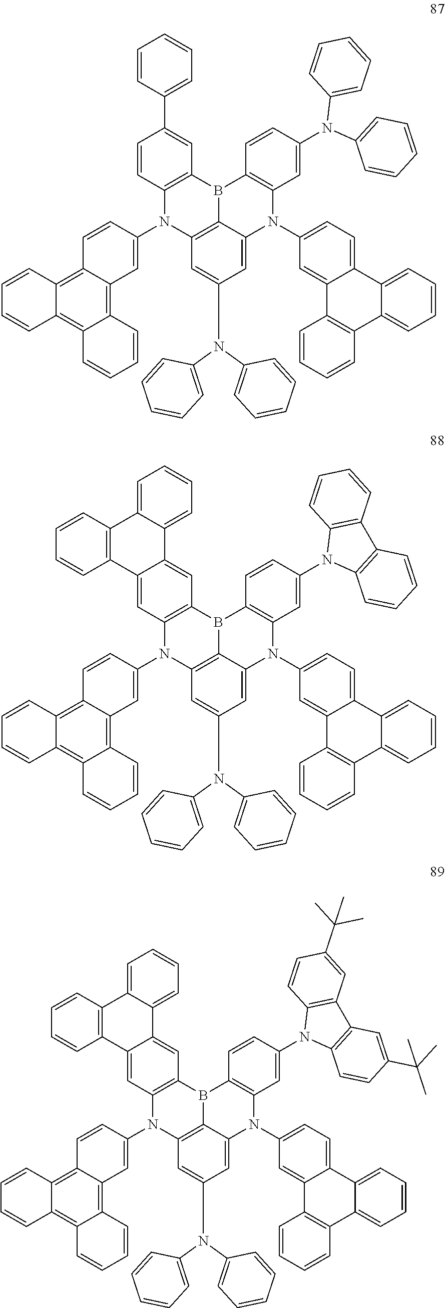 [SMILES: c1ccc(-c2ccc3c(c2)B2c4ccc(N(c5ccccc5)c5ccccc5)cc4N(c4ccc5c6ccccc6c6ccccc6c5c4)c4cc(N(c5ccccc5)c5ccccc5)cc(c42)N3c2ccc3c4ccccc4c4ccccc4c3c2)cc1 ; c1ccc(N(c2ccccc2)c2cc3c4c(c2)N(c2ccc5c6ccccc6c6ccccc6c5c2)c2cc5c6ccccc6c6ccccc6c5cc2B4c2ccc(-n4c5ccccc5c5ccccc54)cc2N3c2ccc3c4ccccc4c4ccccc4c3c2)cc1 ; CC(C)(C)c1ccc2c(c1)c1cc(C(C)(C)C)ccc1n2-c1ccc2c(c1)N(c1ccc3c4ccccc4c4ccccc4c3c1)c1cc(N(c3ccccc3)c3ccccc3)cc3c1B2c1cc2c4ccccc4c4ccccc4c2cc1N3c1ccc2c3ccccc3c3ccccc3c2c1] 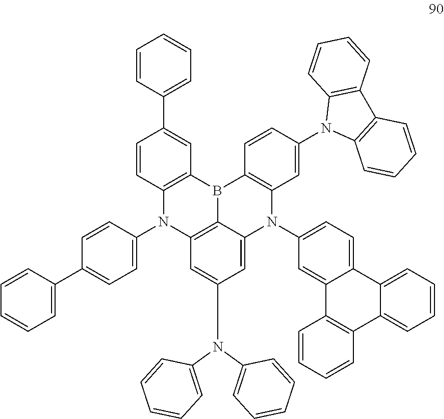 [SMILES: c1ccc(-c2ccc(N3c4ccc(-c5ccccc5)cc4B4c5ccc(-n6c7ccccc7c7ccccc76)cc5N(c5ccc6c7ccccc7c7ccccc7c6c5)c5cc(N(c6ccccc6)c6ccccc6)cc3c54)cc2)cc1] 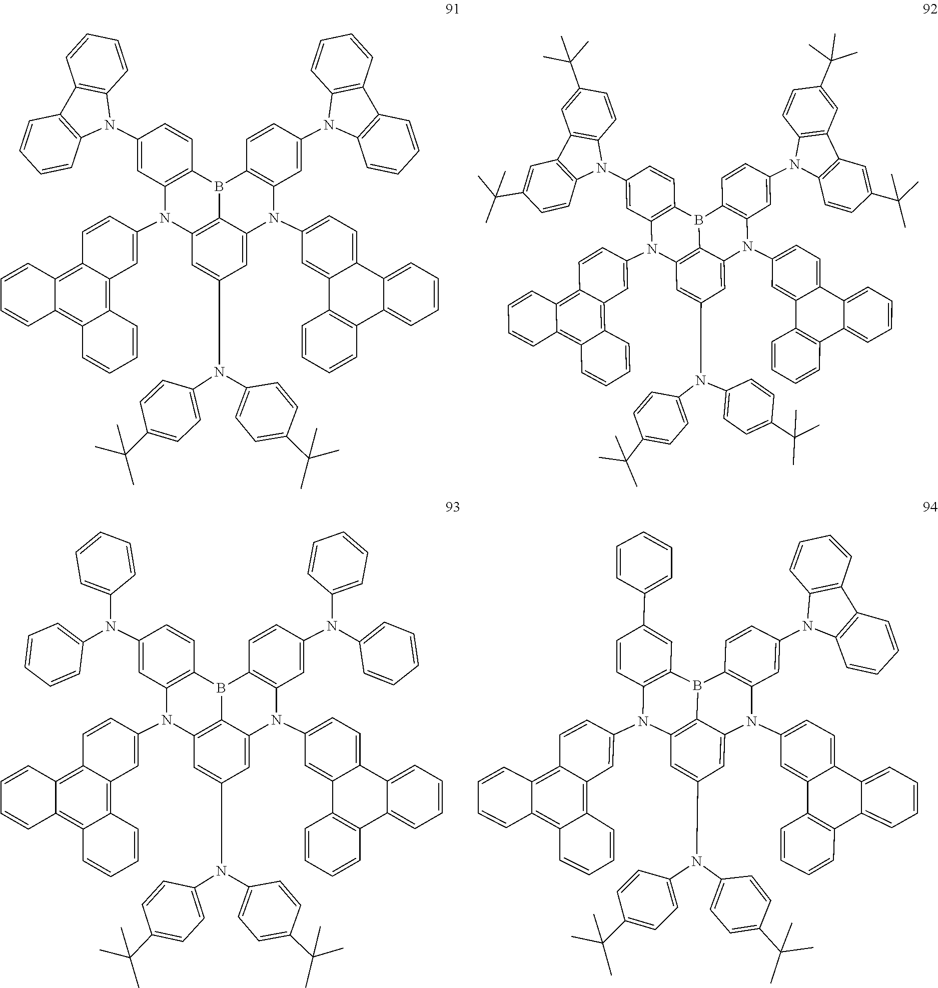 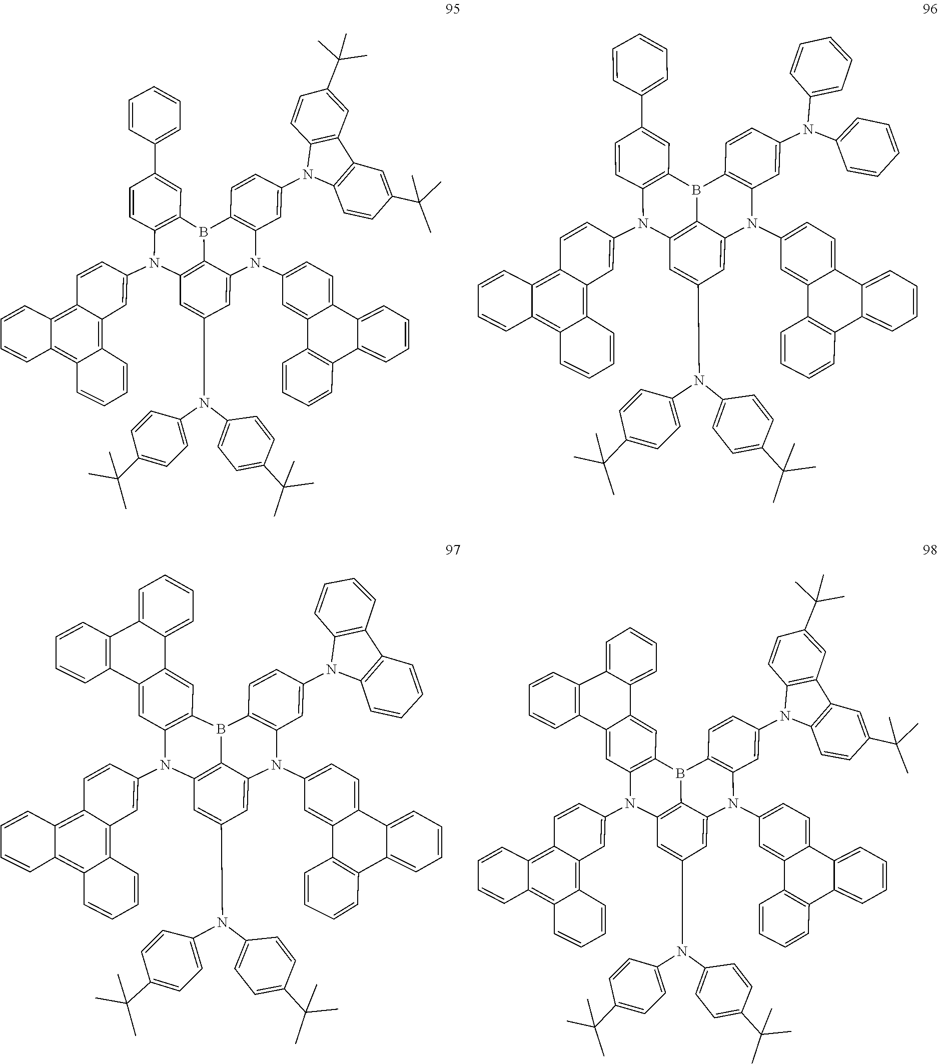 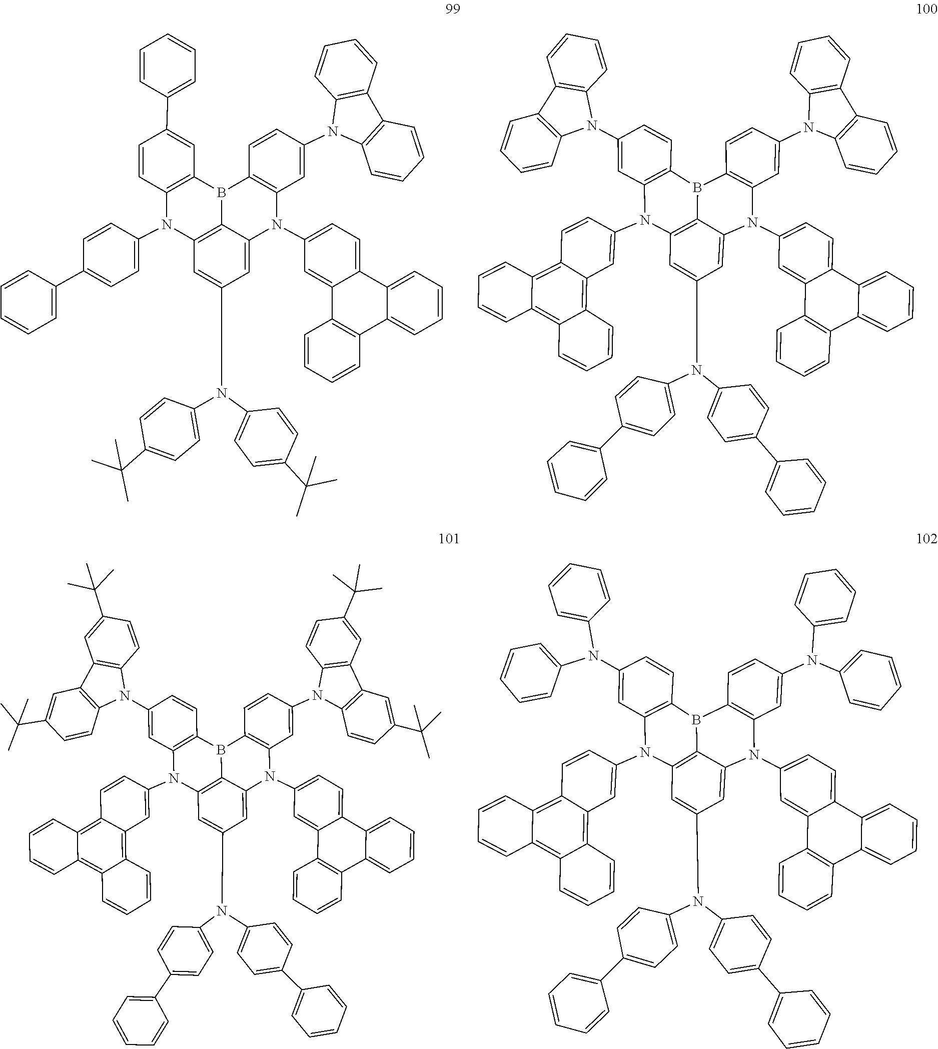 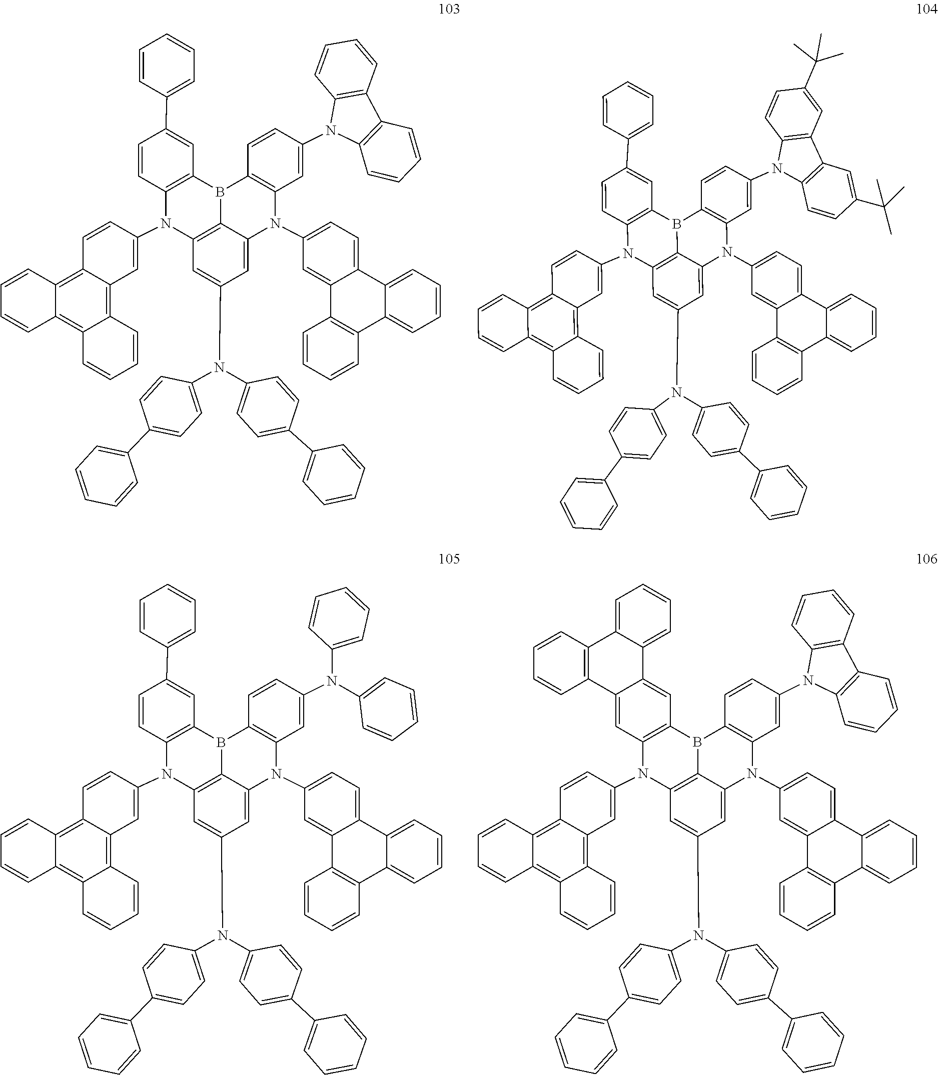 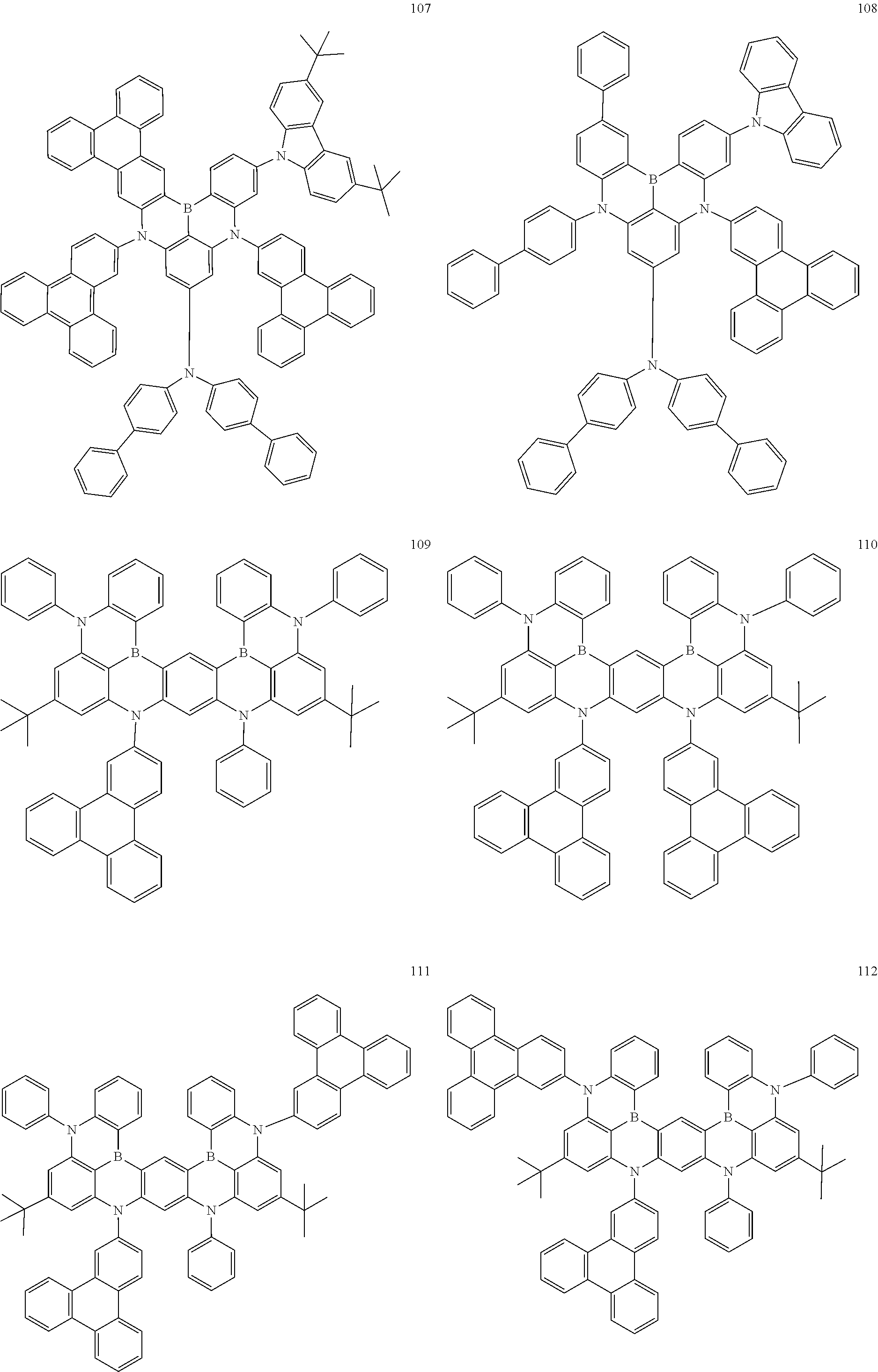 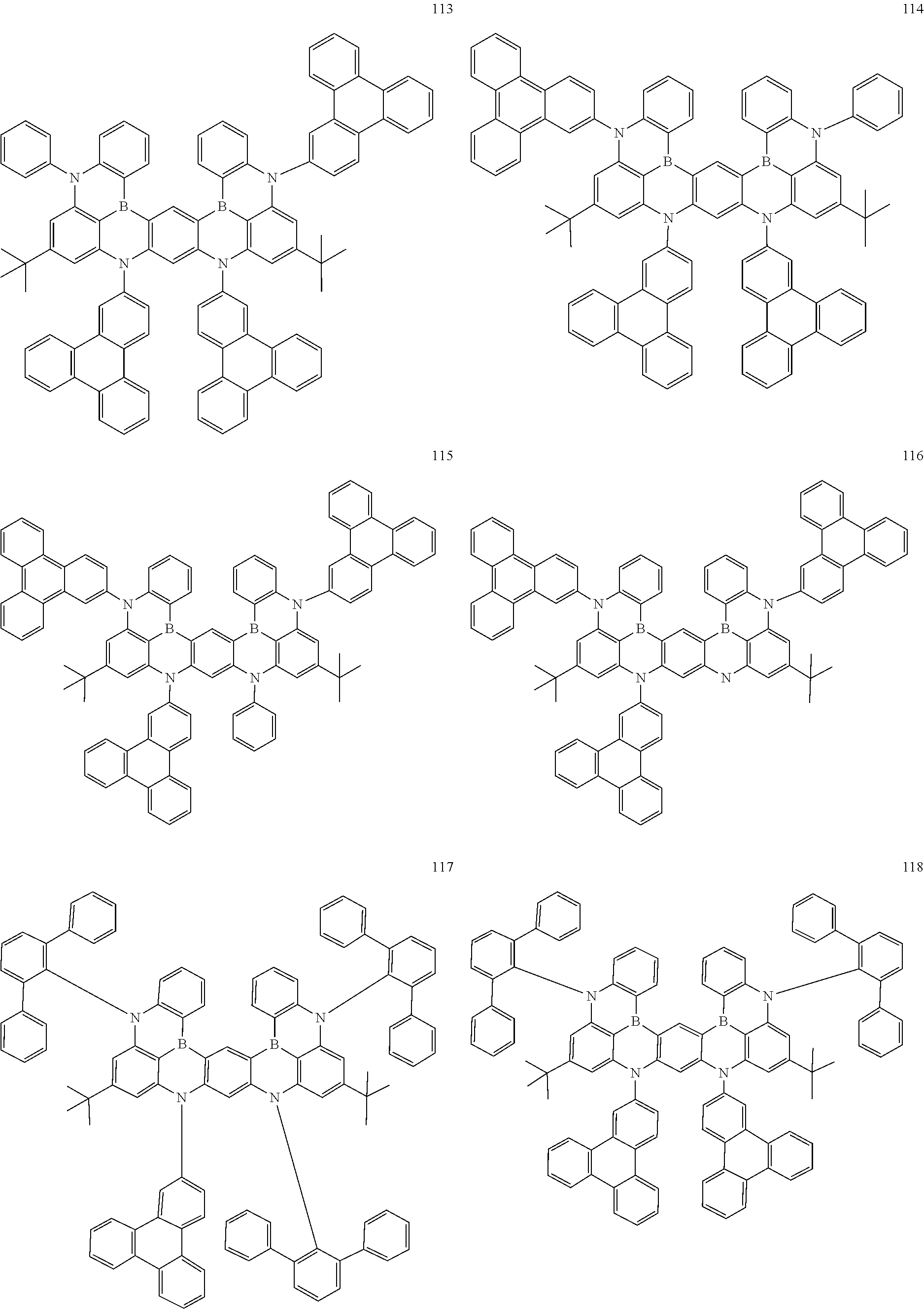 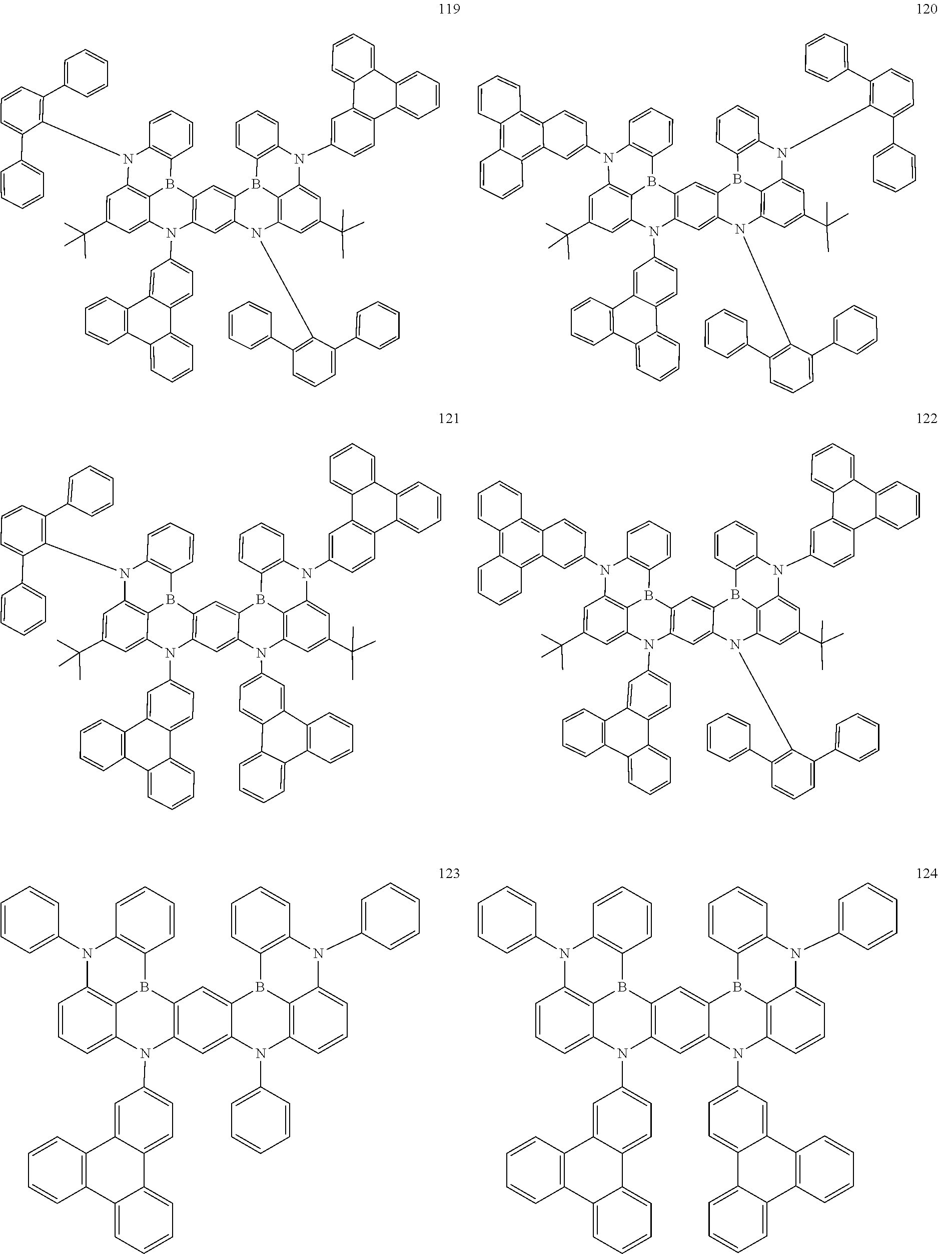 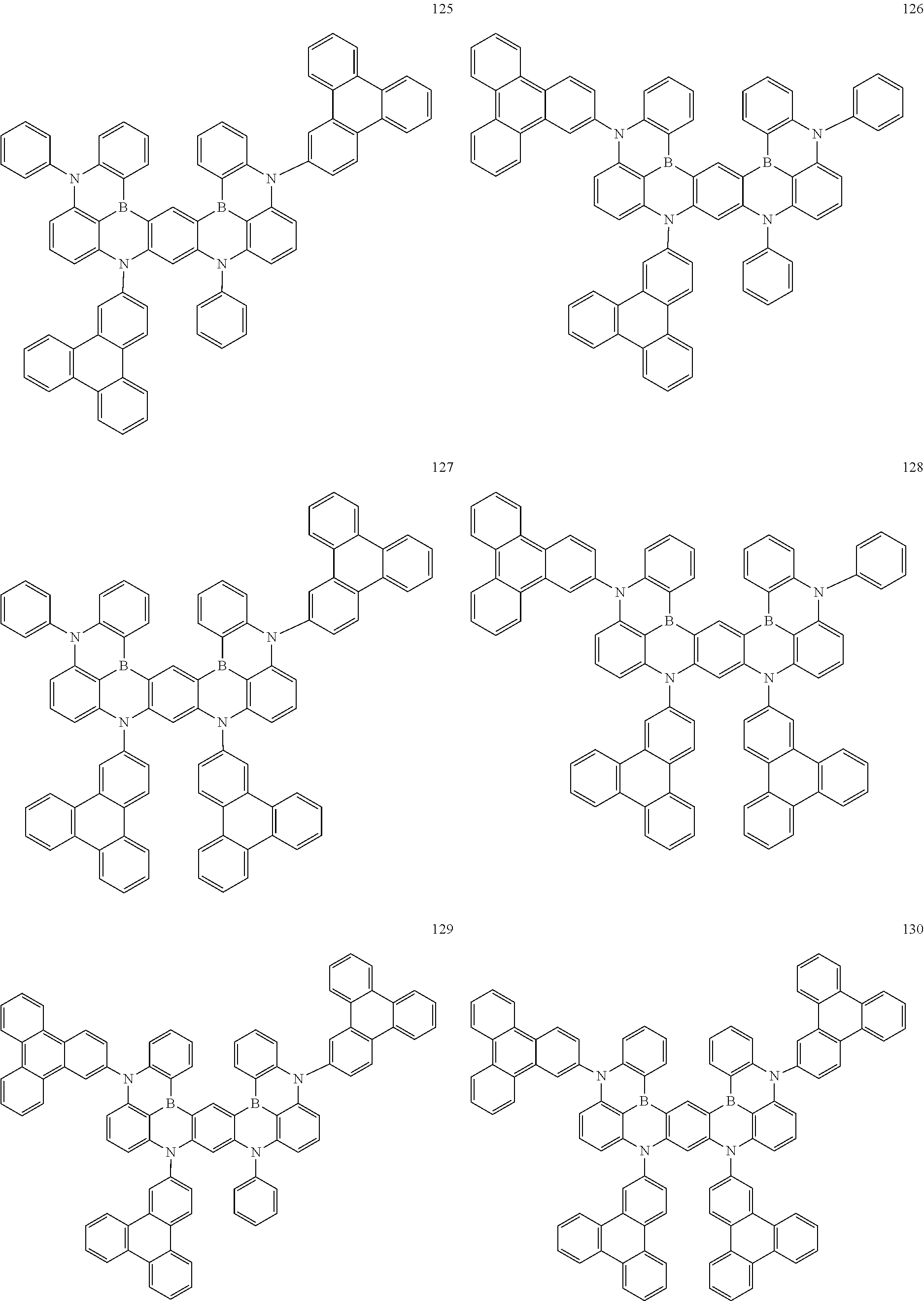 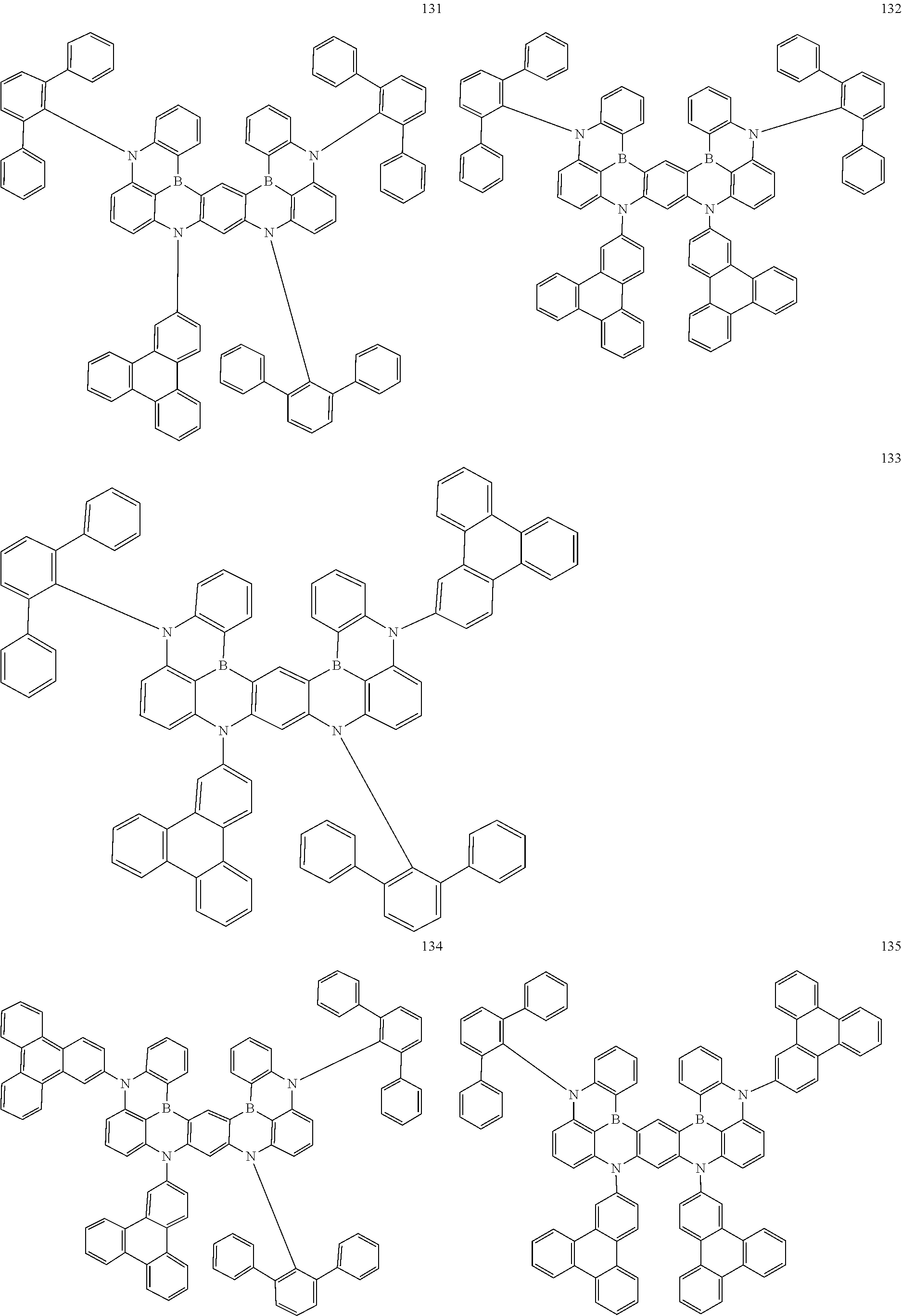 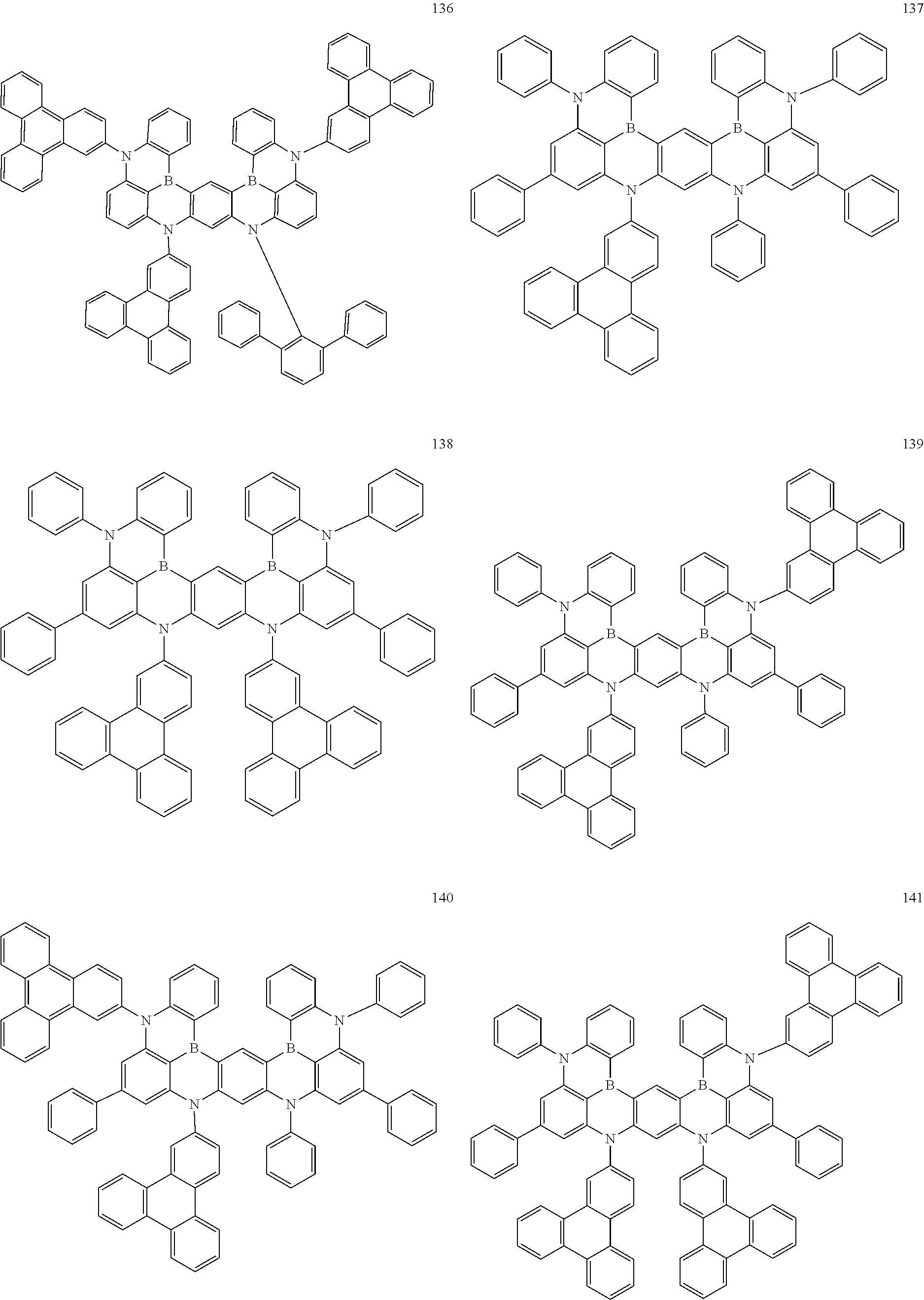 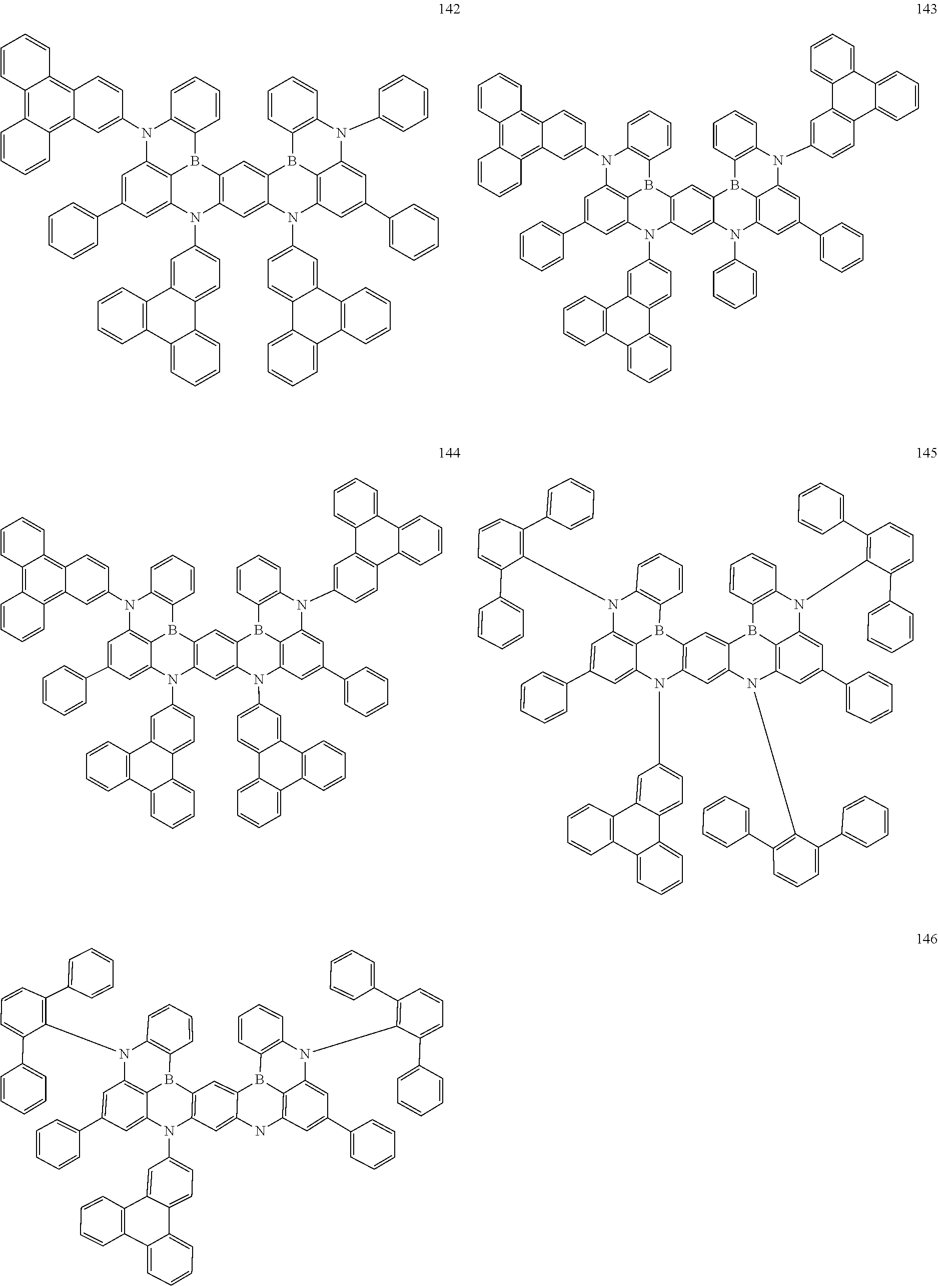 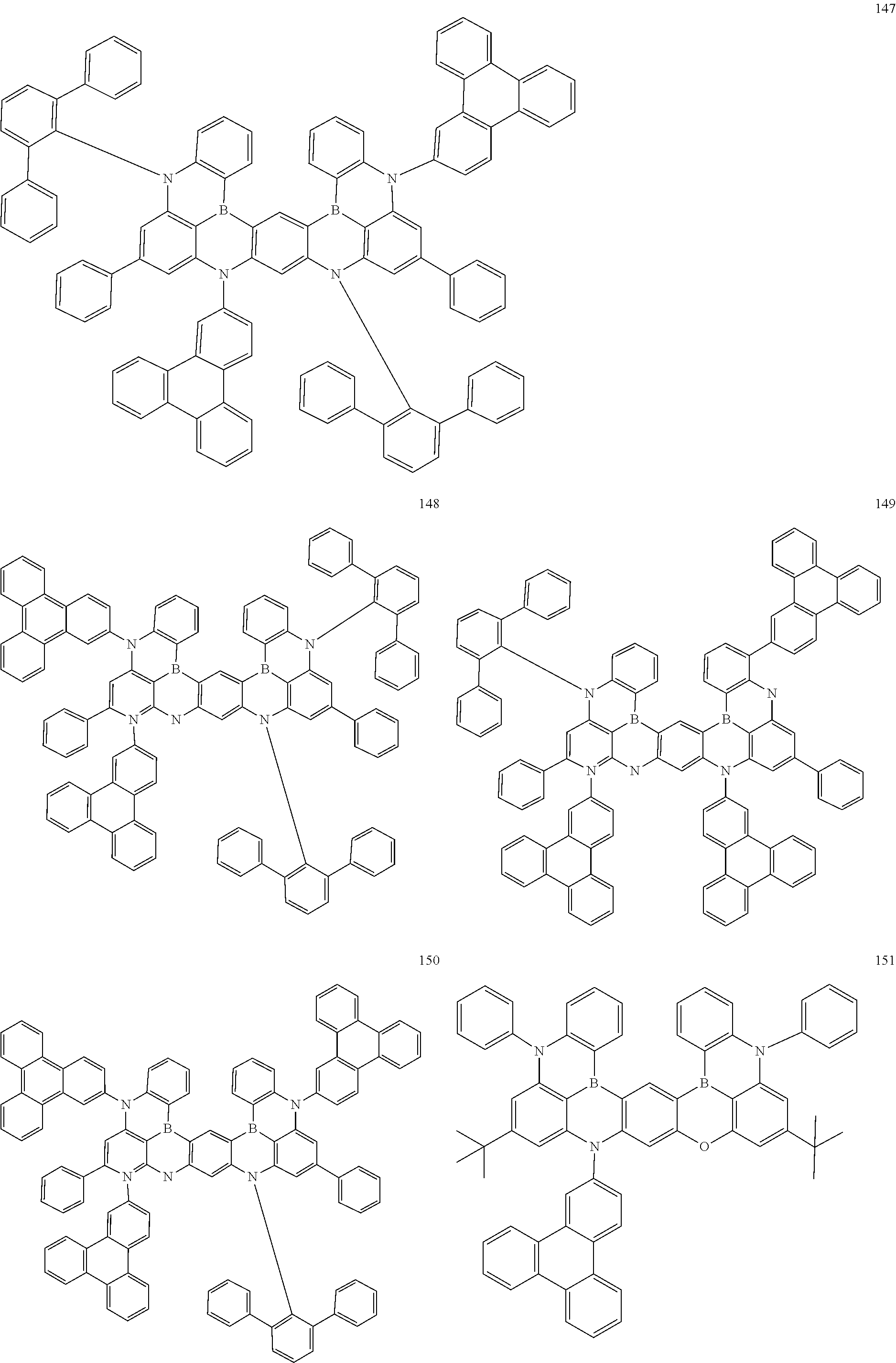 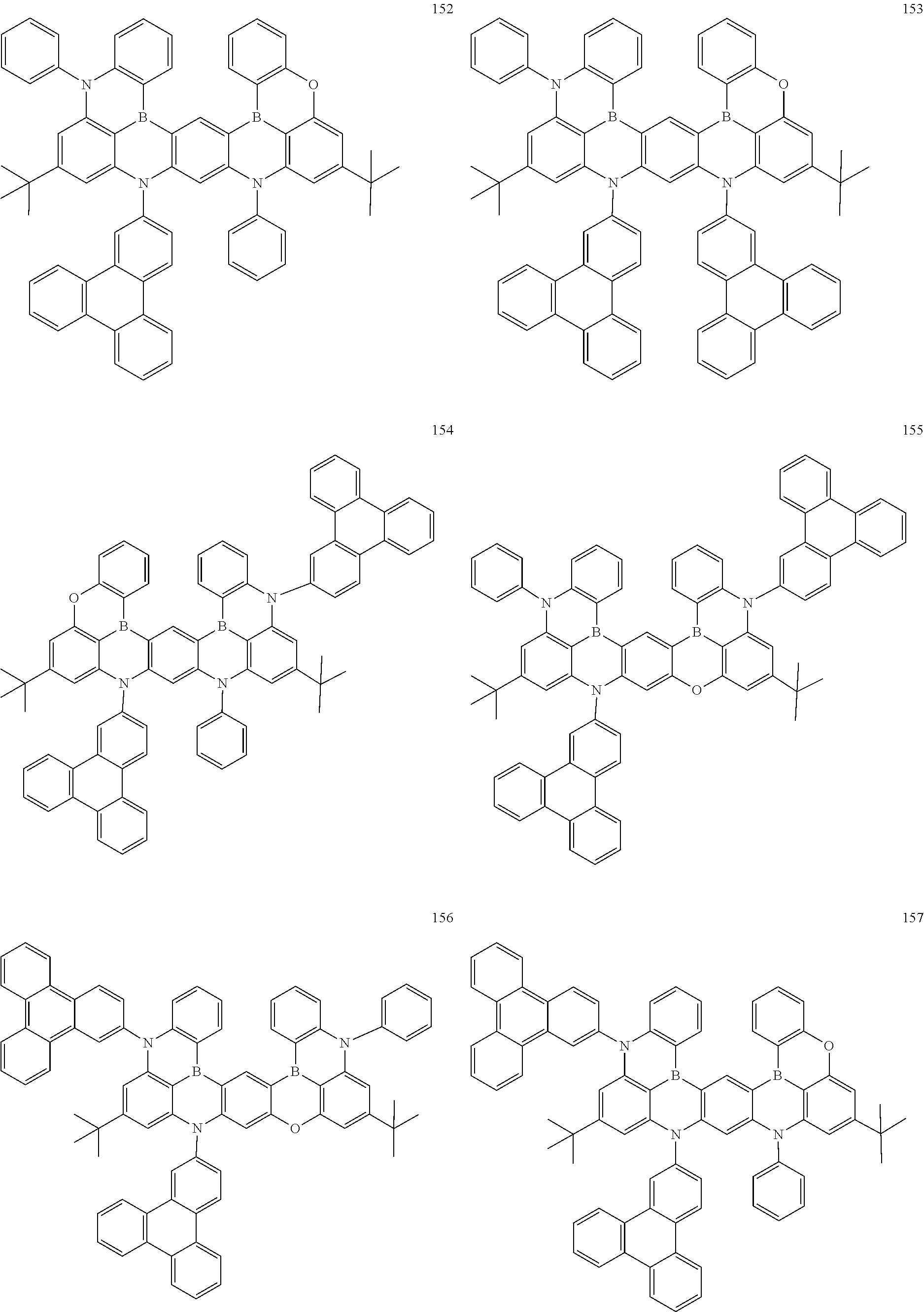 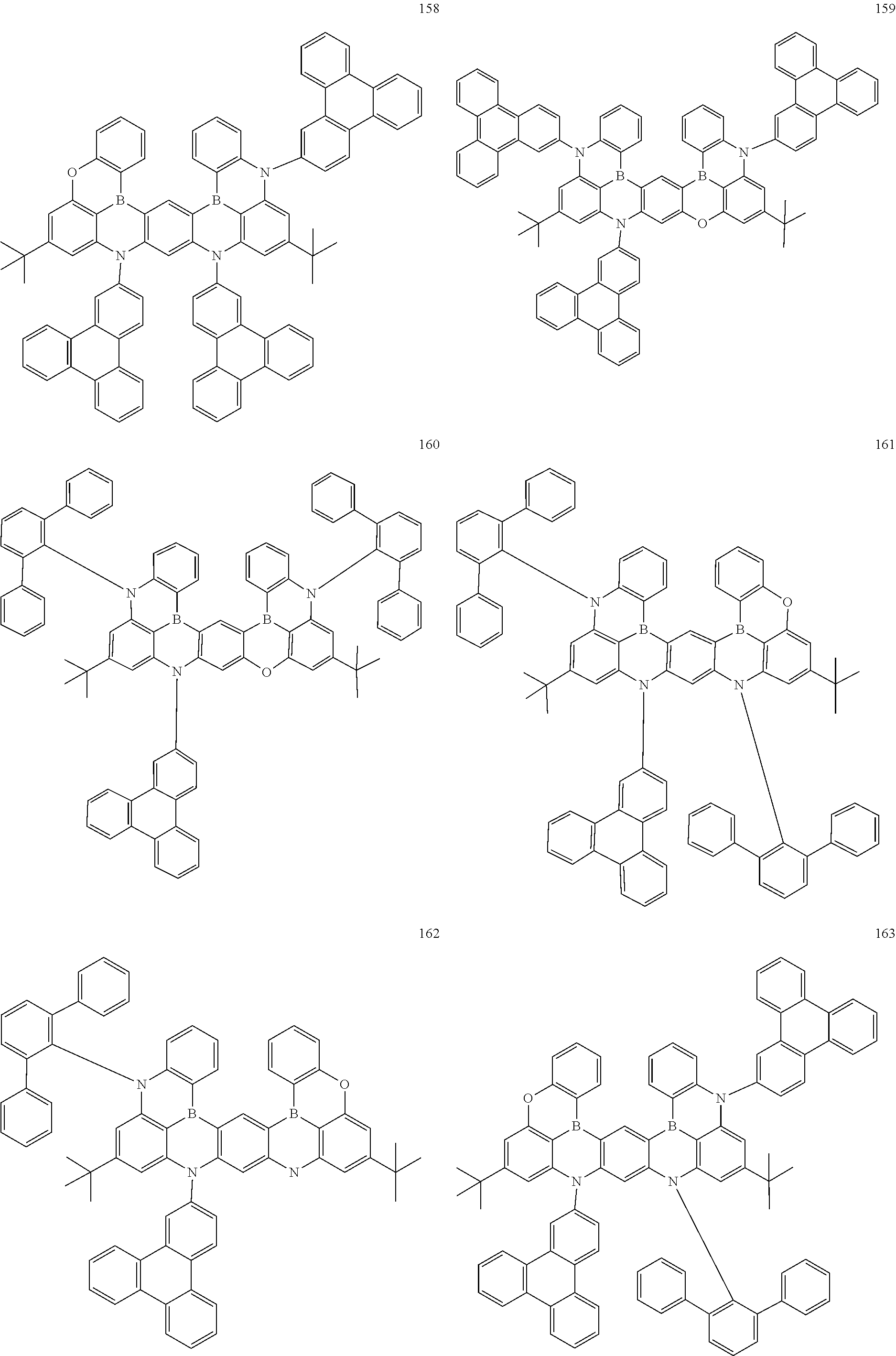 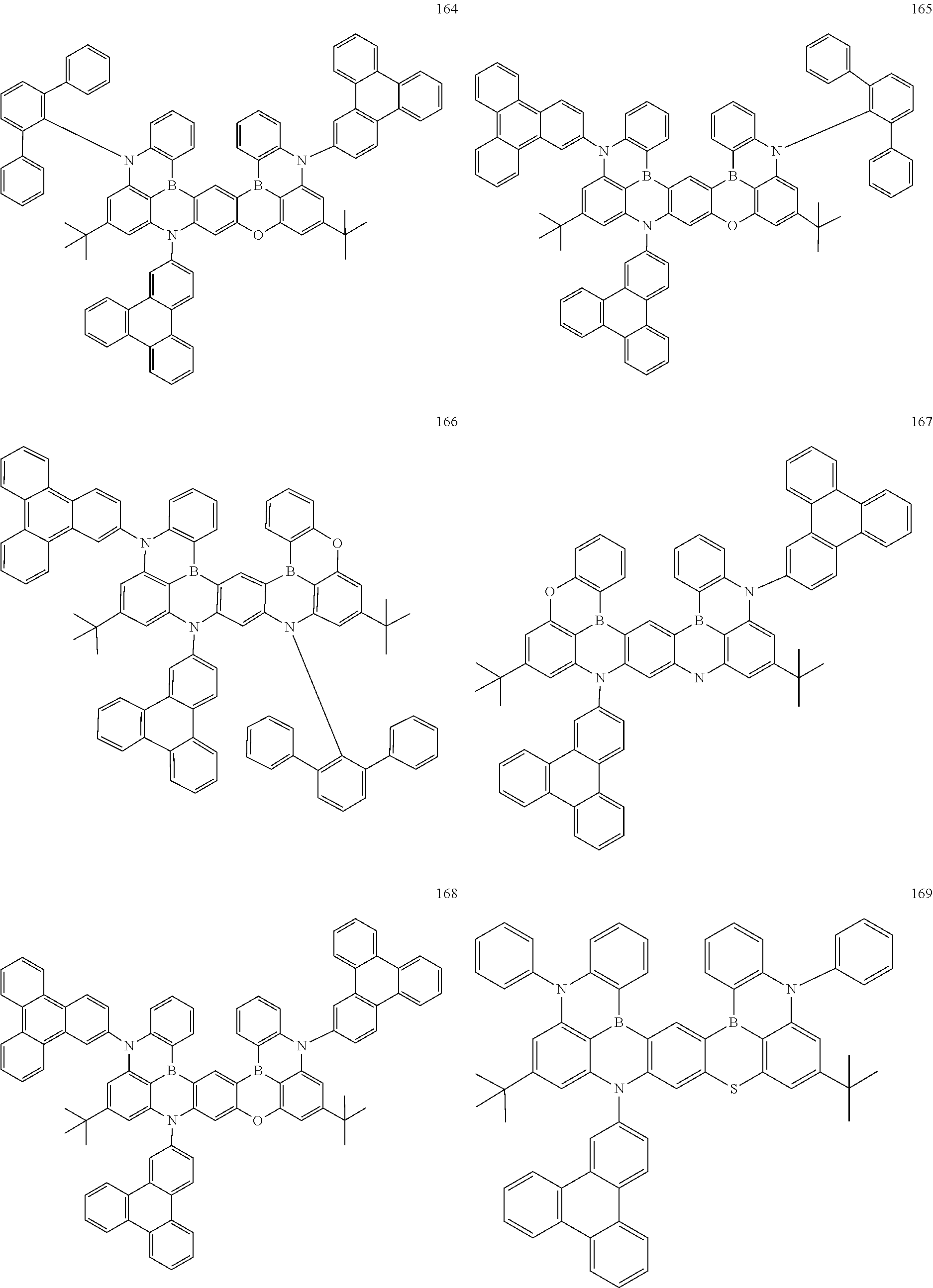 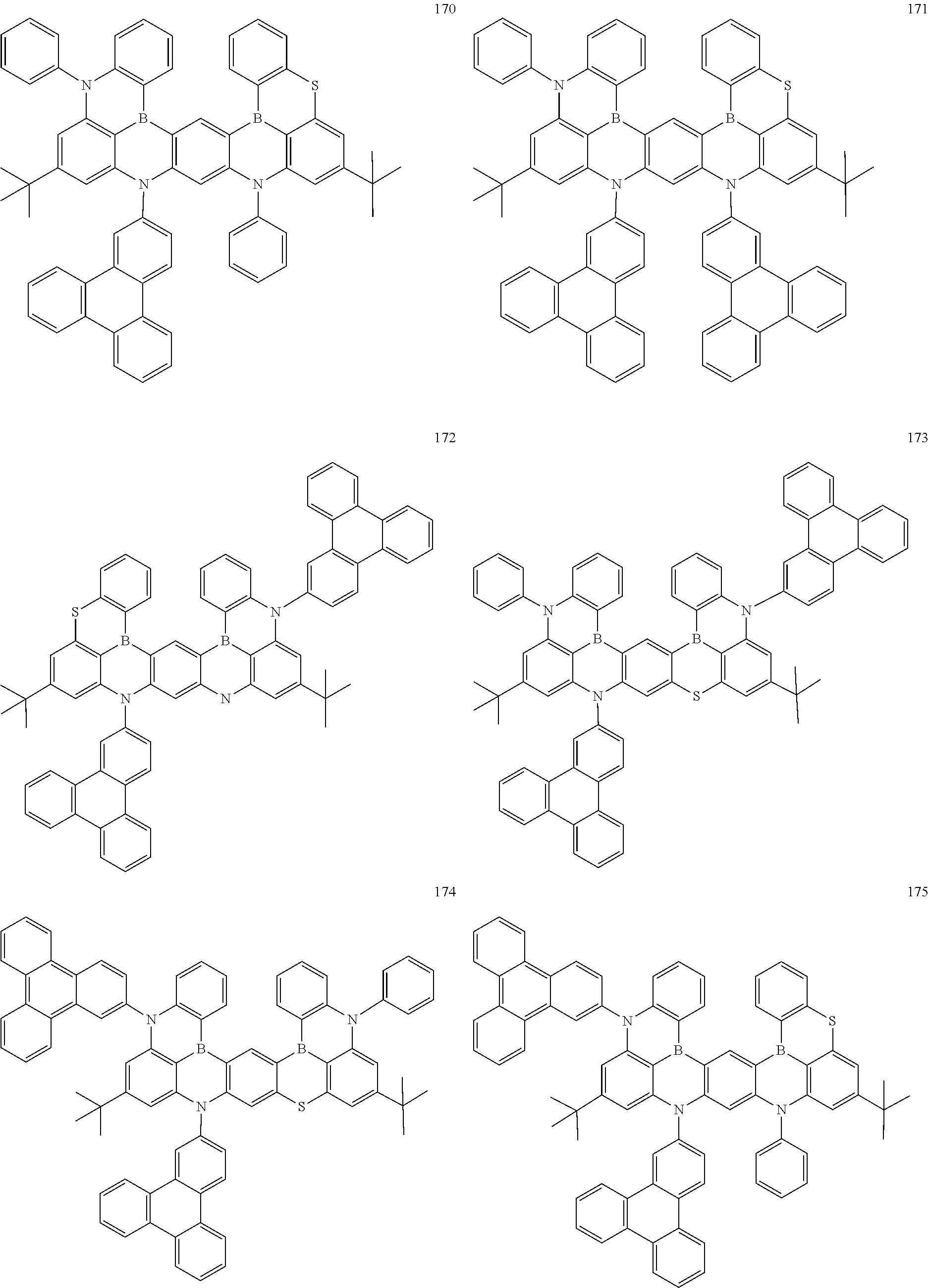 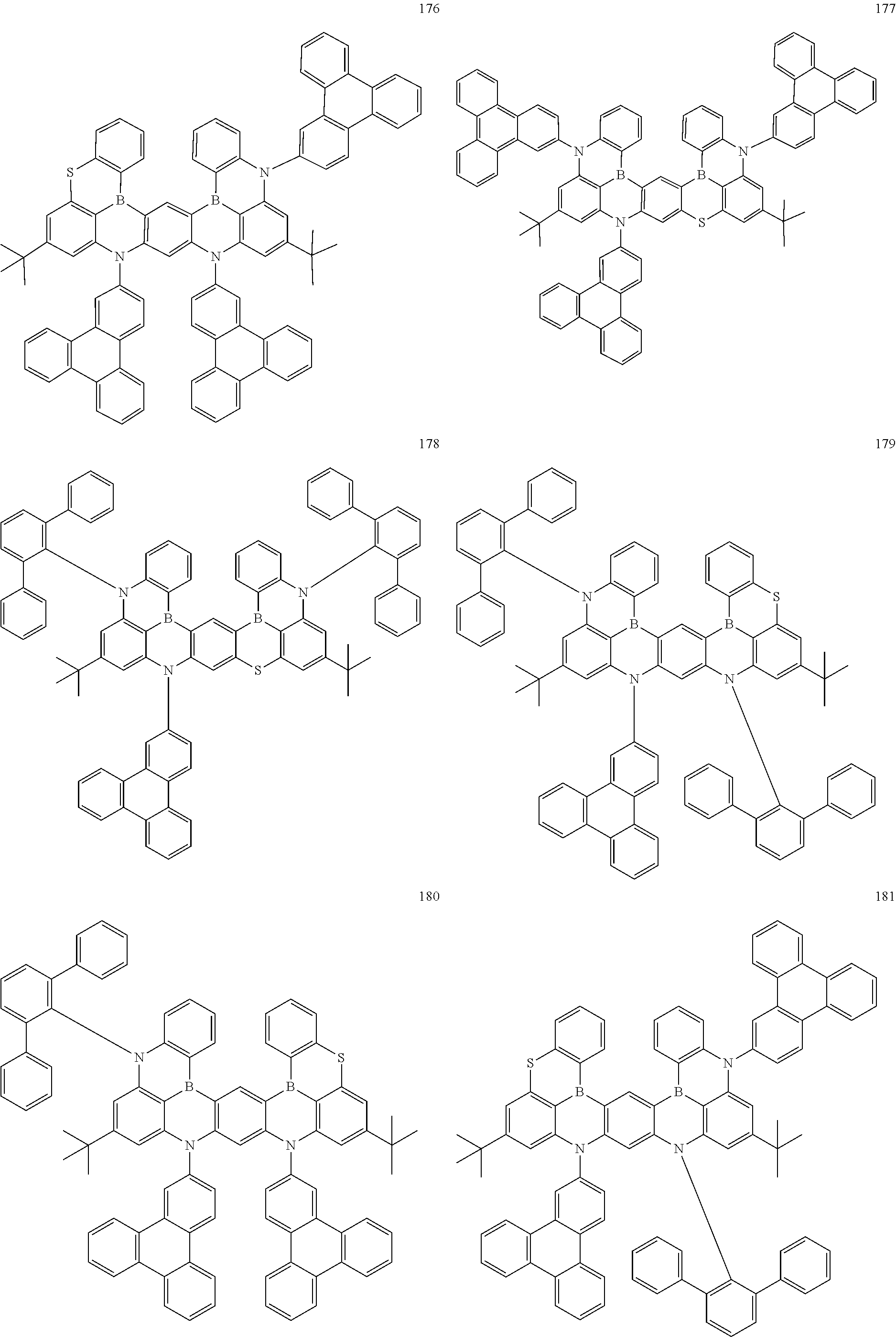 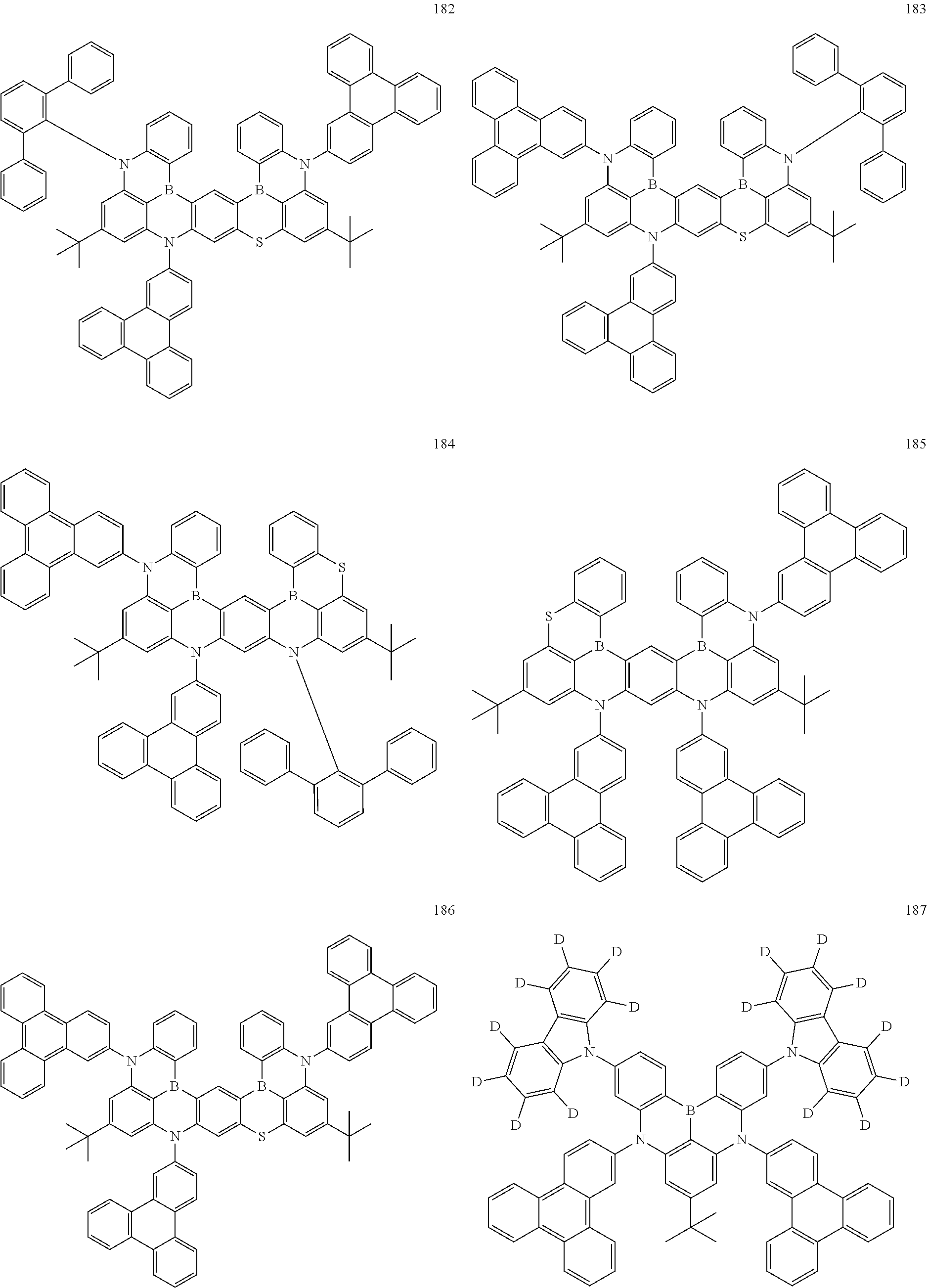 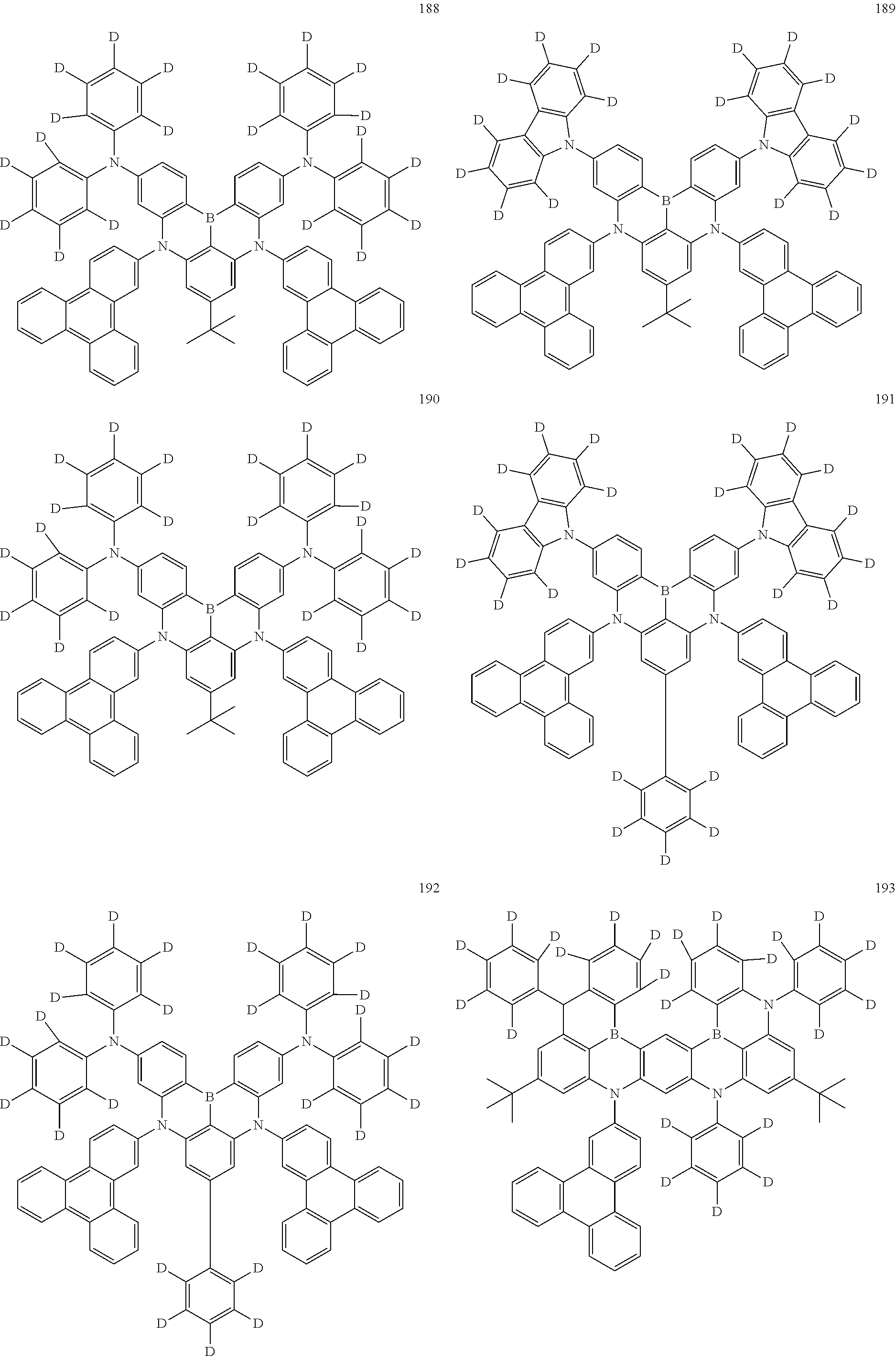
wherein in Compound Group 1,
D is a deuterium atom.
